(19) United States
(12) Patent Application Publication
(10) Pub. No.: US 2025/0351644 A1
(43) Pub. Date: Nov. 13, 2025

(54) DISPLAY APPARATUS

(71) Applicant: Semiconductor Energy Laboratory Co., Ltd., Atsugi-shi, Kanagawa-ken (JP)

(72) Inventors: Hajime KIMURA, Atsugi (JP); Kentaro HAYASHI, Atsugi (JP)

(21) Appl. No.: 18/881,322

(22) PCT Filed: Jul. 6, 2023
(86) PCT No.: PCT/IB2023/056977

§ 371 Date: Jan. 6, 2025

(30) Foreign Application Priority Data
Jul. 20, 2022 (JP) 2022-115226

(51) Int. Cl. H10H 29/49; H10D 86/40; H10D 86/60; H10H 29/01; H10H 29/32; H10K 59/12; H10K 59/121; H10K 59/131

(52) U.S. Cl. CPC H10H 29/49; H10H 29/012; H10H 29/32; H10K 59/1201; H10K 59/1213; H10K 59/131; H10D 86/423; H10D 86/441; H10D 86/60

(57) ABSTRACT

A display apparatus which is driven at high speed is provided. The display apparatus includes a pixel, a scan line driver circuit, and a power supply circuit. The pixel includes first and second transistors. In the second transistor, a semiconductor layer is provided in an opening formed in an interlayer insulating layer over a substrate. A first conductive layer functioning a gate electrode of the first transistor includes a region extending in the first direction and is electrically connected to the scan line driver circuit. A second conductive layer functioning as a source electrode or a drain electrode of the second transistor is provided below the opening. The second conductive layer includes a region extending in the second direction perpendicular to the first direction and is electrically connected to the power supply circuit. The first conductive layer and the second conductive layer include a region where they overlap with each other with the interlayer insulating layer therebetween.

### TECHNICAL FIELD

One embodiment of the present invention relates to a display apparatus, a semiconductor device, a display module, and an electronic device. One embodiment of the present invention relates to a method for manufacturing a display apparatus and a method for manufacturing a semiconductor device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Semiconductor devices including transistors have been widely used in display apparatuses and electronic devices, and the semiconductor devices have been required increasingly to achieve high integration and high-speed operation. In the case where semiconductor devices are used for high-definition display apparatuses, highly integrated semiconductor devices are required, for example. The development of transistors having minute sizes is ongoing as one way of increasing the degree of integration of transistors.

In recent years, there has been a need for display apparatuses applicable to virtual reality (VR), augmented reality (AR), substitutional reality (SR), or mixed reality (MR). VR, AR, SR, and MR are collectively referred to as XR (Extended Reality). Display apparatuses for XR have been desired to have higher definition and higher color reproducibility so that realistic feeling and the sense of immersion can be enhanced. Examples of apparatuses applicable to such display apparatuses include a liquid crystal display apparatus and a light-emitting apparatus including a light-emitting element such as organic EL (Electro Luminescence) element or a light-emitting diode (LED).

Patent Document 1 discloses a display apparatus using an organic EL element (also referred to as an organic EL device) for VR.

### REFERENCE

### Patent Document

[Patent Document 1] PCT International Publication No. 2018/087625

### SUMMARY OF THE INVENTION

### Problems to be Solved by the Invention

In the case of a high-definition display apparatus including a large number of pixels per unit area, for example, the display apparatus is preferably driven at high speed in order to ensure a frame frequency.

In view of the above, an object of one embodiment of the present invention is to provide a display apparatus which is driven at high speed and a manufacturing method thereof. Another object of one embodiment of the present invention is to provide a high-definition display apparatus and a manufacturing method thereof. Another object of one embodiment of the present invention is to provide a display apparatus including a transistor having a minute size and a manufacturing method thereof. Another object of one embodiment of the present invention is to provide a display apparatus including a transistor with high on-state current and a manufacturing method thereof. Another object of one embodiment of the present invention is to provide a display apparatus having favorable electrical characteristics and a manufacturing method thereof. Another object of one embodiment of the present invention is to provide a novel display apparatus, a novel semiconductor device, and a manufacturing method thereof.

Note that the description of these objects does not preclude the existence of other objects. One embodiment of the present invention does not need to achieve all these objects. Note that objects other than these can be derived from the descriptions of the specification, the drawings, the claims, and the like.

### Means for Solving the Problems

One embodiment of the present invention is a display apparatus including a pixel, a power supply circuit, and a scan line driver circuit. The pixel includes a first transistor, a second transistor, and a first insulating layer. The first transistor includes a first conductive layer, a second conductive layer, a third conductive layer, a first semiconductor layer, and a second insulating layer. The first insulating layer is provided over the first conductive layer. The first insulating layer includes a first opening reaching the first conductive layer. The first conductive layer is electrically connected to the power supply circuit. The second conductive layer is provided over the first insulating layer. The second conductive layer includes a second opening including a region overlapping with the first opening. The first semiconductor layer is provided to include a region in contact with the first conductive layer and a region in contact with the second conductive layer and include a region positioned in the first opening and a region positioned in the second opening. The second insulating layer is provided over the first semiconductor layer to include a region positioned in the first opening and a region positioned in the second opening. The third conductive layer is provided to include a region positioned in the first opening and a region positioned in the second opening and include a region facing the first semiconductor layer with the second insulating layer therebetween. The second transistor includes the second insulating layer, a second semiconductor layer below the second insulating layer, and a fourth conductive layer over the second insulating layer. The fourth conductive layer includes a region overlapping with the second semiconductor layer. The fourth conductive layer is electrically connected to the scan line driver circuit. The fourth conductive layer includes a region overlapping with the first conductive layer with the first insulating layer and the second insulating layer therebetween.

Alternatively, in the above embodiment, the second transistor may include a fifth conductive layer in contact with the second semiconductor layer. The fifth conductive layer may be electrically connected to the third conductive layer.

Alternatively, in the above embodiment, the display apparatus may include a signal line driver circuit. The second transistor may include a sixth conductive layer in contact with the second semiconductor layer. The sixth conductive layer may be electrically connected to the signal line driver circuit.

Alternatively, in the above embodiment, the pixel may include a display element. A pixel electrode of the display element may be electrically connected to the second conductive layer.

Alternatively, in the above embodiment, the display apparatus may include a reference potential generation circuit. The pixel may include a third transistor. The third transistor may include a seventh conductive layer, an eighth conductive layer, a ninth conductive layer, a third semiconductor layer, and the second insulating layer. The first insulating layer may be provided over the seventh conductive layer. The first insulating layer may include a third opening reaching the seventh conductive layer. The seventh conductive layer may be electrically connected to the pixel electrode. The eighth conductive layer may be provided over the first insulating layer. The eighth conductive layer may include a fourth opening including a region overlapping with the third opening. The eighth conductive layer may be electrically connected to the reference potential generation circuit. The third semiconductor layer may be provided to include a region in contact with the seventh conductive layer and a region in contact with the eighth conductive layer and include a region positioned in the third opening and a region positioned in the fourth opening. The second insulating layer may be provided over the third semiconductor layer to include a region positioned in the third opening and a region positioned in the fourth opening. The ninth conductive layer may be provided to include a region positioned in the third opening and a region positioned in the fourth opening and include a region facing the third semiconductor layer with the second insulating layer therebetween. The ninth conductive layer may be electrically connected to the scan line driver circuit. The eighth conductive layer may include a region overlapping with the fourth conductive layer and a region overlapping with the ninth conductive layer.

Alternatively, one embodiment of the present invention is a display apparatus including a pixel, a scan line driver circuit, and a power supply circuit. The pixel includes a first transistor, a second transistor, and a first insulating layer. The first transistor includes a first conductive layer, a second conductive layer, a third conductive layer, a first semiconductor layer, and a second insulating layer. The first insulating layer is provided over the first conductive layer. The first insulating layer includes a first opening reaching the first conductive layer. The second conductive layer is provided over the first insulating layer. The second conductive layer includes a second opening including a region overlapping with the first opening. The first semiconductor layer is provided to include a region in contact with the first conductive layer and a region in contact with the second conductive layer and include a region positioned in the first opening and a region positioned in the second opening. The second insulating layer is provided over the first semiconductor layer to include a region positioned in the first opening and a region positioned in the second opening. The third conductive layer is provided to include a region positioned in the first opening and a region positioned in the second opening and include a region facing the first semiconductor layer with the second insulating layer therebetween. The third conductive layer is electrically connected to the scan line driver circuit. The second transistor includes a fourth conductive layer, a fifth conductive layer, a sixth conductive layer, a second semiconductor layer, and the second insulating layer. The first insulating layer is provided over the fourth conductive layer. The first insulating layer includes a third opening reaching the fourth conductive layer. The fourth conductive layer is electrically connected to the power supply circuit. The fifth conductive layer is provided over the first insulating layer. The fifth conductive layer includes a fourth opening including a region overlapping with the third opening. The second semiconductor layer is provided to include a region in contact with the fourth conductive layer and a region in contact with the fifth conductive layer and include a region positioned in the third opening and a region positioned in the fourth opening. The second insulating layer is provided over the second semiconductor layer to include a region positioned in the third opening and a region positioned in the fourth opening. The sixth conductive layer is provided to include a region positioned in the third opening and a region positioned in the fourth opening and include a region facing the second semiconductor layer with the second insulating layer therebetween. The third conductive layer includes a region overlapping with the fourth conductive layer with the first insulating layer and the second insulating layer therebetween.

Alternatively, in the above embodiment, the display apparatus may include a signal line driver circuit. The first conductive layer may be electrically connected to the signal line driver circuit. The first conductive layer may include a region overlapping with the third conductive layer.

Alternatively, in the above embodiment, the second conductive layer may be electrically connected to the sixth conductive layer.

Alternatively, in the above embodiment, the pixel may include a display element. A pixel electrode of the display element may be electrically connected to the fifth conductive layer.

Alternatively, in the above embodiment, the display apparatus may include a reference potential generation circuit. The pixel may include a third transistor. The third transistor may include a seventh conductive layer, an eighth conductive layer, a ninth conductive layer, a third semiconductor layer, and the second insulating layer. The first insulating layer may be provided over the seventh conductive layer. The first insulating layer may include a fifth opening reaching the seventh conductive layer. The seventh conductive layer may be electrically connected to the pixel electrode. The eighth conductive layer may be provided over the first insulating layer. The eighth conductive layer may include a sixth opening including a region overlapping with the fifth opening. The eighth conductive layer may be electrically connected to the reference potential generation circuit. The third semiconductor layer may be provided to include a region in contact with the seventh conductive layer and a region in contact with the eighth conductive layer and include a region positioned in the fifth opening and a region positioned in the sixth opening. The second insulating layer may be provided over the third semiconductor layer to include a region positioned in the fifth opening and a region positioned in the sixth opening. The ninth conductive layer may be provided to include a region positioned in the fifth opening and a region positioned in the sixth opening and include a region facing the third semiconductor layer with the second insulating layer therebetween. The ninth conductive layer may be electrically connected to the scan line driver circuit. The eighth conductive layer may include a region overlapping with the third conductive layer and a region overlapping with the ninth conductive layer.

Alternatively, in the above embodiments, the first to third semiconductor layers may each include a metal oxide. The metal oxide can contain indium, zinc, and M (M is one or more kinds selected from aluminum, titanium, gallium, germanium, tin, yttrium, zirconium, lanthanum, cerium, neodymium, and hafnium), for example.

### Effect of the Invention

One embodiment of the present invention can provide a display apparatus which is driven at high speed and a manufacturing method thereof. Another embodiment of the present invention can provide a high-definition display apparatus and a manufacturing method thereof. Another embodiment of the present invention can provide a display apparatus including a transistor having a minute size and a manufacturing method thereof. Another embodiment of the present invention can provide a display apparatus including a transistor with high on-state current and a manufacturing method thereof. Another embodiment of the present invention can provide a display apparatus having favorable electrical characteristics and a manufacturing method thereof. Another embodiment of the present invention can provide a novel display apparatus, a novel semiconductor device, and a manufacturing method thereof.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a block diagram illustrating a structure example of a display apparatus. FIG. 1B is a plan view illustrating a structure example of a pixel. FIG. 1C and FIG. 1D are circuit diagrams illustrating structure examples of a pixel.

FIG. 2A is a block diagram illustrating a structure example of a display apparatus. FIG. 2B is a circuit diagram illustrating a structure example of a pixel.

FIG. 3A to FIG. 3C are circuit diagrams illustrating structure examples of a pixel.

FIG. 4A1 to FIG. 4A3 are plan views illustrating structure examples of a display apparatus. FIG. 4B is a cross-sectional view illustrating the structure example of the display apparatus.

FIG. 5A is a plan view illustrating a structure example of a display apparatus. FIG. 5B is a cross-sectional view illustrating the structure example of the display apparatus.

FIG. 6 is a plan view illustrating a structure example of a display apparatus.

FIG. 7 is a cross-sectional view illustrating a structure example of a display apparatus.

FIG. 8A is a plan view illustrating a structure example of a display apparatus. FIG. 8B is a cross-sectional view illustrating the structure example of the display apparatus.

FIG. 9 is a plan view illustrating a structure example of a display apparatus.

FIG. 10A is a plan view of a structure example of a display apparatus. FIG. 10B is a cross-sectional view illustrating the structure example of the display apparatus.

FIG. 11 is a plan view illustrating a structure example of a display apparatus.

FIG. 12A is a plan view illustrating a structure example of a display apparatus. FIG. 12B is a cross-sectional view illustrating the structure example of the display apparatus.

FIG. 13 is a plan view illustrating a structure example of a display apparatus.

FIG. 14A is a plan view illustrating a structure example of a display apparatus. FIG. 14B is a cross-sectional view illustrating the structure example of the display apparatus.

FIG. 15A is a plan view illustrating a structure example of a display apparatus. FIG. 15B is a cross-sectional view illustrating the structure example of the display apparatus.

FIG. 16 is a plan view illustrating a structure example of a display apparatus.

FIG. 17 is a plan view illustrating a structure example of a display apparatus.

FIG. 18 is a plan view illustrating a structure example of a display apparatus.

FIG. 19 is a plan view illustrating a structure example of a display apparatus.

FIG. 20A is a plan view illustrating a structure example of a display apparatus. FIG. 20B is a cross-sectional view illustrating the structure example of the display apparatus.

FIG. 21A is a plan view illustrating a structure example of a display apparatus. FIG. 21B is a cross-sectional view illustrating the structure example of the display apparatus.

FIG. 22A is a plan view illustrating a structure example of a display apparatus. FIG. 22B is a cross-sectional view illustrating the structure example of the display apparatus.

FIG. 23 is a plan view illustrating a structure example of a display apparatus.

FIG. 24A is a plan view illustrating a structure example of a display apparatus. FIG. 24B is a cross-sectional view illustrating the structure example of the display apparatus.

FIG. 25 is a plan view illustrating a structure example of a display apparatus.

FIG. 26A is a plan view illustrating a structure example of a display apparatus. FIG. 26B is a cross-sectional view illustrating the structure example of the display apparatus.

FIG. 27 is a plan view illustrating a structure example of a display apparatus.

FIG. 28A is a plan view illustrating a structure example of a display apparatus. FIG. 28B is a cross-sectional view illustrating the structure example of the display apparatus.

FIG. 29 is a plan view illustrating a structure example of a display apparatus.

FIG. 30A is a plan view illustrating a structure example of a display apparatus. FIG. 30B is a cross-sectional view illustrating the structure example of the display apparatus.

FIG. 31 is a plan view illustrating a structure example of a display apparatus.

FIG. 32A is a plan view illustrating a structure example of a display apparatus. FIG. 32B is a cross-sectional view illustrating the structure example of the display apparatus.

FIG. 33 is a plan view illustrating a structure example of a display apparatus.

FIG. 34A is a plan view illustrating a structure example of a display apparatus. FIG. 34B is a cross-sectional view illustrating the structure example of the display apparatus.

FIG. 35 is a plan view illustrating a structure example of a display apparatus.

FIG. 36A is a plan view illustrating a structure example of a display apparatus. FIG. 36B is a cross-sectional view illustrating the structure example of the display apparatus.

FIG. 37 is a plan view illustrating a structure example of a display apparatus.

FIG. 38A is a plan view illustrating a structure example of a display apparatus. FIG. 38B is a cross-sectional view illustrating the structure example of the display apparatus.

FIG. 39A is a block diagram illustrating a structure example of a memory device. FIG. 39B to FIG. 39F are circuit diagrams each illustrating a structure example of a memory cell.

FIG. 40A to FIG. 40C are plan views illustrating structure examples of a display apparatus.

FIG. 41A is a plan view illustrating a structure example of a display apparatus. FIG. 41B is a cross-sectional view illustrating the structure example of the display apparatus.

FIG. 42A is a plan view illustrating a structure example of a display apparatus. FIG. 42B is a cross-sectional view illustrating the structure example of the display apparatus.

FIG. 43A is a plan view illustrating a structure example of a display apparatus. FIG. 43B1 to FIG. 43B3 are cross-sectional views illustrating structure examples of a display apparatus.

FIG. 44A and FIG. 44B are plan views illustrating structure examples of a display apparatus.

FIG. 45A1 and FIG. 45A2 are plan views illustrating structure examples of a display apparatus. FIG. 45B is a cross-sectional view illustrating the structure example of the display apparatus.

FIG. 46A is a plan view illustrating a structure example of a display apparatus. FIG. 46B is a cross-sectional view illustrating the structure example of the display apparatus.

FIG. 47A is a plan view illustrating a structure example of a display apparatus. FIG. 47B is a cross-sectional view illustrating the structure example of the display apparatus.

FIG. 48A is a plan view illustrating a structure example of a display apparatus. FIG. 48B is a cross-sectional view illustrating the structure example of the display apparatus.

FIG. 49A1 and FIG. 49A2 are plan views illustrating structure examples of a display apparatus. FIG. 49B is a cross-sectional view illustrating the structure example of the display apparatus.

FIG. 50A is a plan view illustrating a structure example of a display apparatus. FIG. 50B is a cross-sectional view illustrating the structure example of the display apparatus.

FIG. 51A is a plan view illustrating a structure example of a display apparatus. FIG. 51B is a cross-sectional view illustrating the structure example of the display apparatus.

FIG. 52A and FIG. 52B are plan views illustrating a structure example of a display apparatus.

FIG. 53A1 and FIG. 53A2 are plan views illustrating structure examples of a display apparatus. FIG. 53B is a cross-sectional view illustrating the structure example of the display apparatus.

FIG. 54A is a plan view illustrating a structure example of a display apparatus. FIG. 54B1 and FIG. 54B2 are cross-sectional views illustrating structure examples of the display apparatus.

FIG. 55A and FIG. 55B are cross-sectional views illustrating structure examples of a display apparatus.

FIG. 56A and FIG. 56B are cross-sectional views illustrating structure examples of a display apparatus.

FIG. 57A and FIG. 57B are cross-sectional views illustrating structure examples of a display apparatus.

FIG. 58A is a plan view illustrating a structure example of a display apparatus. FIG. 58B is a cross-sectional view illustrating the structure example of the display apparatus.

FIG. 59A and FIG. 59B are plan views illustrating structure examples of a display apparatus.

FIG. 60A is a plan view illustrating a structure example of a display apparatus. FIG. 60B is a cross-sectional view illustrating the structure example of the display apparatus.

FIG. 61A to FIG. 61C are plan views illustrating structure examples of a display apparatus.

FIG. 62A to FIG. 62C are plan views illustrating structure examples of a display apparatus.

FIG. 63A and FIG. 63B are plan views illustrating structure examples of a display apparatus.

FIG. 64A is a plan view illustrating a structure example of a display apparatus. FIG. 64B is a cross-sectional view illustrating the structure example of the display apparatus.

FIG. 65A is a plan view illustrating a structure example of a display apparatus. FIG. 65B is a cross-sectional view illustrating the structure example of the display apparatus.

FIG. 66 is a plan view illustrating a structure example of a display apparatus.

FIG. 67A to FIG. 67C are plan views illustrating structure examples of a display apparatus.

FIG. 68A and FIG. 68B are plan views illustrating structure examples of a semiconductor device.

FIG. 69A is a plan view illustrating a structure example of a display apparatus. FIG. 69B is a cross-sectional view illustrating the structure example of the display apparatus.

FIG. 70A1 and FIG. 70A2 are plan views illustrating structure examples of a display apparatus.

FIG. 70B is a cross-sectional view illustrating the structure example of the display apparatus.

FIG. 71A is a plan view illustrating a structure example of a display apparatus. FIG. 71B is a cross-sectional view illustrating the structure example of the display apparatus.

FIG. 72A is a plan view illustrating a structure example of a display apparatus. FIG. 72B is a cross-sectional view illustrating the structure example of the display apparatus.

FIG. 73A is a plan view illustrating a structure example of a display apparatus. FIG. 73B is a cross-sectional view illustrating the structure example of the display apparatus.

FIG. 74A to FIG. 74C are plan views illustrating structure examples of a display apparatus.

FIG. 75A to FIG. 75C are plan views illustrating structure examples of a display apparatus.

FIG. 76A and FIG. 76B are plan views illustrating structure examples of a semiconductor device.

FIG. 77A is a plan view illustrating a structure example of a display apparatus. FIG. 77B is a cross-sectional view illustrating the structure example of the display apparatus.

FIG. 78A1 and FIG. 78B1 are plan views illustrating an example of a method for manufacturing a display apparatus. FIG. 78A2 and FIG. 78B2 are cross-sectional views illustrating an example of a method for manufacturing a display apparatus.

FIG. 79A1 and FIG. 79B1 are plan views illustrating an example of a method for manufacturing a display apparatus. FIG. 79A2 and FIG. 79B2 are cross-sectional views illustrating an example of a method for manufacturing a display apparatus.

FIG. 80A1 and FIG. 80B1 are plan views illustrating an example of a method for manufacturing a display apparatus. FIG. 80A2 and FIG. 80B2 are cross-sectional views illustrating an example of a method for manufacturing a display apparatus.

FIG. 81A1 and FIG. 81B1 are plan views illustrating an example of a method for manufacturing a display apparatus. FIG. 81A2 and FIG. 81B2 are cross-sectional views illustrating an example of a method for manufacturing a display apparatus. FIG. 82A1 and FIG. 82B1 are plan views illustrating an example of a method for manufacturing a display apparatus. FIG. 82A2 and FIG. 82B2 are cross-sectional views illustrating an example of a method for manufacturing a display apparatus.

FIG. 83A to FIG. 83G are plan views illustrating structure examples of pixels.

FIG. 84A to FIG. 84K are plan views illustrating structure examples of a pixel.

FIG. 85 is a perspective view illustrating a structure example of a display apparatus.

FIG. 86 is a cross-sectional view illustrating a structure example of a display apparatus.

FIG. 87 is a cross-sectional view illustrating a structure example of a display apparatus.

FIG. 88 is a cross-sectional view illustrating a structure example of a display apparatus.

FIG. 89 is a cross-sectional view illustrating a structure example of a display apparatus.

FIG. 90 is a cross-sectional view illustrating a structure example of a display apparatus.

FIG. 91 is a cross-sectional view illustrating a structure example of a display apparatus.

FIG. 92A to FIG. 92D are diagrams illustrating examples of electronic devices.

FIG. 93A to FIG. 93F are diagrams illustrating examples of electronic devices.

FIG. 94A to FIG. 94G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same reference numerals are used in common for the same portions or portions having similar functions in different drawings, and repeated description thereof is omitted. The same hatching pattern is applied to portions having similar functions, and the portions are not especially denoted by reference numerals in some cases. Furthermore, a plurality of layers that can be formed in the same step are shown with the same hatching pattern in some cases.

The position, size, range, or the like of each component illustrated in drawings does not represent the actual position, size, range, or the like in some cases for easy understanding. Therefore, the disclosed invention is not necessarily limited to the position, size, range, and the like disclosed in drawings.

Note that the terms “film” and “layer” can be used interchangeably depending on the case or the circumstances. For example, the term “conductive layer” can be changed into the term “conductive film” in some cases. For another example, the term “insulating film” can be changed into the term “insulating layer” in some cases.

In this specification and the like, the terms such as “electrode” and “wiring” do not limit the functions of the components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, a structure in which at least light-emitting layers of light-emitting elements with different emission wavelengths are separately formed may be referred to as an SBS (Side By Side) structure. The SBS structure can optimize materials and structures of light-emitting elements and thus can extend freedom of choice of materials and structures, whereby the luminance and the reliability can be easily improved.

In this specification and the like, a light-emitting element (also referred to as a light-emitting device) includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). Note that the carrier-injection layer, the carrier-transport layer, and the carrier-blocking layer cannot be clearly distinguished from each other in some cases depending on the cross-sectional shape, the characteristics, or the like. One layer may have two or three functions of the carrier-injection layer, the carrier-transport layer, and the carrier-blocking layer in some cases.

In this specification and the like, a light-receiving element (also referred to as a light-receiving device) includes at least an active layer functioning as a photoelectric conversion layer between a pair of electrodes.

In this specification and the like, a tapered shape refers to such a shape that at least part of a side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

In this specification and the like, when a side surface of a layer has a tapered shape, an outermost portion of the side surface of the layer is referred to as an end portion of the layer unless otherwise specified. For example, in the case where an end portion of a bottom surface of a layer is positioned outward from an end portion of a top surface, the end portion of the bottom surface is simply referred to as an end portion unless otherwise specified.

In this specification and the like, terms for describing arrangement, such as “over”, “below”, “left”, and “right”, are used for convenience in describing a positional relation between components with reference to drawings. The positional relation between components is changed as appropriate in accordance with the direction in which the components are described. Thus, without limitation to terms described in the specification, the description can be changed appropriately depending on the situation.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor. Note that a metal oxide containing nitrogen is also referred to as a metal oxide in some cases. Furthermore, a metal oxide containing nitrogen may be referred to as a metal oxynitride.

### Embodiment 1

In this embodiment, a display apparatus of one embodiment of the present invention, a manufacturing method thereof, and the like will be described with reference to drawings.

One embodiment of the present invention relates to a display apparatus in which a display portion, a scan line driver circuit, a signal line driver circuit, and a power supply circuit are included and pixels are arranged in a matrix in the display portion. In the pixel, a first transistor and a second transistor are provided in addition to a display element (also referred to as a display device). The first transistor can be a transistor including a first semiconductor layer provided in an opening formed in an interlayer insulating layer over a substrate. The second transistor can be a transistor including a second semiconductor layer provided in an opening formed in the interlayer insulating layer over the substrate, which is different from the above opening. With this structure, the channel length direction of the transistor can be a direction that is along a side surface of the interlayer insulating layer in the opening. Thus, the channel length is not influenced by the performance of a light-exposure apparatus used for manufacturing the transistor and can be shorter than the resolution limit of the light-exposure apparatus.

Here, a first conductive layer provided below the opening is used as one of a source electrode and a drain electrode of the first transistor. Specifically, the interlayer insulating layer is provided over the first conductive layer, and the opening is provided in the interlayer insulating layer so as to reach the first conductive layer. Then, the first semiconductor layer is provided so as to include a region in contact with the first conductive layer in the opening. As the other of the source electrode and the drain electrode of the first transistor, a second conductive layer, which surrounds the periphery of the opening in a plan view, is used. A gate insulating layer is provided over the first semiconductor layer and the second conductive layer, and a third conductive layer functioning as a gate electrode of the first transistor is provided over the gate insulating layer.

In this specification and the like, a plan view can be rephrased as a top view in some cases. A plan view can be rephrased as a top view in some cases.

The second transistor can have a structure similar to that of the first transistor. A fourth conductive layer provided below an opening is used as one of a source electrode and a drain electrode of the second transistor. As the other of the source electrode and the drain electrode of the second transistor, a fifth conductive layer, which surrounds the periphery of the opening in a plan view, is used. The gate insulating layer is provided over the second semiconductor layer and the fifth conductive layer, and a sixth conductive layer functioning as a gate electrode of the second transistor is provided over the gate insulating layer.

The first conductive layer or the second conductive layer is electrically connected to the signal line driver circuit. The third conductive layer includes a region extending in the row direction and is electrically connected to the scan line driver circuit. The fourth conductive layer includes a region extending in the column direction and is electrically connected to the power supply circuit. Since the third conductive layer includes a region extending in the row direction and the fourth conductive layer includes a region extending in the column direction, the third conductive layer and the fourth conductive layer overlap with each other in a region.

In the region where the third conductive layer and the fourth conductive layer overlap with each other, the interlayer insulating layer is provided over the fourth conductive layer, the gate insulating layer is provided over the interlayer insulating layer, and the third conductive layer is provided over the gate insulating layer in the display apparatus of one embodiment of the present invention. In this case, parasitic capacitance formed by the third conductive layer and the fourth conductive layer is smaller than that in the case where the insulating layer provided between the third conductive layer and the fourth conductive layer is only the gate insulating layer, for example. Accordingly, the time from when the scan line driver circuit outputs a signal to the third conductive layer to when the signal is supplied to the pixel can be shortened. Thus, the display apparatus can be driven at high speed.

### Structure Example of Display Apparatus

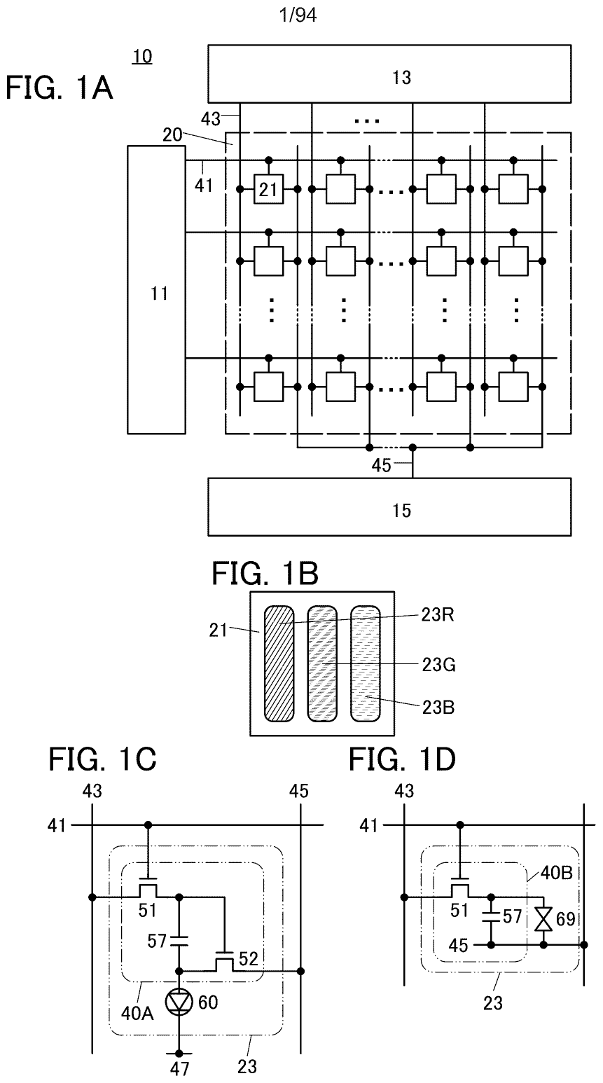

FIG. 1A is a block diagram illustrating a structure example of a display apparatus 10 that is the display apparatus of one embodiment of the present invention. The display apparatus 10 includes a display portion 20, a scan line driver circuit 11, a signal line driver circuit 13, and a power supply circuit 15. The display portion 20 includes a plurality of pixels 21 arranged in a matrix.

The scan line driver circuit 11 is electrically connected to the pixels 21 through a wiring 41. The wiring 41 extend in the row direction of the matrix, for example.

The signal line driver circuit 13 is electrically connected to the pixels 21 through a wiring 43. The wiring 43 extend in the column direction of the matrix, for example.

The power supply circuit 15 is electrically connected to the pixels 21 through a wiring 45. For example, all the pixels 21 can be electrically connected to the power supply circuit 15 through the same wiring 45.

The pixel 21 includes a display element, and an image can be displayed on the display portion 20 with the display element. As the display element, a light-emitting element can be used, for example; specifically, an organic EL element can be used. As the display element, a liquid crystal element (also referred to as a liquid crystal device) may also be used.

The scan line driver circuit 11 has a function of selecting, row by row, the pixel 21 to which image data is to be written, for example. Specifically, the scan line driver circuit 11 can select the pixel 21 to which image data is to be written by outputting a signal to the wiring 41. Here, the scan line driver circuit 11 can select all the pixels 21 by, for example, outputting the signal to the wiring 41 in the first row, outputting the signal to the wiring 41 in the second row, and then outputting the signals to the wirings 41 from the third row to the last row sequentially. Thus, the signal output from the scan line driver circuit 11 to the wiring 41 is a scan signal, and the wiring 41 can be referred to as a scan line.

The signal line driver circuit 13 has a function of generating image data. The image data is supplied to the pixel 21 through the wiring 43. For example, image data can be written to all the pixels 21 included in a row selected by the scan line driver circuit 11. Here, the image data can be represented as a signal (image signal). Thus, the wiring 43 can be referred to as a signal line.

The power supply circuit 15 has a function of generating a power supply potential and supplying it to the wiring 45. The power supply circuit 15 has a function of generating, for example, a high power supply potential (hereinafter, also simply referred to as “high potential” or “VDD”) and supplying it to the wiring 45. The power supply circuit 15 may have a function of generating a low power supply potential (hereinafter, also simply referred to as “low potential” or “VSS”). The wiring 45 is supplied with a power supply potential and thus can be referred to as a power supply line.

FIG. 1B is a plan view illustrating a structure example of the pixel 21. The pixel 21 includes a plurality of subpixels 23. FIG. 1B illustrates an example in which the pixel 21 includes a subpixel 23R, a subpixel 23G, and a subpixel 23B. Here, in the case where the pixel 21 includes a light-emitting element as the display element, for example, a planar shape of the subpixel illustrated in FIG. 1B corresponds to the planar shape of a light-emitting region of the light-emitting element. Although FIG. 1B illustrates the subpixel 23R, the subpixel 23G, and the subpixel 23B that have the same or substantially the same aperture ratio (also referred to as size or size of a light-emitting region), one embodiment of the present invention is not limited thereto. The aperture ratio of each of the subpixel 23R, the subpixel 23G, and the subpixel 23B can be determined as appropriate. The subpixel 23R, the subpixel 23G, and the subpixel 23B may have different aperture ratios, or two or more of the subpixel 23R, the subpixel 23G, and the subpixel 23B may have the same or substantially the same aperture ratio.

In this specification and the like, for example, description common to the subpixel 23R, the subpixel 23G, and the subpixel 23B is sometimes made using the collective term “subpixel 23” without letters of the alphabet distinguishing them from each other. As for other components that are distinguished from each other using letters of the alphabet, matters common to the components are sometimes described using reference numerals without the letters of the alphabet.

The pixel 21 illustrated in FIG. 1B employs stripe arrangement as the arrangement method of the subpixels 23. Examples of the arrangement of the subpixels 23 include S-stripe arrangement, matrix arrangement, delta arrangement, Bayer arrangement, and PenTile arrangement. Embodiment 2 can be referred to for an example of the planar shape of the subpixel, arrangement of the subpixels, and the like.

The subpixel 23R, the subpixel 23G, and the subpixel 23B emit light of different colors. The subpixel 23R, the subpixel 23G, and the subpixel 23B are subpixels of three colors of red (R), green (G), and blue (B) or subpixels of three colors of yellow (Y), cyan (C), and magenta (M), for example. The pixel 21 may include four or more subpixels 23. For example, the pixel 21 may include subpixels of four colors of R, G, B, and white (W). In the display apparatus 10, the display portion 20 can display a full-color image by including, in the pixel 21, the plurality of subpixels 23 emitting light of different colors. For example, the pixel 21 may include subpixels of R, G, B, and infrared (IR) light.

Note that a sensor may be provided in the display portion 20, for example, in the pixel 21. For example, the display portion 20 may have a function of a fingerprint sensor. For example, the display portion 20 may have a function of an optical or ultrasonic fingerprint sensor.

FIG. 1C is a circuit diagram illustrating a structure example of the subpixel 23. The subpixel 23 illustrated in FIG. 1C includes a pixel circuit 40A and a light-emitting element 60.

The pixel circuit 40A includes a transistor 51, a transistor 52, and a capacitor 57. That is, the pixel circuit 40A is a 2Tr1C-type pixel circuit.

In the pixel circuit 40A, one of a source and a drain of the transistor 51 is electrically connected to the wiring 43. The other of the source and the drain of the transistor 51 is electrically connected to a gate of the transistor 52. The gate of the transistor 52 is electrically connected to one electrode of the capacitor 57. A gate of the transistor 51 is electrically connected to the wiring 41.

One of a source and a drain of the transistor 52 is electrically connected to the wiring 45. The other of the source and the drain of the transistor 52 is electrically connected to the other electrode of the capacitor 57. The other electrode of the capacitor 57 is electrically connected to one electrode of the light-emitting element 60. The other electrode of the light-emitting element 60 is electrically connected to a wiring 47. Here, the one electrode of the light-emitting element 60 is also referred to as a pixel electrode. The wiring 47 can be shared between all the subpixels 23, for example; thus, the other electrode of the light-emitting element 60 can also be referred to as a common electrode.

As described above, the wiring 41, the wiring 43, and the wiring 45 function as a scan line, a signal line, and a power supply line, respectively. The wiring 47 functions as a power supply line; for example, when the wiring 45 is supplied with a high power supply potential, the wiring 47 is supplied with a low power supply potential. The wiring 47 can be electrically connected to the power supply circuit 15, for example.

The transistor 51 has a function of a switch and is also referred to as a selection transistor. The transistor 51 has a function of controlling the conduction/non-conduction between the wiring 43 and the gate of the transistor 52 on the basis of the potential of the wiring 41. When the transistor 51 is turned on, image data is written to the pixel circuit 40A, and when the transistor 51 is turned off, the written image data is retained.

The transistor 52 has a function of controlling the amount of current flowing through the light-emitting element 60 and is also referred to as a driving transistor. The capacitor 57 has a function of retaining a gate potential of the transistor 52. The emission luminance of the light-emitting element 60 is controlled in accordance with a potential that corresponds to image data and is supplied to the gate of the transistor 52. Specifically, in the case where the wiring 45 is supplied with a high power supply potential and the wiring 47 is supplied with a low power supply potential, the amount of current flowing from the wiring 45 to the wiring 47 is controlled in accordance with the gate potential of the transistor 52, whereby the emission luminance of the light-emitting element 60 is controlled.

OS transistors are preferably used as the transistor 51 and the transistor 52. An OS transistor has higher field-effect mobility than a transistor including amorphous silicon, for example. Thus, by using an OS transistor as each of the transistor 51 and the transistor 52, the display apparatus 10 can be driven at high speed.

The OS transistor has an extremely low leakage current between a source and a drain in an off state (hereinafter, also referred to as an off-state current). Thus, by using an OS transistor as the transistor 51, charge accumulated in the capacitor 57 can be retained for a long period. Therefore, image data written to the subpixel 23 can be retained for a long period and therefore the frequency of the refresh operation (rewriting image data to the subpixel 23) can be reduced. Thus, power consumption of the display apparatus 10 can be reduced.

To increase the emission luminance of the light-emitting element 60, it is necessary to increase the amount of current flowing through the light-emitting element 60. To increase the current amount, it is necessary to increase the source-drain voltage of the transistor 52 which is a driving transistor. Since the OS transistor has higher breakdown voltage between a source and a drain than a transistor including silicon (also referred to as a Si transistor), high voltage can be applied between the source and the drain of the OS transistor. Accordingly, when an OS transistor is used as the transistor 52, the amount of current flowing through the light-emitting element 60 can be increased, so that the emission luminance of the light-emitting element 60 can be increased.

In the case where transistors are driven in a saturation region, a change in source-drain current relative to a change in gate-source voltage can be smaller in an OS transistor than in a Si transistor. Thus, when an OS transistor is used as the transistor 52, a current flowing between the source and the drain can be set minutely by a change in a gate-source voltage. This allows the amount of current flowing through the light-emitting element 60 can be controlled minutely. Accordingly, the luminance of light emitted from the subpixel 23 can be controlled minutely. As a result, the number of gray levels represented by the subpixel 23 can be increased.

Regarding saturation characteristics of current flowing when a transistor is driven in a saturation region, even in the case where the source-drain voltage of an OS transistor increases gradually, a more stable current (saturation current) can be made flow through an OS transistor than through a Si transistor. Thus, by using an OS transistor as the transistor 52, a stable current can flow through the light-emitting elements 60 even when the current-voltage characteristics vary among the light-emitting elements 60, for example. In other words, when the OS transistor is driven in the saturation region, the source-drain current hardly changes with an increase in the source-drain voltage; hence, the emission luminance of the light-emitting element 60 can be stable.

As described above, by using an OS transistor as the transistor 52, it is possible to “inhibit black-level degradation”, “increase the emission luminance”, “increase the number of gray levels”, and “inhibit a variation in the emission luminance among the light-emitting elements 60”, for example.

Note that although the transistor 51 and the transistor 52 are n-channel transistors in FIG. 1C, one or both of the transistor 51 and the transistor 52 may be p-channel transistors. The same applies to other transistors described in this specification and the like.

As the light-emitting element 60, an OLED (Organic Light Emitting Diode) or a QLED (Quantum-dot Light Emitting Diode) is preferably used, for example. Examples of a light-emitting substance contained in the light-emitting element 60 include a substance that emits fluorescent light (a fluorescent material), a substance that emits phosphorescent light (a phosphorescent material), a substance that exhibits thermally activated delayed fluorescence (a thermally activated delayed fluorescent (TADF) material), and an inorganic compound (e.g., a quantum dot material). An LED such as a micro-LED (Light Emitting Diode) can also be used as the light-emitting element 60.

FIG. 1D is a circuit diagram illustrating a structure example of the subpixel 23. The subpixel 23 illustrated in FIG. 1D includes a pixel circuit 40B and a liquid crystal element 69. The pixel circuit 40B includes the transistor 51 and the capacitor 57. That is, the pixel circuit 40B is a 1Tr1C-type pixel circuit.

In the pixel circuit 40B, the one of the source and the drain of the transistor 51 is electrically connected to the wiring 43. The other of the source and the drain of the transistor 51 is electrically connected to the one electrode of the capacitor 57. The one electrode of the capacitor 57 is electrically connected to one electrode of the liquid crystal element 69. A gate of the transistor 51 is electrically connected to the wiring 41. The other electrode of the capacitor 57 and the other electrode of the liquid crystal element 69 are electrically connected to the wiring 45. Here, the one electrode of the liquid crystal element 69 is also referred to as a pixel electrode. The other electrode of the liquid crystal element 69 may be referred to as a common electrode. In the pixel circuit 40B, a ground potential can be supplied to the wiring 45, for example.

In the pixel circuit 40B, the transistor 51 has a function of a switch and has a function of controlling the conduction/non-conduction between the wiring 43 and the one electrode of the liquid crystal element 69 on the basis of the potential of the wiring 41. When the transistor 51 is turned on, image data is written to the pixel circuit 40B, and when the transistor 51 is turned off, the written image data is retained.

The capacitor 57 has a function of retaining the potential of the one electrode of the liquid crystal element 69. The alignment state of the liquid crystal element 69 is controlled in accordance with a potential that corresponds to image data and is supplied to the one electrode of the liquid crystal element 69.

As examples of a mode of the liquid crystal element 69, any of the following modes can be given: a TN (twisted nematic) mode, an STN (super twisted nematic) mode, a VA (vertical alignment) mode, an ASM (axially symmetric aligned micro-cell) mode, an OCB (optically compensated birefringence) mode, an FLC (ferroelectric liquid crystal) mode, an AFLC (antiferroelectric liquid crystal) mode, an MVA (multi-domain vertical alignment) mode, a PVA (patterned vertical alignment) mode, an IPS (in-plane switching) mode, an FFS (fringe field switching) mode, and a TBA (transverse bend alignment) mode. Other examples include an ECB (Electrically Controlled Birefringence) mode, a PDLC (Polymer Dispersed Liquid Crystal) mode, a PNLC (Polymer Network Liquid Crystal) mode, a guest-host mode, and the like. However, the mode is not limited thereto, and a variety of modes can be used.

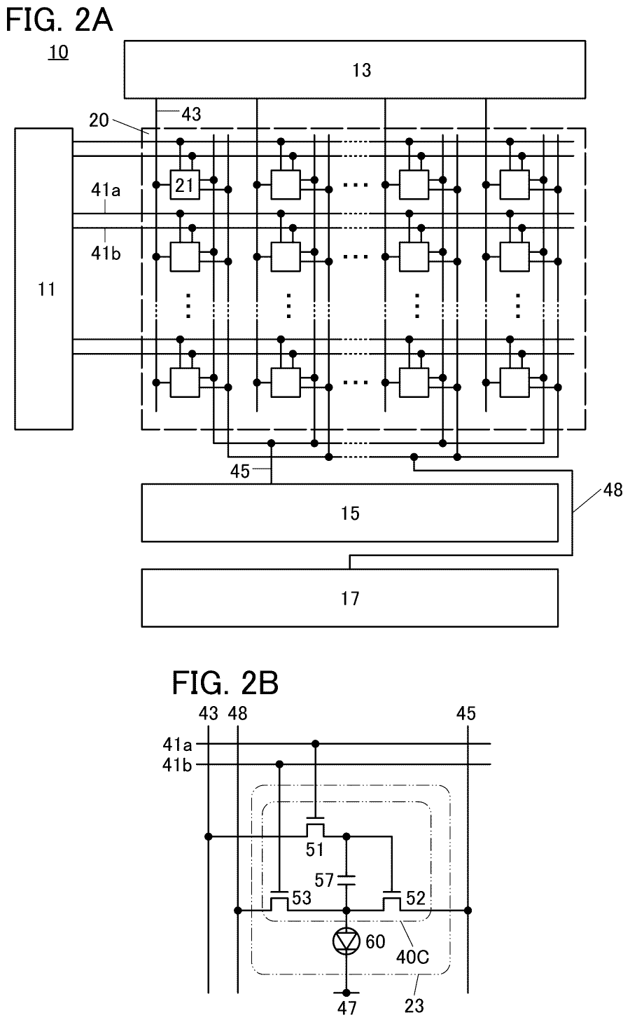

FIG. 2A is a block diagram illustrating a structure example of the display apparatus 10, and shows a variation example of the display apparatus 10 illustrated in FIG. 1A. The display apparatus 10 illustrated in FIG. 2A is different from the display apparatus 10 illustrated in FIG. 1A in including a wiring 41a and a wiring 41b as the wiring 41 and including a reference potential generation circuit 17.

The reference potential generation circuit 17 is electrically connected to the pixels 21 through a wiring 48. For example, all the pixels 21 can be electrically connected to the reference potential generation circuit 17 through the same wiring 48. The reference potential generation circuit 17 has a function of generating a reference potential for correcting a variation in the gate-source potential among the transistors 52 and supplying it to the wiring 48, for example. The potential of the wiring 48 is a reference potential and thus the wiring 48 can be referred to as a reference potential line. Note that the reference potential generation circuit 17 may also be referred to as a power supply circuit. The power supply circuit 15 and the reference potential generation circuit 17 may be combined to be one circuit. For example, the reference potential generation circuit 17 may be included in the power supply circuit 15.

FIG. 2B is a circuit diagram illustrating a structure example of the subpixel 23 included in the pixel 21 illustrated in FIG. 2A. The subpixel 23 illustrated in FIG. 2B includes a pixel circuit 40C and the light-emitting element 60. The pixel circuit 40C has a structure in which a transistor 53 is added to the pixel circuit 40A. The pixel circuit 40C is a 3Tr1C-type pixel circuit.

In the pixel circuit 40C, a gate of the transistor 51 is electrically connected to the wiring 41a. One of a source and a drain of the transistor 53 is electrically connected to the other of a source and a drain of the transistor 52, the other electrode of the capacitor 57, and the one electrode of the light-emitting element 60. The other of the source and the drain of the transistor 53 is electrically connected to the wiring 48. A gate of the transistor 53 is electrically connected to the wiring 41b.

The transistor 53 has a function of a switch and has a function of controlling the conduction/non-conduction between the wiring 48 and the one electrode of the light-emitting element 60 on the basis of the potential of the wiring 41b. A reference potential is supplied to the wiring 48, for example. A variation in the gate-source potential among the transistors 52 can be inhibited by the reference potential of the wiring 48 supplied through the transistor 53.

A current value that can be used for setting of pixel parameters can be obtained on the basis of the current value of the wiring 48. Specifically, the wiring 48 can function as a monitor line for outputting a current flowing through the transistor 52 or a current flowing through the light-emitting element 60 to the outside of the pixel 21. A current output to the wiring 48 can be converted into a potential by a source follower circuit, for example. Alternatively, the current can be converted into a digital signal by an A/D converter, for example. In the case where the wiring 48 functions as a monitor line, the display apparatus 10 does not necessarily include the reference potential generation circuit 17. In the case where the wiring 48 functions as a monitor line, each column including the pixels 21 can be electrically connected to a different wiring.

An OS transistor is preferably used as the transistor 53. As described above, an OS transistor has higher field-effect mobility than a transistor including amorphous silicon, for example. Consequently, by using an OS transistor as the transistor 53, the display apparatus 10 can be driven at high speed.

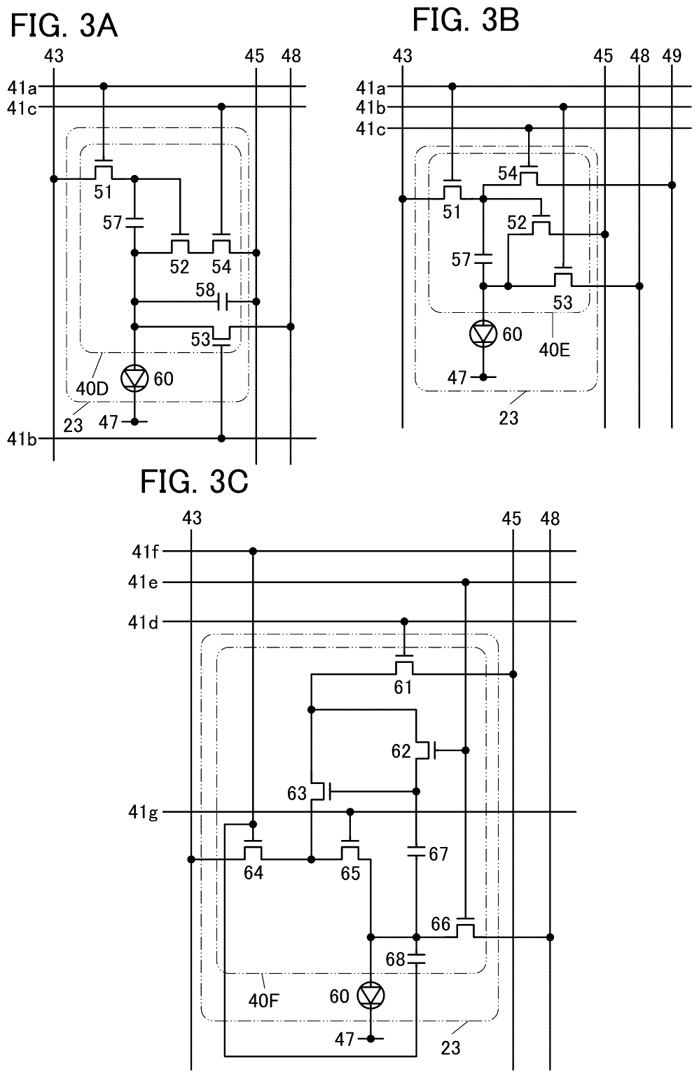

FIG. 3A, FIG. 3B, and FIG. 3C are circuit diagrams illustrating structure examples of the subpixel 23 included in the pixel 21 illustrated in FIG. 2A. The subpixel 23 illustrated in FIG. 3A includes a pixel circuit 40D and the light-emitting element 60. The pixel circuit 40D has a structure in which a transistor 54 and a capacitor 58 are added to the pixel circuit 40C. The pixel circuit 40D is a 4Tr2C-type pixel circuit.

In the pixel circuit 40D, the one of the source and the drain of the transistor 52 is electrically connected to one of a source and a drain of the transistor 54. The other of the source and the drain of the transistor 54 is electrically connected to the wiring 45. A gate of the transistor 54 is electrically connected to a wiring 41c. One electrode of the capacitor 58 is electrically connected to the other of the source and the drain of the transistor 52, the one of the source and the drain of the transistor 53, the other electrode of the capacitor 57, and the one electrode of the light-emitting element 60.

The wiring 41c is electrically connected to the scan line driver circuit 11. In other words, in the case where the subpixel 23 included in the pixel 21 has the structure illustrated in FIG. 3A, the wiring 41a, the wiring 41b, and the wiring 41c are provided as the wiring 41 in the display apparatus 10.

The transistor 54 has a function of a switch and has a function of controlling the conduction/non-conduction between the wiring 45 and the one of the source and the drain of the transistor 52 on the basis of the potential of the wiring 41c.

When the transistor 54 is turned on, a current having a level corresponding to the gate potential of the transistor 52 flows from the wiring 45 to the wiring 47, for example. Thus, the light-emitting element 60 emits light with a luminance corresponding to the gate potential of the transistor 52. Meanwhile, when the transistor 54 is turned off, current can be made not to flow through the light-emitting element 60; thus, the light-emitting element 60 can be made not to emit light.

An OS transistor is preferably used as the transistor 54. As described above, an OS transistor has higher field-effect mobility than a transistor including amorphous silicon, for example. Consequently, by using an OS transistor as the transistor 54, the display apparatus 10 can be driven at high speed.

The subpixel 23 illustrated in FIG. 3B includes a pixel circuit 40E and the light-emitting element 60. The pixel circuit 40E has a structure in which the transistor 54 is added to the pixel circuit 40C. The pixel circuit 40E is a 4Tr1C-type pixel circuit.

In the pixel circuit 40E, the one of the source and the drain of the transistor 54 is electrically connected to the other of the source and the drain of the transistor 51, a gate of the transistor 52, and the one electrode of the capacitor 57. The other of the source and the drain of the transistor 54 is electrically connected to a wiring 49. A gate of the transistor 54 is electrically connected to a wiring 41c. In the case where the subpixel 23 has the structure illustrated in FIG. 3B, the wiring 41a, the wiring 41b, and the wiring 41c are provided as the wiring 41 in the display apparatus 10.

When the transistor 54 is turned on, the gate potential of the transistor 52 can be the potential of the wiring 49. Here, a low potential can be supplied to the wiring 49, for example. Accordingly, a current does not flow through the light-emitting element 60, for example; thus, the light-emitting element 60 does not emit light.

The subpixel 23 illustrated in FIG. 3C includes a pixel circuit 40F and the light-emitting element 60.

The pixel circuit 40F includes a transistor 61, a transistor 62, a transistor 63, a transistor 64, a transistor 65, a transistor 66, a capacitor 67, and a capacitor 68. That is, the pixel circuit 40F is a 6Tr2C-type pixel circuit.

In the pixel circuit 40F, one of a source and a drain of the transistor 61 is electrically connected to the wiring 45. The other of the source and the drain of the transistor 61 is electrically connected to one of a source and a drain of the transistor 62. The one of the source and the drain of the transistor 62 is electrically connected to one of a source and a drain of the transistor 63. A gate of the transistor 61 is electrically connected to a wiring 41d.

The other of the source and the drain of the transistor 62 is electrically connected to a gate of the transistor 63. The gate of the transistor 63 is electrically connected to one electrode of the capacitor 67. A gate of the transistor 62 is electrically connected to a wiring 41e. One of a source and a drain of the transistor 64 is electrically connected to the wiring 43. The other of the source and the drain of the transistor 64 is electrically connected to the other of the source and the drain of the transistor 63. The other of the source and the drain of the transistor 63 is electrically connected to one of a source and a drain of a transistor 65. A gate of the transistor 64 is electrically connected to a wiring 41f.

The other of the source and the drain of the transistor 65 is electrically connected to one of a source and a drain of the transistor 66. The one of the source and the drain of the transistor 66 is electrically connected to the other electrode of the capacitor 67. The other electrode of the capacitor 67 is electrically connected to one electrode of the capacitor 68. The one electrode of the capacitor 68 is electrically connected to the one electrode of the light-emitting element 60. A gate of the transistor 65 is electrically connected to a wiring 41g.

The other of the source and the drain of the transistor 66 is electrically connected to the wiring 48. A gate of the transistor 66 is electrically connected to the wiring 41e.

The other electrode of the capacitor 68 is electrically connected to the wiring 41f. The other electrode of the light-emitting element 60 is electrically connected to the wiring 47.

The wiring 41d, the wiring 41e, the wiring 41f, and the wiring 41g are electrically connected to the scan line driver circuit 11. In other words, in the case where the subpixel 23 included in the pixel 21 has the structure illustrated in FIG. 3C, the wiring 41d, the wiring 41e, the wiring 41f, and the wiring 41g are provided as the wiring 41 in the display apparatus 10.

The transistor 61, the transistor 62, the transistor 64, the transistor 65, and the transistor 66 each have a function of a switch. The transistor 61 has a function of controlling the conduction/non-conduction between the wiring 45 and the one of the source and the drain of the transistor 62 and between the wiring 45 and the one of the source and the drain of the transistor 63 on the basis of the potential of the wiring 41d. The transistor 62 has a function of controlling the conduction/non-conduction between the other of the source and the drain of the transistor 61 and the one of the source and the drain of the transistor 63 and between the gate of the transistor 63 and the one electrode of the capacitor 67 on the basis of the potential of the wiring 41e. The transistor 64 has a function of controlling the conduction/non-conduction between the wiring 43 and the other of the source and the drain of the transistor 63 and between the wiring 43 and the one of the source and the drain of the transistor 65 on the basis of the potential of the wiring 41f. The transistor 65 has a function of controlling the conduction/non-conduction between the one electrode of the light-emitting element 60 and the other of the source and the drain of the transistor 63 and between the one electrode of the light-emitting element 60 and the other of the source and the drain of the transistor 64 on the basis of the potential of the wiring 41g. The transistor 66 has a function of controlling the conduction/non-conduction between the wiring 48 and the one electrode of the light-emitting element 60 on the basis of the potential of the wiring 41e.

OS transistors are preferably used as the transistor 61 to the transistor 66. An OS transistor has higher field-effect mobility than a transistor including amorphous silicon, for example. Consequently, by using an OS transistor as each of the transistor 61 to the transistor 66, the display apparatus 10 can be driven at high speed.

### Structure Example 1 of Semiconductor Device

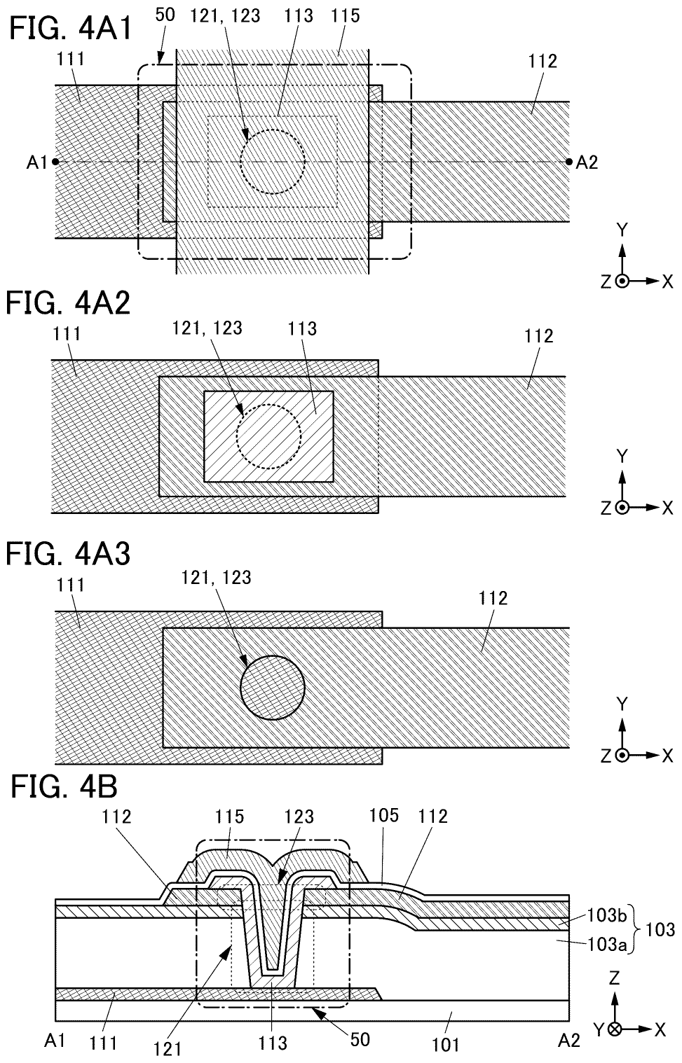

FIG. 4A1 is a plan view illustrating a structure example of a semiconductor device included in the display apparatus of one embodiment of the present invention. Specifically, FIG. 4A1 is a plan view illustrating a structure example of a transistor 50 included in the display apparatus of one embodiment of the present invention and the vicinity thereof. FIG. 4B is a cross-sectional view taken along the dashed-dotted line A1-A2 in FIG. 4A1. Note that in FIG. 4A1, some components of the transistor 50 such as an insulating layer, are not illustrated. Some components such as an insulating layer are not illustrated in plan views of transistors in the following drawings.

The transistor 50 can be used as at least one of the transistors included in the pixel 21, for example. For example, the transistor 50 can be used as the transistor 51 to the transistor 54 and the transistor 61 to the transistor 66. The transistor 50 may be used as at least part of the transistors included in the scan line driver circuit 11, the transistors included in the signal line driver circuit 13, the transistors included in the power supply circuit 15, and the transistors included in the reference potential generation circuit 17.

The transistor 50 is provided over a substrate 101. The transistor 50 includes a conductive layer 111, a conductive layer 112, a semiconductor layer 113, an insulating layer 105, and a conductive layer 115. FIG. 4A1 illustrates an example in which the conductive layer 112 extends in a direction that is parallel to the conductive layer 111 and perpendicular to the conductive layer 115.

In FIG. 4A1 and FIG. 4B, the direction in which the conductive layer 112 extends is the X direction, as indicated by the coordinate axes. The direction perpendicular to the X direction and parallel to the top surface of the substrate 101, for example, is referred to as the Y direction, and the direction perpendicular the top surface of the substrate 101 is referred to as the Z direction. The definition of the X direction, the Y direction, and the Z direction applies in some drawings and does not apply in other drawings. The X direction, the Y direction, and the Z direction can be perpendicular to each other.

The conductive layer 111 has a function of one of a source electrode and a drain electrode of the transistor 50. The conductive layer 112 functions as the other of the source electrode and the drain electrode of the transistor 50. The insulating layer 105 functions as a gate insulating layer of the transistor 50. The conductive layer 115 functions as a gate electrode of the transistor 50.

In the semiconductor layer 113 between the source electrode and the drain electrode, the whole region overlapping with the gate electrode with the gate insulating layer therebetween functions as a channel formation region. In the semiconductor layer 113, a region in contact with the source electrode functions as a source region, and a region in contact with the drain electrode functions as a drain region.

The conductive layer 111 is provided over the substrate 101, an insulating layer 103 is provided over the substrate 101 and the conductive layer 111, and the conductive layer 112 is provided over the insulating layer 103. The insulating layer 103 can have a function of an interlayer insulating layer. The conductive layer 111 has a region overlapping with the conductive layer 112 with the insulating layer 103 therebetween. Here, the thickness of the insulating layer 103 functioning as an interlayer insulating layer can be larger than the thickness of the insulating layer 105 functioning as the gate insulating layer of the transistor 50.

The insulating layer 103 has an opening 121 reaching the conductive layer 111. The conductive layer 112 has an opening 123 reaching the opening 121. That is, the opening 123 includes a region overlapping with the opening 121.

FIG. 4A1 illustrates the conductive layer 111, the conductive layer 112, the semiconductor layer 113, the conductive layer 115, the opening 121, and the opening 123, as components of the transistor 50. FIG. 4A2 illustrates a structure example in which the conductive layer 115 is omitted from the components illustrated in FIG. 4A1. That is, FIG. 4A2 illustrates the conductive layer 111, the conductive layer 112, the semiconductor layer 113, the opening 121, and the opening 123. FIG. 4A3 illustrates a structure example in which the semiconductor layer 113 is omitted from the components illustrated in FIG. 4A2. That is, FIG. 4A3 illustrates the conductive layer 111, the conductive layer 112, the opening 121, and the opening 123.

As illustrated in FIG. 4A3 and FIG. 4B, the conductive layer 112 has the opening 123 in a region overlapping with the conductive layer 111. As illustrated in FIG. 4A3, the conductive layer 112 can be formed to entirely surround the periphery of the opening 121 in the plan view. It is preferable that the conductive layer 112 not be provided in the opening 121. In other words, it is preferable that the conductive layer 112 be not in contact with a side surface of the insulating layer 103 on the opening 121 side.

FIG. 4A1, FIG. 4A2, and FIG. 4A3 each show an example in which each of the opening 121 and the opening 123 are circular in the plan view. In the case where the planar shapes of the opening 121 and the opening 123 are circular, high processing accuracy to form each of the opening 121 and the opening 123 is possible and the opening 121 and the opening 123 having minute sizes can be formed. Note that in this specification and the like, a circular shape is not necessarily a perfect circular shape. For example, the planar shapes of the opening 121 and the opening 123 may be elliptical.

FIG. 4B illustrates an example in which an end portion of the conductive layer 112 on the opening 123 side is aligned or substantially aligned with end portion of the insulating layer 103 on the opening 121 side. In other words, the planar shape of the opening 123 is the same or substantially the same as the planar shape of the opening 121. Note that in this specification and the like, the end portion of the conductive layer 112 on the opening 123 side and an end portion of the opening 123 each refer to an end portion of the bottom surface of the conductive layer 112 on the opening 123 side. The bottom surface of the conductive layer 112 refers to the surface thereof on the insulating layer 103 side. The end portion of the insulating layer 103 on the opening 121 side and an end portion of the opening 121 each refer to an end portion of the top surface of the insulating layer 103 on the opening 121 side. The top surface of the insulating layer 103 refers to the surface thereof on the conductive layer 112 side. The planar shape of the opening 123 refers to the shape of the end portion of the bottom surface of the conductive layer 112 on the opening 123 side. The planar shape of the opening 121 refers to the shape of the end portion of the top surface of the insulating layer 103 on the opening 121 side.

In the case where end portions are aligned or substantially aligned with each other, the end portions can also be said to match or substantially match. In the case where end portions are aligned or substantially aligned with each other and the case where planar shapes are the same or substantially the same, it can be said that outlines of stacked layers at least partly overlap with each other in a plan view. For example, the case of processing an upper layer and a lower layer with the use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions substantially match” or the expression “planar shapes are substantially the same”.

The opening 121 can be formed using a resist mask used for the formation of the opening 123, for example. Specifically, first, the conductive layer 111 is formed over the substrate 101, the insulating layer 103 is then formed over the substrate 101 and the conductive layer 111, a conductive film to be the conductive layer 112 is formed over the insulating layer 103, and a resist mask is formed over the conductive film. Then, the opening 123 is formed in the conductive film using the resist mask and then the opening 121 is formed in the insulating layer 103 using the resist mask, whereby the end portion of the opening 121 and the end portion of the opening 123 can be aligned or substantially aligned with each other. With such a structure, processes can be simplified.

The semiconductor layer 113 is provided to cover the opening 121 and the opening 123 and include a region positioned in the opening 121 and the opening 123. The semiconductor layer 113 has a shape along the top surface and the side surface of the conductive layer 112, the side surface of the insulating layer 103, and the top surface of the conductive layer 111. The semiconductor layer 113 includes a region in contact with the top surface and the side surface of the conductive layer 112, the side surface of the insulating layer 103, and the top surface of the conductive layer 111, for example.

The semiconductor layer 113 preferably covers the end portion of the conductive layer 112 on the opening 123 side. For example, FIG. 4B illustrates a structure where an end portion of the semiconductor layer 113 is positioned over the conductive layer 112. In other words, the end portion of the semiconductor layer 113 is in contact with the top surface of the conductive layer 112.

Although the semiconductor layer 113 has a single-layer structure in FIG. 4B, for example, one embodiment of the present invention is not limited thereto. The semiconductor layer 113 may have a stacked-layer structure of two or more layers.

The insulating layer 105 functioning as the gate insulating layer of the transistor 50 is provided to cover the opening 121 and the opening 123 and include a region positioned in the opening 121 and the opening 123. The insulating layer 105 is provided over the semiconductor layer 113, the conductive layer 112, and the insulating layer 103. The insulating layer 105 can include a region in contact with the top surface and the side surface of the semiconductor layer 113, the top surface and the side surface of the conductive layer 112, and the top surface of the insulating layer 103. The insulating layer 105 has a shape along the top surface of the insulating layer 103, the top surface and the side surface of the conductive layer 112, and the top surface and the side surface of the semiconductor layer 113.

The conductive layer 115 functioning as the gate electrode of the transistor 50 can be provided over the insulating layer 105 and can include a region in contact with the top surface of the insulating layer 105. The conductive layer 115 includes a region overlapping with the semiconductor layer 113 with the insulating layer 105 therebetween.

For example, as illustrated in FIG. 4B, the conductive layer 115 is provided to include a region positioned in the opening 121, a region positioned in the opening 123, and a region facing the semiconductor layer 113 with the insulating layer 105 therebetween. Moreover, in the example illustrated in FIG. 4B, the conductive layer 115 includes regions overlapping with the conductive layer 111 and the conductive layer 112 with the insulating layer 105 and the semiconductor layer 113 therebetween. The conductive layer 115 covers the entire semiconductor layer 113. With such a structure, a gate electric field can be applied to the entire the semiconductor layer 113, which allows the transistor 50 to have better electrical characteristics, such as a higher on-state current. When the insulating layer 103 is provided between the conductive layer 111 and the conductive layer 115 in addition to the insulating layer 105 functioning as a gate insulating layer, parasitic capacitance formed by the conductive layer 111 and the conductive layer 115 is smaller than that in the case where the insulating layer provided between the conductive layer 111 and the conductive layer 115 is only the insulating layer 103, for example.

The transistor 50 is what is called a top-gate transistor including the gate electrode above the semiconductor layer 113. Furthermore, since the bottom surface of the semiconductor layer 113 includes a region in contact with the source electrode and the drain electrode, the transistor 50 can be referred to as a TGBC (Top Gate Bottom Contact) transistor.

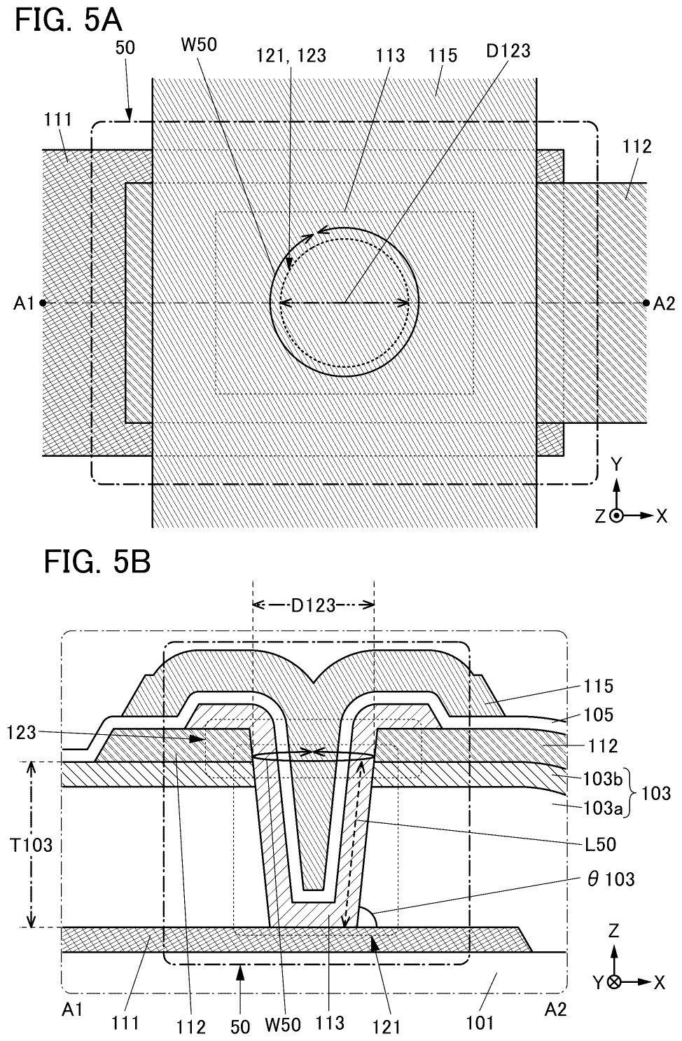

Here, the channel length and the channel width of the transistor 50 will be described with reference to FIG. 5A and FIG. 5B. FIG. 5A is an enlarged view of the plan view of FIG. 4A1 illustrating the structure example of the transistor 50 and the vicinity thereof. FIG. 5B is a cross-sectional view taken along the dashed-dotted line A1-A2 in FIG. 5A.

In the semiconductor layer 113, a region in contact with the conductive layer 111 functions as one of the source region and the drain region, a region in contact with the conductive layer 112 functions as the other of the source region and the drain region, and a region between the source region and the drain region functions as the channel formation region.

The channel length of the transistor 50 is a distance between the source region and the drain region. In FIG. 5B, a channel length L50 of the transistor 50 is indicated by a dashed double-headed arrow. In the cross-sectional view, the channel length L50 is a distance between an end portion of the region where the semiconductor layer 113 is in contact with the conductive layer 111 and an end portion of the region where the semiconductor layer 113 is in contact with the conductive layer 112.

Here, the channel length L50 of the transistor 50 corresponds to the length of the side surface of the insulating layer 103 on the opening 121 side when seen from an XZ plane. In other words, the channel length L50 is determined depending on a thickness T103 of the insulating layer 103 and an angle θ103 formed by the side surface of the insulating layer 103 on the opening 121 side and the formation surface of the insulating layer 103 (here, the top surface of the conductive layer 111), and is not affected by the performance of a light-exposure apparatus used for manufacturing the transistor. Thus, the channel length L50 can be a value smaller than that of the resolution limit of the light-exposure apparatus, which enables the transistor to have a minute size. For example, the channel length L50 is preferably longer than or equal to 0.01 μm and shorter than 3.0 μm, further preferably longer than or equal to 0.05 μm and shorter than 3.0 μm, further preferably longer than or equal to 0.10 μm and shorter than 3.0 μm, further preferably longer than or equal to 0.15 μm and shorter than 3.0 μm, further preferably longer than or equal to 0.20 μm and shorter than 3.0 μm, further preferably longer than or equal to 0.20 μm and shorter than 2.5 μm, further preferably longer than or equal to 0.20 μm and shorter than 2.0 μm, further preferably longer than or equal to 0.20 μm and shorter than 1.5 μm, further preferably longer than or equal to 0.30 μm and shorter than 1.5 μm, further preferably longer than or equal to 0.30 μm and shorter than or equal to 1.2 μm, further preferably longer than or equal to 0.40 μm and shorter than or equal to 1.2 μm, further preferably longer than or equal to 0.40 μm and shorter than or equal to 1.0 μm, further preferably longer than or equal to 0.50 μm and shorter than or equal to 1.0 μm. In FIG. 5B, the thickness T103 of the insulating layer 103 is indicated by a dashed-dotted double-headed arrow.

The reduction in the channel length L50 can increase the on-state current of the transistor 50. Thus, with the use of the transistor 50 as the transistor included in the display apparatus 10, such as the transistor included in the pixel 21, the display apparatus 10 can be driven at high speed.

By adjusting the thickness T103 and the angle θ103 of the insulating layer 103, the channel length L50 can be controlled.

The thickness T103 of the insulating layer 103 is preferably larger than or equal to 0.01 μm and smaller than 3.0 μm, further preferably larger than or equal to 0.05 μm and smaller than 3.0 μm, further preferably larger than or equal to 0.10 μm and smaller than 3.0 μm, further preferably larger than or equal to 0.15 μm and smaller than 3.0 μm, further preferably larger than or equal to 0.20 μm and smaller than 3.0 μm, further preferably larger than or equal to 0.20 μm and smaller than 2.5 μm, further preferably larger than or equal to 0.20 μm and smaller than 2.0 μm, further preferably larger than or equal to 0.20 μm and smaller than 1.5 μm, further preferably larger than or equal to 0.30 μm and smaller than 1.5 μm, further preferably larger than or equal to 0.30 μm and smaller than or equal to 1.2 μm, further preferably larger than or equal to 0.40 μm and smaller than or equal to 1.2 μm, further preferably larger than or equal to 0.40 μm and smaller than or equal to 1.0 μm, further preferably larger than or equal to 0.50 μm and smaller than or equal to 1.0 μm.

The side surface of the insulating layer 103 on the opening 121 side preferably has a tapered shape. The angle θ103 formed by the side surface of the insulating layer 103 on the opening 121 side and the formation surface of the insulating layer 103 (here, the top surface of the conductive layer 111) is preferably smaller than 90°. By reducing the angle θ103, the coverage with a layer (e.g., the semiconductor layer 113) provided over the insulating layer 103 can be improved. However, reducing the angle θ103 might reduce the contact area between the semiconductor layer 113 and the conductive layer 111 and increase the contact resistance between the semiconductor layer 113 and the conductive layer 111. The angle θ103 is preferably greater than or equal to 45° and less than 90°, further preferably greater than or equal to 50° and less than 90°, further preferably greater than or equal to 55° and less than 90°, further preferably greater than or equal to 60° and less than 90°, further preferably greater than or equal to 60° and less than or equal to 85°, still further preferably greater than or equal to 65° and less than or equal to 85°, yet further preferably greater than or equal to 65° and less than or equal to 80°, yet still further preferably greater than or equal to 70° and less than or equal to 80°. When the angle θ103 is within the above range, the coverage with the layer (e.g., the semiconductor layer 113) formed over the conductive layer 111 and the insulating layer 103 can be improved while the channel length of the transistor 50 is reduced, which can inhibit defects such as step disconnection or a void from being generated in the layer. In addition, the contact resistance between the semiconductor layer 113 and the conductive layer 111 can be reduced.

In this specification and the like, step disconnection refers to a phenomenon in which a layer, a film, or an electrode is split because of the shape of the formation surface (e.g., a step).

Although FIG. 5B illustrates the structure in which the side surface of the insulating layer 103 on the opening 121 side is linear in the cross-sectional view, one embodiment of the present invention is not limited thereto. In the cross-sectional view, the side surface of the insulating layer 103 on the opening 121 side may be curved, or the side surface may include both a linear region and a curved region.

The channel width of the transistor 50 is the width of the source region or the width of the drain region in a direction orthogonal to the channel length direction. In other words, the channel width is the width of the region where the semiconductor layer 113 is in contact with the conductive layer 111 or the width of the region where the semiconductor layer 113 is in contact with the conductive layer 112 in the direction orthogonal to the channel length direction. Here, the channel width of the transistor 50 is described as the width of the region where the semiconductor layer 113 is in contact with the conductive layer 112 in the direction orthogonal to the channel length direction. In FIG. 5A and FIG. 5B, a channel width W50 of the transistor 50 is indicated by a solid double-headed arrow. In the plan view, the channel width W50 is the length of the end portion of the bottom surface of the conductive layer 112 on the opening 123 side.

The channel width W50 is determined depending on the planar shape of the opening 123. In FIG. 5A and FIG. 5B, a width D123 of the opening 123 is denoted by a dashed double-dotted double-headed arrow. In the plan view, the width D123 is the short side of the smallest rectangle that is circumscribed around the opening 123. In the case where the opening 123 is formed by a photolithography method, the width D123 of the opening 123 is larger than or equal to the resolution limit of a light-exposure apparatus. For example, the width D123 is preferably larger than or equal to 0.20 μm and smaller than 5.0 μm, further preferably larger than or equal to 0.20 μm and smaller than 4.5 μm, further preferably larger than or equal to 0.20 μm and smaller than 4.0 μm, further preferably larger than or equal to 0.20 μm and smaller than 3.5 μm, further preferably larger than or equal to 0.20 μm and smaller than 3.0 μm, further preferably larger than or equal to 0.20 μm and smaller than 2.5 μm, further preferably larger than or equal to 0.20 μm and smaller than 2.0 μm, further preferably larger than or equal to 0.20 μm and smaller than 1.5 μm, further preferably larger than or equal to 0.30 μm and smaller than 1.5 μm, further preferably larger than or equal to 0.30 μm and smaller than or equal to 1.2 μm, further preferably larger than or equal to 0.40 μm and smaller than or equal to 1.2 μm, further preferably larger than or equal to 0.40 μm and smaller than or equal to 1.0 μm, further preferably larger than or equal to 0.50 μm and smaller than or equal to 1.0 μm. Note that when the planar shape of the opening 123 is circular, the width D123 corresponds to the diameter of the opening 123, the channel width W50 can be equal to the length of the periphery of the opening 123 in the plan view and calculated to be “D123×π”.

### Structure Example 1 of Pixel

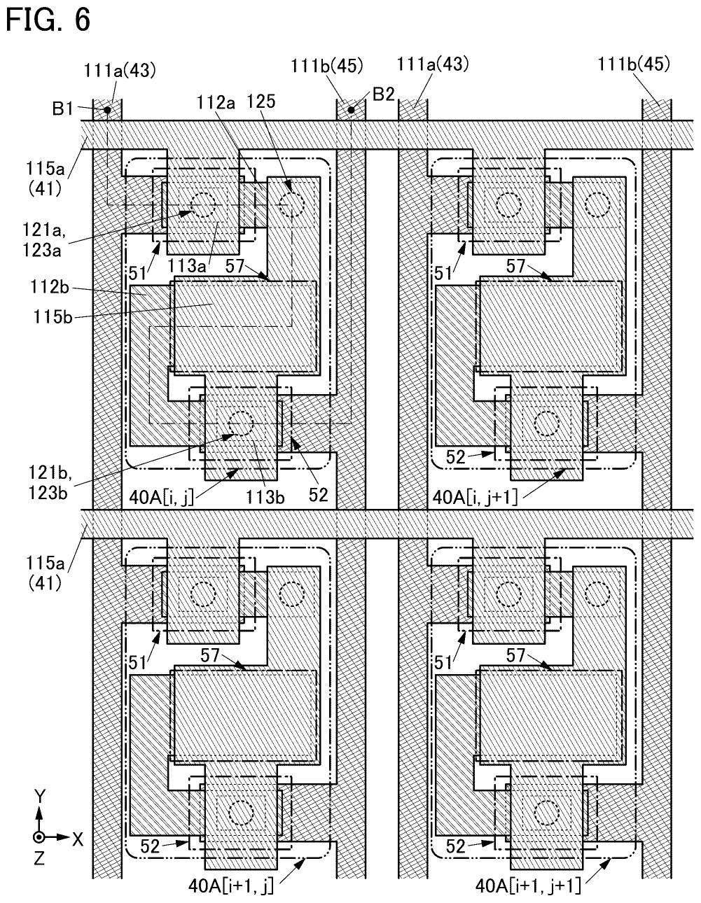

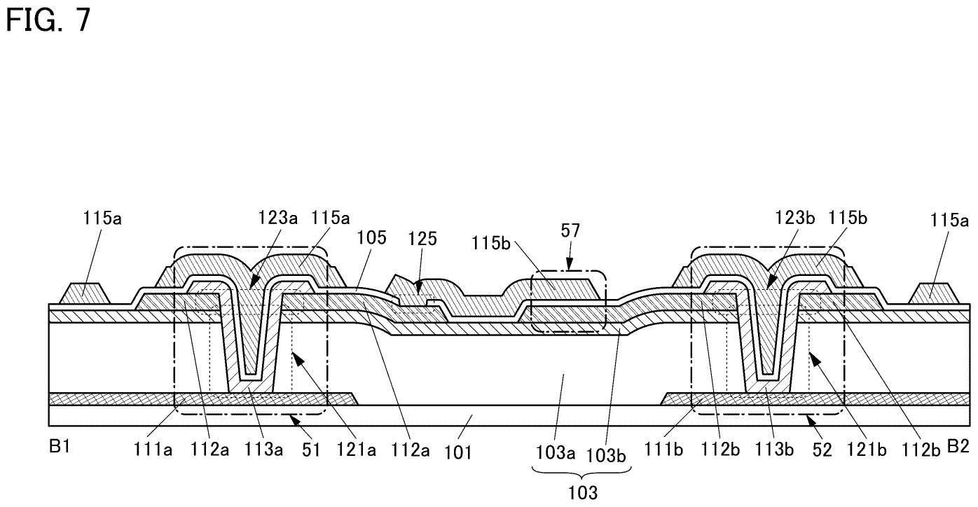

FIG. 6 is a plan view illustrating a structure example of the pixel circuit 40A illustrated in FIG. 1C. FIG. 7 is a cross-sectional view taken along the dashed-dotted line B1-B2 in FIG. 6, and illustrates a structure example of the transistor 51 and the capacitor 57. FIG. 6 illustrates the pixel circuits 40A (a pixel circuit 40A [i,j], a pixel circuit 40A [i,j+1], a pixel circuit 40A [i+1,j], and a pixel circuit 40A [i+1,j+1]) in two rows and two columns. Here, i and j are each an integer greater than or equal to 1. Note that other plan views illustrating structure examples of pixel circuits also illustrates the pixel circuits in two rows and two columns.

In the example illustrated in FIG. 6 and FIG. 7, the structure of the transistor 51 and the structure of the transistor 52 are similar to the transistor 50 illustrated in FIG. 4A1 and FIG. 4B. Here, the conductive layer 111, the conductive layer 112, the semiconductor layer 113, and the conductive layer 115 included in the transistor 51 are referred to as a conductive layer 111a, a conductive layer 112a, a semiconductor layer 113a, and a conductive layer 115a, respectively. The conductive layer 111, the conductive layer 112, the semiconductor layer 113, and the conductive layer 115 included in the transistor 52 are referred to as a conductive layer 111b, a conductive layer 112b, a semiconductor layer 113b, and a conductive layer 115b, respectively. The opening 121 and the opening 123 provided in the transistor 51 are referred to as an opening 121a and an opening 123a, respectively, and the opening 121 and the opening 123 provided in the transistor 52 are referred to as an opening 121b and an opening 123b, respectively.

The capacitor 57 includes the conductive layer 112b over the insulating layer 103, the insulating layer 105 over the conductive layer 112b, and the conductive layer 115b that is provided over the insulating layer 105 and includes a region overlapping with the conductive layer 112b. That is, the same conductive layer can be used for the other of the source electrode and the drain electrode of the transistor 52 and the other electrode of the capacitor 57. The same conductive layer can be used for a gate electrode of the transistor 52 and the one electrode of the capacitor 57.

The insulating layer 105 includes an opening 125 reaching the conductive layer 112a, and the conductive layer 112a and the conductive layer 115b are electrically connected to each other through the opening 125. Specifically, the conductive layer 112a and the conductive layer 115b are in contact with each other in the opening 125, for example.

Although the shape of the opening 125 in the plan view is circular in FIG. 6, one embodiment of the present invention is not limited thereto, and the opening 125 can have a shape similar to the shape that the opening 121 or the opening 123 can have.

At least part of the conductive layer 111a functions as the wiring 43 functioning as a signal line and is electrically connected to the signal line driver circuit 13 illustrated in FIG. 1A. At least part of the conductive layer 111b functions as the wiring 45 functioning as a power supply line and is electrically connected to the power supply circuit 15 illustrated in FIG. 1A. At least part of the conductive layer 115a functions as the wiring 41 functioning as a scan line and is electrically connected to the scan line driver circuit 11 illustrated in FIG. 1A.

The conductive layer 115a includes a region extending in the X direction. The conductive layer 111a and the conductive layer 111b each include a region extending in the Y direction. The conductive layer 115a includes a region overlapping with the conductive layer 111a and a region overlapping with the conductive layer 111b. Specifically, part of the region of the conductive layer 115a extending in the X direction overlaps with part of the region of the conductive layer 111a extending in the Y direction. Part of the region of the conductive layer 115a extending in the X direction overlaps with part of the region of the conductive layer 111b extending in the Y direction.

Here, it can be said that the region of the conductive layer 115a extending in the X direction functions as the wiring 41 and the entire conductive layer 115a functions as the wiring 41. It can be said that the region of the conductive layer 111a extending in the Y direction functions as the wiring 43 and the entire conductive layer 111a functions as the wiring 43. It can be said that the region of the conductive layer 111b extending in the Y direction functions as the wiring 45 and the entire conductive layer 111b functions as the wiring 45. Unless otherwise specified, the same applies to other conductive layers including regions functioning as the wiring 41, the wiring 43, or the wiring 45.

In the example illustrated in FIG. 6 and FIG. 7, in the region where the conductive layer 111a and the conductive layer 115a overlap with each other, the insulating layer 103 is provided over the conductive layer 111a, the insulating layer 105 is provided over the insulating layer 103, and the conductive layer 115a is provided over the insulating layer 105. Thus, the parasitic capacitance formed by the conductive layer 111a and the conductive layer 115a is smaller than that in the case where the insulating layer provided between the conductive layer 111a and the conductive layer 115a is only the insulating layer 105, for example. In the region where the conductive layer 111b and the conductive layer 115a overlap with each other, the insulating layer 103 is provided over the conductive layer 111b, the insulating layer 105 is provided over the insulating layer 103, and the conductive layer 115a is provided over the insulating layer 105. Thus, the parasitic capacitance formed by the conductive layer 111b and the conductive layer 115a is smaller than that in the case where the insulating layer provided between the conductive layer 111b and the conductive layer 115a is only the insulating layer 105, for example. Accordingly, the time from when the scan line driver circuit 11 outputs a signal to the conductive layer 115a to when the signal is supplied to the pixel circuit 40A can be shortened. Thus, the display apparatus of one embodiment of the present invention can be driven at high speed.

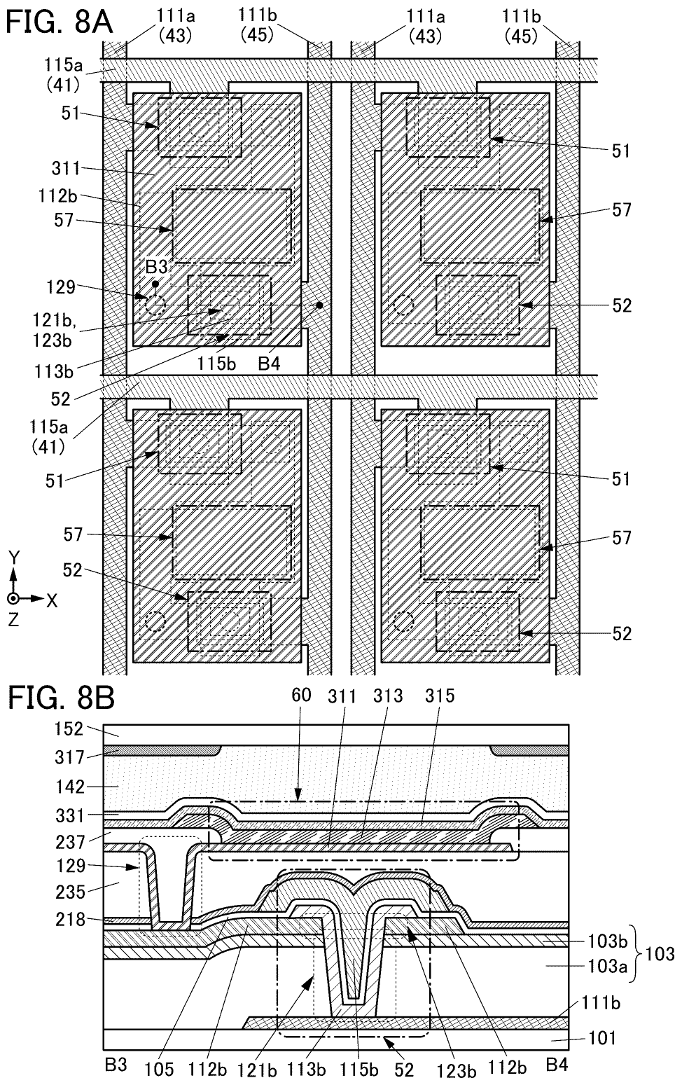

FIG. 8A illustrates a structure example where a pixel electrode 311 of the light-emitting element 60 is added to the plan view in FIG. 6. FIG. 8B is a cross-sectional view taken along the dashed-dotted line B3-B4 in FIG. 8A and illustrates a structure example of the transistor 52, for example. FIG. 8B also illustrates a structure example of layers above the transistor 52, for example. Note that some of the reference numerals illustrated in FIG. 6 are omitted in FIG. 8A.

An insulating layer 218 and an insulating layer 235 over the insulating layer 218 are provided to cover the transistor 51, the transistor 52, and the capacitor 57. The light-emitting element 60 is provided over the insulating layer 235, and a protective layer 331 is provided to cover the light-emitting element 60. A substrate 152 is attached onto the protective layer 331 with an adhesive layer 142.

The light-emitting element 60 includes the pixel electrode 311 over the insulating layer 235, an island-shaped layer 313 over the pixel electrode 311, and a common electrode 315 over the island-shaped layer 313. The layer 313 includes at least a light-emitting layer. Note that the layer 313 can be referred to as an EL layer. The common electrode is also referred to as a counter electrode.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

The insulating layer 105, the insulating layer 218, and the insulating layer 235 have an opening 129 reaching the conductive layer 112b. The pixel electrode 311 is provided to cover the opening 129. The pixel electrode 311 has a shape along the top surface and the side surface of the insulating layer 235, the side surface of the insulating layer 218, the side surface of the insulating layer 105, and the top surface of the conductive layer 112b. The pixel electrode 311 includes a region in contact with the top surface and the side surface of the insulating layer 235, the side surface of the insulating layer 218, the side surface of the insulating layer 105, and the top surface of the conductive layer 112b, for example. The pixel electrode 311 can be electrically connected to the conductive layer 112b in the opening 129.

An insulating layer 237 can be provided to cover the end portion of the top surface of the pixel electrode 311. The insulating layer 237 functions as a partition (also referred to as a bank or a spacer). Provision of the insulating layer 237 can prevent a contact between the pixel electrode 311 and the common electrode 315 to inhibit a short-circuit in the light-emitting element 60.

A depressed portion is formed in the pixel electrode 311 to cover the opening 129, and the insulating layer 237 is embedded in the depressed portion. For example, the insulating layer 237 covering the end portion of the top surface of the pixel electrode 311 and the opening 129 is formed, and then the layer 313 can be formed with a fine metal mask (FMM).

Note that the pixel electrode 311 may include a region overlapping with the region of the conductive layer 111a extending in the Y direction or a region overlapping with the region of the conductive layer 115a extending in the X direction. Thus, the aperture ratio of a pixel can be increased. By contrast, when the pixel electrode 311 does not include a region overlapping with the region of the conductive layer 111a extending in the Y direction or the region of the conductive layer 115a extending in the X direction, noise due to a signal supplied to the conductive layer 111a and noise due to a signal supplied to the conductive layer 115a can be inhibited from being transmitted to the pixel electrode 311.

A light-blocking layer 317 may be provided on the surface of the substrate 152 on the adhesive layer 142 side. The light-blocking layer 317 can be provided between the adjacent light-emitting elements 60. Provision of the light-blocking layer 317 can block light emitted from adjacent the subpixels 23. This can prevent color mixture. Note that a structure without the light-blocking layer 317 may be employed.

### Structure Example 2 of Pixel

A structure example of a pixel circuit whose structure is partly different from that in FIG. 6 and FIG. 7 is described below. Note that description of the same portions as those in FIG. 6 and FIG. 7 is omitted below in some cases.

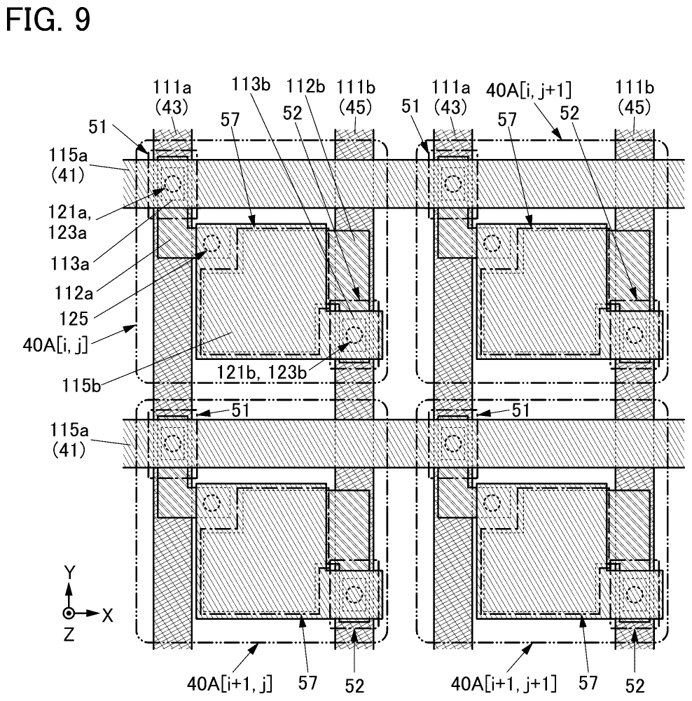

FIG. 9 is a plan view illustrating a structure example of the pixel circuit 40A, in which at least part of the transistor 51 is provided in a region where the wiring 41 and the wiring 43 overlap with each other, and at least part of the transistor 52 is provided in a region of the wiring 45 extending in the Y direction. Specifically, FIG. 9 illustrates an example in which the semiconductor layer 113a, the opening 121a, and the opening 123a are provided in the region where the wiring 41 and the wiring 43 overlap with each other, and the semiconductor layer 113b, the opening 121b, and the opening 123b are provided in the region of the wiring 45 extending in the Y direction. FIG. 9 illustrates an example in which the semiconductor layer 113a, the opening 121a, and the opening 123a overlap with the region of the conductive layer 111a extending in the Y direction and the region of the conductive layer 115a extending in the X direction. FIG. 9 illustrates an example in which the semiconductor layer 113b, the opening 121b, and the opening 123b overlap with the region of the conductive layer 111b extending in the Y direction.

When the pixel circuit 40A has the structure illustrated in FIG. 9, with the area of the capacitor 57 maintained, the pixel can be miniaturized as compared with the case where the pixel circuit 40A has the structure illustrated in FIG. 6. Meanwhile, when the pixel circuit 40A has the structure illustrated in FIG. 6, the layout flexibility of the pixel circuit 40A can be increased as compared with the case where the pixel circuit 40A has the structure illustrated in FIG. 9.

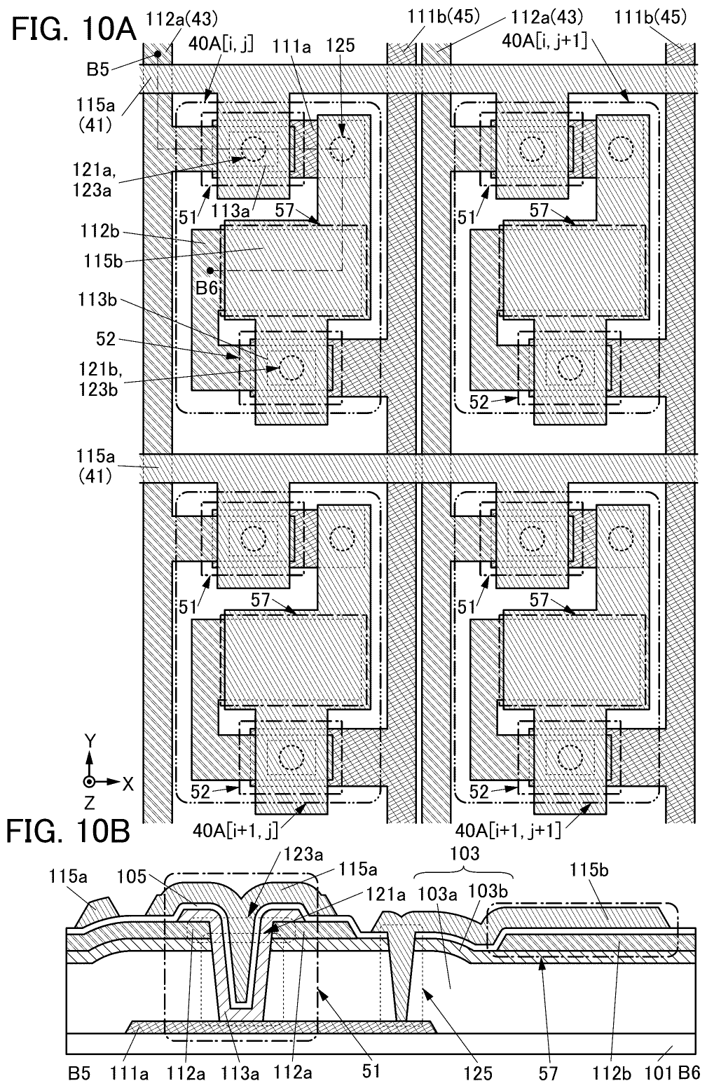

FIG. 10A is a plan view illustrating a structure example of the pixel circuit 40A, in which at least part of the conductive layer 112a functions as the wiring 43 functioning as a signal line. FIG. 10B is a cross-sectional view taken along the dashed-dotted line B5-B6 in FIG. 10A. In the example illustrated in FIG. 10A, the conductive layer 112a includes a region extending in the Y direction, and part of the region overlaps with the conductive layer 115a.

In the example illustrated in FIG. 10B, the opening 125 is provided in the insulating layer 103 and the insulating layer 105 to reach the conductive layer 111a. With the opening 125, the conductive layer 111a and the conductive layer 115b are electrically connected to each other. Specifically, the conductive layer 111a and the conductive layer 115b are in contact with each other in the opening 125, for example.

In the example illustrated in FIG. 10A, the wiring 43 and the wiring 45 are conductive layers provided in different layers. Thus, the distance between the wiring 43 and the wiring 45 can be shorter than that in the case where the wiring 43 and the wiring 45 are conductive layers provided in the same layer. Accordingly, the display apparatus of one embodiment of the present invention can be a high-definition display apparatus. By contrast, when the conductive layer 111a is used as the wiring 43 as illustrated in FIG. 6, parasitic capacitance formed in the region where the wiring 41 and the wiring 43 overlap with each other can be smaller than that in the structure illustrated in FIG. 10A.

Here, in the example illustrated in FIG. 10A, the distance in the plan view between the region of the conductive layer 111b extending in the Y direction and the region of the conductive layer 112a extending in the Y direction can be shorter than the width of the region of the conductive layer 111b extending in the Y direction and the width of the region of the conductive layer 112a extending in the Y direction, for example. In other words, the length in the X direction between the region of the conductive layer 111b extending in the Y direction and the region of the conductive layer 112a extending in the Y direction can be shorter than the length in the X direction of the region of the conductive layer 111b extending in the Y direction and the length in the X direction of the region of the conductive layer 112a extending in the Y direction.

In the example illustrated in FIG. 10A, for example, the distance in the plan view between the region of the conductive layer 111b extending in the Y direction and the region of the conductive layer 112a extending in the Y direction can be shorter than the distance between the conductive layer 111a and the conductive layer 111b or the distance between the conductive layer 112a and the conductive layer 112b. For example, the distance between the region of the conductive layer 111b extending in the Y direction and the region of the conductive layer 112a extending in the Y direction can be shorter than the shorter of the distances in the X direction and the Y direction between the conductive layer 111a and the conductive layer 111b, and can be shorter than the shorter of the distances in the X direction and the Y direction between the conductive layer 112a and the conductive layer 112b.

Note that in the example illustrated in FIG. 10A, a region where the conductive layer 111b and the conductive layer 112a overlap with each other may be included. In this case, the distance between the conductive layer 111b and the conductive layer 112a in the plan view can be regarded as 0.

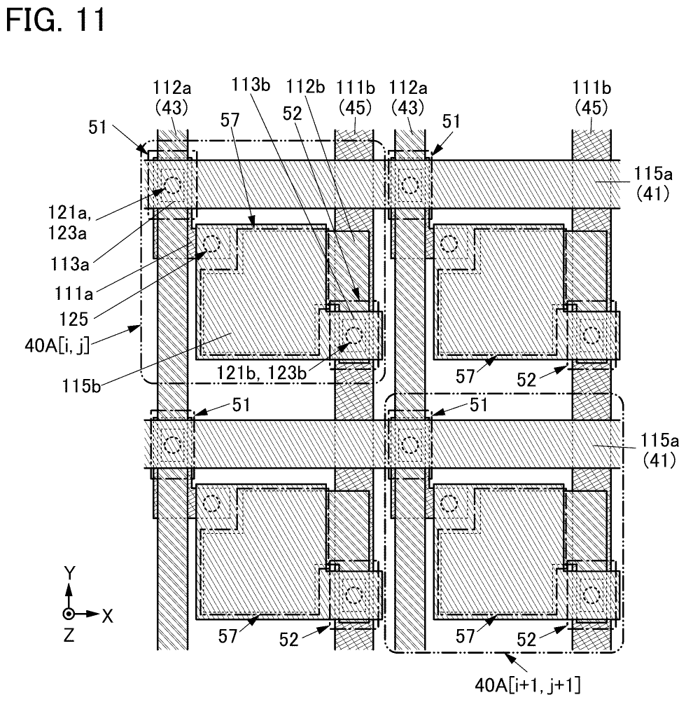

FIG. 11 illustrates a variation example of the structure illustrated in FIG. 10A, in which at least part of the transistor 51 is provided in the region where the wiring 41 and the wiring 43 overlap with each other, and at least part of the transistor 52 is provided in the region of the wiring 45 extending in the Y direction. Specifically, FIG. 11 illustrates an example in which the semiconductor layer 113a, the opening 121a, and the opening 123a are provided in the region where the wiring 41 and the wiring 43 overlap with each other, and the semiconductor layer 113b, the opening 121b, and the opening 123b are provided in the region of the wiring 45 extending in the Y direction. FIG. 11 illustrates an example in which the semiconductor layer 113a, the opening 121a, and the opening 123a overlap with the region of the conductive layer 112a extending in the Y direction and the region of the conductive layer 115a extending in the X direction. FIG. 11 illustrates an example in which the semiconductor layer 113b, the opening 121b, and the opening 123b overlap with the region of the conductive layer 111b extending in the Y direction.

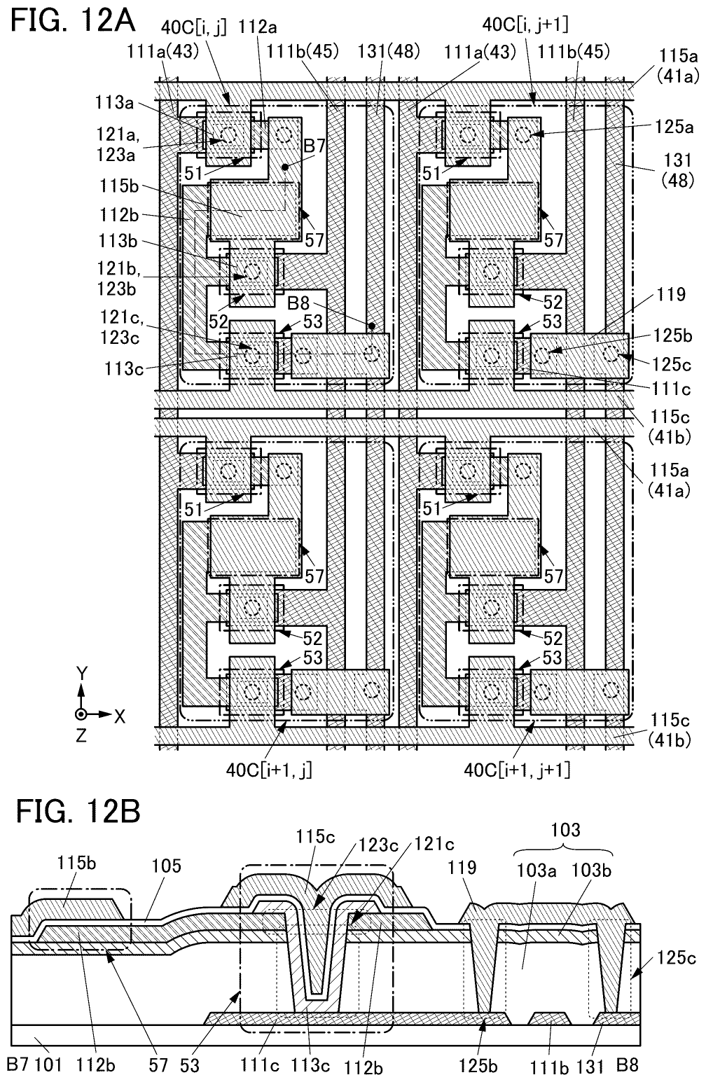

FIG. 12A is a plan view illustrating the structure example of the pixel circuit 40C illustrated in FIG. 2B. FIG. 12B is a cross-sectional view taken along the dashed-dotted line B7-B8 in FIG. 12A and illustrates a structure example of the transistor 53 and the capacitor 57.

In the example illustrated in FIG. 12A and FIG. 12B, the structure of the transistor 53 in addition to the structure of the transistor 51 and the transistor 52 are similar to that illustrated in FIG. 4A1 and FIG. 4B. Here, the conductive layer 111, the conductive layer 112, the semiconductor layer 113, and the conductive layer 115 included in the transistor 53 are referred to as a conductive layer 111c, the conductive layer 112b, a semiconductor layer 113c, and a conductive layer 115c, respectively. The opening 121 and the opening 123 provided in the transistor 53 are referred to as an opening 121c and an opening 123c, respectively.

The conductive layer 111c functions as one of a source electrode and a drain electrode of the transistor 53, and the conductive layer 112b functions as the other of the source electrode and the drain electrode of the transistor 53. Here, FIG. 12A illustrates an example in which the same conductive layer 112b is used as the other of the source electrode and the drain electrode of the transistor 52, the other of the source electrode and the drain electrode of the transistor 53, and the other electrode of the capacitor 57.

Although not illustrated in FIG. 12B, the insulating layer 105 includes an opening 125a reaching the conductive layer 112a, and the conductive layer 112a and the conductive layer 115b are electrically connected to each other through the opening 125a. Specifically, the conductive layer 112a and the conductive layer 115b are in contact with each other in the opening 125a, for example.

In the example illustrated in FIG. 12A and FIG. 12B, the conductive layer 115a functions as the wiring 41a, and at least part of the conductive layer 115c functions as the wiring 41b. A conductive layer 131 is illustrated as the wiring 48, and the conductive layer 131 is electrically connected to the reference potential generation circuit 17 illustrated in FIG. 2A.

The insulating layer 103 and the insulating layer 105 have an opening 125b reaching the conductive layer 111c and an opening 125c reaching the conductive layer 131. The conductive layer 111c and a conductive layer 119 are electrically connected to each other through the opening 125b, and the conductive layer 131 and the conductive layer 119 are electrically connected to each other through the opening 125c. Specifically, for example, the conductive layer 111c and the conductive layer 119 are in contact with each other in the opening 125b, and the conductive layer 131 and the conductive layer 119 are in contact with each other in the opening 125c. In the above manner, the conductive layer 111c and the conductive layer 131 can be electrically connected to each other through the conductive layer 119. When the conductive layer 111c and the conductive layer 131 are electrically connected to each other through the conductive layer 119, a short circuit between the conductive layer 111c and the conductive layer 111b due to contact can be prevented.

The conductive layer 131 and the conductive layer 111 can be provided in the same layer, and the conductive layer 119 and the conductive layer 115 can be provided in the same layer. Thus, the conductive layer 131 and the conductive layer 111 can be formed using the same material and in the same step. The conductive layer 119 and the conductive layer 115 can be formed using the same material and in the same step. For example, the conductive layer 111 and the conductive layer 131 can be formed by processing the same conductive film, and the conductive layer 115 and the conductive layer 119 can be formed by processing the same conductive film.

Although the shape of the opening 125a, the opening 125b, and the opening 125c in the plan view are circular in FIG. 12A, one embodiment of the present invention is not limited thereto, and the opening 125a, the opening 125b, and the opening 125c can have a shape similar to the shape that the opening 121 or the opening 123 can have.

The conductive layer 115a and the conductive layer 115c each include a region extending in the X direction. The conductive layer 131 includes a region extending in the Y direction. The conductive layer 115a and the conductive layer 115c each include a region overlapping with the conductive layer 131 in addition to a region overlapping with the conductive layer 111a and a region overlapping with the conductive layer 111b. Specifically, parts of the region of the conductive layer 115a extending in the X direction overlap with the respective parts of the regions of the conductive layer 111a, the conductive layer 111b, and the conductive layer 131 extending in the Y direction. Parts of the region of the conductive layer 115c extending in the X direction overlap with the respective parts of regions of the conductive layer 111a, the conductive layer 111b, and the conductive layer 131 extending in the Y direction.

Here, it can be said that the region of the conductive layer 115a extending in the X direction functions as the wiring 41a, or the whole conductive layer 115a functions as the wiring 41a. It can be said that the region of the conductive layer 115c extending in the X direction functions as the wiring 41b or the whole conductive layer 115c functions as the wiring 41b. Furthermore, it can be said that the region of the conductive layer 131 extending in the Y direction functions as the wiring 48 or the whole conductive layer 131 functions as the wiring 48. Unless otherwise specified, the same applies to other conductive layers including regions functioning as the wiring 41a, the wiring 41b, or the wiring 48.

In the example illustrated in FIG. 12A, the conductive layer 111a, the conductive layer 111b, and the conductive layer 131 each include a region overlapping with the conductive layer 115a with the insulating layer 103 and the insulating layer 105 therebetween. The conductive layer 111a, the conductive layer 111b, and the conductive layer 131 each include a region overlapping with the conductive layer 115b with the insulating layer 103 and the insulating layer 105 therebetween. Thus, the parasitic capacitance of the conductive layer 115a and the conductive layer 115b is smaller than that in the case where the insulating layer provided between the conductive layer 115a and the conductive layer 111a, the conductive layer 111b, and the conductive layer 131, and the insulating layer provided between the conductive layer 115b and the conductive layer 111a, the conductive layer 111b, and the conductive layer 131 are each only the insulating layer 105. Accordingly, the time from when the scan line driver circuit 11 outputs a signal to the conductive layer 115a or the conductive layer 115b to when the signal is supplied to the pixel circuit 40C can be shortened. Thus, the display apparatus of one embodiment of the present invention can be driven at high speed.

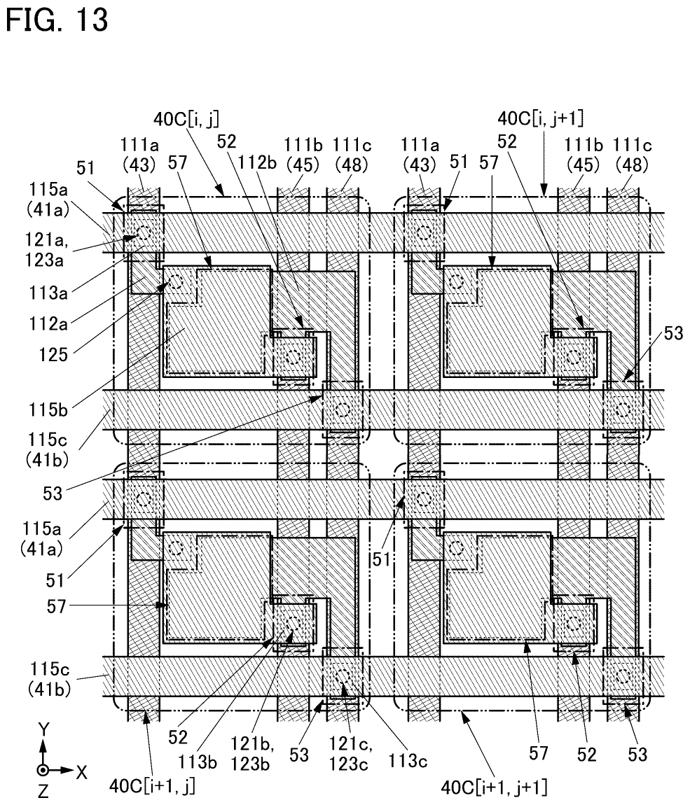

FIG. 13 is a variation example of the structure illustrated in FIG. 12A, in which at least part of the transistor 51 is provided in the region where the wiring 41a and the wiring 43 overlap with each other. In addition, an example in which at least part of the transistor 52 is provided in the region of the wiring 45 extending in the Y direction is illustrated. Furthermore, an example in which at least part of the transistor 53 is provided in a region where the wiring 41b and the wiring 48 overlap with each other is illustrated. Specifically, FIG. 13 illustrates an example in which the semiconductor layer 113a, the opening 121a, and the opening 123a are provided in the region where the wiring 41a and the wiring 43 overlap with each other. FIG. 13 illustrates an example in which the semiconductor layer 113b, the opening 121b, and the opening 123b are provided in the region of the wiring 45 extending in the Y direction. FIG. 13 illustrates an example in which the semiconductor layer 113c, the opening 121c, and the opening 123c are provided in the region where the wiring 41b and the wiring 48 overlap with each other. FIG. 13 illustrates an example in which the semiconductor layer 113a, the opening 121a, and the opening 123a overlap with the region of the conductive layer 111a extending in the Y direction and the region of the conductive layer 115a extending in the X direction. FIG. 13 illustrates an example in which the semiconductor layer 113b, the opening 121b, and the opening 123b overlap with the region of the conductive layer 111b extending in the Y direction. FIG. 13 illustrates an example in which the semiconductor layer 113c, the opening 121c, and the opening 123c overlap with a region of the conductive layer 111c extending in the Y direction and the region of the conductive layer 115c extending in the X direction.

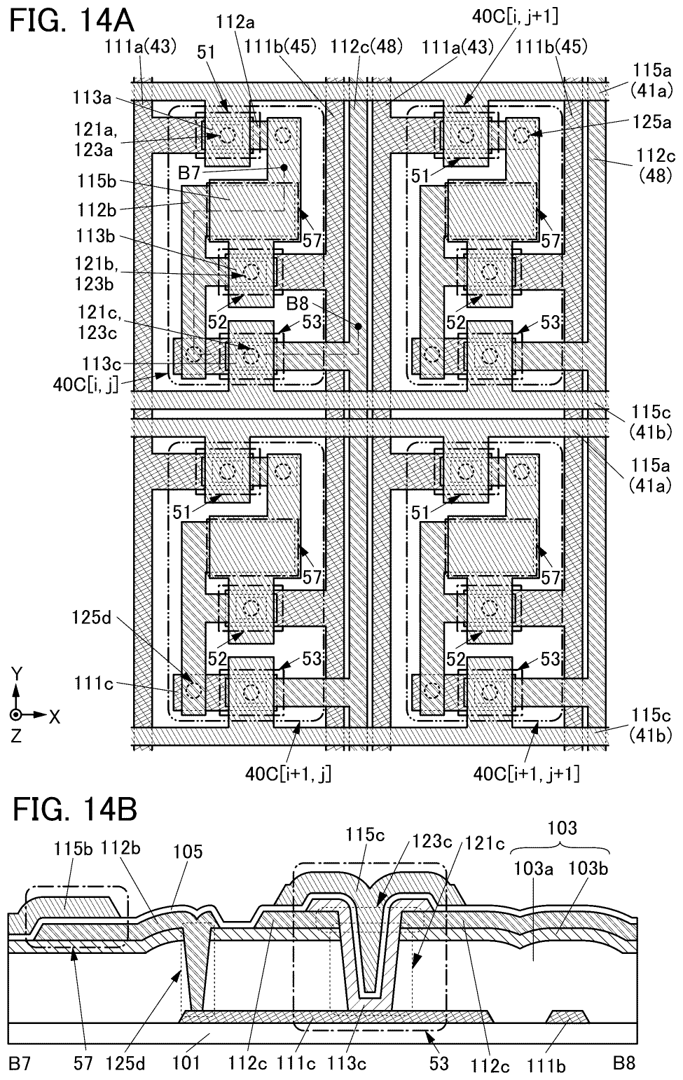

FIG. 14A is a plan view illustrating a structure example of the pixel circuit 40C, in which a conductive layer 112c functioning as the other of the source electrode and the drain electrode of the transistor 53 is provided and at least part of the conductive layer 112c functions as the wiring 48. FIG. 14B is a cross-sectional view taken along the dashed-dotted line B7-B8 in FIG. 14A. In the example illustrated in FIG. 14A, the conductive layer 112c includes a region extending in the Y direction, and parts of the region overlap with the conductive layer 115a and the conductive layer 115c, respectively.

In the example illustrated in FIG. 14B, an opening 125d reaching the conductive layer 111c is provided in the insulating layer 103, and the conductive layer 111c and the conductive layer 112b are electrically connected to each other through the opening 125d. Specifically, the conductive layer 111c and the conductive layer 112b are in contact with each other in the opening 125d, for example.

Although the shape of the opening 125d in the plan view is circular in FIG. 14A, one embodiment of the present invention is not limited thereto, and the opening 125d can have a shape similar to the shape that the opening 121 or the opening 123 can have.

In the example illustrated in FIG. 14A, the wiring 48 is a conductive layer provided in a layer different from the wiring 43 and the wiring 45. Accordingly, the distance between the wiring 43 and the wiring 48 and the distance between the wiring 45 and the wiring 48 can be shorter than those in the case where the wiring 48 is a conductive layer provided in the same layer as the wiring 43 and the wiring 45. Accordingly, the display apparatus of one embodiment of the present invention can be a high-definition display apparatus. By contrast, as illustrated in FIG. 12A, by using the conductive layer 131 which is provided in the same layer as the conductive layer 111 as the wiring 48, parasitic capacitance formed in the region where the wiring 41a and the wiring 48 overlap with each other and parasitic capacitance formed in the region where the wiring 41b and the wiring 48 overlap with each other can be smaller than those in the structure illustrated in FIG. 14A.

Here, in the example illustrated in FIG. 14A, the distance in the plan view between the region of the conductive layer 111b extending in the Y direction and the region of the conductive layer 112c extending in the Y direction can be shorter than the width of the region of the conductive layer 111b extending in the Y direction and the width of the region of the conductive layer 112c extending in the Y direction, for example. In other words, the length in the X direction between the region of the conductive layer 111b extending in the Y direction and the region of the conductive layer 112c extending in the Y direction can be shorter than the length in the X direction of the region of the conductive layer 111b extending in the Y direction and the length in the X direction of the region of the conductive layer 112c extending in the Y direction.

Similarly, for example, the distance in the plan view between the region of the conductive layer 111a extending in the Y direction and the region of the conductive layer 112c extending in the Y direction can be shorter than the width of the region of the conductive layer 111a extending in the Y direction and the width of the region of the conductive layer 112c extending in the Y direction. In other words, the length in the X direction between the region of the conductive layer 111a extending in the Y direction and the region of the conductive layer 112c extending in the Y direction can be shorter than the length in the X direction of the region of the conductive layer 111a extending in the Y direction and the length in the X direction of the region of the conductive layer 112c extending in the Y direction.

In the example illustrated in FIG. 14A, for example, the distance in the plan view between the region of the conductive layer 111b extending in the Y direction and the region of the conductive layer 112c extending in the Y direction can be shorter than the distance between the conductive layer 111a and the conductive layer 111b, can be shorter than the distance between the conductive layer 111b and the conductive layer 111c, can be shorter than the distance between the conductive layer 112a and the conductive layer 112b, and can be shorter than the distance between the conductive layer 112b and the conductive layer 112c. For example, the distance between the region of the conductive layer 111b extending in the Y direction and the region of the conductive layer 112c extending in the Y direction can be shorter than the shorter of the distances in the X direction and the Y direction between the conductive layer 111a and the conductive layer 111b, can be shorter than the shorter of the distances in the X direction and the Y direction between the conductive layer 111b and the conductive layer 111c, can be shorter than the shorter of the distances in the X direction and the Y direction between the conductive layer 112a and the conductive layer 112b, and can be shorter than the shorter of the distances in the X direction and the Y direction between the conductive layer 112b and the conductive layer 112c.

Similarly, for example, the distance in the plan view between the region of the conductive layer 111a extending in the Y direction and the region of the conductive layer 112c extending in the Y direction can be shorter than the distance between the conductive layer 111a and the conductive layer 111b, can be shorter than the distance between the conductive layer 111b and the conductive layer 111c, can be shorter than the distance between the conductive layer 112a and the conductive layer 112b, and can be shorter than the distance between the conductive layer 112b and the conductive layer 112c. For example, the distance between the region of the conductive layer 111a extending in the Y direction and the region of the conductive layer 112c extending in the Y direction can be shorter than the shorter of the distances in the X direction and the Y direction between the conductive layer 111a and the conductive layer 111b, can be shorter than the shorter of the distances in the X direction and the Y direction between the conductive layer 111b and the conductive layer 111c, can be shorter than the shorter of the distances in the X direction and the Y direction between the conductive layer 112a and the conductive layer 112b, and can be shorter than the shorter of the distances in the X direction and the Y direction between the conductive layer 112b and the conductive layer 112c.

Note that in the example illustrated in FIG. 14A, the conductive layer 111b and the conductive layer 112c may overlap with each other in a region. In this case, the distance between the conductive layer 111b and the conductive layer 112c in the plan view can be regarded as 0. Similarly, the conductive layer 111a and the conductive layer 112c may overlap with each other in a region. In this case, the distance between the conductive layer 111a and the conductive layer 112c in the plan view can be regarded as 0.

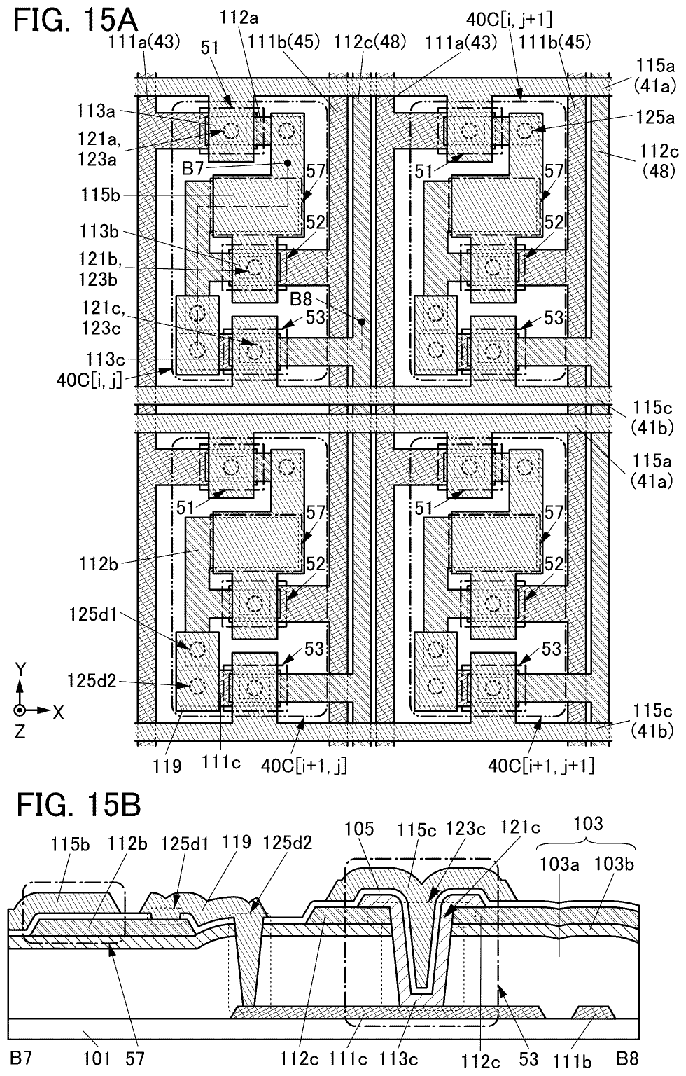

FIG. 15A is a variation example of the structure illustrated in FIG. 14A, in which the conductive layer 112b and the conductive layer 111c are electrically connected to each other through the conductive layer 119 provided in the same layer as the conductive layer 115. FIG. 15B is a cross-sectional view taken along the dashed-dotted line B7-B8 in FIG. 15A, and illustrates a structure example of the transistor 53 and the capacitor 57.

In the example illustrated in FIG. 15B, an opening 125d1 reaching the conductive layer 112b is provided in the insulating layer 105, and the conductive layer 112b and the conductive layer 119 are electrically connected to each other through the opening 125d1. Specifically, for example, the conductive layer 112b and the conductive layer 119 are in contact with each other in the opening 125d1. An opening 125d2 reaching the conductive layer 111c is provided in the insulating layer 103 and the insulating layer 105, and the conductive layer 111c and the conductive layer 119 are electrically connected to each other through the opening 125d2. Specifically, the conductive layer 111c and the conductive layer 119 are in contact with each other in the opening 125d2, for example.

In the above manner, the conductive layer 112b and the conductive layer 111c can be electrically connected to each other through the conductive layer 119. When the display apparatus of one embodiment of the present invention has such a structure, the opening 125d (the opening 125d1 and the opening 125d2) can be formed in the same step as the opening 125a.

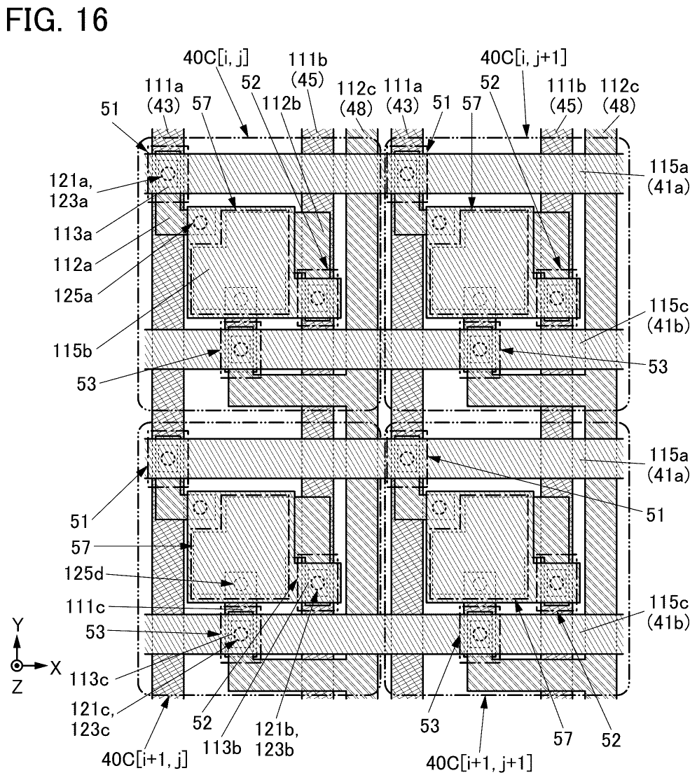

FIG. 16 is a variation example of the structure illustrated in FIG. 14A, in which at least part of the transistor 51 is provided in the region where the wiring 41a and the wiring 43 overlap with each other. In addition, an example in which at least part of the transistor 52 is provided in the region of the wiring 45 extending in the Y direction is illustrated. Furthermore, an example in which at least part of the transistor 53 is provided in the region of the wiring 41b extending in the X direction is illustrated. Specifically, FIG. 16 illustrates an example in which the semiconductor layer 113a, the opening 121a, and the opening 123a are provided in the region where the wiring 41 and the wiring 43 overlap with each other. FIG. 16 illustrates an example in which the semiconductor layer 113b, the opening 121b, and the opening 123b are provided in the region of the wiring 45 extending in the Y direction. FIG. 16 illustrates an example in which the semiconductor layer 113c, the opening 121c, and the opening 123c are provided in the region of the wiring 41b extending in the X direction. FIG. 16 illustrates an example in which the semiconductor layer 113a, the opening 121a, and the opening 123a overlap with the region of the conductive layer 111a extending in the Y direction and the region of the conductive layer 115a extending in the X direction. FIG. 16 illustrates an example in which the semiconductor layer 113b, the opening 121b, and the opening 123b overlap with the region of the conductive layer 111b extending in the Y direction. FIG. 16 illustrates an example in which the semiconductor layer 113c, the opening 121c, and the opening 123c overlap with the region of the conductive layer 115c extending in the X direction. FIG. 16 illustrates an example in which the opening 125d overlaps with the conductive layer 115b.

When the pixel circuit 40C has the structure illustrated in FIG. 16, for example, the pixel can be miniaturized while the area of the capacitor 57 is ensured as compared with the case where the pixel circuit 40C has the structure illustrated in FIG. 14A. Meanwhile, when the pixel circuit 40C has the structure illustrated in FIG. 14A, the layout flexibility of the pixel circuit 40C can be increased as compared with the case where the pixel circuit 40C has the structure illustrated in FIG. 16.

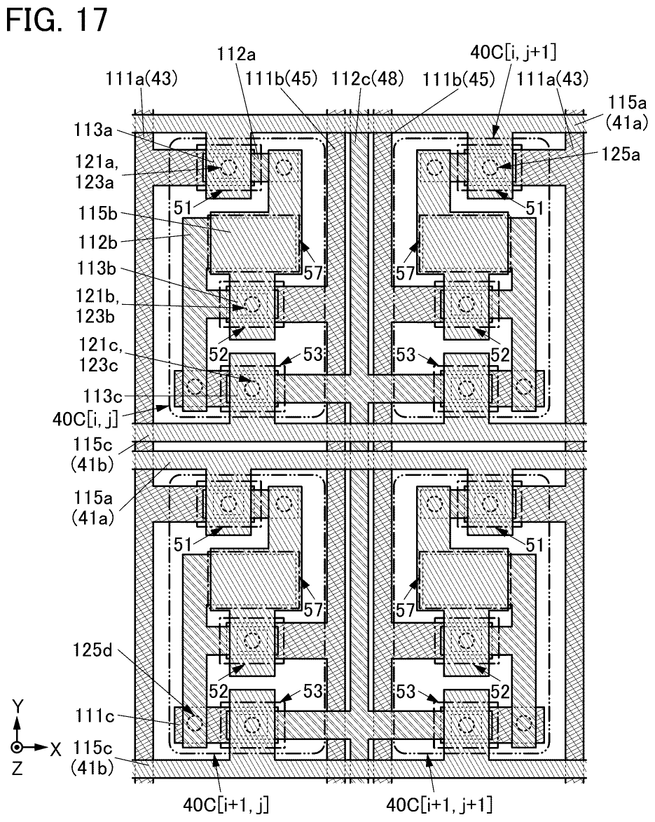

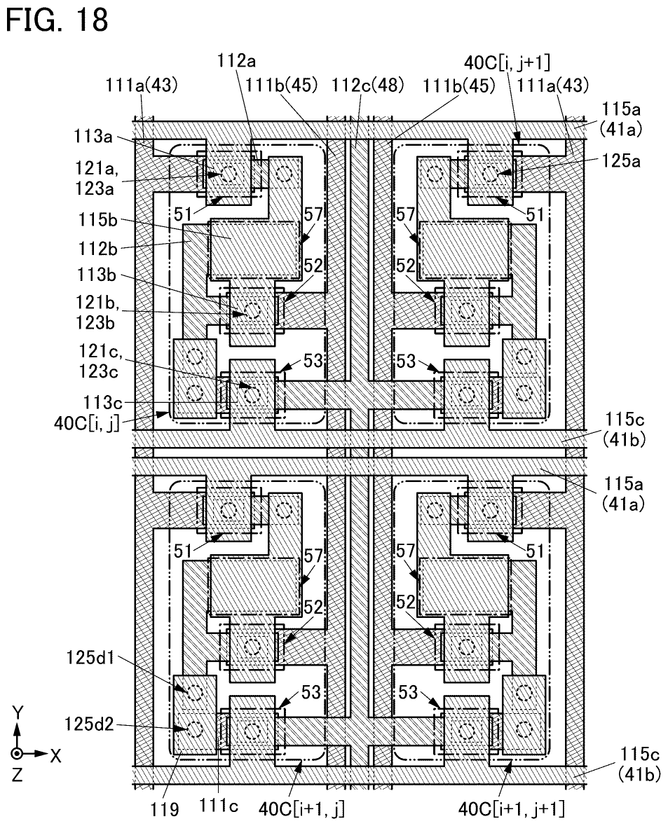

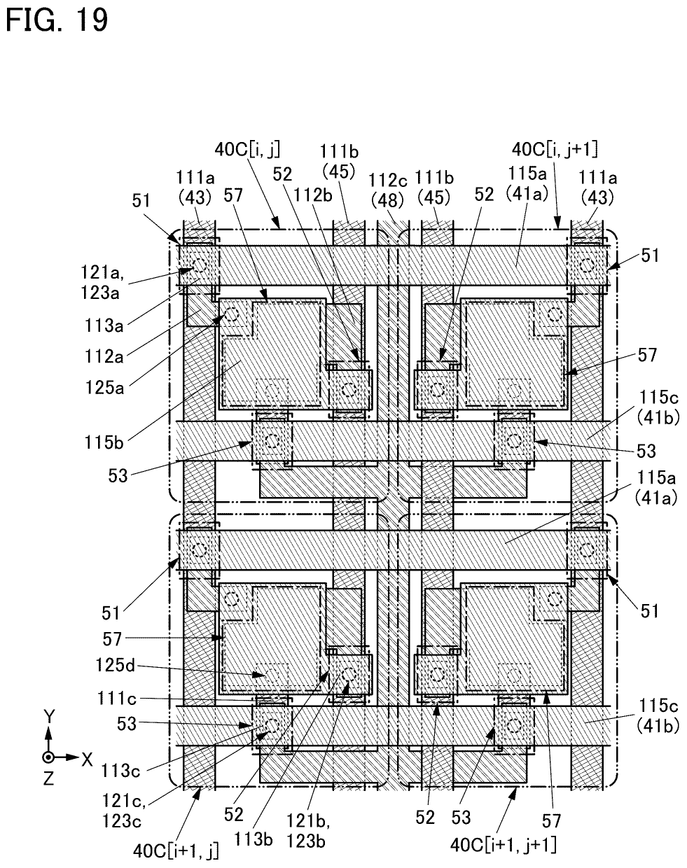

FIG. 17, FIG. 18, and FIG. 19 are variation examples of the structures illustrated in FIG. 14A, FIG. 15A, and FIG. 16, respectively, and each illustrate an example in which the conductive layer 112c is shared by adjacent two-column pixel circuits 40C. FIG. 17, FIG. 18, and FIG. 19 each illustrate an example in which the conductive layer 112c is shared by the pixel circuit 40C in the j-th column and the pixel circuit 40C in the j+1-th column. FIG. 17, FIG. 18, and FIG. 19 each illustrate an example in which the region of the conductive layer 112c extending in the Y direction is provided between the region of the conductive layer 112b which extends in the Y direction and is electrically connected to the transistor 52 provided in the pixel circuit 40C in the j-th column and the region of the conductive layer 111b which extends in the Y direction and is electrically connected to the pixel circuit 40C in the j+1-th column.

In the examples illustrated in FIG. 17, FIG. 18, and FIG. 19, the number of conductive layers 112c provided in the display apparatus of one embodiment of the present invention can be smaller than that in the examples illustrated in FIG. 14A, FIG. 15A, and FIG. 16; thus, the display apparatus can achieve high definition. Meanwhile, in the examples illustrated in FIG. 14A, FIG. 15A, and FIG. 16, the load on the conductive layer 112c can be smaller than that in the examples illustrated in FIG. 17, FIG. 18, and FIG. 19. Thus, the display apparatus driven at high speed can be achieved.

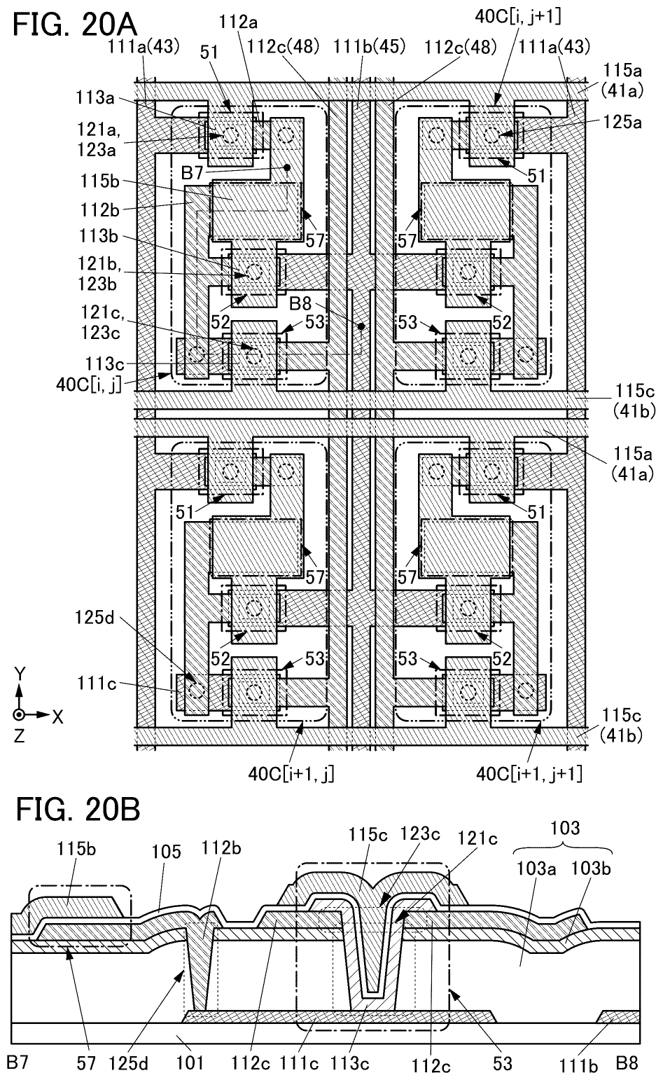

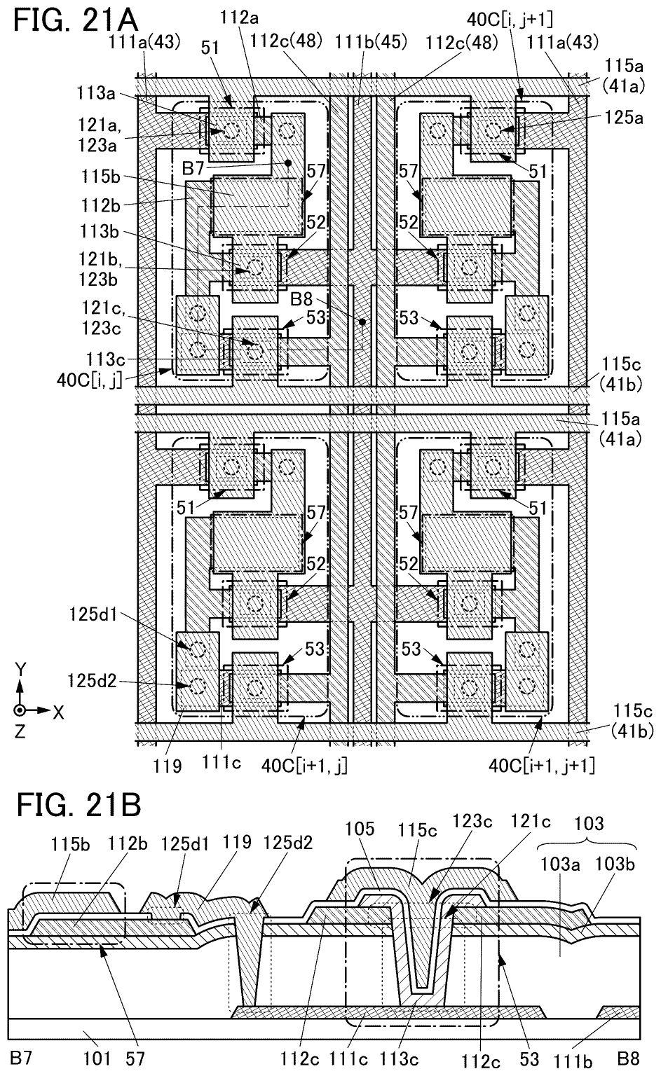

FIG. 20A, FIG. 20B, FIG. 21A, and FIG. 21B are variation examples of the structures illustrated in FIG. 14A, FIG. 14B, FIG. 15A, and FIG. 15B, respectively, and each illustrate an example in which the conductive layer 111b is shared by adjacent two-column pixel circuits 40C. FIG. 20A and FIG. 21A each illustrate an example in which the conductive layer 111b is shared by the pixel circuit 40C in the j-th column and the pixel circuit 40C in the j+1-th column. FIG. 20A and FIG. 21A each illustrate an example in which the region of the conductive layer 111b extending in the Y direction is provided between the region of the conductive layer 112c which extends in the Y direction and is electrically connected to the transistor 53 provided in the pixel circuit 40C in the j-th column and the region of the conductive layer 112c which extends in the Y direction and is electrically connected to the pixel circuit 40C in the j+1-th column.

In the examples illustrated in FIG. 20A, FIG. 20B, FIG. 21A, and FIG. 21B, the number of conductive layers 111b provided in the display apparatus of one embodiment of the present invention can be smaller than that in the examples illustrated in FIG. 14A, FIG. 14B, FIG. 15A, and FIG. 15B; thus, the display apparatus can achieve high definition. Meanwhile, in the examples illustrated in FIG. 14A, FIG. 14B, FIG. 15A, and FIG. 15B, the load on the conductive layer 111b can be smaller than that in the examples illustrated in FIG. 20A, FIG. 20B, FIG. 21A, and FIG. 21B. Thus, the display apparatus driven at high speed can be achieved.

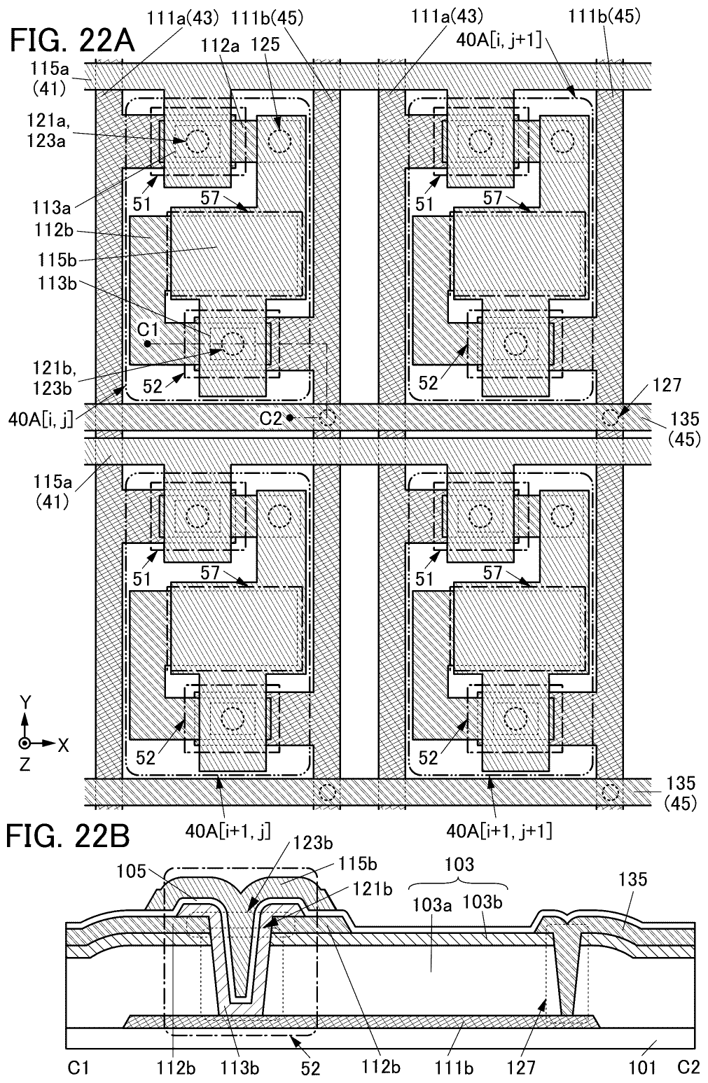

FIG. 22A is a variation example of the structure illustrated in FIG. 6, in which a conductive layer 135 is provided. FIG. 22A illustrates a structure example of the pixel circuit 40A. FIG. 22B is a cross-sectional view taken along the dashed-dotted line C1-C2 in FIG. 22A and illustrates a structure example of the transistor 52.

The conductive layer 135 includes a region extending in the X direction and includes a region overlapping with the conductive layer 111a and a region overlapping with the conductive layer 111b. The conductive layer 135 can be provided in the same layer as the conductive layer 112. Thus, the conductive layer 135 and the conductive layer 112 can be formed using the same material and in the same step. For example, the conductive layer 112 and the conductive layer 135 can be formed by processing the same conductive film.

In the example illustrated in FIG. 22B, an opening 127 reaching the conductive layer 111b is provided in the insulating layer 103, and the conductive layer 111b and the conductive layer 135 are electrically connected to each other through the opening 127. Specifically, the conductive layer 111b and the conductive layer 135 are in contact with each other in the opening 127, for example.

Although the shape of the opening 127 in the plan view is circular in FIG. 22A, one embodiment of the present invention is not limited thereto, and the opening 127 can have a shape similar to the shape that the opening 121, the opening 123, or the opening 125 can have.

With the structure illustrated in FIG. 22A, not only the conductive layer 111b including the region extending in the Y direction but also the conductive layer 135 including the region extending in the X direction function as the wiring 45 functioning as a power supply line in the display apparatus of one embodiment of the present invention. Thus, the power supply circuit 15 illustrated in FIG. 1A can supply a power supply potential to the transistor 52 not only through the conductive layer 111b but also through the conductive layer 135. Thus, a power supply potential generated by the power supply circuit 15 can be inhibited from being dropped before supplied to the pixel circuit 40A. In particular, a power supply potential generated by the power supply circuit 15 can be suitably inhibited from being dropped before supplied to the pixel circuit 40A whose wiring distance from the power supply circuit 15 is long.

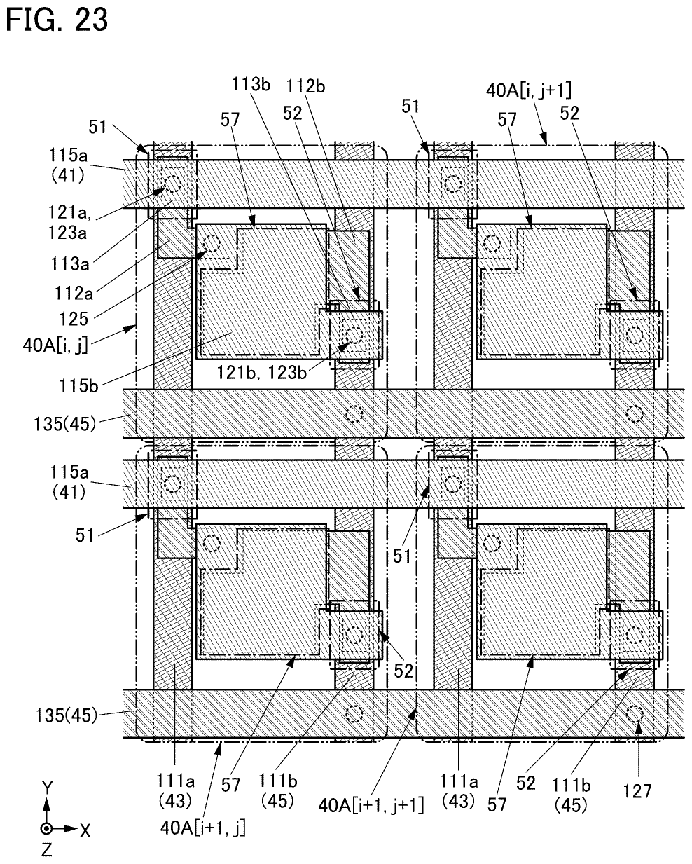

FIG. 23 is a variation example of the structure illustrated in FIG. 22A, in which at least part of the transistor 51 is provided in the region where the wiring 41 and the wiring 43 overlap with each other, and at least part of the transistor 52 is provided in the region of the wiring 45 extending in the Y direction.

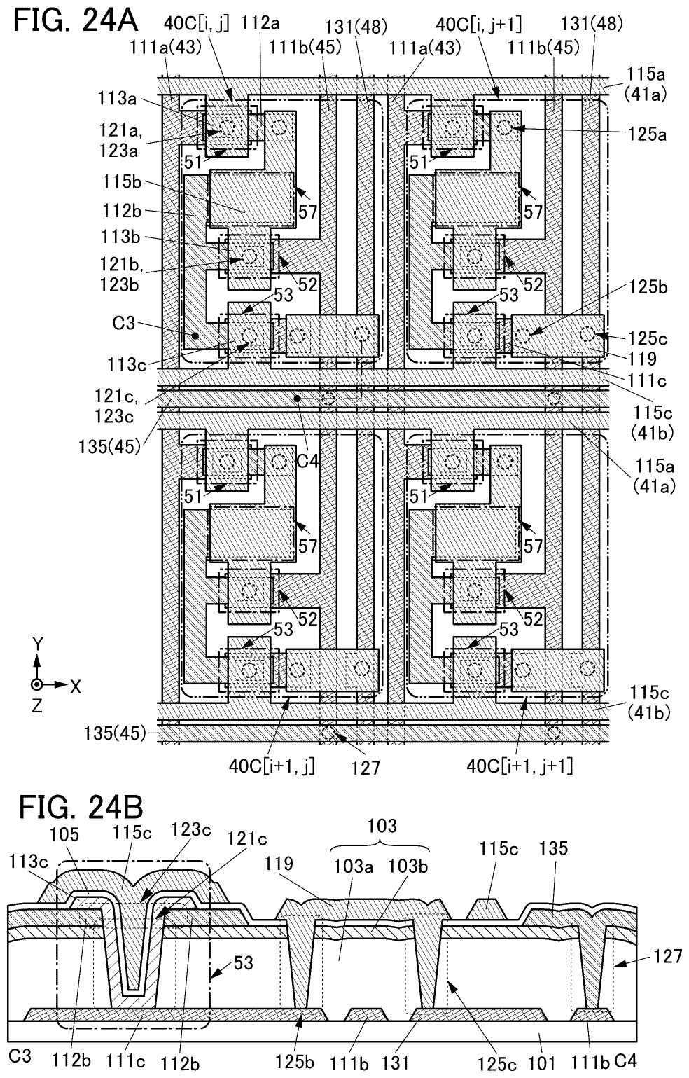

FIG. 24A is a variation example of the structure illustrated in FIG. 12A, in which the conductive layer 135 is provided. FIG. 24A illustrates a structure example of the pixel circuit 40C. FIG. 24B is a cross-sectional view taken along the dashed-dotted line C3-C4 in FIG. 24A and illustrates a structure example of the transistor 53.

The conductive layer 135 includes a region extending in the X direction and includes a region overlapping with the conductive layer 111a, a region overlapping with the conductive layer 111b, and a region overlapping with the conductive layer 131. As described above, the conductive layer 135 can be provided in the same layer as the conductive layer 112.

In the example illustrated in FIG. 24B, as in the example illustrated in FIG. 22B, the opening 127 reaching the conductive layer 111b is provided in the insulating layer 103, and the conductive layer 111b and the conductive layer 135 are electrically connected to each other through the opening 127. Specifically, the conductive layer 111b and the conductive layer 135 are in contact with each other in the opening 127, for example.

With the structure illustrated in FIG. 24A, a power supply potential generated by the power supply circuit 15 illustrated in FIG. 2A can be inhibited from being dropped before supplied to the pixel circuit 40C in the display apparatus of one embodiment of the present invention. In particular, a power supply potential generated by the power supply circuit 15 can be suitably inhibited from being dropped before supplied to the pixel circuit 40C whose wiring distance from the power supply circuit 15 is long.

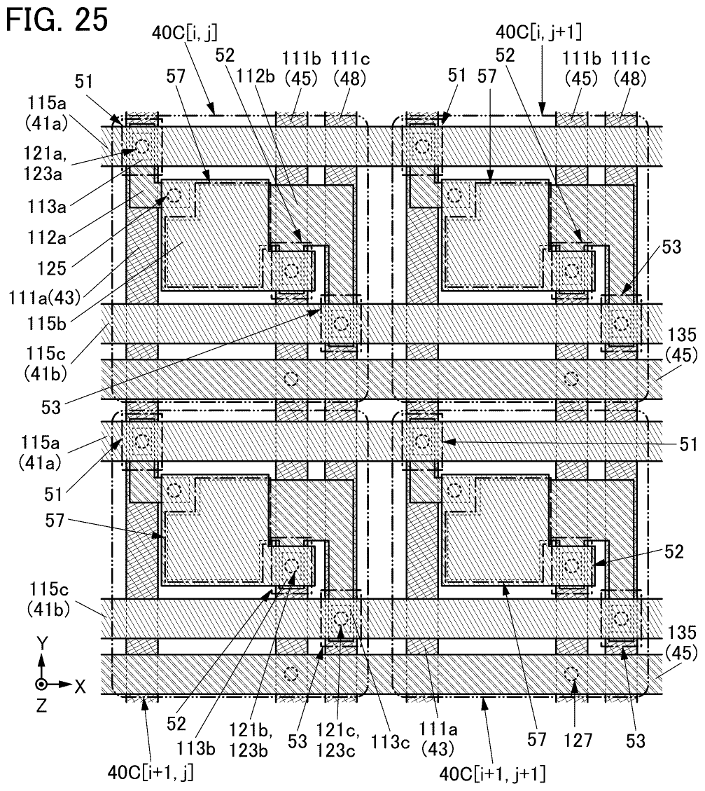

FIG. 25 is a variation example of the structure illustrated in FIG. 24A, in which at least part of the transistor 51 is provided in a region where the wiring 41a and the wiring 43 overlap with each other. In addition, an example in which at least part of the transistor 52 is provided in the region of the wiring 45 extending in the Y direction is illustrated. Furthermore, an example in which at least part of the transistor 53 is provided in a region where the wiring 41b and the wiring 48 overlap with each other is illustrated.

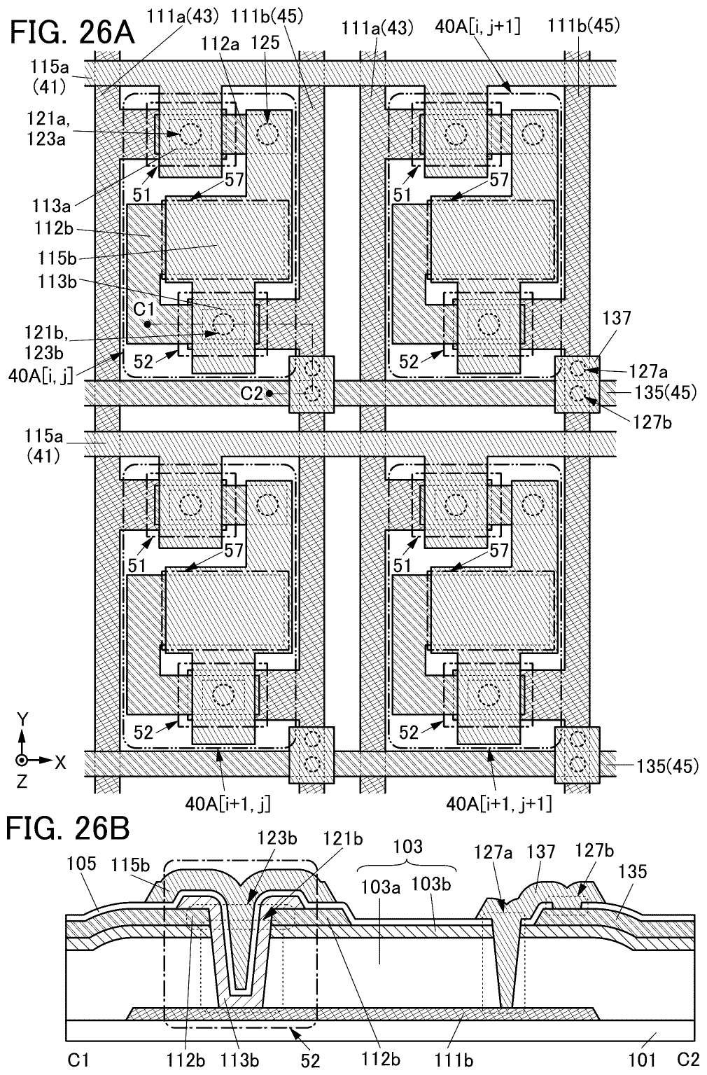

FIG. 26A is a variation example of the structure illustrated in FIG. 22A, in which the conductive layer 111b and the conductive layer 135 are electrically connected to each other through a conductive layer 137 provided in the same layer as the conductive layer 115. FIG. 26A illustrates a structure example of the pixel circuit 40A. FIG. 26B is a cross-sectional view taken along the dashed-dotted line C1-C2 in FIG. 26A and illustrates a structure example of the transistor 52.

In the example illustrated in FIG. 26B, an opening 127a reaching the conductive layer 111b is provided in the insulating layer 103 and the insulating layer 105, and the conductive layer 111b and the conductive layer 137 are electrically connected to each other through the opening 127a. Specifically, the conductive layer 111b and the conductive layer 137 are in contact with each other in the opening 127a, for example. An opening 127b reaching the conductive layer 135 is provided in the insulating layer 105, and the conductive layer 135 and the conductive layer 137 are electrically connected to each other through the opening 127b. Specifically, the conductive layer 135 and the conductive layer 137 are in contact with each other in the opening 127b, for example.

In the above manner, the conductive layer 111b and the conductive layer 135 can be electrically connected to each other through the conductive layer 137. When the display apparatus of one embodiment of the present invention has such a structure, the opening 127 (the opening 127a and the opening 127b) can be formed in the same step as the opening 125.

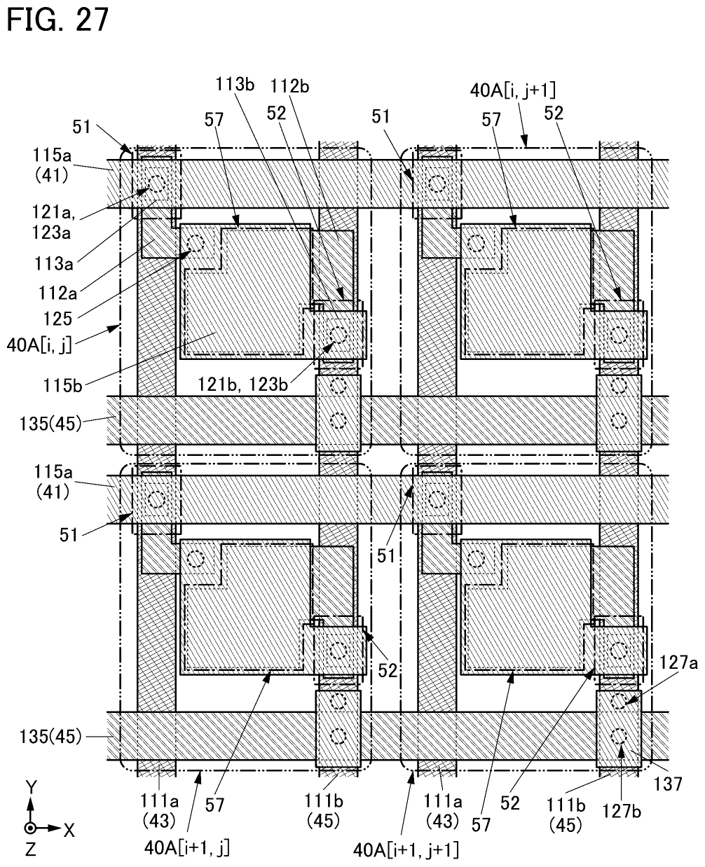

FIG. 27 is a variation example of the structure illustrated in FIG. 26A, in which at least part of the transistor 51 is provided in a region where the wiring 41 and the wiring 43 overlap with each other, and at least part of the transistor 52 is provided in the region of the wiring 45 extending in the Y direction.

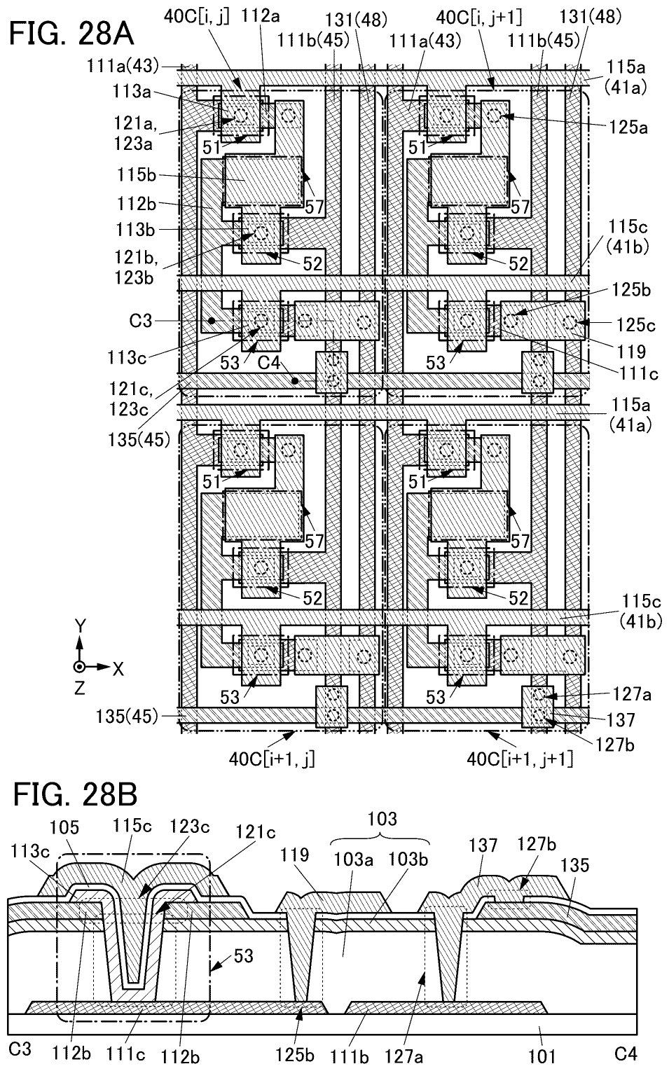

FIG. 28A is a variation example of the structure illustrated in FIG. 24A, in which the conductive layer 111b and the conductive layer 135 are electrically connected to each other through the conductive layer 137 provided in the same layer as the conductive layer 115. FIG. 28A illustrates a structure example of the pixel circuit 40C. FIG. 28B is a cross-sectional view taken along the dashed-dotted line C3-C4 in FIG. 28A and illustrates a structure example of the transistor 53.

FIG. 28A illustrates an example in which the region of the conductive layer 115c extending in the X direction is provided between the transistor 52 and the transistor 53 in order to prevent contact between the conductive layer 115c and the conductive layer 137.

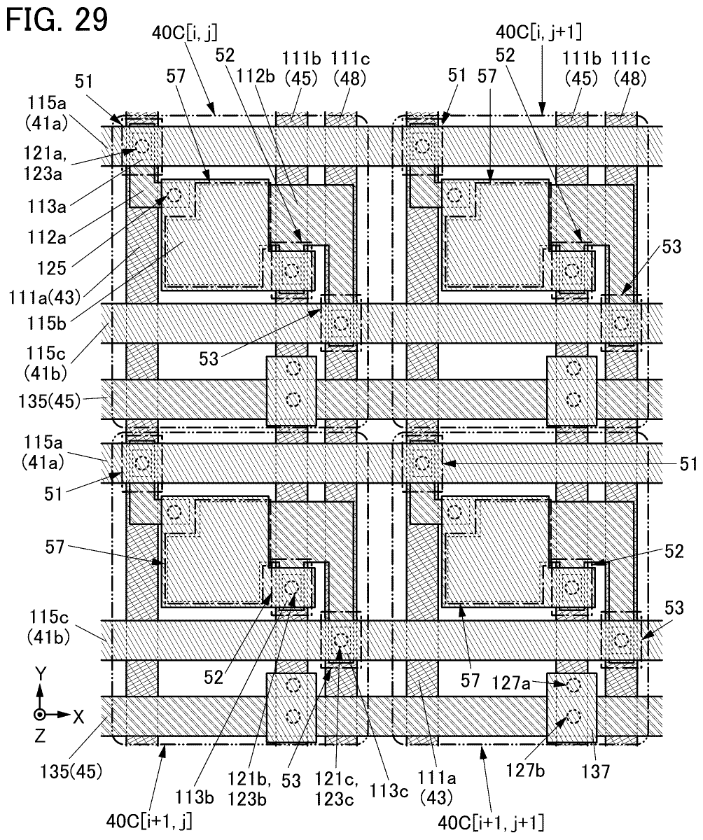

FIG. 29 illustrates a variation example of the structure illustrated in FIG. 28A, in which at least part of the transistor 51 is provided in a region where the wiring 41a and the wiring 43 overlap with each other, at least part of the transistor 52 is provided in the region of the wiring 45 extending in the Y direction, and at least part of the transistor 53 is provided in a region where the wiring 41b and the wiring 48 overlap with each other.

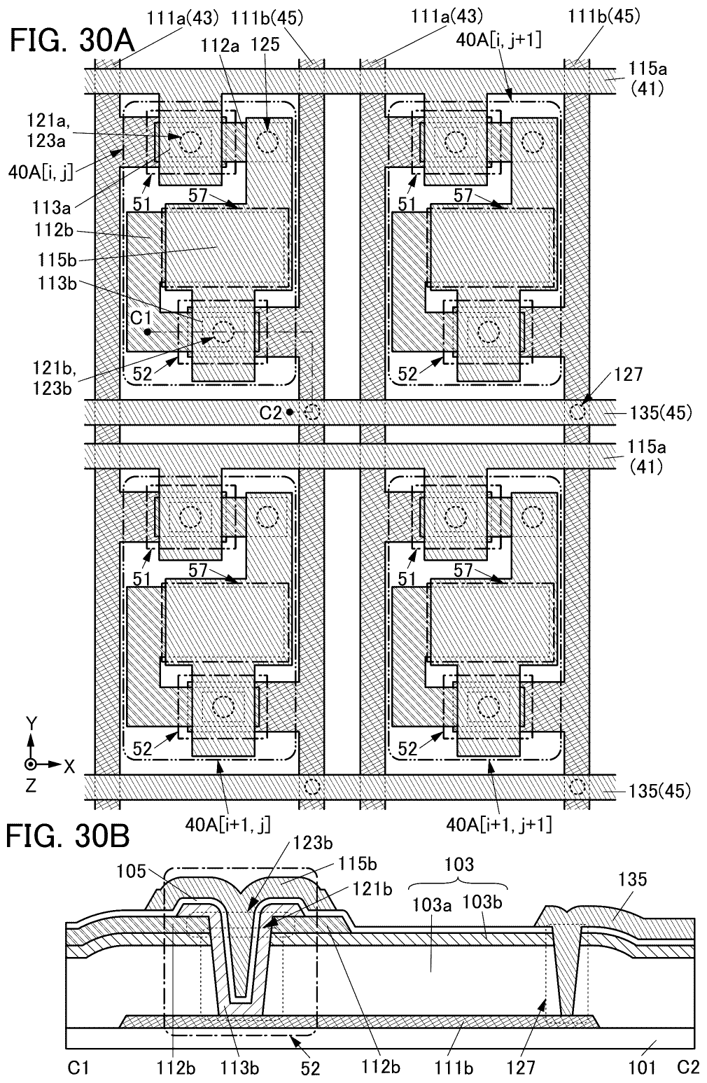

FIG. 30A is a variation example of the structure illustrated in FIG. 22A, in which the conductive layer 135 is provided in the same layer as the conductive layer 115. FIG. 30A illustrates a structure example of the pixel circuit 40A. FIG. 30B is a cross-sectional view taken along the dashed-dotted line C1-C2 in FIG. 30A and illustrates a structure example of the transistor 52.

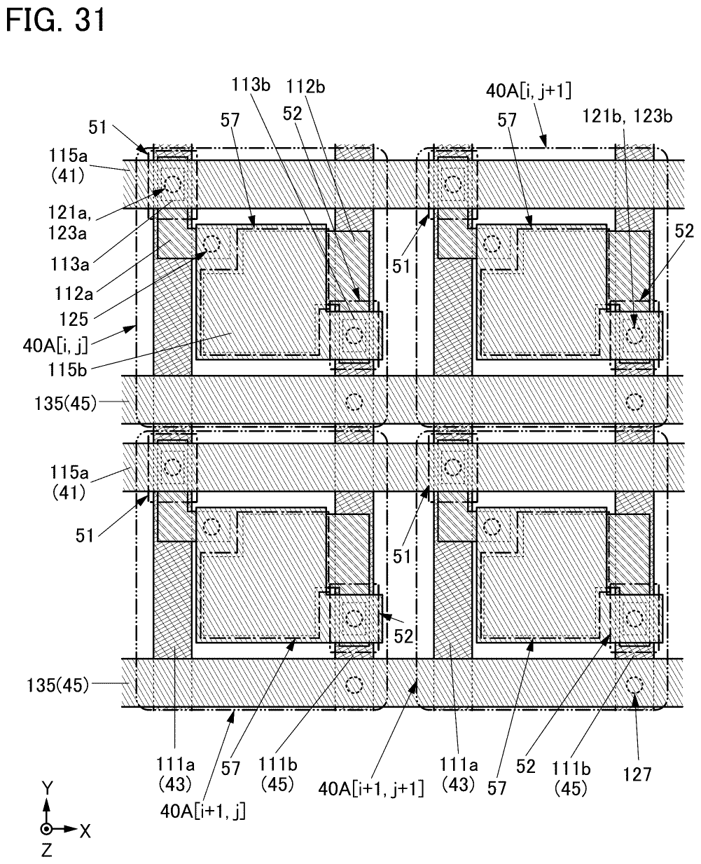

FIG. 31 is a variation example of the structure illustrated in FIG. 30A, in which at least part of the transistor 51 is provided in a region where the wiring 41 and the wiring 43 overlap with each other, and at least part of the transistor 52 is provided in the region of the wiring 45 extending in the Y direction.

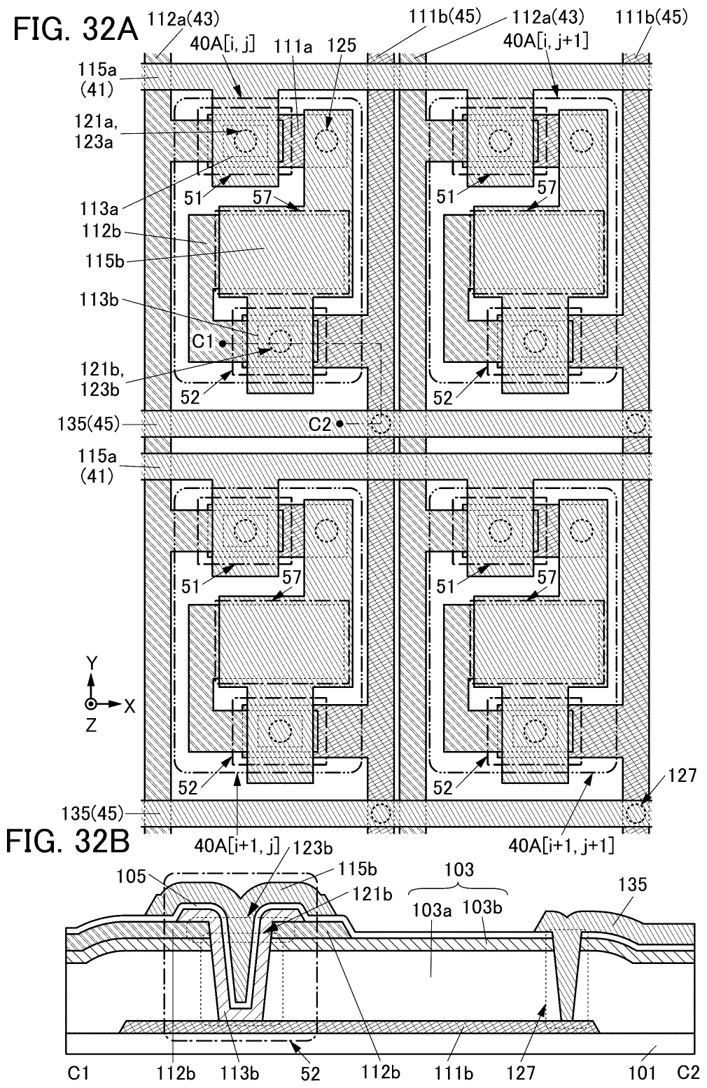

FIG. 32A is a variation example of the structure illustrated in FIG. 30A, in which at least part of the conductive layer 112a functions as the wiring 43 functioning as a signal line. FIG. 32B is a cross-sectional view taken along the dashed-dotted line C1-C2 in FIG. 32A.

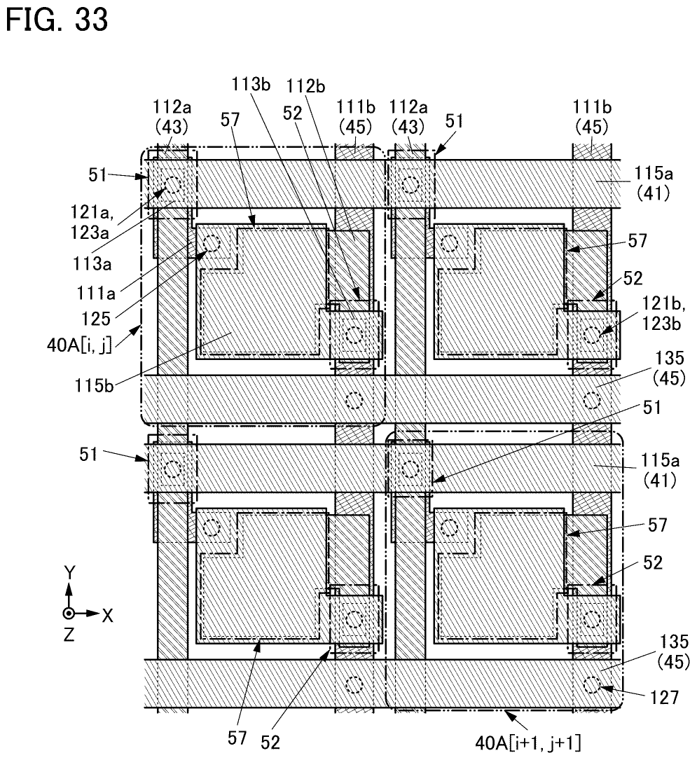

FIG. 33 is a variation example of the structure illustrated in FIG. 32A, in which at least part of the transistor 51 is provided in a region where the wiring 41 and the wiring 43 overlap with each other, and at least part of the transistor 52 is provided in the region of the wiring 45 extending in the Y direction.

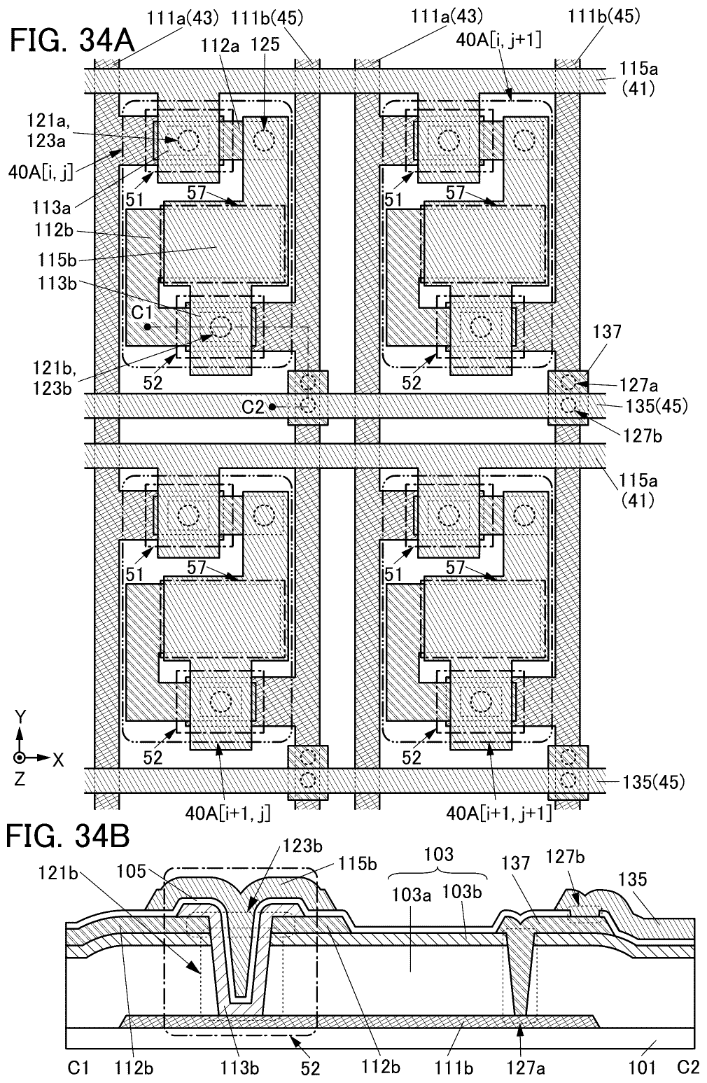

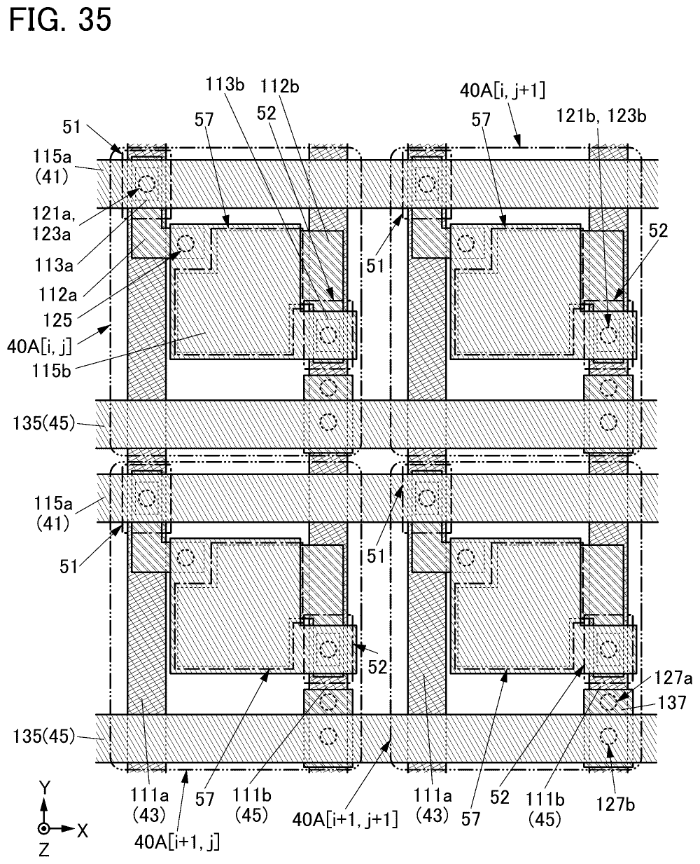

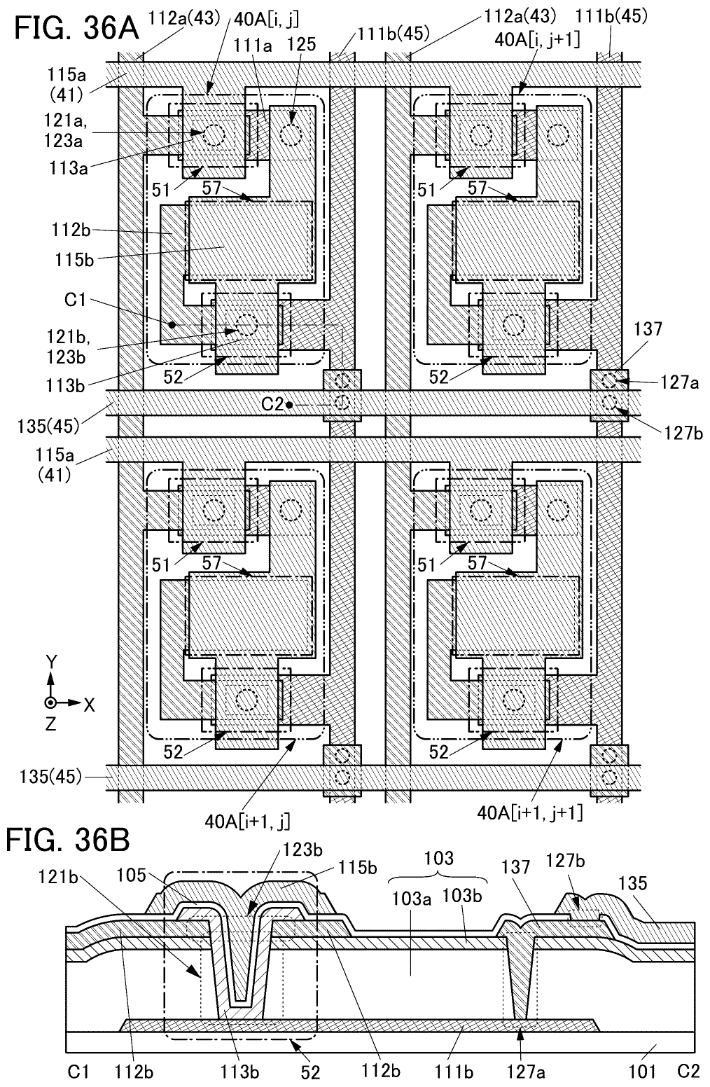

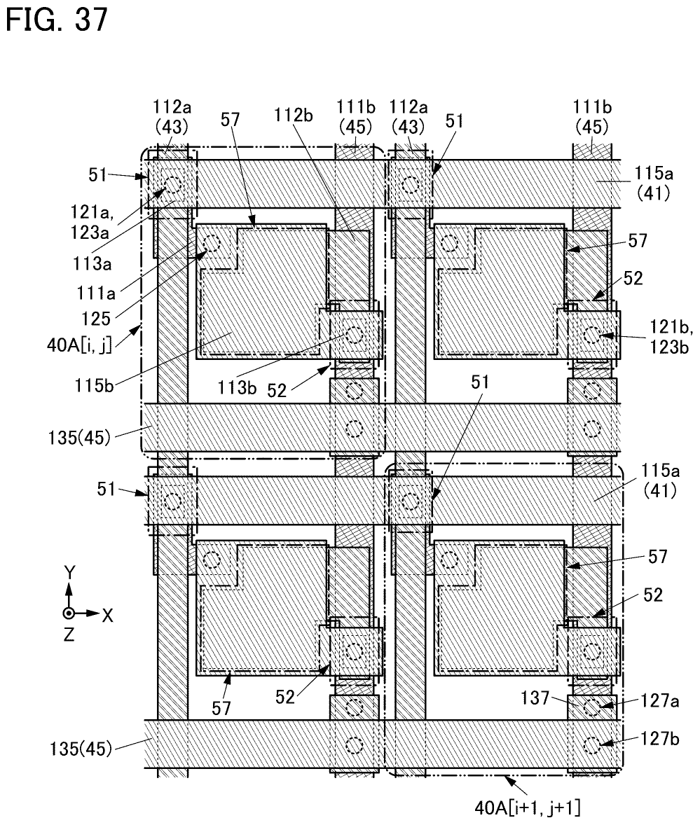

FIG. 34A, FIG. 34B, FIG. 35, FIG. 36A, FIG. 36B, and FIG. 37 are variation examples of the structures illustrated in FIG. 30A, FIG. 30B, FIG. 31, FIG. 32A, FIG. 32B, and FIG. 33, respectively, and each illustrate an example in which the conductive layer 111b and the conductive layer 135 are electrically connected to each other through the conductive layer 137 provided in the same layer as the conductive layer 112.

In the example illustrated in FIG. 34A, FIG. 34B, FIG. 35, FIG. 36A, FIG. 36B, and FIG. 37, the opening 127a reaching the conductive layer 111b is provided in the insulating layer 103, and the conductive layer 111b and the conductive layer 137 are electrically connected to each other through the opening 127a. Specifically, the conductive layer 111b and the conductive layer 137 are contact with each other in the opening 127a, for example. The opening 127b reaching the conductive layer 137 is provided in the insulating layer 105, and the conductive layer 137 and the conductive layer 135 are electrically connected to each other through the opening 127b. Specifically, the conductive layer 137 and the conductive layer 135 are in contact with each other in the opening 127b, for example. In the above manner, the conductive layer 111b and the conductive layer 135 can be electrically connected to each other through the conductive layer 137. Note that the structures of the opening 127a and the opening 127b illustrated in FIG. 34A, FIG. 34B, FIG. 35, FIG. 36A, FIG. 36B, and FIG. 37 can also be employed for the opening 125b and the opening 125c. The structure of the conductive layer 137 illustrated in FIG. 34A, FIG. 34B, FIG. 35, FIG. 36A, FIG. 36B, and FIG. 37 can also be employed for the conductive layer 119.

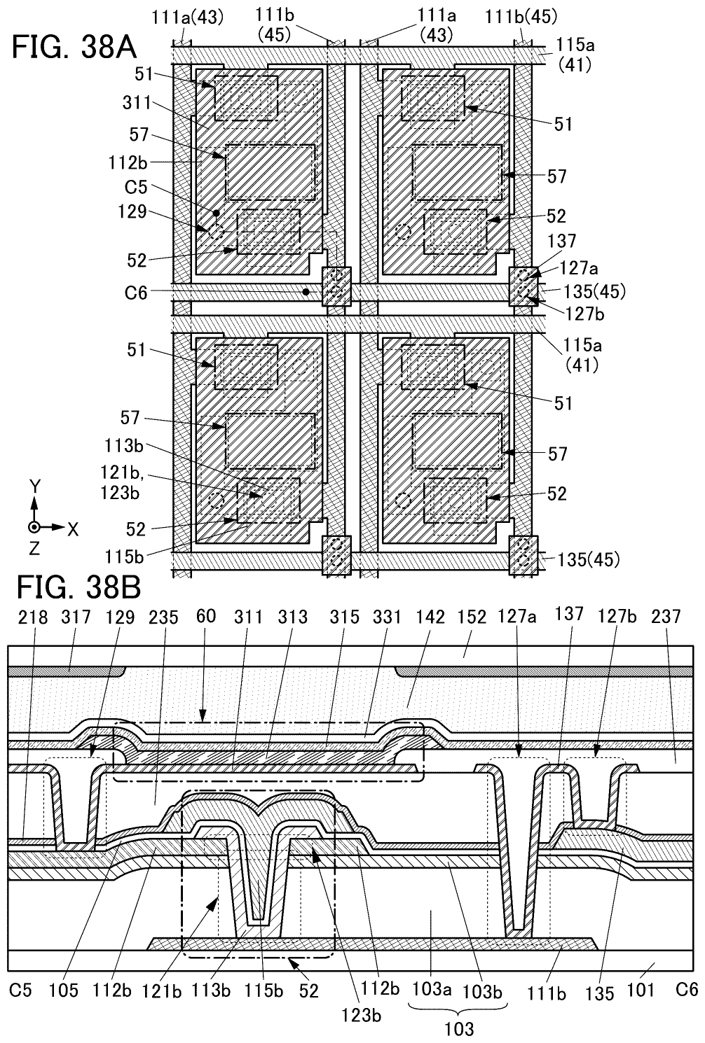

FIG. 38A is a variation example of the structure illustrated in FIG. 34A, which is different from the structure illustrated in FIG. 34A in the layer where the conductive layer 137 is provided. FIG. 38A illustrates the pixel electrode 311 and illustrates an example in which the conductive layer 137 is provided in the same layer as the pixel electrode 311. Thus, in the example illustrated in FIG. 38A, the conductive layer 137 can contain the same material as the pixel electrode 311 and can be formed in the same step. For example, the pixel electrode 311 and the conductive layer 137 can be formed by processing the same conductive film. FIG. 38B is a cross-sectional view taken along the dashed-dotted line C5-C6 in FIG. 38A and illustrates a structure example of the transistor 52, for example. FIG. 38B also illustrates a structure example of layers above the transistor 52, for example. Note that some of the reference numerals illustrated in FIG. 34A are omitted in FIG. 38A.

Although FIG. 38A illustrates an example in which the pixel electrode 311 does not overlap with any of the region of the conductive layer 111a extending in the Y direction, the region of the conductive layer 111b extending in the Y direction, the region of the conductive layer 115a extending in the X direction, and the region of the conductive layer 135 extending in the X direction, the pixel electrode 311 may include a region overlapping with at least one of these regions. Thus, the aperture ratio of a pixel can be increased. By contrast, when the pixel electrode 311 has a structure not overlapping with these regions, noise caused by the conductive layer 111a, the conductive layer 111b, the conductive layer 115a, and the conductive layer 135 can be inhibited from being transmitted to the pixel electrode 311. In particular, when the pixel electrode 311 does not overlap with the region of the conductive layer 111a which extends in the Y direction and receives an image signal and the region of the conductive layer 115a which extends in the X direction and receives a scan signal, noise can be effectively inhibited from being transmitted to the pixel electrode 311.

The insulating layer 218 and the insulating layer 235 over the insulating layer 218 are provided to cover the transistor 51, the transistor 52, and the capacitor 57. The insulating layer 105, the insulating layer 218, and the insulating layer 235 have the opening 129 reaching the conductive layer 112b. For example, the description of FIG. 8B can be referred to for the description of the components provided over the insulating layer 235, the description of the opening 129, and the like.

In the example illustrated in FIG. 38B, the opening 127a reaching the conductive layer 111b is provided in the insulating layer 103, the insulating layer 105, the insulating layer 218, and the insulating layer 235. The opening 127b reaching the conductive layer 135 is provided in the insulating layer 218 and the insulating layer 235. Here, the opening 127a and the opening 127b can be formed in the same step as the opening 129.

The conductive layer 137 is provided to cover the opening 127a and the opening 127b. The conductive layer 137 has a shape along the top surface and the side surface of the insulating layer 235, the side surface of the insulating layer 218, the side surface of the insulating layer 105, the side surface of the insulating layer 103, the top surface of the conductive layer 111b, and the top surface of the conductive layer 135. The conductive layer 137 includes a region in contact with the top surface and the side surface of the insulating layer 235, the side surface of the insulating layer 218, the side surface of the insulating layer 105, the side surface of the insulating layer 103, the top surface of the conductive layer 111b, and the conductive layer 135. The conductive layer 137 can be electrically connected to the conductive layer 111b in the opening 127a and can be electrically connected to the conductive layer 135 in the opening 127b. Thus, the conductive layer 111b and the conductive layer 135 can be electrically connected to each other through the conductor layer 137.

The insulating layer 237 can be provided to cover the end portion of the top surface of the conductive layer 137. Provision of the insulating layer 237 can inhibit a short circuit between the conductive layer 137 and the pixel electrode 311 due to contact, for example.

In the conductive layer 137, a depressed portion is formed to cover the opening 127a and a depressed portion is formed to cover the opening 127b. The insulating layer 237 is embedded in these depressed portions.

Note that the structures of the opening 127a, the opening 127b, and the conductive layer 137 illustrated in FIG. 38A and FIG. 38B can also be employed for the opening 127a, the opening 127b, and the conductive layer 137 illustrated in drawings other than FIG. 34A and FIG. 34B. For example, the conductive layers 137 illustrated in drawings other than FIG. 34A and FIG. 34B can be provided in the same layer as pixel electrodes. The structures of the opening 127a and the opening 127b illustrated in FIG. 38A and FIG. 38B can also be employed for the opening 125b, the opening 125c, the opening 125dl, and the opening 125d2. The structure of the conductive layer 137 illustrated in FIG. 38A and FIG. 38B can also be employed for the conductive layer 119. For example, the conductive layer 119 can be provided in the same layer as a pixel electrode.

### <Components of Display Apparatus>

Components included in the display apparatus of this embodiment will be described below.

### [Semiconductor Layer 113]

There is no particular limitation on a semiconductor material that can be used for the semiconductor layer 113. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics can be used. These semiconductor materials may contain an impurity as a dopant.

There is no particular limitation on the crystallinity of a semiconductor material used for the semiconductor layer 113, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case deterioration of the transistor characteristics can be inhibited.

Silicon can be used for the semiconductor layer 113. As silicon, single crystal silicon, polycrystalline silicon, microcrystalline silicon, and amorphous silicon can be given. An example of polycrystalline silicon is low-temperature polysilicon (LTPS).

A transistor using amorphous silicon in the semiconductor layer 113 can be formed over a large glass substrate, and can be manufactured at low cost. The transistor using polycrystalline silicon in the semiconductor layer 113 has high field-effect mobility and enables high-speed driving. The transistor using microcrystalline silicon in the semiconductor layer 113 has higher field-effect mobility and enables higher speed driving than the transistor using amorphous silicon.

The semiconductor layer 113 preferably includes a metal oxide (an oxide semiconductor). Examples of the metal oxide that can be used for the semiconductor layer 113 include indium oxide, gallium oxide, and zinc oxide. The metal oxide preferably contains at least indium (In) or zinc (Zn). The metal oxide preferably contains two or three selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

For the semiconductor layer 113, indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide, also referred to as ITZO (registered trademark)), indium titanium zinc oxide (In—Ti—Zn oxide), indium gallium zinc oxide (In—Ga—Zn oxide, also referred to as IGZO), indium gallium tin oxide (In—Ga—Sn oxide, also referred to as IGTO), and indium gallium tin zinc oxide (In—Ga—Sn—Zn oxide), indium tin gallium oxide (In—Sn—Ga oxide), indium gallium aluminum zinc oxide (In—Ga—Al—Zn oxide, also referred to as IGAZO or IAGZO), or the like can be used, for example. Alternatively, indium tin oxide containing silicon or the like can be used. Alternatively, the above-described oxide having an amorphous structure can be used. For example, indium oxide having an amorphous structure, indium tin oxide having an amorphous structure, or the like can be used.

The element M is preferably one or more kinds selected from gallium, aluminum, yttrium, and tin. In particular, the element Mis preferably gallium.

Here, the composition of the metal oxide included in the semiconductor layer 113 greatly affects the electrical characteristics and reliability of the transistor 50.

For example, a higher content percentage of indium in the metal oxide enables the transistor to have a high on-state current.

In the case where an In—Zn oxide is used for the semiconductor layer 113, a metal oxide in which the atomic ratio of indium is higher than or equal to that of zinc is preferably used. For example, a metal oxide in which the atomic ratio of metal elements is In:Zn=1:1, In:Zn=2:1, In:Zn=3:1, In:Zn=4:1, In:Zn=5:1, In:Zn=7:1, In:Zn=10:1, or the neighborhood thereof can be used.

In the case where an In—Sn oxide is used for the semiconductor layer 113, a metal oxide in which the atomic ratio of indium is higher than or equal to that of tin is preferably used. For example, a metal oxide in which the atomic ratio of metal elements is In:Sn=1:1, In:Sn=2:1, In:Sn=3:1, In:Sn=4:1, In:Sn=5:1, In:Sn=7:1, In:Sn=10:1, or the neighborhood thereof can be used.

In the case where an In-M-Zn oxide is used for the semiconductor layer 113, a metal oxide in which the atomic ratio of indium in the metal elements is higher than that of the element M can be used. It is further preferable to use a metal oxide in which the atomic ratio of zinc is higher than the atomic ratio of the element M. For example, a metal oxide having any of the following atomic ratios of metal elements can be used for the semiconductor layer 113: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and the neighborhood thereof.

In the case where a plurality of metal elements are contained as the element M, the sum of the atomic ratios of the metal elements can be the atomic ratio of the element M. In In—Ga—Al—Zn oxide where gallium and aluminum are contained as the element M, for example, the sum of the atomic ratio of gallium and the atomic ratio of aluminum can be the atomic ratio of the element M. The atomic ratio between indium, the element M, and zinc is preferably within the ranges described above.

It is preferable to use a metal oxide in which the atomic ratio of indium to the metal elements included in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, still further preferably higher than or equal to 35 atomic % and lower than or equal to 90 atomic %, yet still further preferably higher than or equal to 40 atomic % and lower than or equal to 90 atomic %, yet still further preferably higher than or equal to 45 atomic % and lower than or equal to 90 atomic %, yet still further preferably higher than or equal to 50 atomic % and lower than or equal to 80 atomic %, yet still further preferably higher than or equal to 60 atomic % and lower than or equal to 80 atomic %, yet still further preferably higher than or equal to 70 atomic % and lower than or equal to 80 atomic %. For example, when an In—Ga—Zn oxide is used for the semiconductor layer 113, the atomic ratio of indium to the total number of the atoms of indium, the element M, and zinc is preferably within the ranges given above.

In this specification and the like, the atomic ratio of indium to the metal elements contained is sometimes referred to as indium content percentage. The same applies to other metal elements.

A metal oxide with a higher indium content percentage enables a transistor to have a higher on-state current. By using such a transistor as a transistor required to have a high on-state current, a display apparatus having excellent electrical characteristics can be provided.

As an analysis method of the composition of a metal oxide, for example, energy dispersive X-ray spectroscopy (EDX), X-ray photoelectron spectroscopy (XPS), inductively coupled plasma-mass spectrometry (ICP-MS), inductively coupled plasma-atomic emission spectroscopy (ICP-AES), or the like can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A composition in the neighborhood in this specification and the like includes the range of ±30% of an intended atomic ratio. For example, in the case of describing an atomic ratio of In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. In the case of describing an atomic ratio of In:M:Zn=5:1:6 or a composition in the neighborhood thereof, the case is included where the atomic ratio of M is greater than 0.1 and less than or equal to 2 and the atomic ratio of zinc is greater than or equal to 5 and less than or equal to 7 with the atomic ratio of indium being 5. In the case of describing an atomic ratio of In:M:Zn=1:1:1 or a composition in the neighborhood thereof, the case is included where the atomic ratio of M is greater than 0.1 and less than or equal to 2 and the atomic ratio of zinc is greater than 0.1 and less than or equal to 2 with the atomic ratio of indium being 1.

For the formation of a metal oxide, a sputtering method or an atomic layer deposition (ALD) method can be suitably used. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation with light is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state (a state where current flows); thus, the amount of change in threshold voltage in the PBTS test is one important item to be focused on as an indicator of the reliability of the transistor.

With use of a metal oxide that does not contain gallium or has a low gallium content percentage in the semiconductor layer 113, the transistor can have high reliability against positive bias application. In other words, the amount of change in the threshold voltage of the transistor in the PBTS test can be small. In the case of using a metal oxide that contains gallium, the gallium content percentage is preferably lower than the indium content percentage. Thus, a transistor with high reliability can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case where an In—Ga—Zn oxide is used for the semiconductor layer 113, a metal oxide in which the atomic ratio of indium is higher than the atomic ratio of gallium can be used for the semiconductor layer 113. It is further preferable to use a metal oxide in which the atomic ratio of zinc is higher than the atomic ratio of gallium. In other words, a metal oxide in which the atomic ratios of metal elements satisfy In>Ga and Zn>Ga is preferably used for the semiconductor layer 113.

For example, a metal oxide with metal elements in any of the following atomic ratios can be used for the semiconductor layer 113: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

The semiconductor layer 113 is preferably formed using a metal oxide having the following compositions; the atomic ratio of gallium to the metal elements contained in the metal oxide is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, still further preferably higher than or equal to 0.1 atomic % and lower than or equal to 30 atomic %, yet still further preferably higher than or equal to 0.1 atomic % and lower than or equal to 25 atomic %, yet still further preferably higher than or equal to 0.1 atomic % and lower than or equal to 20 atomic %, yet still further preferably higher than or equal to 0.1 atomic % and lower than or equal to 15 atomic %, yet still further preferably higher than or equal to 0.1 atomic % and lower than or equal to 10 atomic %. The reduction in the gallium content percentage in the semiconductor layer enables the transistor to be highly resistant to the PBTS test. Note that oxygen vacancies (V_{O}) are less likely to be generated in the metal oxide when the metal oxide contains gallium, for example.

A metal oxide not containing gallium may be used for the semiconductor layer 113. For example, an In—Zn oxide can be used for the semiconductor layer 113. In that case, when the atomic ratio of indium to the metal elements contained in the metal oxide is increased, the field-effect mobility of the transistor can be increased. By contrast, when the atomic ratio of zinc to the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used for the semiconductor layer 113. The use of a metal oxide not containing gallium can make a change in the threshold voltage particularly in the PBTS test extremely small.

For example, an oxide containing indium and zinc can be used for the semiconductor layer 113. At that time, for example, a metal oxide with metal elements in an atomic ratio of In:Zn=2:3, In:Zn=4:1, or the neighborhood thereof can be used.

Although the case of using gallium is described as a typical example, the same applies to the case where the element M is used instead of gallium. In particular, a metal oxide in which the atomic ratio of indium is higher than the atomic ratio of the element M is preferably used for the semiconductor layer 113. Furthermore, a metal oxide in which the atomic ratio of zinc is higher than the atomic ratio of the element M is preferably used.

With use of a metal oxide that has a low content percentage of the element M in the semiconductor layer 113, the transistor can have high reliability against positive bias application. With use of the transistor as a transistor that is required to have high reliability against positive bias application, a highly reliable display apparatus can be provided.

Next, the reliability of a transistor against light is described.

Light incidence on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in a NBTIS test, for example.

The high content percentage of the element M in the metal oxide enables the transistor to be highly reliable against light. In other words, the amount of change in the threshold voltage of the transistor in the NBTIS test can be small. Specifically, in a metal oxide in which the atomic ratio of the element M is higher than or equal to the atomic ratio of indium, the band gap is increased and accordingly the amount of change in the threshold voltage of the transistor in the NBTIS test can be reduced. The band gap of the metal oxide included in the semiconductor layer 113 is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, a metal oxide with metal elements in any of the following atomic ratios can be used for the semiconductor layer 113: In:M:Zn=1:1:1, In:M:Zn=1:1:1.2, In:M:Zn=1:3:2, In:M:Zn=1:3:3, In:M:Zn=1:3:4, and the neighborhood thereof.

For the semiconductor layer 113, in particular, it is preferable to use a metal oxide in which the atomic ratio of the element M to the metal elements contained in the metal oxide is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet still further preferably higher than or equal to 50 atomic % and lower than or equal to 60 atomic %.

In the case where an In—Ga—Zn oxide is used for the semiconductor layer 113, a metal oxide in which the atomic ratio of indium to the metal elements is lower than or equal to that of gallium can be used. For example, a metal oxide with metal elements in any of the following atomic ratios can be used: In:Ga:Zn=1:1:1, In:Ga:Zn=1:1:1.2, In:Ga:Zn=1:3:2, In:Ga:Zn=1:3:3, In:Ga:Zn=1:3:4, and the neighborhood thereof.

For the semiconductor layer 113, in particular, it is preferable to use a metal oxide in which the atomic ratio of gallium to the metal elements contained in the semiconductor layer is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, further preferably higher than or equal to 40 atomic % and lower than or equal to 60 atomic %, further preferably higher than or equal to 50 atomic % and lower than or equal to 60 atomic %.

With the use of a metal oxide with a high content percentage of the element M for the semiconductor layer 113, the transistor can be highly reliable against light. With use of the transistor as a transistor that is required to have high reliability against light, a highly reliable display apparatus can be provided.

As described above, electrical characteristics and reliability of a transistor depend on the composition of the metal oxide used for the semiconductor layer 113. Thus, by determining the composition of the metal oxide in accordance with the electrical characteristics and reliability required for the transistor, the display apparatus can have both excellent electrical characteristics and high reliability.

The semiconductor layer 113 may have a stacked-layer structure including two or more metal oxide layers. The two or more metal oxide layers included in the semiconductor layer 113 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 113 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

It is preferable to use a metal oxide layer having crystallinity as the semiconductor layer 113. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer 113, the density of defect states in the semiconductor layer 113 can be reduced, which enables the display apparatus to have high reliability.

The higher the crystallinity of the metal oxide layer 113 used as the semiconductor layer is, the lower the density of defect states in the semiconductor layer 113 can be. By contrast, the use of a metal oxide layer having low crystallinity enables a transistor to flow a large amount of current.

In the case where the metal oxide layer is formed by a sputtering method, the higher the substrate temperature (the stage temperature) in the formation is, the higher the crystallinity of the metal oxide layer can be. Furthermore, the higher the proportion of a flow rate of an oxygen gas in the whole deposition gas (also referred to as an oxygen flow rate ratio) used in the formation is, the higher the crystallinity of the metal oxide layer can be.

The semiconductor layer 113 may have a stacked-layer structure of two or more metal oxide layers having different crystallinities. For example, a stacked-layer structure of a first metal oxide layer and a second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 113 may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer 113 may have different compositions.

The thickness of the semiconductor layer 113 is preferably greater than or equal to 3 nm and less than or equal to 100 nm, further preferably greater than or equal to 5 nm and less than or equal to 100 nm, further preferably greater than or equal to 10 nm and less than or equal to 100 nm, further preferably greater than or equal to 10 nm and less than or equal to 70 nm, further preferably greater than or equal to 15 nm and less than or equal to 70 nm, further preferably greater than or equal to 15 nm and less than or equal to 50 nm, further preferably greater than or equal to 20 nm and less than or equal to 50 nm, further preferably greater than or equal to 20 nm and less than or equal to 40 nm, further preferably greater than or equal to 25 nm and less than or equal to 40 nm.

The substrate temperature at the time of forming the semiconductor layer 113 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancies that might be formed in the semiconductor layer 113 will be described.

In the case where an oxide semiconductor is used for the semiconductor layer 113, hydrogen contained in the oxide semiconductor reacts with oxygen bonded to a metal atom to be water, and thus sometimes forms an oxygen vacancy (V_{O}) in the oxide semiconductor. In some cases, a defect that is an oxygen vacancy into which hydrogen enters (hereinafter referred to as V_{O}H) functions as a donor and generates an electron serving as a carrier. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor contains a large amount of hydrogen.

V_{O}H can function as a donor of the oxide semiconductor. However, it is difficult to evaluate the defect quantitatively. Thus, the oxide semiconductor is sometimes evaluated not by its donor concentration but by its carrier concentration. Therefore, in this specification and the like, the carrier concentration assuming the state where an electric field is not applied is sometimes used as the parameter of the oxide semiconductor, instead of the donor concentration. That is, “carrier concentration” described in this specification and the like can be replaced with “donor concentration” in some cases.

Accordingly, in the case where an oxide semiconductor is used as the semiconductor layer 113, the amount of V_{O}H in the semiconductor layer 113 is preferably reduced as much as possible so that the semiconductor layer 113 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydration or dehydrogenation treatment) and supply oxygen to the oxide semiconductor to fill an oxygen vacancy (V_{O}). When an oxide semiconductor with sufficiently reduced impurities such as V_{O}H is used for a channel formation region of a transistor, stable electrical characteristics can be given. Supplying oxygen to an oxide semiconductor to fill an oxygen vacancy (V_{O}) is sometimes referred to as oxygen adding treatment.

In the case where an oxide semiconductor is used for the semiconductor layer 113, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in a region functioning as the channel formation region is not particularly limited and can be, for example, 1×10⁻⁹ cm⁻³.

### [Insulating Layer 103]

For the insulating layer 103, an inorganic insulating material or an organic insulating material can be used. The insulating layer 103 may have a stacked-layer structure of an inorganic insulating material and an organic insulating material.

For the insulating layer 103, an inorganic insulating material can be suitably used. As the inorganic insulating material, one or more of an oxide, an oxynitride, a nitride oxide, and a nitride can be used. For the insulating layer 103, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The contents of oxygen and nitrogen can be analyzed using secondary ion mass spectrometry (SIMS) or X-ray photoelectron spectroscopy (XPS). When the content percentage of a target element is high (e.g., higher than or equal to 0.5 atomic %, or higher than or equal to 1 atomic %), XPS is suitable. By contrast, when the content percentage of a target element is low (e.g., lower than or equal to 1 atomic %, or lower than or equal to 0.5 atomic %), SIMS is suitable. To compare the contents of elements, analysis with a combination of SIMS and XPS is preferably used.

The insulating layer 103 may have a stacked-layer structure of two or more layers. In the above cross-sectional view illustrating a structure example of the transistor 50, a structure in which the insulating layer 103 has a stacked-layer structure of an insulating layer 103a and an insulating layer 103b over the insulating layer 103a is illustrated. For each of the insulating layer 103a and the insulating layer 103b, the above-described material that can be used for the insulating layer 103 can be used. Note that the insulating layer 103a and the insulating layer 103b may be formed using the same material or different materials. Note that the insulating layer 103a may have a stacked-layer structure of two or more layers. The insulating layer 103b may have a stacked-layer structure of two or more layers.

The thickness of the insulating layer 103a can be larger than that of the insulating layer 103b. The film formation speed of the insulating layer 103a (also referred to as film formation rate) is preferably high, and is preferably higher than the film formation speed of the insulating layer 103b, for example. In particular, the film formation speed of the insulating layer 103a is preferably high in the case where the thickness of the insulating layer 103a is large. By increasing the film formation speed of the insulating layer 103a, the productivity can be increased. For example, by increasing power at the time of forming the insulating layer 103a, the film formation speed can be increased.

The stress of the insulating layer 103a is preferably low. When the thickness of the insulating layer 103a is increased, the stress of the insulating layer 103a is increased, so that warpage of the substrate might be caused. By making the stress of the insulating layer 103a low, a problem in the process caused by stress such as warpage of the substrate can be inhibited from arising.

The insulating layer 103b functions as a blocking layer that inhibits release of gas from the insulating layer 103a. For the insulating layer 103b, a material that does not easily allow diffusion of gas is preferably used. The insulating layer 103b preferably includes a region having a higher film density than the insulating layer 103a. The insulating layer 103b having a higher film density can have a higher blocking property. A material containing more nitrogen than the insulating layer 103a can be used for the insulating layer 103b. The insulating layer 103b having a higher content of nitrogen can have a higher blocking property.

The insulating layer 103b can be thinner than the insulating layer 103a as long as the insulating layer 103b has a thickness that is sufficient for the function of a blocking layer that inhibits release of gas from the insulating layer 103a. The film formation speed of the insulating layer 103b is preferably low, and is preferably lower than the film formation speed of the insulating layer 103a, for example. Note that when the film formation speed of the insulating layer 103b is made low, the insulating layer 103b can have a higher film density and thus can have a higher blocking property. When the substrate temperature at the time of forming the insulating layer 103b is increased, the insulating layer 103b can have a higher film density and thus can have a higher blocking property.

The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Therefore, the transmission electron (TE) image of the insulating layer 103b is a dark-colored (dark) image compared to the insulating layer 103a in some cases. Note that since the insulating layer 103a and the insulating layer 103b have different film densities even when including the same materials, it is sometimes possible to identify the boundary between the insulating layer 103a and the insulating layer 103b by a difference in contrast in a TEM image of a cross section.

The insulating layer 103b may include a region where the hydrogen concentration in the film is lower than that in the insulating layer 103a. The difference in hydrogen concentration between the insulating layer 103a and the insulating layer 103b can be evaluated by secondary ion mass spectrometry (SIMS), for example.

Here, the insulating layer 103 will be described in detail with use of a structure where a metal oxide is used for the semiconductor layer 113 as an example.

In the case where an oxide semiconductor is used for the semiconductor layer 113, an inorganic insulating material can be suitably used for each of the insulating layer 103a and the insulating layer 103b.

An oxide or an oxynitride is preferably used as the insulating layer 103a. A film from which oxygen is released by heating is preferably used as the insulating layer 103a. For the insulating layer 103a, a silicon oxide or a silicon oxynitride can be suitably used, for example.

Oxygen release from the insulating layer 103a enables oxygen supply from the insulating layer 103a to the semiconductor layer 113. Supplying oxygen from the insulating layer 103a to the semiconductor layer 113, particularly to the channel formation region of the semiconductor layer 113, can reduce oxygen vacancies (V_{O}) and V_{O}H in the semiconductor layer 113. Consequently, the transistor 50 can have favorable electrical characteristics and high reliability. The insulating layer 103a preferably has a high oxygen diffusion coefficient. A high oxygen diffusion coefficient of the insulating layer 103a facilitates diffusion of oxygen in the insulating layer 103a, so that oxygen can be efficiently supplied from the insulating layer 103a to the semiconductor layer 113. Examples of treatment for supplying oxygen to the semiconductor layer 113 include heat treatment in an oxygen-containing atmosphere and plasma treatment in an oxygen-containing atmosphere.

The amount of impurities (e.g., water and hydrogen) released from the insulating layer 103a itself is preferably small. A reduction in the amount of impurities released from the insulating layer 103a inhibits diffusion of impurities into the semiconductor layer 113. Consequently, the transistor 50 can have favorable electrical characteristics and high reliability.

For the insulating layer 103a, silicon oxide or silicon oxynitride formed by a plasma-enhanced chemical vapor deposition (PECVD) method can be suitably used, for example. In that case, a mixed gas including a gas containing silicon and a gas containing oxygen is preferably used as a source gas. As the gas containing silicon, one or more of silane, disilane, trisilane, and silane fluoride can be used, for example. As the gas containing oxygen, one or more of oxygen (O₂), ozone (O₃), dinitrogen monoxide (N₂O), nitric oxide (NO), or nitrogen dioxide (NO₂) can be used, for example. Note that by increasing power at the time of forming the insulating layer 103a, the amount of impurities (e.g., water and hydrogen) released from the insulating layer 103a can be reduced.

The insulating layer 103b is preferably less likely to transmit oxygen. The insulating layer 103b functions as a blocking layer that inhibits release of oxygen from the insulating layer 103a. Moreover, the insulating layer 103b is preferably less likely to transmit hydrogen. The insulating layer 103b functions as a blocking layer that inhibits diffusion of hydrogen into the semiconductor layer 113 from the outside of the transistor through the insulating layer 103. The insulating layer 103b preferably has a high film density. The insulating layer 103b having a higher film density can have a higher blocking property against oxygen and hydrogen. The film density of the insulating layer 103b is preferably higher than that of the insulating layer 103a. In the case where silicon oxide or silicon oxynitride is used for the insulating layer 103a, silicon nitride, silicon nitride oxide, or aluminum oxide can be suitably used for the insulating layer 103b, for example. The insulating layer 103b preferably includes a region containing more nitrogen than the insulating layer 103a, for example. A material containing more nitrogen than the insulating layer 103a can be used for the insulating layer 103b. A nitride or a nitride oxide is preferably used for the insulating layer 103b. For example, silicon nitride or silicon nitride oxide can be suitably used for the insulating layer 103b.

When oxygen contained in the insulating layer 103a is diffused upward from a region of the insulating layer 103a that is not in contact with the semiconductor layer 113 (e.g., the top surface of the insulating layer 103a), the amount of oxygen supplied from the insulating layer 103a to the semiconductor layer 113 might be reduced. Provision of the insulating layer 103b over the insulating layer 103a can inhibit diffusion of oxygen contained in the insulating layer 103a from a region of the insulating layer 103a that is not in contact with the semiconductor layer 113. Accordingly, the amount of oxygen supplied from the insulating layer 103a to the semiconductor layer 113 is increased, whereby oxygen vacancies (V_{O}) and V_{O}H in the semiconductor layer 113 can be reduced. Consequently, the transistor 50 can have favorable electrical characteristics and high reliability.

The conductive layer 112 is oxidized by oxygen contained in the insulating layer 103a and has high resistance in some cases. Moreover, when the conductive layer 112 is oxidized by oxygen contained in the insulating layer 103a, the amount of oxygen supplied from the insulating layer 103a to the semiconductor layer 113 is reduced in some cases. Provision of the insulating layer 103b over the insulating layer 103a can inhibit the conductive layer 112 from being oxidized and having high resistance. At the same time, the amount of oxygen supplied from the insulating layer 103a to the semiconductor layer 113 is increased, whereby oxygen vacancies (V_{O}) and V_{O}H in the semiconductor layer 113 can be reduced. Consequently, the transistor 50 can have favorable electrical characteristics and high reliability.

Hydrogen diffused in the semiconductor layer 113 reacts with an oxygen atom contained in an oxide semiconductor to be water, and thus sometimes forms an oxygen vacancy (V_{O}). Furthermore, V_{O}H is formed and the carrier concentration is increased in some cases. Provision of the insulating layer 103b over the insulating layer 103a can reduce oxygen vacancies (V_{O}) and V_{O}H in the semiconductor layer 113. Consequently, the transistor 50 can have favorable electrical characteristics and high reliability.

The insulating layer 103b preferably has a thickness that is sufficient for the function of a blocking layer against oxygen and hydrogen. When the thickness of the insulating layer 103b is small, the function of a blocking layer deteriorates in some cases. Meanwhile, when the thickness of the insulating layer 103b is large, a region of the semiconductor layer 113 in contact with the insulating layer 103a is narrowed and the amount of oxygen supplied from the insulating layer 103a to the semiconductor layer 113 is sometimes reduced. The thickness of the insulating layer 103b may be smaller than that of the insulating layer 103a. The thickness of the insulating layer 103b is preferably larger than or equal to 5 nm and smaller than or equal to 100 nm, further preferably larger than or equal to 5 nm and smaller than or equal to 70 nm, still further preferably larger than or equal to 10 nm and smaller than or equal to 70 nm, yet still further preferably larger than or equal to 10 nm and smaller than or equal to 50 nm, yet still further preferably larger than or equal to 20 nm and smaller than or equal to 50 nm, yet still further preferably larger than or equal to 20 nm and smaller than or equal to 40 nm. When the thickness of the insulating layer 103b is within the above range, oxygen vacancies (V_{O}) and V_{O}H in the semiconductor layer 113, in particular, in the channel formation region, can be reduced. Consequently, the transistor 50 can have favorable electrical characteristics and high reliability.

The amount of impurities (e.g., water and hydrogen) released from the insulating layer 103b itself is preferably small. A reduction in the amount of impurities released from the insulating layer 103b inhibits diffusion of impurities into the semiconductor layer 113. Consequently, the transistor 50 can have favorable electrical characteristics and high reliability.

In the transistor 50, a region of the semiconductor layer 113 in contact with the insulating layer 103 can function as the channel formation region. That is, oxygen is selectively supplied to the channel formation region, so that oxygen vacancies (V_{O}) and V_{O}H can be reduced. Consequently, the transistor 50 can have favorable electrical characteristics and high reliability.

### [Conductive Layer 111, Conductive Layer 112, and Conductive Layer 115]

The conductive layer 111 and the conductive layer 112 functioning as the source electrode and the drain electrode and the conductive layer 115 functioning as the gate electrode can each be formed using one or more of chromium, copper, aluminum, magnesium, gold, silver, zinc, molybdenum, tantalum, titanium, tungsten, manganese, nickel, iron, cobalt, molybdenum, and niobium; or an alloy containing one or more of the above-described metals as its components. For the conductive layer 111, the conductive layer 112, and the conductive layer 115, a conductive material with low resistance that contains one or more of copper, silver, gold, and aluminum can be suitably used. Copper or aluminum is particularly preferable because of its high mass-productivity.

For the conductive layer 111, the conductive layer 112, and the conductive layer 115, a metal oxide film (also referred to as an oxide conductor) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

In addition, each of the conductive layer 111, the conductive layer 112, and the conductive layer 115 may have a stacked-layer structure of a conductive layer containing the above-described oxide conductor (metal oxide) and a conductive layer containing a metal or an alloy. The use of the conductive layer containing a metal or an alloy can reduce the wiring resistance.

A Cu—X alloy film (X is Mn, Ni, Cr, Fe, Co, Mo, Ta, or Ti) may be used for the conductive layer 111, the conductive layer 112, and the conductive layer 115. The use of a Cu—X alloy enables the manufacturing cost to be reduced because a wet etching process can be used in the processing.

Note that the conductive layer 111, the conductive layer 112, and the conductive layer 115 may be formed using the same material or different materials.

Here, the conductive layer 111 and the conductive layer 112 will be described in detail in an example of a structure in which a metal oxide is used for the semiconductor layer 113.

When an oxide semiconductor is used for the semiconductor layer 113, the conductive layer 111 and the conductive layer 112 are oxidized by oxygen contained in the semiconductor layer 113 and have high resistance in some cases. The conductive layer 111 and the conductive layer 112 are oxidized by oxygen contained in the insulating layer 103a and have high resistance in some cases. Moreover, when the conductive layer 111 and the conductive layer 112 are oxidized by oxygen contained in the semiconductor layer 113, the amount of oxygen vacancies (V_{O}) in the semiconductor layer 113 is increased in some cases. When the conductive layer 111 and the conductive layer 112 are oxidized by oxygen contained in the insulating layer 103a, the amount of oxygen supplied from the insulating layer 103a to the semiconductor layer 113 might be reduced.

A material that is less likely to be oxidized is preferably used for the conductive layer 111 and the conductive layer 112. An oxide conductor is preferably used for each of the conductive layer 111 and the conductive layer 112. For example, In—Sn oxide (ITO) or In—Sn—Si oxide (ITSO) can be suitably used. For each of the conductive layer 111 and the conductive layer 112, a nitride conductor may be used. Examples of the nitride conductor include tantalum nitride and titanium nitride. The conductive layer 111 and the conductive layer 112 may have a stacked-layer structure of the above-described materials.

With the use of a material that is less likely to be oxidized for each of the conductive layer 111 and the conductive layer 112, the conductive layer 111 and the conductive layer 112 can be inhibited from being oxidized by oxygen contained in the semiconductor layer 113 or oxygen contained in the insulating layer 103a and having higher resistance. Furthermore, it is possible to increase the amount of oxygen supplied from the insulating layer 103a to the semiconductor layer 113 while an increase in oxygen vacancies (V_{O}) in the semiconductor layer 113 is inhibited. Accordingly, oxygen vacancies (V_{O}) and V_{O}H in the semiconductor layer 113 can be reduced. Consequently, the transistor 50 can have favorable electrical characteristics and high reliability. Note that the conductive layer 111 and the conductive layer 112 may be formed using the same material or different materials.

### [Insulating Layer 105]

The insulating layer 105 functioning as the gate insulating layer preferably has low defect density. With the insulating layer 105 having low defect density, the transistor can have favorable electrical characteristics. In addition, the insulating layer 105 preferably has high breakdown voltage. With the insulating layer 105 having high breakdown voltage, the transistor 50 can have high reliability.

For the insulating layer 105, one or more of an insulating oxide, an insulating oxynitride, an insulating nitride oxide, and an insulating nitride can be used, for example. For the insulating layer 105, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used. The insulating layer 105 may be either a single layer or a stacked layer. The insulating layer 105 may have a stacked-layer structure of an oxide and a nitride.

A miniaturized transistor including a thin gate insulating layer may have a high leakage current. When a high dielectric constant material (also referred to as a high-k material) is used for the gate insulating layer, the voltage at the time of driving of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 105 itself is preferably small. When the amount of impurities released from the insulating layer 105 is small, diffusion of impurities into the semiconductor layer 113 is inhibited. Consequently, the transistor 50 can have favorable electrical characteristics and high reliability.

The insulating layer 105 is formed over the semiconductor layer 113, and thus is preferably a film formed under conditions where damage to the semiconductor layer 113 is small. For example, the insulating layer 105 is preferably formed under conditions where the film formation speed is sufficiently low, specifically, under conditions where the film formation speed is lower than that of the insulating layer 103b. For example, when the insulating layer 105 is formed by a PECVD method under a low-power condition, damage to the semiconductor layer 113 can be small.

Here, the insulating layer 105 will be described in detail using a structure where a metal oxide is used for the semiconductor layer 113 as an example.

To improve the properties of the interface with the semiconductor layer 113, the insulating layer 105 is preferably formed using an oxide. For example, one or more of silicon oxide and silicon oxynitride can be suitably used for the insulating layer 105. Moreover, a film from which oxygen is released by heating is preferably used as the insulating layer 105.

Note that the insulating layer 105 may have a stacked-layer structure. The insulating layer 105 can have a stacked-layer structure of the oxide film on a side in contact with the semiconductor layer 113 and a nitride film on the side in contact with the conductive layer 115. For example, one or more of silicon oxide and silicon oxynitride can be suitably used for the oxide film. Silicon nitride can be suitably used for the nitride film. In the case where the insulating layer 105 has a stacked-layer structure, at least the side of the insulating layer 105 that is in contact with the semiconductor layer 113 is preferably formed using an oxide, in which case the properties of the interface with the semiconductor layer 113 can be improved.

### [Substrate 101]

Although there is no particular limitation on a material of the substrate 101, for example, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 101. Alternatively, any of these substrates provided with a semiconductor element may be used as the substrate 101. A printed circuit board may be used as the substrate 101. Note that the shape of the semiconductor substrate and an insulating substrate may be circular or square.

A flexible substrate may be used as the substrate 101, and for example, the transistor 50 may be formed directly on the flexible substrate. Alternatively, a separation layer may be provided between the substrate 101 and the transistor 50 and the like. The separation layer can be used when part or the whole of the display apparatus completed thereover is separated from the substrate 101 and transferred onto another substrate. In that case, for example, the transistor 50 can be transferred onto a substrate having low heat resistance or a flexible substrate as well.

### [Insulating Layer 218]

The insulating layer 218 is preferably formed using a material through which impurities are not easily diffused. In that case, the insulating layer 218 functions as a blocking layer that inhibits the diffusion of impurities from the outside into the transistors. Examples of the impurities include water and hydrogen. With the insulating layer 218, the reliability of the display apparatus can be increased.

The insulating layer 218 can be an insulating layer containing an inorganic material or an insulating layer containing an organic material. For example, an inorganic material such as oxide or nitride can be suitably used for the insulating layer 218. Specifically, one or more of silicon nitride, silicon nitride oxide, silicon oxynitride, aluminum oxide, aluminum oxynitride, aluminum nitride, hafnium oxide, and hafnium aluminate can be used. For example, silicon nitride oxide can be suitably used for the insulating layer 218 because the amount of impurities (such as water and hydrogen) released from the silicon nitride oxide itself is small and a layer of silicon nitride oxide can function as a blocking layer that inhibits the diffusion of impurities into the transistors from above the transistors. As the organic material, for example, one or more of acrylic resins and polyimide resins can be used. As the organic material, a photosensitive material may be used. A stack including two or more of the above insulating films may also be used. The insulating layer 218 may have a stacked-layer structure of an insulating layer containing an inorganic material and an insulating layer containing an organic material.

### [Insulating Layer 235]

The insulating layer 235 has a function of reducing unevenness caused by the transistor 51, the transistor 52, the capacitor 57, and the like. In this specification and the like, the insulating layer 235 is referred to as a planarization layer in some cases.

An insulating layer containing an organic material can be suitably used as the insulating layer 235. As the organic material, a photosensitive organic resin is preferably used, and for example, a photosensitive resin composition including an acrylic resin is preferably used. Note that in this specification and the like, an acrylic resin refers to not only a polymethacrylic acid ester or a methacrylic resin, but also all the acrylic polymer in a broad sense in some cases.

The insulating layer 235 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, the insulating layer 235 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive-type material or a negative-type material may be used.

The insulating layer 235 may have a stacked-layer structure of an organic insulating layer and an inorganic insulating layer. For example, the insulating layer 235 can have a stacked-layer structure of an organic insulating layer and an inorganic insulating layer over the organic insulating layer. In the case where an inorganic insulating layer is provided on the outermost surface of the insulating layer 235, the inorganic insulating layer can function as an etching protective layer. This can inhibit a decrease in the planarity of the insulating layer 235, which is caused by etching of part of the insulating layer 235 in the formation of the pixel electrode 311.

The low planarity of the top surface of the insulating layer 235, which is the formation surface of the light-emitting element 60, might cause a connection defect due to step disconnection of the common electrode 315. The low planarity of the top surface of the insulating layer 235 causes local thinning of the common electrode 315 and an increase in electric resistance. In addition, the low planarity of the top surface of the insulating layer 235 may lower the processing accuracy of the layer to be formed over the insulating layer 235 in some cases. Planarizing the top surface of the insulating layer 235 increases the processing accuracy of the light-emitting element 60 provided over the insulating layer 235, whereby a high-definition display apparatus can be achieved. Furthermore, occurrence of a connection defect due to step disconnection of the common electrode 315 and an increase in electric resistance due to the locally thinned regions of the common electrode 315 can be inhibited, whereby a display apparatus with high display quality can be achieved.

In some cases, the insulating layer 235 is partly removed when the pixel electrode 311 is formed. The insulating layer 235 may have a depressed portion in a region not overlapping with the pixel electrode 311.

### [Insulating Layer 237]

The insulating layer 237 can be an insulating layer containing an inorganic material or an insulating layer containing an organic material. A material that can be used for the insulating layer 218 or a material that can be used for the insulating layer 235 can be used for the insulating layer 237. The insulating layer 237 may have a stacked-layer structure of an insulating layer containing an inorganic material and an insulating layer containing an organic material.

### [Protective Layer 331]

The protective layer 331 may have a single-layer structure or a stacked-layer structure including two or more layers. There is no limitation on the conductivity of the protective layer 331. For the protective layer 331, at least one of an insulating film, a semiconductor film, and a conductive film can be used.

The protective layer 331 includes an inorganic film, which can inhibit oxidation of the common electrode 315 and entry of impurities (e.g., moisture and oxygen) into the light-emitting element 60. Accordingly, deterioration of the light-emitting element 60 can be inhibited, and the reliability of the display apparatus can be increased.

As the protective layer 331, an inorganic insulating film such as an oxide insulating film, a nitride insulating film, an oxynitride insulating film, or a nitride oxide insulating film can be used, for example. The protective layer 331 can be an insulating layer containing an inorganic material. As the protective layer 331, an inorganic insulating film such as an oxide insulating film, a nitride insulating film, an oxynitride insulating film, or a nitride oxide insulating film can be used, for example. The protective layer 331 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the protective layer 331 preferably includes a nitride insulating film or a nitride oxide insulating film, and further preferably includes a nitride insulating film.

As the protective layer 331, an insulating film containing In—Sn oxide (ITO), In—Zn oxide, Ga—Zn oxide, Al—Zn oxide, In—Ga—Zn oxide (IGZO), or the like can also be used. The inorganic film preferably has high resistance, specifically, higher resistance than the common electrode 315. The inorganic film may further contain nitrogen.

When light emitted from the light-emitting element 60 is extracted through the protective layer 331, the protective layer 331 preferably has a high visible-light-transmitting property. For example, ITO, IGZO, and aluminum oxide are preferable because they are each an inorganic material having a high visible-light-transmitting property.

The protective layer 331 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

The protective layer 331 may be formed using an organic material. For example, as the protective layer 331, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used. Alternatively, the protective layer 331 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. Furthermore, the protective layer 331 may contain both an inorganic material and an organic material.

The protective layer 331 may have a stacked-layer structure of two layers that are formed by different film formation methods. Specifically, the first layer of the protective layer 331 may be formed by an ALD method, and the second layer of the protective layer 331 may be formed by a sputtering method.

### [Substrate 152]

For the substrate 152, glass, quartz, ceramic, sapphire, a resin, a metal, an alloy, a semiconductor, or the like can be used. The substrate on the side from which light from the light-emitting element 60 is extracted is formed using a material that transmits the light. When a flexible material is used for the substrate 152, the flexibility of the display apparatus can be increased. Furthermore, a polarizing plate may be used as the substrate 152. Alternatively, an attachment film or a base film may be used as the substrate 152.

For the substrate 152, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 152.

In the case where a film used as the substrate absorbs water, the shape of the display apparatus might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

A variety of optical members can be provided on the outer surface of the substrate 152. Examples of the optical members include a polarizing plate (e.g., a circularly polarizing plate), a retardation plate, a light diffusion layer (such as a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer surface of the substrate 152. For example, a glass layer or a silica layer (SiOₓ layer) is preferably provided as the surface protective layer to inhibit the surface contamination and generation of a scratch. The surface protective layer may be formed using DLC (diamond-like carbon), aluminum oxide (AlOₓ), a polyester-based material, a polycarbonate-based material, or the like. For the surface protective layer, a material having a high visible light transmittance is preferably used. The surface protective layer is preferably formed using a material with high hardness.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

### [Adhesive Layer 142]

For the adhesive layer 142, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet may be used, for example.

### [Light-Blocking Layer 317]

Examples of a material that can be used for the light-blocking layer 317 include carbon black, titanium black, a metal, a metal oxide, and a composite oxide containing a solid solution of a plurality of metal oxides. Alternatively, the light-blocking layer 317 can have a stacked-layer structure of a plurality of layers containing a material of a coloring layer. For example, a stacked-layer structure of a layer containing a material used for a coloring layer that transmits light of a certain color and a layer containing a material used for a coloring layer that transmits light of another color can be employed for the light-blocking layer 317.

The above is the description of the components.

### <Memory Cell>

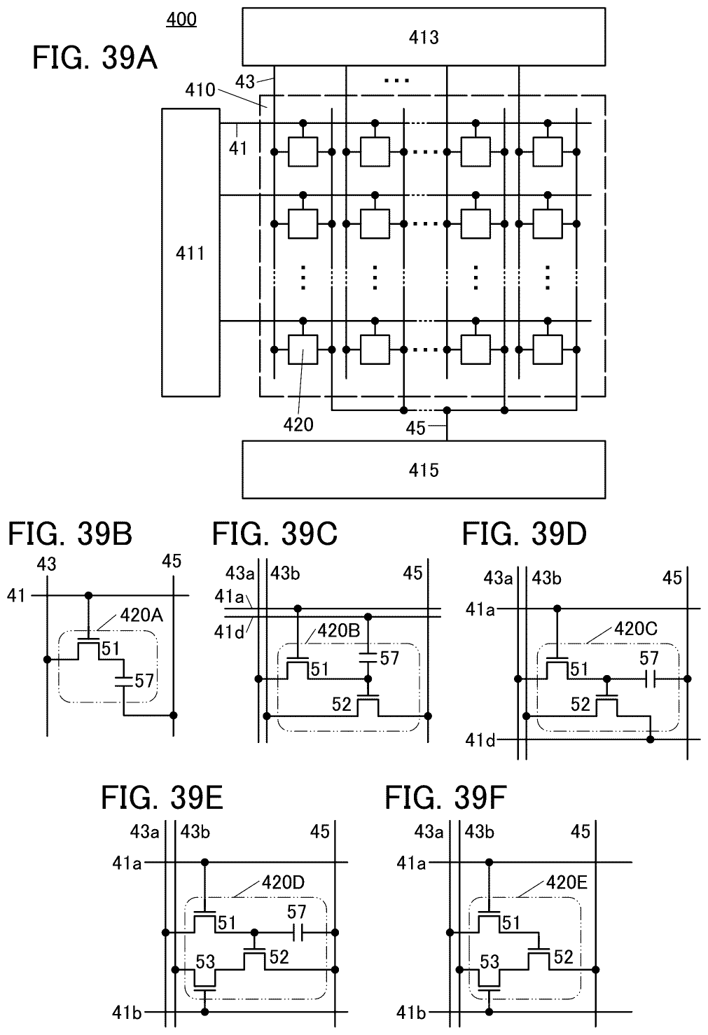

One embodiment of the present invention is applicable to not only a display apparatus but also a memory device. FIG. 39A is a block diagram illustrating a structure example of a memory device 400 to which one embodiment of the present invention can be applied. The memory device 400 includes a memory portion 410, a word line driver circuit 411, a bit line driver circuit 413, and a power supply circuit 415. The memory portion 410 includes a plurality of memory cells 420 arranged in a matrix. Note that the power supply circuit 415 may be provided outside the memory device 400.

The word line driver circuit 411 is electrically connected to the memory cells 420 through the wirings 41. As in the display apparatus 10 illustrated in FIG. 1, for example, the wiring 41 extends in the row direction of the matrix, for example. In the memory device 400, the wiring 41 functions as a word line.

The bit line driver circuit 413 is electrically connected to the memory cells 420 through the wirings 43. As in the display apparatus 10 illustrated in FIG. 1, for example, the wiring 43 extends in the column direction of the matrix, for example. In the memory device 400, the wiring 41 functions as a bit line.

The power supply circuit 415 is electrically connected to the memory cells 420 through the wiring 45. For example, all the memory cells 420 can be electrically connected to the power supply circuit 415 through the same wiring 45. The wiring 45 functions as a power supply line.

The word line driver circuit 411 has a function of selecting, row by row, the memory cells 420 to which data is to be written. The word line driver circuit 411 has a function of selecting, row by row, the memory cells 420 from which data is to be read. Specifically, by outputting a signal to the wiring 41, the word line driver circuit 411 can select the memory cell 420 to which data is to be written or the memory cell 420 from which data is to be read.

The bit line driver circuit 413 has a function of writing data through the wiring 43 to the memory cell 420 selected by the word line driver circuit 411. The bit line driver circuit 413 has a function of reading data retained in the memory cell 420 by amplifying data output from the memory cell 420 to the wiring 43 and outputting the amplified data to, for example, the outside of the memory device 400. Furthermore, the bit line driver circuit 413 has a function of precharging the wiring 43 before data is read from the memory cell 420.

The power supply circuit 415 has a function of generating a power supply potential and supplying it to the wiring 45. The power supply circuit 415 has a function of generating, for example, a high potential or a low potential and supplying it to the wiring 45.

FIG. 39B, FIG. 39C, FIG. 39D, FIG. 39E, and FIG. 39F are circuit diagrams illustrating structure examples of the memory cell 420. Here, the memory cells 420 illustrated in FIG. 39B, FIG. 39C, FIG. 39D, FIG. 39E, and FIG. 39F are a memory cell 420A, a memory cell 420B, a memory cell 420C, a memory cell 420D, and a memory cell 420E, respectively.

The memory cell 420A includes the transistor 51 and the capacitor 57. In other words, the memory cell 420A is a 1Tr1C-type memory cell.

In the memory cell 420A, the one of the source and the drain of the transistor 51 is electrically connected to the wiring 43. The other of the source and the drain of the transistor 51 is electrically connected to the one electrode of the capacitor 57. The gate of the transistor 51 is electrically connected to the wiring 41. The other electrode of the capacitor 57 is electrically connected to the wiring 45.

In the memory cell 420A, when the transistor 51 is turned on, data is written to the memory cell 420A through the wiring 43, and when the transistor 51 is turned off, the written data is retained. When the transistor 51 is turned on, the data retained in the memory cell 420A can be output to the wiring 43, so that the data can be read by the bit line driver circuit 413.

The memory cell 420B includes the transistor 51, the transistor 52, and the capacitor 57. In other words, the memory cell 420B is a 2Tr1C-type memory cell.

To the memory cell 420B, the wiring 41a and the wiring 41d are electrically connected as the wiring 41 and a wiring 43a and a wiring 43b are electrically connected as the wiring 43. Specifically, the one of the source and the drain of the transistor 51 is electrically connected to the wiring 43a. The other of the source and the drain of the transistor 51 is electrically connected to the one electrode of the capacitor 57. The one electrode of the capacitor 57 is electrically connected to the gate of the transistor 52. The gate of the transistor 51 is electrically connected to the wiring 41a. The other electrode of the capacitor 57 is electrically connected to the wiring 41d. Specifically, the one of the source and the drain of the transistor 52 is electrically connected to the wiring 43b. The other of the source and the drain of the transistor 52 is electrically connected to the wiring 45.

In the memory cell 420B, when the transistor 51 is turned on, data is written to the memory cell 420B through the wiring 43a, and when the transistor 51 is turned off, the written data is retained. Thus, in the memory cell 420B, the wiring 41a can be referred to as a write word line and the wiring 43a can be referred to as a write bit line. By controlling the potential of the wiring 41d, the gate potential of the transistor 52 can be changed by capacitive coupling and the potential of the wiring 43b can be a potential corresponding to data retained in the memory cell 420B. Thus, the bit line driver circuit 413 can read the data retained in the memory cell 420B. Accordingly, in the memory cell 420B, the wiring 41d can be referred to as a read word line and the wiring 43b can be referred to as a read bit line.

The memory cell 420C is a variation example of the memory cell 420B, in which the other of the source and the drain of the transistor 52 is electrically connected to the wiring 41d and the other electrode of the capacitor 57 is electrically connected to the wiring 45. In the memory cell 420C, the word line driver circuit 411 controls the potential of the other of the source and the drain of the transistor 52, whereby data retained in the memory cell 420C can be output to the wiring 43b.

The memory cell 420D is a variation example of the memory cell 420C and is different from the memory cell 420C in including the transistor 53. The memory cell 420D is a 3Tr1C-type memory cell.

To the memory cell 420D, the wiring 41a and the wiring 41b are electrically connected as the wiring 41. Specifically, the gate of the transistor 53 is electrically connected to the wiring 41b. One of the source and the drain of the transistor 52 is electrically connected to the one of the source and the drain of the transistor 53. The other of the source and the drain of the transistor 52 is electrically connected to the wiring 45. The other of the source and the drain of the transistor 53 is electrically connected to the wiring 43b.

The transistor 53 has a function of a switch and has a function of controlling the conduction/non-conduction between the wiring 43b and the one of the source and the drain of the transistor 52 on the basis of the potential of the wiring 41b. When the transistor 53 is turned on, the potential of the wiring 43b can be a potential corresponding to data retained in the memory cell 420D. Thus, the bit line driver circuit 413 can read the data retained in the memory cell 420D. Accordingly, in the memory cell 420D, the wiring 41b can be referred to as a read word line.

The memory cell 420E is a variation example of the memory cell 420D and is different from the memory cell 420D in not including the capacitor 57. In the memory cell 420E, the wiring 45 is electrically connected to the other of the source and the drain of the transistor 52.

In the case where parasitic capacitance such as the gate capacitance of the transistor 52 is sufficiently high, for example, data can be retained in the memory cell even without the capacitor 57.

An OS transistor is preferably used as the transistor 51 included in each of the memory cell 420A to the memory cell 420E. As described above, an OS transistor has a significantly low off-state current. Thus, by using an OS transistor as the transistor 51, charge accumulated in the capacitor 57 can be retained for a long period. In addition, the gate potential of the transistor 52 can be retained for a long period. Accordingly, data written to the memory cell 420 can be retained for a long period and therefore the frequency of the refresh operation (rewriting data to the memory cell 420) can be reduced. Thus, the power consumption of the memory device 400 can be reduced.

An OS transistor is preferably used as each of the transistor 52 and the transistor 53 as well. As described above, an OS transistor has higher field-effect mobility than a transistor including amorphous silicon, for example. Thus, by using an OS transistor as each of the transistor 51 to the transistor 53, the memory device 400 can be driven at high speed.

The memory cell 420A can be referred to as a DOSRAM (registered trademark). The DOSRAM is an abbreviation for a “Dynamic Oxide Semiconductor Random Access Memory”. The DOSRAM is a RAM including a 1Tr1C-type memory cell. The DOSRAM is a DRAM formed using an OS transistor and is a memory that temporarily stores information transmitted from the outside. The DOSRAM is a memory utilizing a low off-state current of an OS transistor.

The memory cell 420B to the memory cell 420E can each be referred to as a NOSRAM (registered trademark). The NOSRAM is an abbreviation for “Nonvolatile Oxide Semiconductor Random Access Memory (RAM)”. The NOSRAM is capable of reading retained data without destruction (non-destructive reading). Thus, the NOSRAM is suitable for arithmetic processing in which only a data reading operation is repeated many times.

<Structure example 2 of semiconductor device>

A structure example of a transistor whose structure is partly different from that in FIG. 4A1, FIG. 4B, and the like is described below. Note that description of the same portions as those in FIG. 4A1, FIG. 4B, and the like is omitted below in some cases.

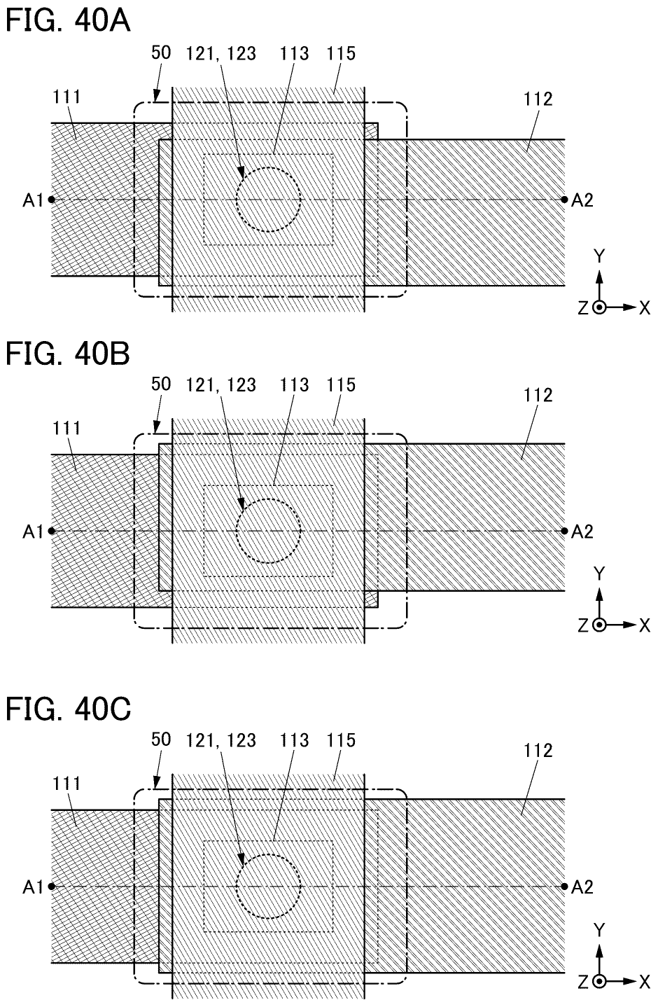

In FIG. 4A1, the end portion of the conductive layer 112 in the Y direction and the end portion of the conductive layer 112 in the −Y direction when seen from the opening 123 both have regions overlapping with the conductive layer 111 in the plan view. In other words, the end portion of the conductive layer 112 in the Y direction when seen from the opening 123 is positioned inside the end portion of the conductive layer 111 in the Y direction when seen from the opening 123, and the end portion of the conductive layer 112 in the −Y direction when seen from the opening 123 is positioned inside the end portion of the conductive layer 111 in the −Y direction when seen from the opening 123; however, one embodiment of the present invention is not limited thereto. FIG. 40A illustrates an example in which the end portion of the conductive layer 112 in the −Y direction does not overlap with the conductive layer 111 when seen from the opening 123 in the plan view. In other words, in the example illustrated in FIG. 40A, the end portion of the conductive layer 112 in the −Y direction is positioned outside the end portion of the conductive layer 111 in the −Y direction when seen from the opening 123. For example, in the case where the transistor 52 illustrated in FIG. 6 has the structure illustrated in FIG. 40A, the end portion of the conductive layer 112b in a region functioning as the transistor 52 can extend beyond the end portion of the conductive layer 111b toward the conductive layer 115a side.

FIG. 40B illustrates an example in which the end portion of the conductive layer 112 in the Y direction does not overlap with the conductive layer 111 when seen from the opening 123 in the plan view. In other words, in the example illustrated in FIG. 40B, the end portion of the conductive layer 112 in the Y direction is positioned outside the end portion of the conductive layer 111 in the Y direction when seen from the opening 123. For example, in the case where the transistor 51 illustrated in FIG. 6 has the structure illustrated in FIG. 40B, the end portion of the conductive layer 112a in a region functioning as the transistor 51 can extend beyond the end portion of the conductive layer 111a toward the region of the conductive layer 115a extending in the X direction.

FIG. 40C illustrates an example in which the end portion of the conductive layer 112 in the Y direction and the end portion of the conductive layer 112 in the −Y direction when seen from the opening 123 both do not overlap with the conductive layer 111 in the plan view. In other words, in the example illustrated in FIG. 40C, the end portion of the conductive layer 112 in the Y direction when seen from the opening 123 is positioned outside the end portion of the conductive layer 111 in the Y direction when seen from the opening 123, and the end portion of the conductive layer 112 in the −Y direction when seen from the opening 123 is positioned outside the end portion of the conductive layer 111 in the Y direction when seen from the opening 123.

Note that FIG. 4B can be referred to for the cross-sectional view taken along the dashed-dotted line A1-A2 in the structures illustrated in each of FIG. 40A, FIG. 40B, and FIG. 40C.

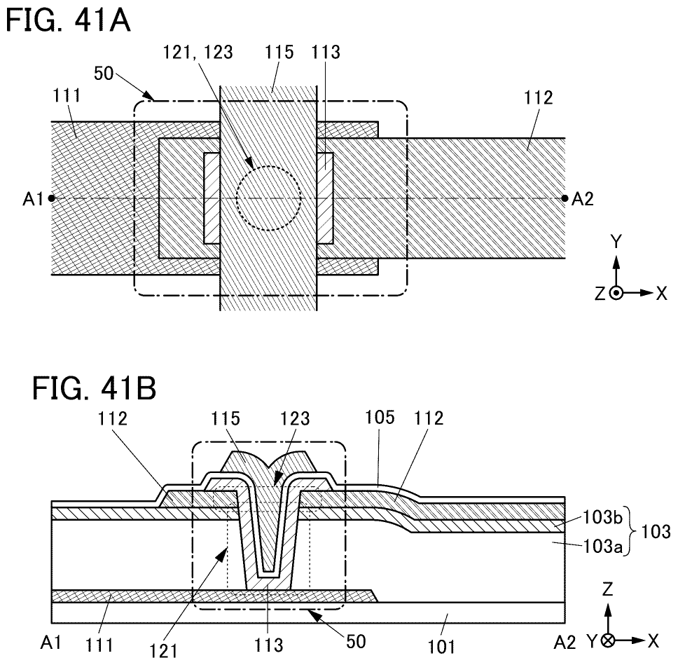

FIG. 41A is a variation example of the structure illustrated in FIG. 4A1, and FIG. 41B is a cross-sectional view taken along the dashed-dotted line A1-A2 in FIG. 41A. FIG. 41A and FIG. 41B illustrate an example in which in the X direction, an end portion of the conductive layer 115 is positioned inside the end portion of the semiconductor layer 113, that is, on the opening 123 side. In the example illustrated in FIG. 41A and FIG. 41B, the semiconductor layer 113 includes a region not overlapping with the conductive layer 115. With such a structure, the area of a region where the conductive layer 115 overlaps with the conductive layer 112 can be small. Thus, parasitic capacitance can be reduced.

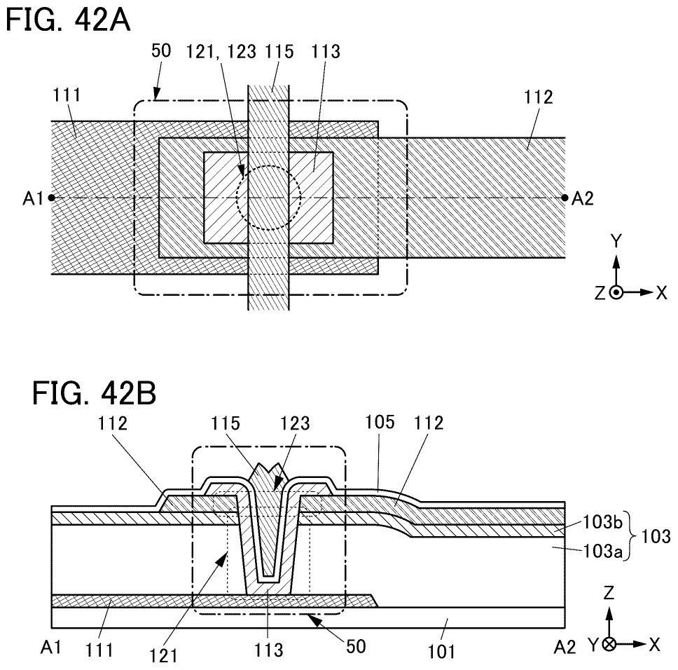

FIG. 42A is a variation example of the structure illustrated in FIG. 41A, and FIG. 42B is a cross-sectional view taken along the dashed-dotted line A1-A2 in FIG. 42A. FIG. 42A and FIG. 42B illustrate an example in which in the X direction, the end portion of the conductive layer 115 is positioned inside the end portion of the conductive layer 112 on the opening 123 side. In the example illustrated in FIG. 42A and FIG. 42B, the opening 121 and the opening 123 include regions not overlapping with the conductive layer 115. With such a structure, the area of a region where the conductive layer 115 overlaps with the conductive layer 112 can be smaller. Thus, parasitic capacitance can be further reduced.

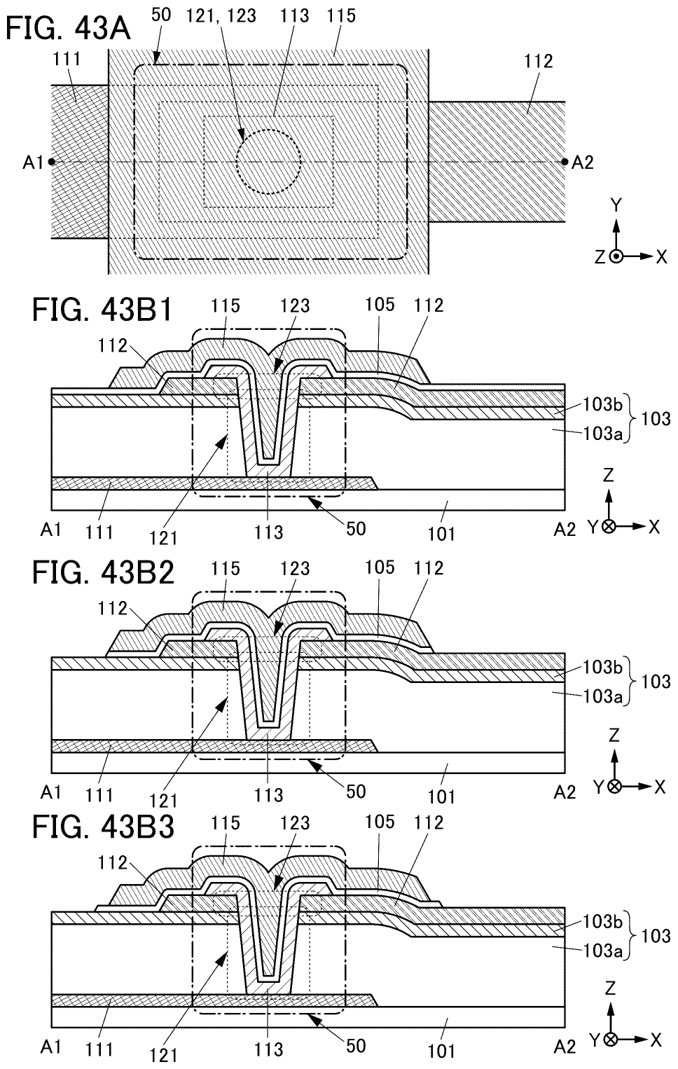

FIG. 43A is a variation example of the structure illustrated in FIG. 4A1, and FIG. 43B1 is a cross-sectional view taken along the dashed-dotted line A1-A2 in FIG. 43A. FIG. 43A and FIG. 43B1 illustrate an example in which the end portion of the conductive layer 115 in the X direction is positioned outside the end portion of the conductive layer 112 in a region where the conductive layer 111 and the conductive layer 112 overlap with each other. In the example illustrated in FIG. 43A and FIG. 43B1, the conductive layer 115 covers the entire region where the conductive layer 111 and the conductive layer 112 overlap with each other. With such a structure, when the conductive layer 115 is formed by a photolithography method and an etching method, the alignment accuracy of a photomask is not necessarily high. Thus, the transistor 50 can be easily manufactured.

FIG. 43B2 is a variation example of the structure illustrated in FIG. 43B1, in which an end portion of the top surface of the insulating layer 105 is aligned or substantially aligned with an end portion of the bottom surface of the conductive layer 115. For example, in the case where the conductive layer 115 is formed by a photolithography method and an etching method and the insulating layer 105 has low etching selectivity with respect to the conductive layer 115, the structure illustrated in FIG. 43B2 may be formed.

FIG. 43B3 is a variation example of the structure illustrated in FIG. 43B2, in which the end portion of the bottom surface of the conductive layer 115 is positioned inside the end portion of the top surface of the insulating layer 105, that is, on the conductive layer 112 side. For example, in the case where the conductive layer 115 is etched in the X direction at a rate higher than a rate at which the insulating layer 105 is etched in the X direction, the structure illustrated in FIG. 43B3 may be formed.

FIG. 43A can be referred to for the plan view of each of the structures illustrated in FIG. 43B2 and FIG. 43B3.

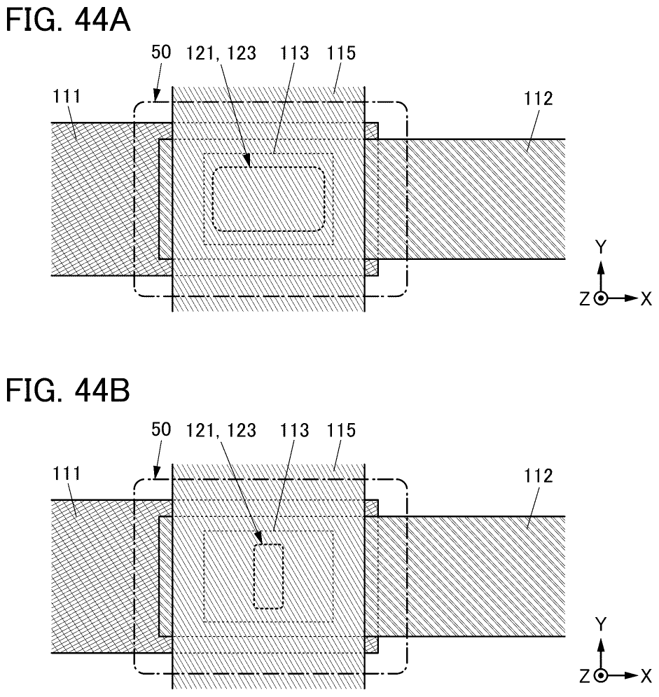

FIG. 44A and FIG. 44B are variation examples of the structure illustrated in FIG. 4A1, in which the opening 121 and the opening 123 each have a rectangular shape with rounded corners in the plan view. FIG. 44A illustrates an example in which the length of each of the opening 121 and the opening 123 in the X direction is longer than the length in the Y direction, and FIG. 44B illustrates an example in which the length of each of the opening 121 and the opening 123 in the X direction is shorter than the length in the Y direction. Note that FIG. 4B can be referred to for the cross-sectional view of the structures illustrated in each of FIG. 44A and FIG. 44B.

In the examples illustrated in FIG. 44A and FIG. 44B, the side surface of the insulating layer 103 in the opening 121 and the side surface of the conductive layer 112 in the opening 123 each include a region not curved but flat. Thus, the coverage with the semiconductor layer 113, the insulating layer 105, and the conductive layer 115 can be increased in the opening 121 and the opening 123. Note that the opening 121 and the opening 123 do not necessarily have rounded corners in a plan view; for example, the opening 121 and the opening 123 may have rectangular, rhombus, or square planar shapes. Alternatively, the opening 121 and the opening 123 may have triangular planar shapes having or not having rounded corners. Further alternatively, the opening 121 and the opening 123 may have polygonal planar shapes such as pentagonal planar shapes, or the polygonal planar shapes having rounded corners. The above is applicable to all the structures described in this specification and the like.

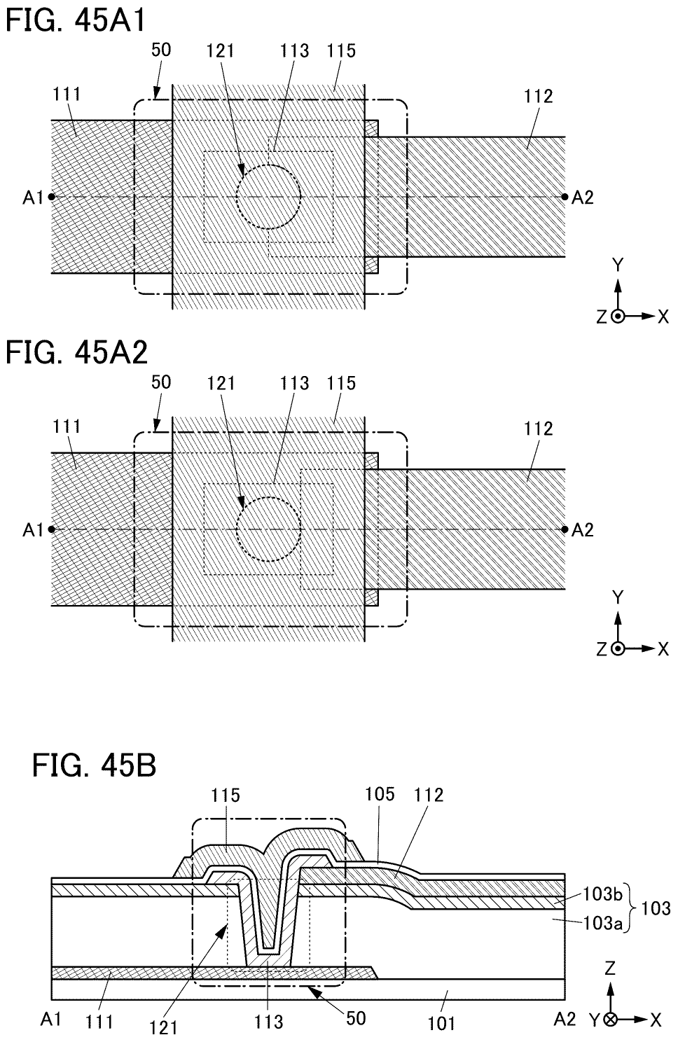

FIG. 45A1 is a variation example of the structure illustrated in FIG. 4A1, in which the conductive layer 112 surrounds the periphery of the opening 121 not entirely but partly in the plan view. FIG. 45A2 is a variation example of the structure illustrated in FIG. 45A1, in which the end portion of the conductive layer 112 is in contact with one point of the periphery of the opening 121 in the plan view. In the example illustrated in FIG. 45A2, the opening 121 has a circular shape and one of end portions of the conductive layer 112 extending in the Y direction is a tangent of the opening 121 in the plan view. FIG. 45B is a cross-sectional view taken along the dashed-dotted line A1-A2 in each of FIG. 45A1 and FIG. 45A2.

In the example illustrated in FIG. 45A1, FIG. 45A2, and FIG. 45B, the area of a region where the conductive layer 112 overlaps with the conductive layer 115 can be small. Thus, parasitic capacitance can be reduced. Meanwhile, in the examples illustrated in FIG. 4A1 and FIG. 4B and the like, the width of the other of the source region and the drain region can be increased.

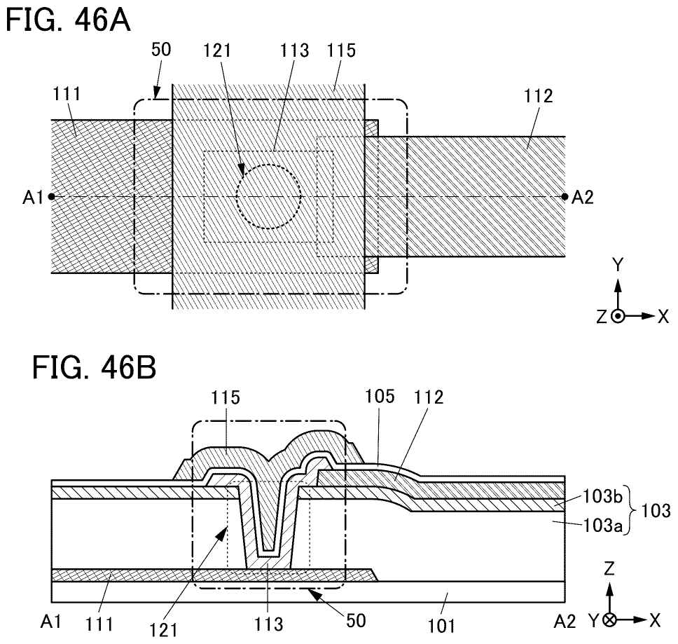

FIG. 46A is a variation example of the structure illustrated in FIG. 45A1 and FIG. 45A2, in which the conductive layer 112 does not cover the opening 121 and the conductive layer 112 is not in contact with the opening 121 in the plan view. FIG. 46B is a cross-sectional view taken along the dashed-dotted line A1-A2 in FIG. 46A.

In the example illustrated in FIG. 46A and FIG. 46B, the area of a region where the conductive layer 112 overlaps with the conductive layer 115 can be small. Thus, parasitic capacitance can be further reduced.

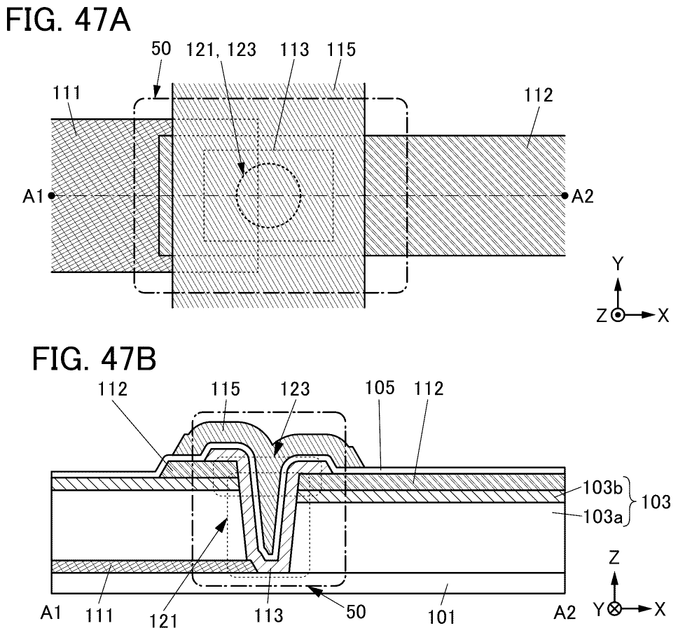

FIG. 47A is a variation example of the structure illustrated in FIG. 4A1, in which the conductive layer 111 overlaps with not the whole but part of the opening 121. FIG. 47B is a cross-sectional view taken along the dashed-dotted line A1-A2 in FIG. 47A. In the example illustrated in FIG. 47A and FIG. 47B, the semiconductor layer 113 includes a region not overlapping with the conductive layer 111 in the opening 121.

In the example illustrated in FIG. 47A and FIG. 47B, parasitic capacitance between the conductive layer 111 and the conductive layer 115 can be small, for example. Meanwhile, in the examples illustrated in FIG. 4A1 and FIG. 4B and the like, the width of the one of the source region and the drain region can be increased.

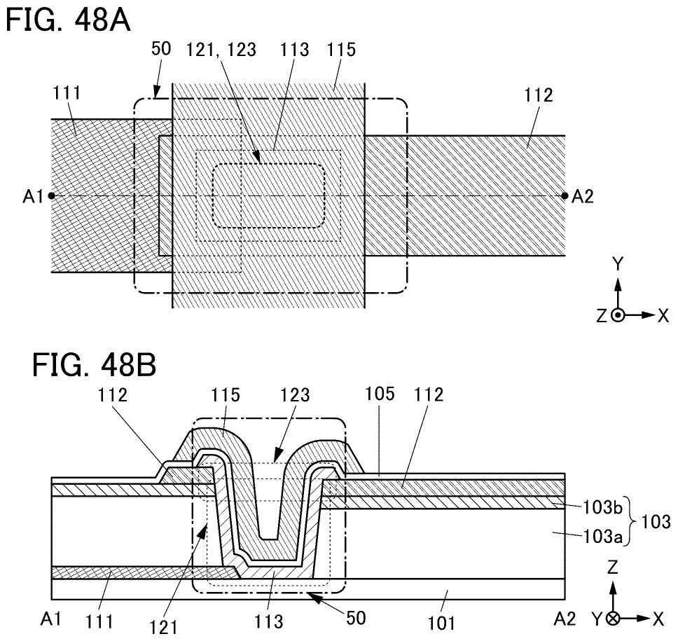

FIG. 48A is a variation example of the structure illustrated in FIG. 47A, in which the opening 121 and the opening 123 each have a rectangular shape with rounded corners in the plan view. FIG. 48B is a cross-sectional view taken along the dashed-dotted line A1-A2 in FIG. 48A.

In the example illustrated in FIG. 48A, the side surface of the insulating layer 103 in the opening 121 and the side surface of the insulating layer 103 in the opening 123 each include a region not curved but flat. Thus, the coverage with the semiconductor layer 113, the insulating layer 105, and the conductive layer 115 can be increased in the opening 121 and the opening 123. Although FIG. 48A illustrates an example in which the length of each of the opening 121 and the opening 123 in the X direction is longer than the length in the Y direction, the length of each of the opening 121 and the opening 123 in the X direction may be shorter than the length in the Y direction.

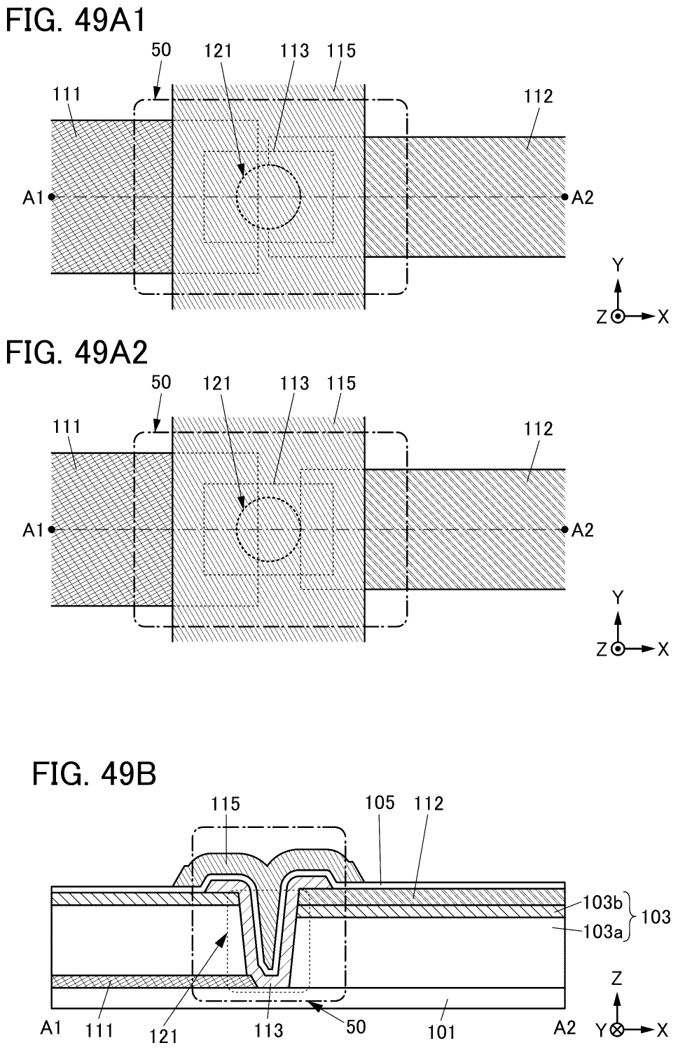

FIG. 49A1 is a variation example of the structure illustrated in FIG. 47A, in which the conductive layer 112 surrounds the periphery of the opening 121 not entirely but partly in the plan view. FIG. 49A2 is a variation example of the structure illustrated in FIG. 49A1, in which the end portion of the conductive layer 112 is in contact with one point of the periphery of the opening 121 in the plan view. In the example illustrated in FIG. 49A2, the opening 121 has a circular shape and one of end portions of the conductive layer 112 extending in the Y direction is a tangent of the opening 121 in the plan view. FIG. 49B is a cross-sectional view taken along the dashed-dotted line A1-A2 in each of FIG. 49A1 and FIG. 49A2.

In the example illustrated in FIG. 49A1, FIG. 49A2, and FIG. 49B, the area of a region where the conductive layer 112 overlaps with the conductive layer 115 can be small. Thus, parasitic capacitance can be reduced. Meanwhile, in the examples illustrated in FIG. 47A and FIG. 47B and the like, the width of the other of the source region and the drain region can be increased.

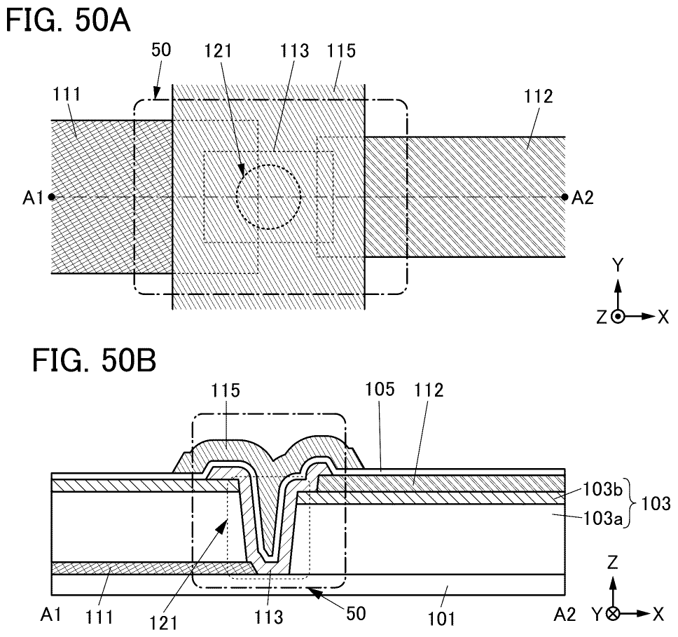

FIG. 50A is a variation example of the structures illustrated in FIG. 49A1 and FIG. 49A2, in which the conductive layer 112 does not overlap with the opening 121. FIG. 50B is a cross-sectional view taken along the dashed-dotted line A1-A2 in FIG. 50A.

In the example illustrated in FIG. 50A and FIG. 50B, the area of a region where the conductive layer 112 overlaps with the conductive layer 115 can be small. Thus, parasitic capacitance can be further reduced.

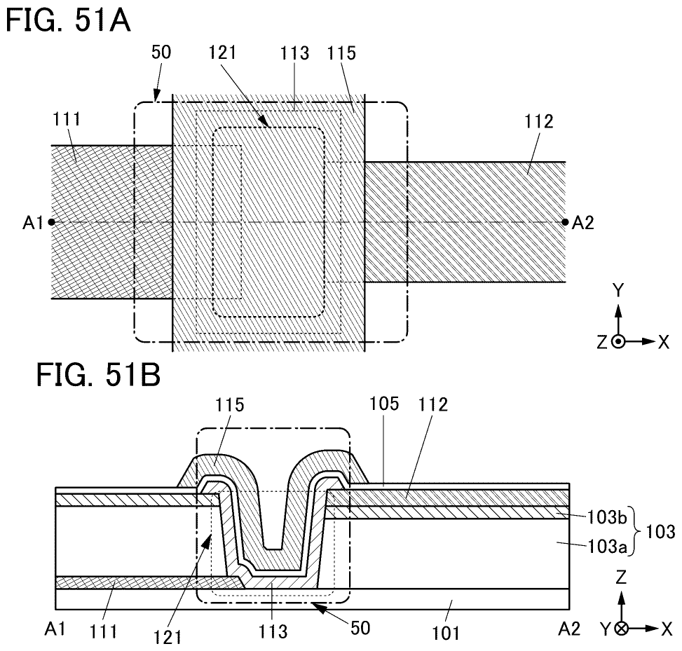

FIG. 51A is a variation example of the structure illustrated in FIG. 48A, in which part of one side of the opening 121 is in contact with the end portion of the conductive layer 112 and the length of the opening 121 in the X direction is shorter than the length in the Y direction in the plan view. FIG. 51B is a cross-sectional view taken along the dashed-dotted line A1-A2 in FIG. 51A.

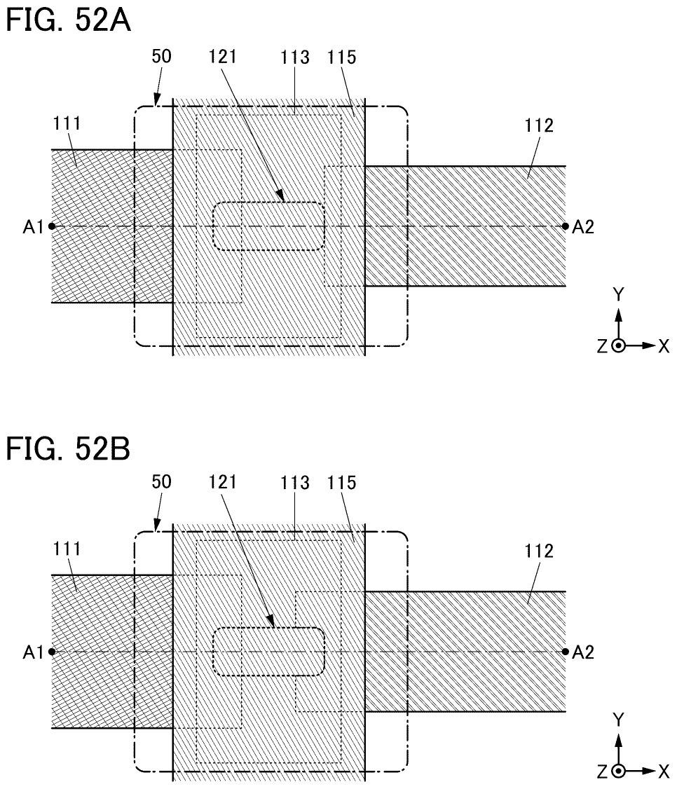

In the example illustrated in FIG. 51A and FIG. 51B, the area of a region where the conductive layer 112 overlaps with the conductive layer 115 can be small. Thus, parasitic capacitance can be reduced. Meanwhile, in the examples illustrated in FIG. 48A and FIG. 48B and the like, the width of the other of the source region and the drain region can be increased. FIG. 52A is a variation example of the structure illustrated in FIG. 51A, in which the length of the opening 121 in the X direction is longer than the length in the Y direction. In the example illustrated in FIG. 52A, the entire one side of the opening 121 can be in contact with the end portion of the conductive layer 112 in the plan view.

FIG. 52B is a variation example of the structure illustrated in FIG. 52A, in which parts of three sides of the opening 121 are in contact with the end portion of the conductive layer 112 in the plan view. In the example illustrated in FIG. 52B, the conductive layer 112 covers the entire side of the opening 121 extending in the Y direction on the conductive layer 112 side and parts of the sides of the opening 121 extending in the X direction in the plan view.

In the example illustrated in FIG. 52B, the width of the other of the source region and the drain region can be increased. Meanwhile, in the example illustrated in FIG. 52A, the area of a region where the conductive layer 112 overlaps with the conductive layer 115 can be small; thus, parasitic capacitance can be reduced. FIG. 51B can be referred to for a cross-sectional view taken along the dashed-dotted line A1-A2 in each of FIG. 52A and FIG. 52B.

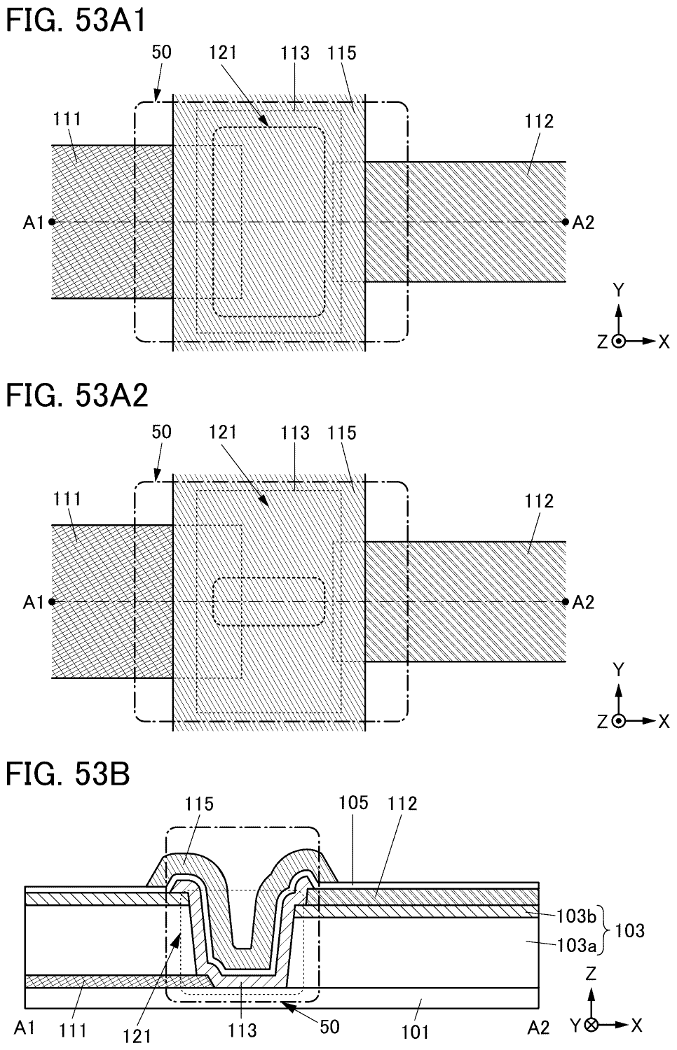

FIG. 53A1 is a variation example of the structure illustrated in FIG. 51A, in which the conductive layer 112 does not cover the opening 121 and the conductive layer 112 is not in contact with the opening 121 in the plan view. FIG. 53A2 is a variation example of the structure illustrated in FIG. 53A1, in which the length of the opening 121 in the X direction is longer than the length in the Y direction. FIG. 53B is a cross-sectional view taken along the dashed-dotted line A1-A2 in FIG. 53A1 and FIG. 53A2.

In the examples illustrated in FIG. 53A1, FIG. 53A2, and FIG. 53B, the area of a region where the conductive layer 112 overlaps with the conductive layer 115 can be small. Thus, parasitic capacitance can be further reduced.

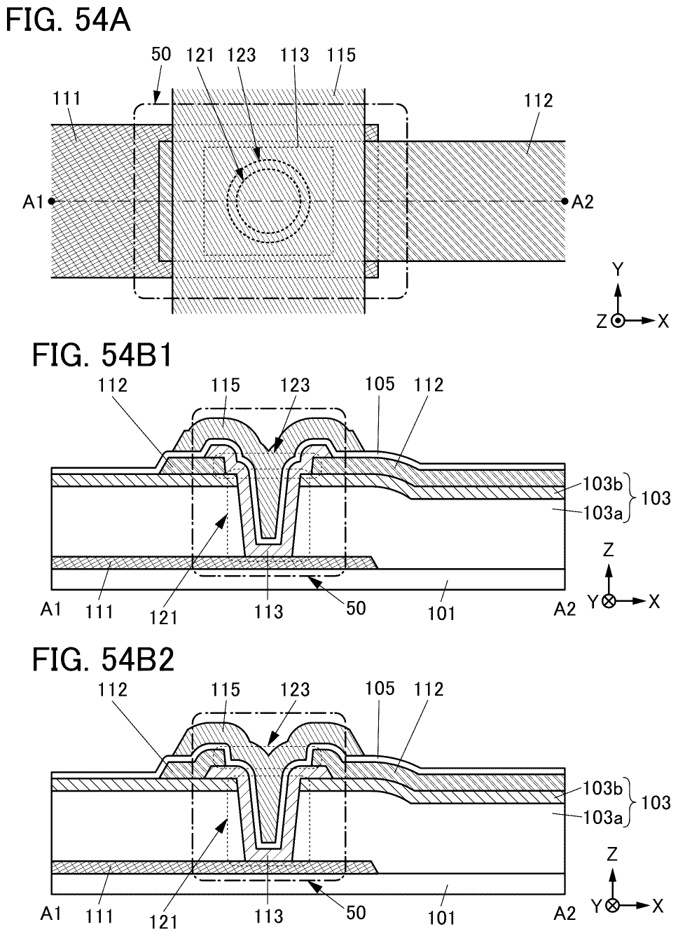

FIG. 54A is a variation example of the structure illustrated in FIG. 4A1, in which the planar shape of the opening 121 is not the same as the planar shape of the opening 123. In the example illustrated in FIG. 54A, the opening 123 has a circular planar shape with a radius larger than that of the opening 121. One or both of the opening 121 and the opening 123 do not necessarily have a circular planar shape. Specifically, one or both of the opening 121 and the opening 123 can have the above-described planar shape such as the rectangular planar shape having rounded corners. FIG. 54B1 is a cross-sectional view taken along the dashed-dotted line A1-A2 in FIG. 54A.

In the case where the opening 121 and the opening 123 are formed in different steps, for example, the opening 121 and the opening 123 may have shapes illustrated in FIG. 54A and FIG. 54B1. For example, in the case where the conductive layer 112 is etched in the X direction and the Y direction at a rate different from a rate at which the insulating layer 103 is etched in the X direction and the Y direction, the opening 121 and the opening 123 may have the shapes illustrated in FIG. 54A and FIG. 54B1 even though being formed in the same step. For example, in the case where the conductive layer 112 is etched in the X direction and the Y direction at a rate higher than a rate at which the insulating layer 103 is etched in the X direction and the Y direction, the opening 121 and the opening 123 may have the shapes illustrated in FIG. 54A and FIG. 54B1 even though being formed in the same step.

FIG. 54B2 is a variation example of the structure illustrated in FIG. 54B1, in which the top surface of the semiconductor layer 113 includes a region in contact with the conductive layer 112. The structure illustrated in FIG. 54B2 can be formed by, for example, forming the opening 121 in the insulating layer 103, forming the semiconductor layer 113, forming a film to be the conductive layer 112, and then forming the opening 123 in the film.

As described above, the channel width of the transistor 50 can be equal to the length of the periphery of the opening 123 in the plan view. Thus, when the opening 123 has a larger area than the opening 121, for example, the transistor 50 can have a large channel width in some cases. Meanwhile, when the areas of the opening 123 and the opening 121 are equal to each other, for example, the transistor 50 can be miniaturized in some cases.

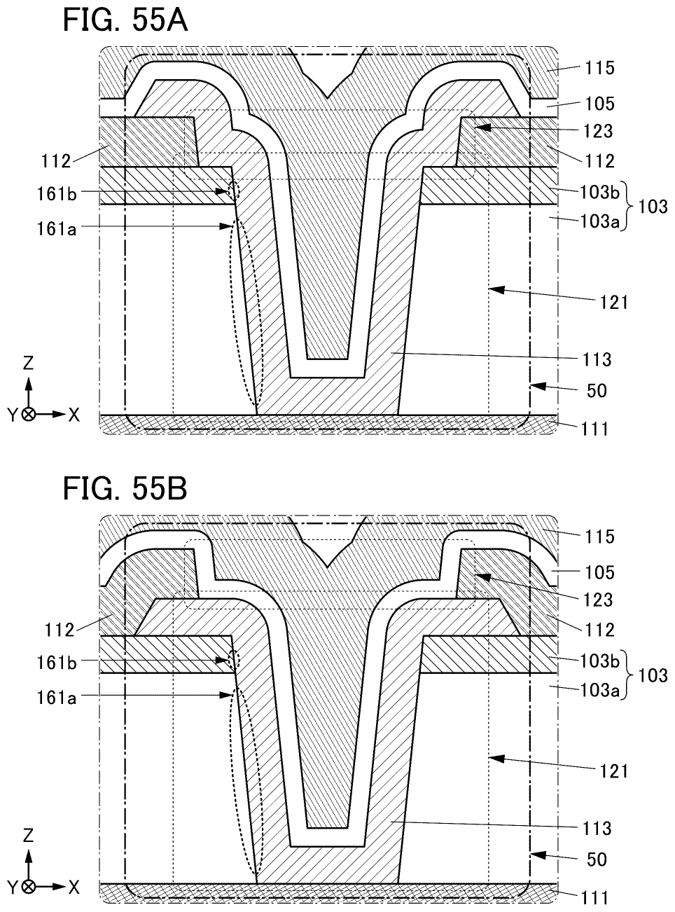

FIG. 55A is an enlarged view illustrating the structure example of the transistor 50 illustrated in FIG. 54B1 and its vicinity, and FIG. 55B is an enlarged view illustrating the structure example of the transistor 50 illustrated in FIG. 54B2 and its vicinity. As illustrated in FIG. 55A and FIG. 55B, the side surface of the insulating layer 103a on the opening 121 side includes a tapered portion 161a and the side surface of the insulating layer 103b on the opening 121 side includes a tapered portion 161b.

As illustrated in FIG. 55A and FIG. 55B, the end portion of the top surface of the insulating layer 103a on the opening 121 side can be the same or substantially the same as the end portion of the bottom surface of the insulating layer 103b on the opening 121 side. Furthermore, the taper angle of the tapered portion 161a can be equal to or substantially equal to the taper angle of the tapered portion 161b. Here, the taper angle of the side surface of the conductive layer 112 on the opening 123 side may be larger or smaller than the taper angles of the tapered portion 161a and the tapered portion 161b. The taper angle of the side surface of the conductive layer 112 on the opening 123 side may be equal to or substantially equal to the taper angles of the tapered portion 161a and the tapered portion 161b.

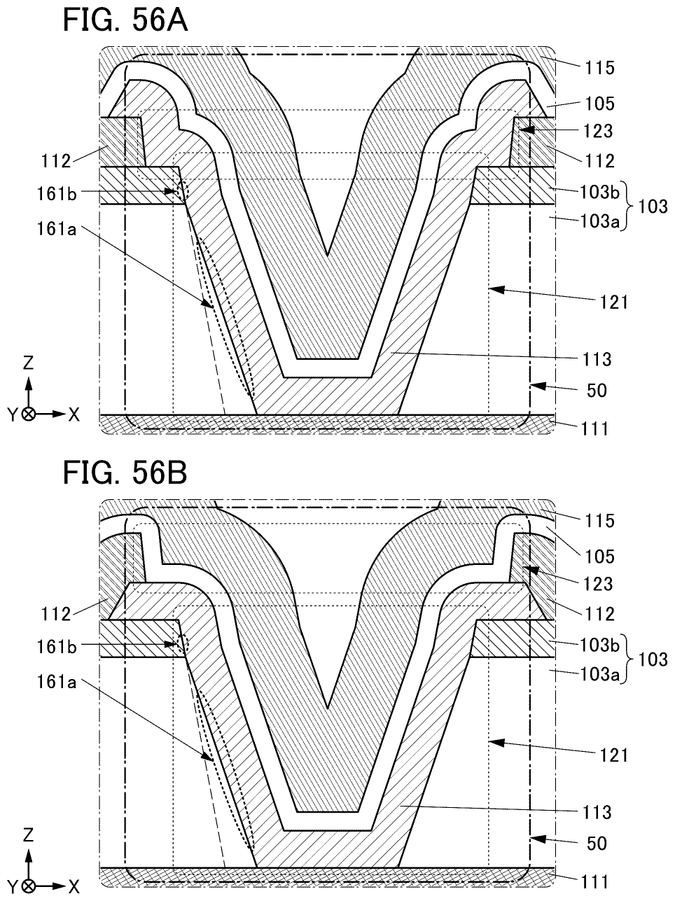

FIG. 56A and FIG. 56B illustrate variation examples of the structures illustrated in FIG. 55A and FIG. 55B, respectively, in which the tapered portion 161a and the tapered portion 161b have different taper angles. In each of FIG. 56A and FIG. 56B, the tapered portion 161b extending to the insulating layer 103a side is indicated by a dashed straight line. For example, in the case where the insulating layer 103a and the insulating layer 103b include different materials and thus the insulating layer 103a and the insulating layer 103b have different processabilities, the tapered portion 161a and the tapered portion 161b have different taper angles in some cases.

FIG. 56A and FIG. 56B illustrate examples where the taper angle of the tapered portion 161a is smaller than the taper angle of the tapered portion 161b. The taper angle of the tapered portion 161a may be larger than the taper angle of the tapered portion 161b. Here, the taper angle of the side surface of the conductive layer 112 on the opening 123 side may be larger or smaller than the taper angle of the tapered portion 161a and may be larger or smaller than the taper angle of the tapered portion 161b. The taper angle of the side surface of the conductive layer 112 on the opening 123 side may be equal to or substantially equal to that of the tapered portion 161a and may be equal to or substantially equal to that of the tapered portion 161b.

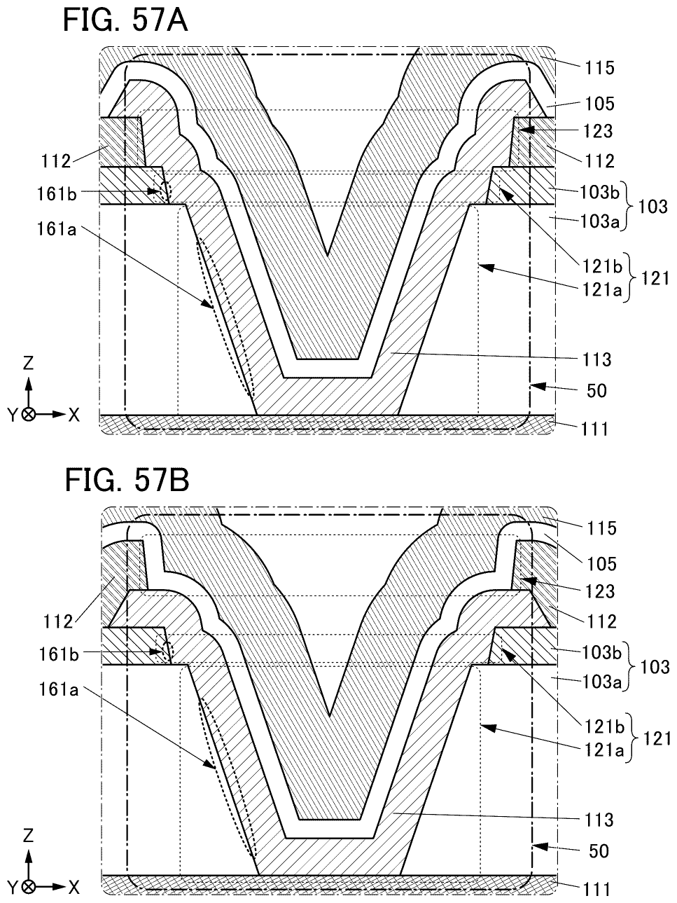

FIG. 57A and FIG. 57B illustrate variation examples of the structures illustrated in FIG. 55A and FIG. 55B, respectively, in which the end portion of the top surface of the insulating layer 103a is not the same as the end portion of the bottom surface of the insulating layer 103b, specifically, an end portion of the insulating layer 103b on the opening 121 side is positioned outward from an end portion of the insulating layer 103a on the opening 121 side. In FIG. 57A and FIG. 57B, the opening 121 provided in the insulating layer 103a is an opening 121a, and the opening 121 provided in the insulating layer 103b is an opening 121b.

For example, in the case where the insulating layer 103a is etched in the X direction at a rate different from a rate at which the insulating layer 103b is etched in the X direction, the end portion of the top surface of the insulating layer 103a is sometimes not the same as the end portion of the bottom surface of the insulating layer 103b. Specifically, in the case where the insulating layer 103b is etched in the X direction at a rate higher than a rate at which the insulating layer 103a is etched in the X direction, any of the structures illustrated in FIG. 57A and FIG. 57B may be formed. Here, the taper angles of the tapered portion 161a and the tapered portion 161b may be equal to, substantially equal to, or different from each other. In addition, the taper angle of the side surface of the conductive layer 112 on the opening 123 side may be larger or smaller than that of the tapered portion 161a and may be larger or smaller than that of the tapered portion 161b. The taper angle of the side surface of the conductive layer 112 on the opening 123 side may be equal to or substantially equal to that of the tapered portion 161a and may be equal to or substantially equal to that of the tapered portion 161b.

The taper angles of the tapered portion 161a, the tapered portion 161b, and the side surface of the conductive layer 112, the positional relationship between the insulating layer 103a, the insulating layer 103b, and the end portion of the conductive layer 112, and the like described with reference to FIG. 55A to FIG. 57B are applicable to all the structures described in this specification and the like.

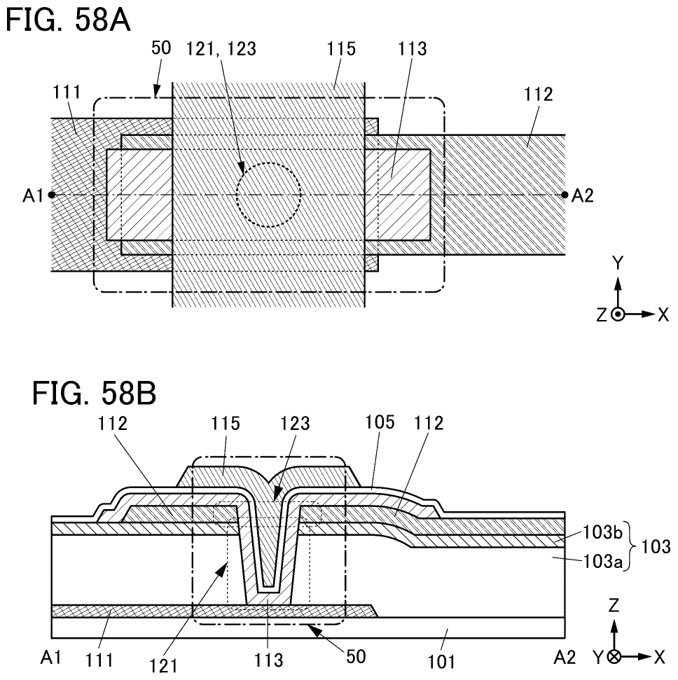

FIG. 58A is a variation example of the structure illustrated in FIG. 4A1, in which the semiconductor layer 113 extends in the X direction beyond an end portion of the conductive layer 112 not facing the opening 123. FIG. 58B is a cross-sectional view taken along the dashed-dotted line A1-A2 in FIG. 58A.

In the example illustrated in FIG. 58B, when seen from the XZ plane, the semiconductor layer 113 covers the end portion of the conductive layer 112 not facing the opening 123. The semiconductor layer 113 can include a region in contact with the top surface of the insulating layer 103.

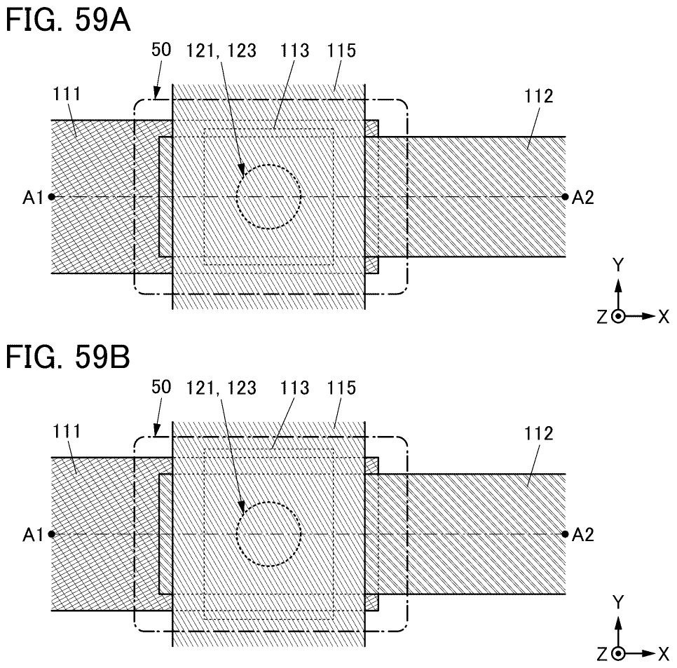

FIG. 59A is a variation example of the structure illustrated in FIG. 4A1, in which the end portion of the semiconductor layer 113 is positioned outside the end portion of the conductive layer 112 and inside the end portion of the conductive layer 111 in the Y direction. In the example illustrated in FIG. 59A, the end portion of the semiconductor layer 113 overlaps with the conductive layer 111 but does not overlap with the conductive layer 112 in the Y direction.

FIG. 59B is a variation example of the structure illustrated in FIG. 4A1, in which the end portion of the semiconductor layer 113 is positioned outside the end portion of the conductive layer 112 and the end portion of the conductive layer 111 in the Y direction. In the example illustrated in FIG. 59B, the end portion of the semiconductor layer 113 overlaps with neither the conductive layer 111 nor the conductive layer 112 in the Y direction. FIG. 4B can be referred to for a cross-sectional view taken along the dashed-dotted line A1-A2 in each of FIG. 59A and FIG. 59B.

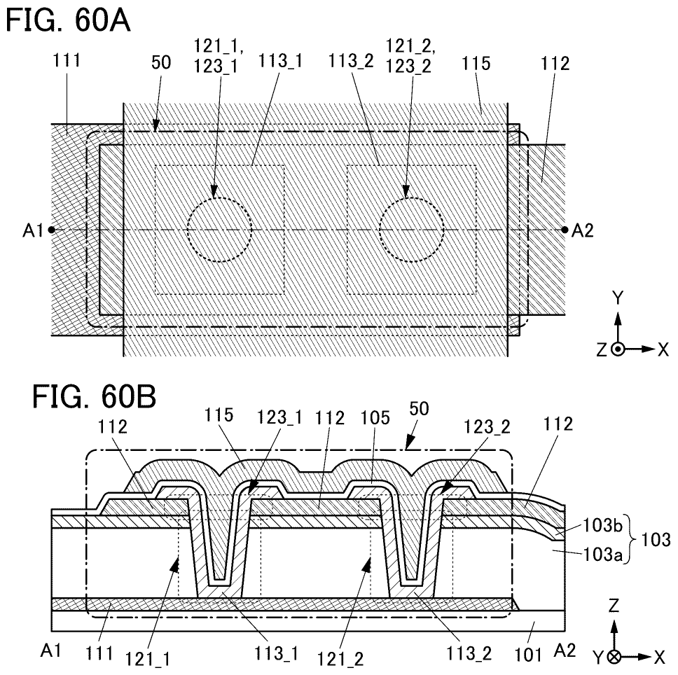

FIG. 60A is a variation example of the structure illustrated in FIG. 4A1, in which two openings 121 and two the opening 123 are included in the transistor 50 and arranged in the X direction. FIG. 60B is a cross-sectional view taken along the dashed-dotted line A1-A2 in FIG. 60A. In the description of the structure in which one transistor 50 includes a plurality of openings 121 and a plurality of openings 123, the X direction and the Y direction are respectively referred to as the row direction and the column direction in some cases.

In FIG. 60A and FIG. 60B, two openings 121 are denoted by an opening 121_1 and an opening 121_2 to be distinguished from each other, and two openings 123 are denoted by an opening 123_1 and an opening 123_2 to be distinguished from each other. In the example illustrated in FIG. 60A and FIG. 60B, the semiconductor layer 113 provided in the opening 121_1 and the opening 123_1 is different from the semiconductor layer 113 provided in the opening 121_2 and the opening 123_2, and the two semiconductor layers 113 are denoted by a semiconductor layer 113_1 and a semiconductor layer 113_2 to be distinguished from each other. The same applies to the following drawings in some cases.

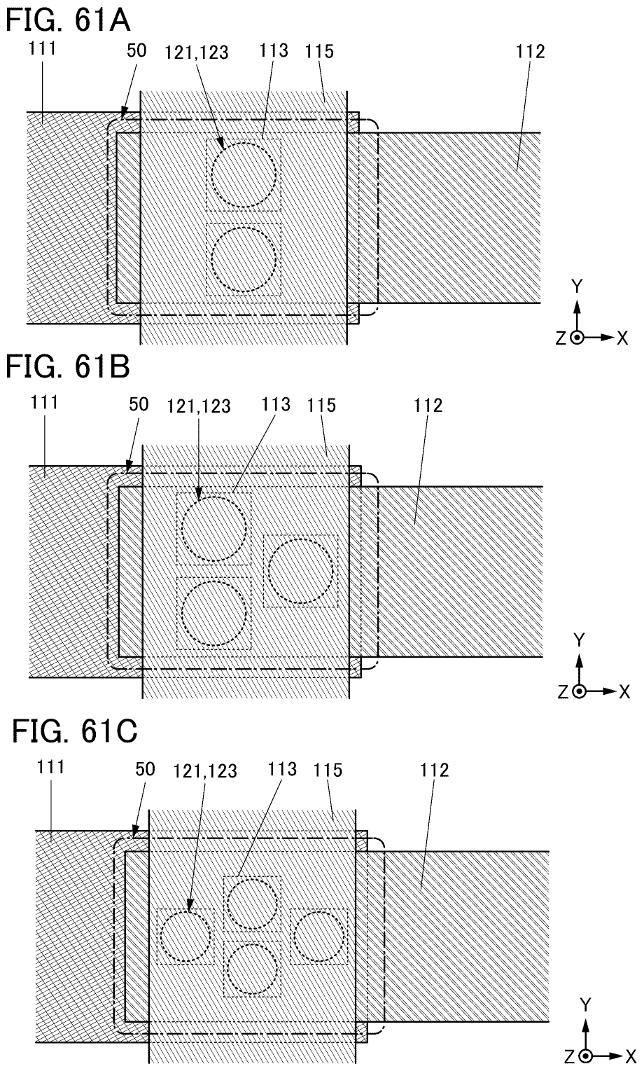

FIG. 61A is a variation example of the structure illustrated in FIG. 60A, in which the two openings 121 and the two openings 123 are arranged in the Y direction. FIG. 61B is a variation example of the structure illustrated in FIG. 61A, in which one opening 121 and one opening 123 are provided on the right side of the two openings 121 and the two openings 123 arranged in the Y direction. When the two openings 121 and the two openings 123 arranged in the Y direction are provided in the first column and the one opening 121 and the one opening 123 are provided in the second column, for example, the centers of the opening 121 and the opening 123 in the second column can be positioned between the centers of the opening 121 and the opening 123 on the upper side in the first column and the centers of the opening 121 and the opening 123 on the lower side in the first column in the Y direction.

FIG. 61C is a variation example of the structure illustrated in FIG. 61A, in which one opening 121 and one opening 123 are provided on each of the left side and the right side of two openings 121 and two openings 123 arranged in the Y direction. When the one opening 121 and the one opening 123 are provided in each of the first column and the third column and the two openings 121 and two openings 123 arranged in the Y direction are provided in the second column, for example, the centers of the opening 121 and the opening 123 in the first column and the centers of the opening 121 and the opening 123 in the third column can be positioned between the centers of the opening 121 and the opening 123 on the upper side in the second column and the centers of the opening 121 and the opening 123 on the lower side in the second column in the Y direction.

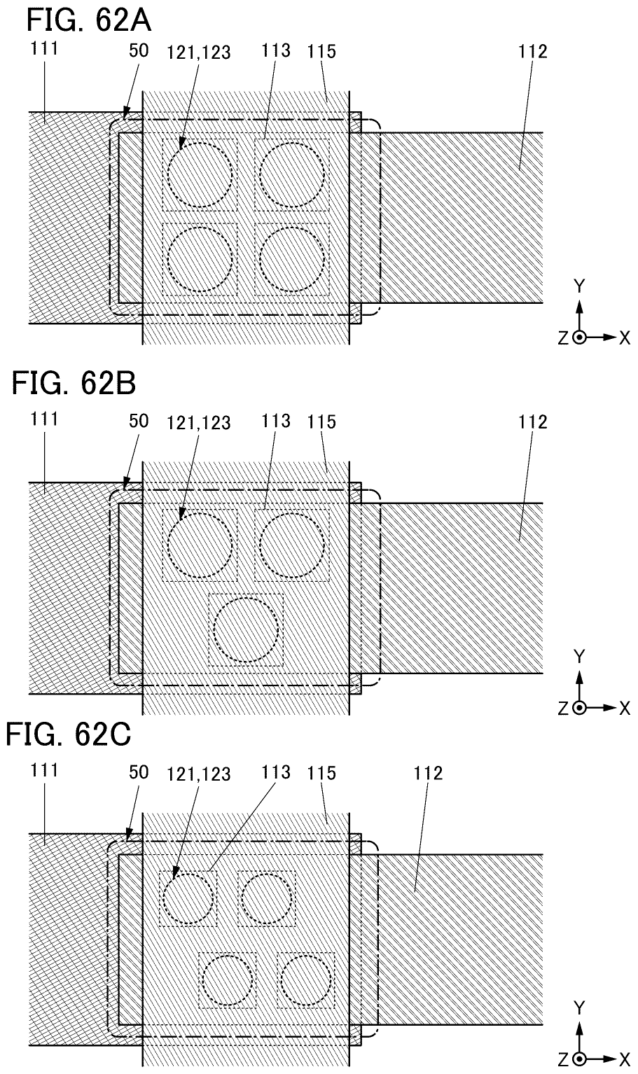

FIG. 62A is a variation example of the structure illustrated in FIG. 4A1, in which four openings 121 and four openings 123 are arranged in a matrix of two rows and two columns. FIG. 62B is a variation example of the structure illustrated in FIG. 60A, in which one opening 121 and one opening 123 are provided below two openings 121 and two openings 123 arranged in the X direction. When the two openings 121 and the two openings 123 arranged in the X direction are provided in the first row and the one opening 121 and the one opening 123 are provided in the second row, for example, the centers of the opening 121 and the opening 123 in the second row can be positioned between the centers of the opening 121 and the opening 123 on the left side in the first row and the centers of the opening 121 and the opening 123 on the right side in the first row in the X direction.

FIG. 62C is a variation example of the structure illustrated in FIG. 62A, in which two openings 121 and two openings 123 on the lower side are positioned closer to the right side than in FIG. 62A. In the structure illustrated in FIG. 62C, four openings 121 and four openings 123 are arranged in a zigzag manner.

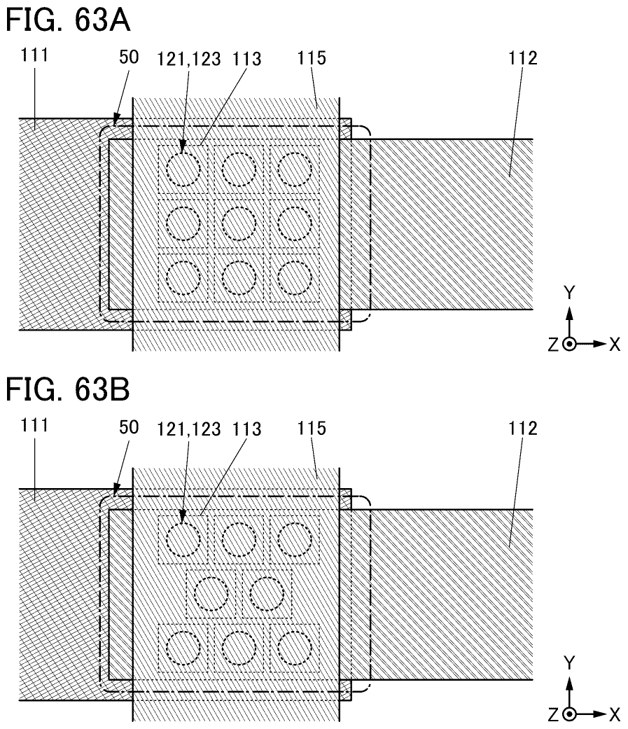

FIG. 63A is a variation example of the structure illustrated in FIG. 4A1, in which nine openings 121 and nine openings 123 are arranged in a matrix of three rows and three columns. FIG. 63B is a variation example of the structure illustrated in FIG. 63A, in which the number of each of the openings 121 and the openings 123 provided in the middle row is two. In the example illustrated in FIG. 63B, the openings 121 and the openings 123 in the upper row and the openings 121 and the openings 123 in the middle row are arranged in a zigzag manner. Also in the structure illustrated in FIG. 63B, the openings 121 and the openings 123 in the lower row and the openings 121 and the openings 123 in the middle row are arranged in a zigzag manner.

When the transistor 50 includes a large number of openings 121 and openings 123, the total length of the periphery of the opening 121 and the periphery of the opening 123 can be long in some cases in the plan view. As described above, the channel width of the transistor 50 can be equal to the length of the periphery of the opening 123 in the plan view, for example. Thus, the transistor 50 including a plurality of openings 121 and a plurality of openings 123 can have a large channel width in some cases. Meanwhile, the transistor 50 including a small number of openings 121 and the openings 123 can be manufactured easily and miniaturized in some cases.

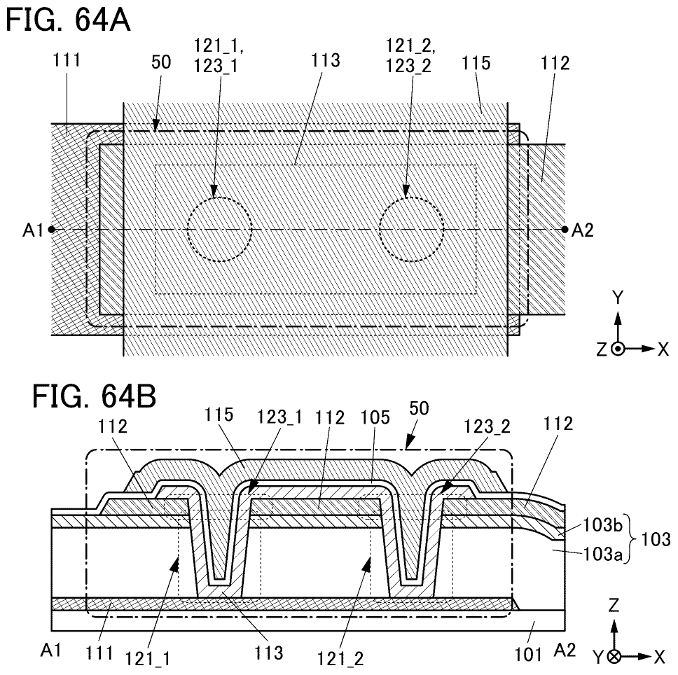

FIG. 64A is a variation example of the structure illustrated in FIG. 60A, in which the semiconductor layer 113 provided in the opening 121_1 and the opening 123_1 is the same as the semiconductor layer 113 provided in the opening 121_2 and the opening 123_2. That is, in the example illustrated in FIG. 64A, the transistor 50 includes two openings 121, two openings 123, and one semiconductor layer 113. FIG. 64B is a cross-sectional view taken along the dashed-dotted line A1-A2 in FIG. 64A.

In the structure illustrated in FIG. 64A and FIG. 64B, for example, when the semiconductor layer 113 is formed by a photolithography method and an etching method, the alignment accuracy of a photomask can be low. Thus, the transistor 50 can be easily manufactured. Meanwhile, in the structure illustrated in FIG. 60A and FIG. 60B, since the surface area of the semiconductor layer 113 can be reduced, entry of impurities into the semiconductor layer 113 can be inhibited in some cases. Note that in the structures illustrated in FIG. 61A to FIG. 63B, the number of semiconductor layers 113 can be one.

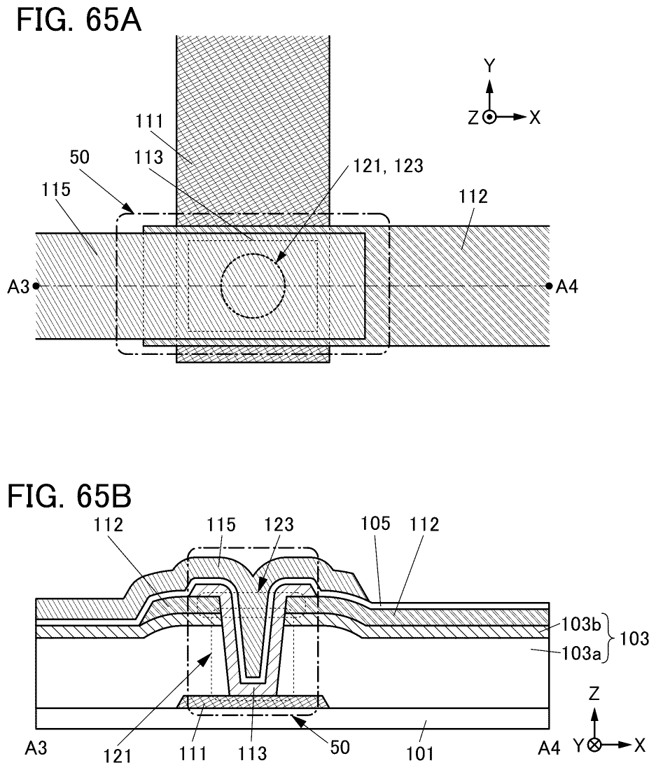

FIG. 65A is a variation example of the structure illustrated in FIG. 4A1, in which the conductive layer 112 extends in a direction that is parallel to the conductive layer 115 and extends in a direction perpendicular to the conductive layer 111. That is, in the example illustrated in FIG. 65A, the conductive layer 112 and the conductive layer 115 extend in the X direction and the conductive layer 111 extends in the Y direction. FIG. 65B is a cross-sectional view taken along the dashed-dotted line A3-A4 in FIG. 65A.

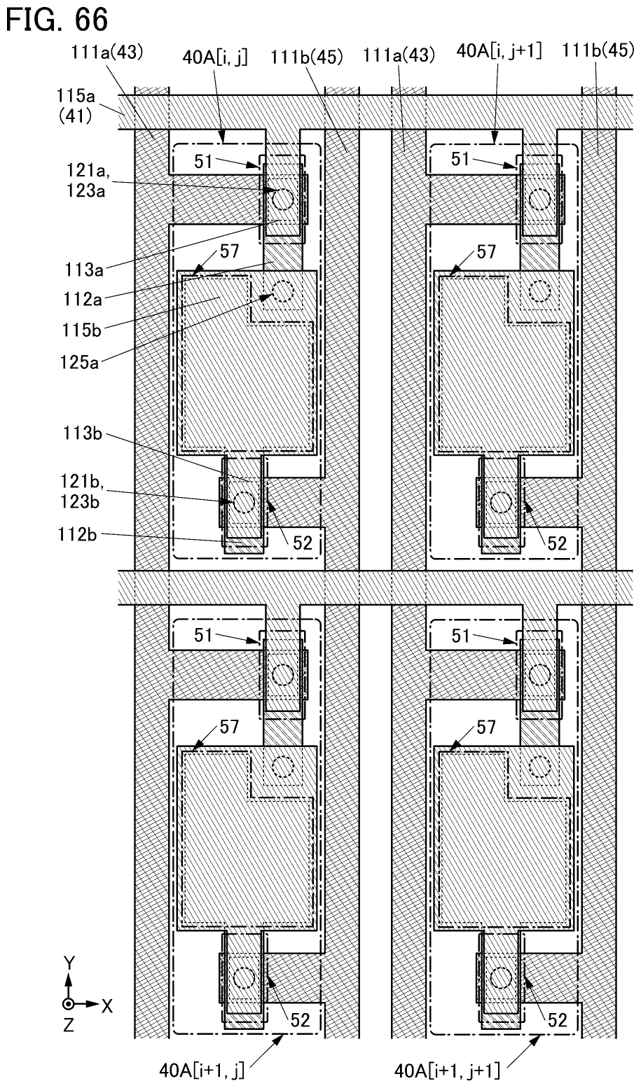

FIG. 66 is a variation example of the structure illustrated in FIG. 6, in which the transistor 50 illustrated in FIG. 65A is used as each of the transistor 51 and the transistor 52. In the example illustrated in FIG. 66, the conductive layer 112a includes a first region overlapping with the opening 121a and the opening 123a and a second region overlapping with the opening 125a, and includes a region extending from the first region toward the second region in the Y direction. Meanwhile, in the example illustrated in FIG. 6, the conductive layer 112a includes a region extending from the first region toward the second region in the X direction.

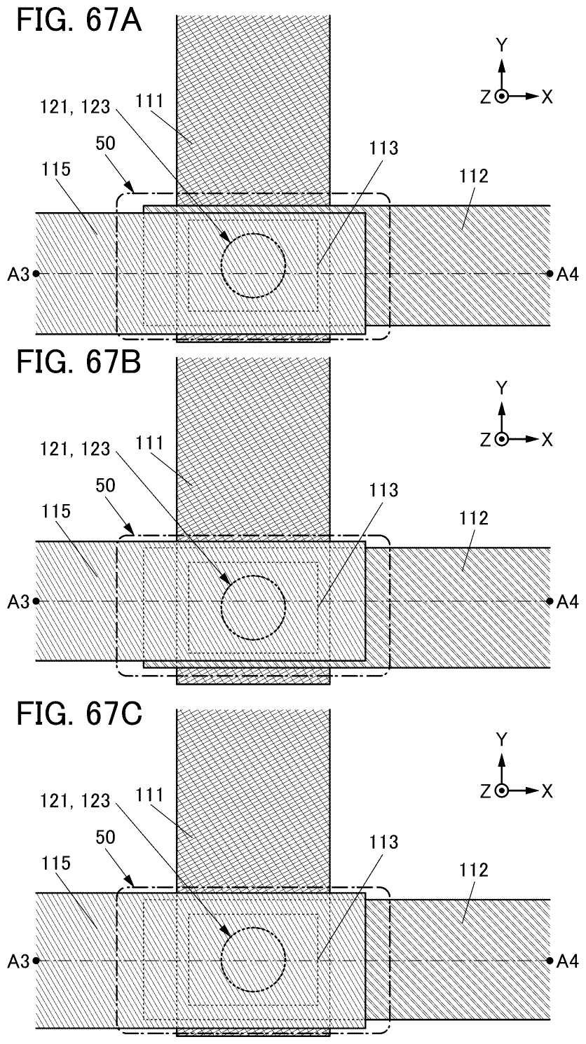

In FIG. 65A, the end portion of the conductive layer 115 in the Y direction and the end portion of the conductive layer 115 in the −Y direction when seen from the opening 123 both have regions overlapping with the conductive layer 112 in the plan view. In other words, the end portion of the conductive layer 115 in the Y direction when seen from the opening 123 is positioned inside the end portion of the conductive layer 112 in the Y direction when seen from the opening 123, and the end portion of the conductive layer 115 in the −Y direction when seen from the opening 123 is positioned inside the end portion of the conductive layer 112 in the Y direction when seen from the opening 123; however, one embodiment of the present invention is not limited thereto. FIG. 67A illustrates an example in which the end portion of the conductive layer 115 in the −Y direction does not overlap with the conductive layer 112 when seen from the opening 123 in the plan view. In other words, in the example illustrated in FIG. 67A, the end portion of the conductive layer 115 in the −Y direction is positioned outside the end portion of the conductive layer 112 in the −Y direction when seen from the opening 123.

FIG. 67B illustrates an example in which the end portion of the conductive layer 115 in the Y direction does not overlap with the conductive layer 112 when seen from the opening 123 in the plan view. In other words, in the example illustrated in FIG. 67B, the end portion of the conductive layer 115 in the Y direction is positioned outside the end portion of the conductive layer 112 in the −Y direction when seen from the opening 123.

FIG. 67C illustrates an example in which the end portion of the conductive layer 115 in the Y direction and the end portion of the conductive layer 115 in the −Y direction when seen from the opening 123 both do not overlap with the conductive layer 112 in the plan view. In other words, in the example illustrated in FIG. 67C, the end portion of the conductive layer 115 in the Y direction when seen from the opening 123 is positioned outside the end portion of the conductive layer 112 in the Y direction when seen from the opening 123, and the end portion of the conductive layer 115 in the −Y direction when seen from the opening 123 is positioned outside the end portion of the conductive layer 112 in the Y direction when seen from the opening 123.

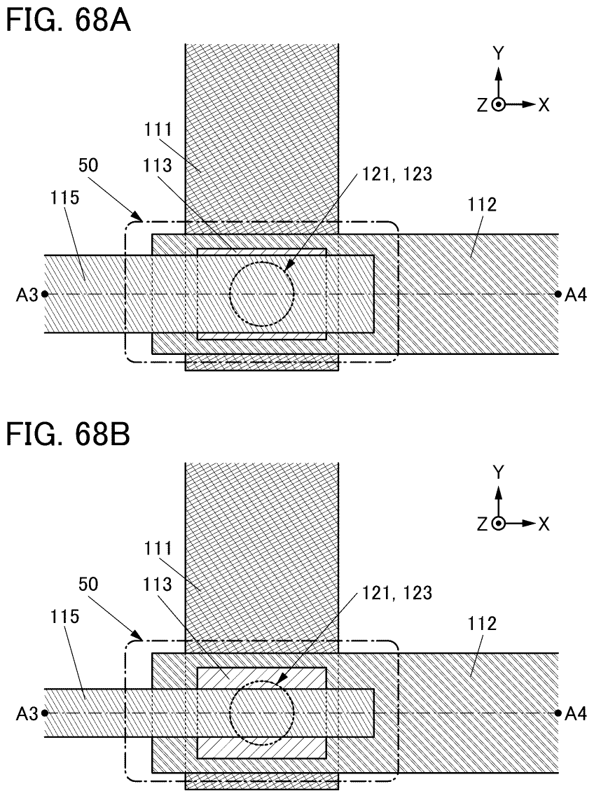

FIG. 68A is a variation example of the structure illustrated in FIG. 65A. FIG. 68A illustrates an example in which in the Y direction, the end portion of the conductive layer 115 is positioned inside the end portion of the semiconductor layer 113, that is, on the opening 123 side. In the example illustrated in FIG. 68A, the semiconductor layer 113 includes a region not overlapping with the conductive layer 115. With such a structure, the area of a region where the conductive layer 115 overlaps with the conductive layer 112 can be small. Thus, parasitic capacitance can be reduced.

FIG. 68B is a variation example of the structure illustrated in FIG. 68A. FIG. 68B illustrates an example in which in the Y direction, the end portion of the conductive layer 115 is positioned inside the end portion of the conductive layer 112 on the opening 123 side. In the example illustrated in FIG. 68B, the opening 121 and the opening 123 include regions not overlapping with the conductive layer 115. With such a structure, the area of the region where the conductive layer 115 overlaps with the conductive layer 112 can be smaller. Thus, parasitic capacitance can be further reduced.

FIG. 65B can be referred to for the cross-sectional view taken along the dashed-dotted line A3-A4 in FIG. 67A, FIG. 67B, FIG. 67C, FIG. 68A, and FIG. 68B.

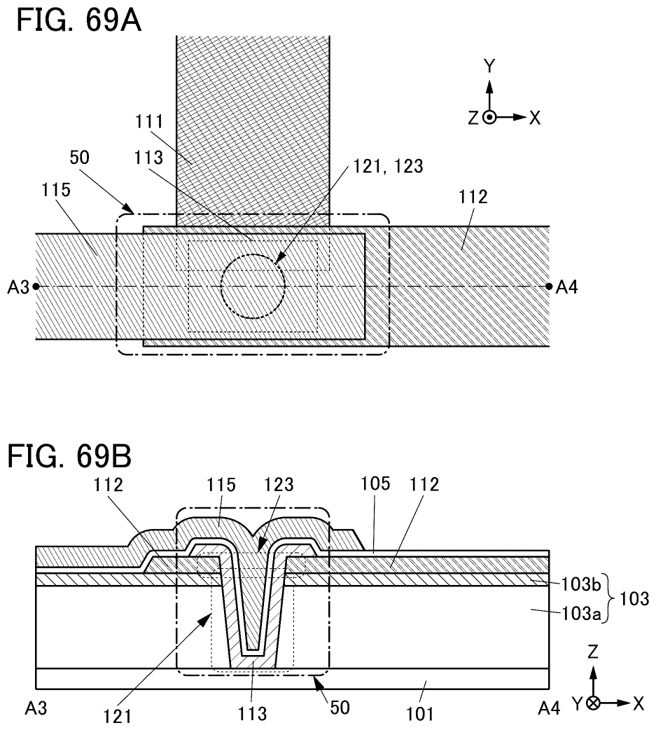

FIG. 69A is a variation example of the structure illustrated in FIG. 65A, in which the conductive layer 111 overlaps with not the whole but part of the opening 121. FIG. 69B is a cross-sectional view taken along the dashed-dotted line A3-A4 in FIG. 69A. In the example illustrated in FIG. 69A and FIG. 69B, the semiconductor layer 113 includes a region not overlapping with the conductive layer 111 in the opening 121.

In the example illustrated in FIG. 69A and FIG. 69B, parasitic capacitance between the conductive layer 111 and the conductive layer 115 can be small, for example. Meanwhile, in the examples illustrated in FIG. 65A and FIG. 65B and the like, the width of the one of the source region and the drain region can be increased.

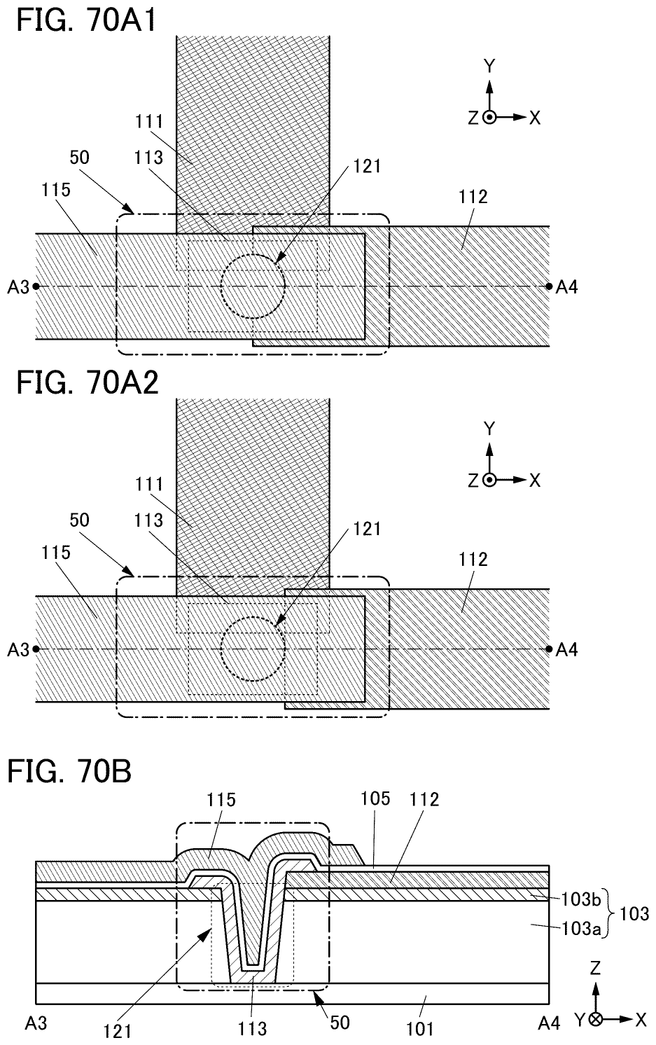

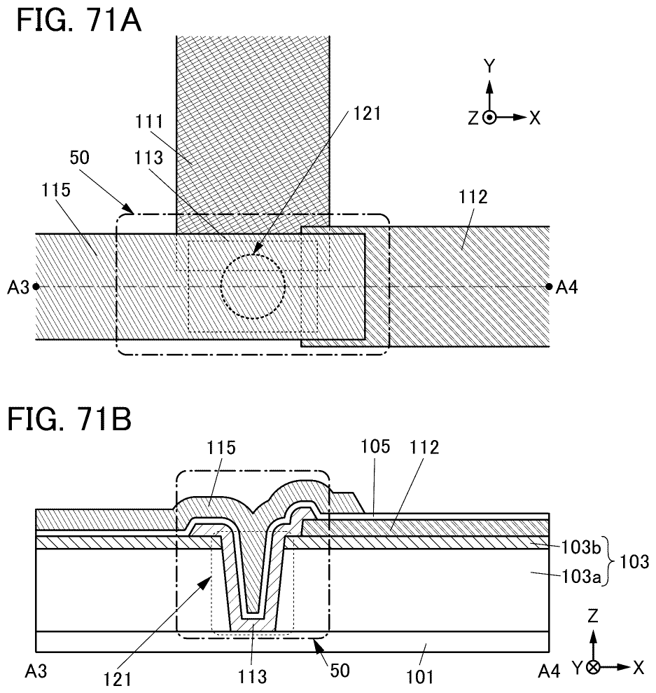

FIG. 70A1 is a variation example of the structure illustrated in FIG. 69A, in which the conductive layer 112 surrounds the periphery of the opening 121 not entirely but partly in the plan view. FIG. 70A2 is a variation example of the structure illustrated in FIG. 70A1, in which the end portion of the conductive layer 112 is in contact with one point of the periphery of the opening 121 in the plan view. In the example illustrated in FIG. 70A2, the opening 121 has a circular shape and one of end portions of the conductive layer 112 extending in the Y direction is a tangent of the opening 121 in the plan view. FIG. 70B is a cross-sectional view taken along the dashed-dotted line A3-A4 in FIG. 70A1 and FIG. 70A2.

In the example illustrated in FIG. 70A1, FIG. 70A2, and FIG. 70B, the area of the region where the conductive layer 112 overlaps with the conductive layer 115 can be small. Thus, parasitic capacitance can be reduced. Meanwhile, in the examples illustrated in FIG. 69A and FIG. 69B and the like, the width of the other of the source region and the drain region can be increased.

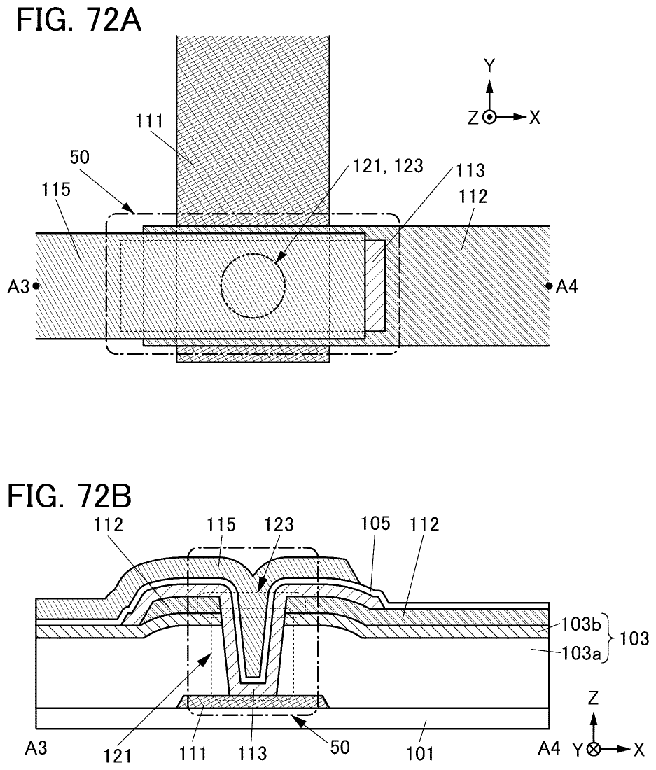

FIG. 71A is a variation example of the structures illustrated in FIG. 70A1 and FIG. 70A2, in which the conductive layer 112 does not overlap with the opening 121. FIG. 71B is a cross-sectional view taken along the dashed-dotted line A3-A4 in FIG. 71A.

In the example illustrated in FIG. 71A and FIG. 71B, the area of the region where the conductive layer 112 overlaps with the conductive layer 115 can be small. Thus, parasitic capacitance can be further reduced.

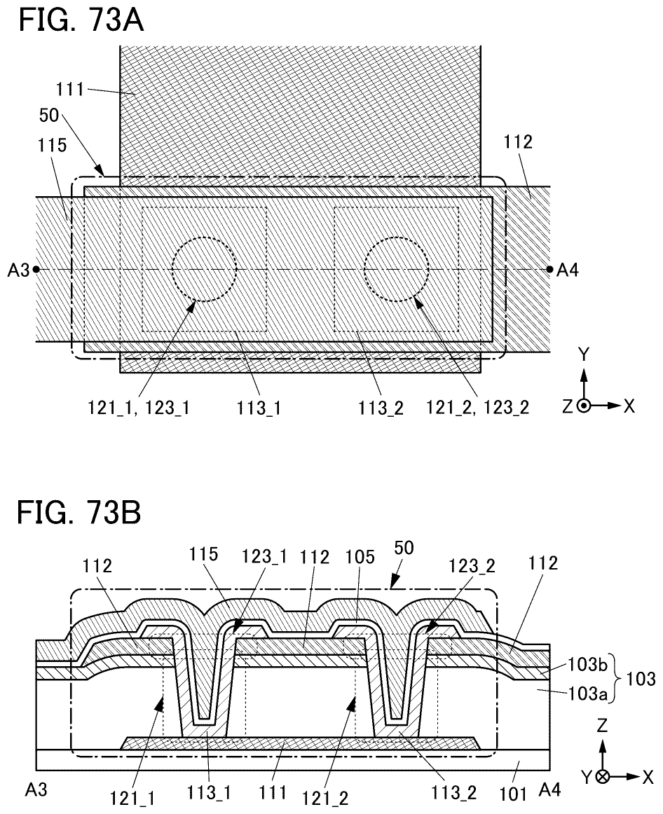

FIG. 72A is a variation example of the structure illustrated in FIG. 65A, in which the semiconductor layer 113 extends in the X direction beyond the end portion of the conductive layer 112 not facing the opening 123. FIG. 72B is a cross-sectional view taken along the dashed-dotted line A3-A4 in FIG. 72A.

In the example illustrated in FIG. 72B, when seen from the XZ plane, the semiconductor layer 113 covers the end portion of the conductive layer 112 on the side not facing the opening 123. The semiconductor layer 113 can include a region in contact with the top surface of the insulating layer 103.

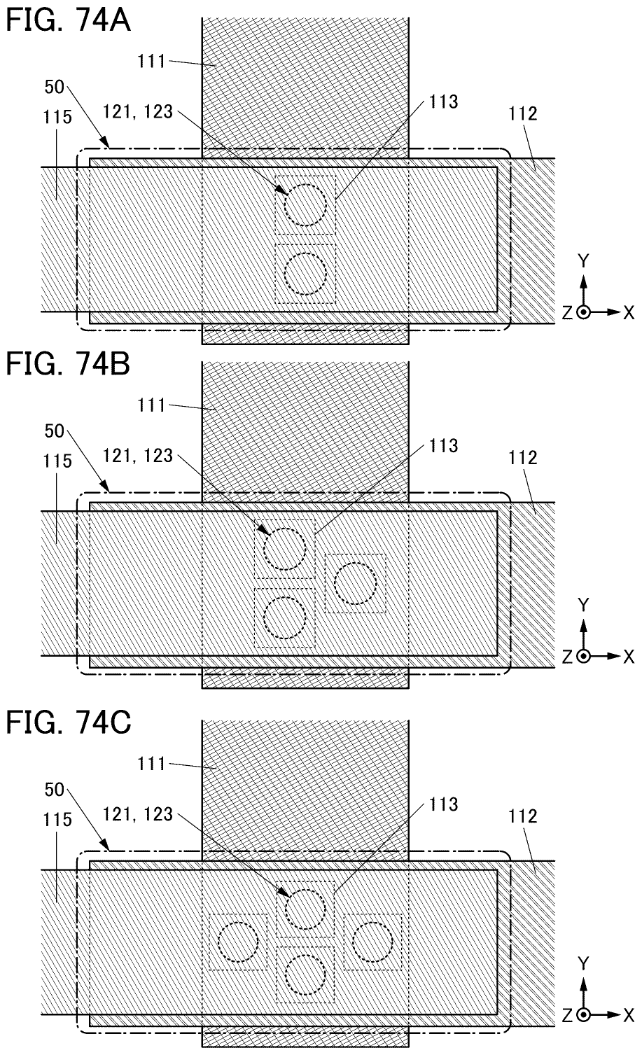

FIG. 73A is a variation example of the structure illustrated in FIG. 65A, in which two openings 121 and two the opening 123 are included in the transistor 50 and arranged in the X direction. FIG. 73B is a cross-sectional view taken along the dashed-dotted line A3-A4 in FIG. 73A.

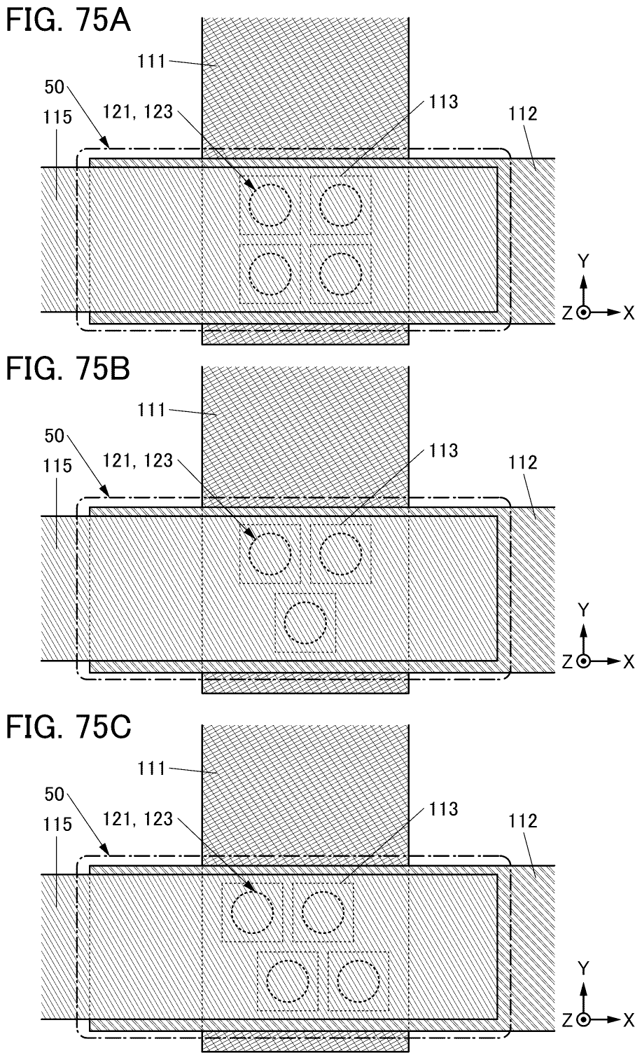

FIG. 74A is a variation example of the structure illustrated in FIG. 73A, in which the two openings 121 and the two openings 123 are arranged in the Y direction. FIG. 74B is a variation example of the structure illustrated in FIG. 74A, in which one opening 121 and one opening 123 are provided on the right side of the two openings 121 and the two openings 123 arranged in the Y direction. When the two openings 121 and the two openings 123 arranged in the Y direction are provided in the first column and the one opening 121 and the one opening 123 are provided in the second column, for example, the centers of the opening 121 and the opening 123 in the second column can be positioned between the centers of the opening 121 and the opening 123 on the upper side in the first column and the centers of the opening 121 and the opening 123 on the lower side in the first column in the Y direction.

FIG. 74C is a variation example of the structure illustrated in FIG. 74A, in which one opening 121 and one opening 123 are provided on each of the left side and the right side of two openings 121 and two openings 123 arranged in the Y direction. When the one opening 121 and the one opening 123 are provided in each of the first column and the third column and the two openings 121 and two openings 123 arranged in the Y direction are provided in the second column, for example, the centers of the opening 121 and the opening 123 in the first column and the centers of the opening 121 and the opening 123 in the third column can be positioned between the centers of the opening 121 and the opening 123 on the upper side in the second column and the centers of the opening 121 and the opening 123 on the lower side in the second column in the Y direction.

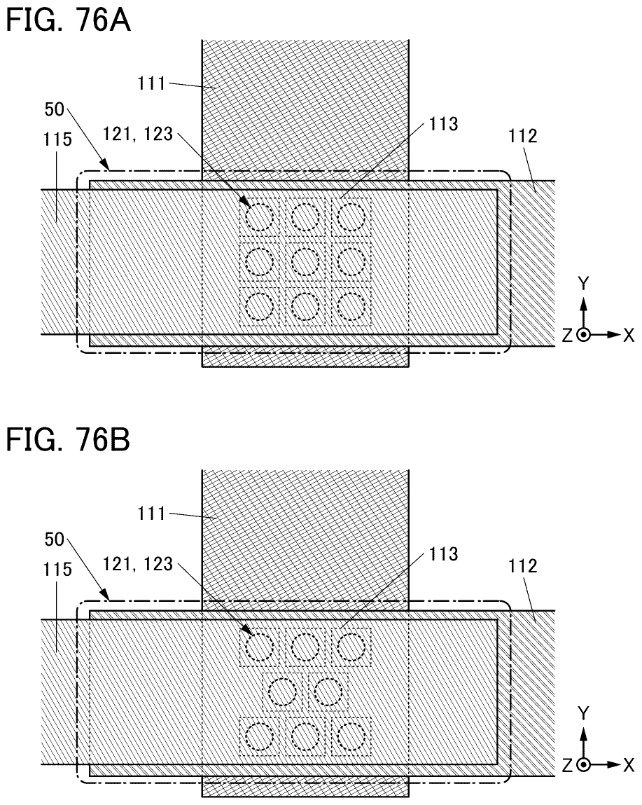

FIG. 75A is a variation example of the structure illustrated in FIG. 65A, in which four openings 121 and four openings 123 are arranged in a matrix of two rows and two columns. FIG. 75B is a variation example of the structure illustrated in FIG. 73A, in which one opening 121 and one opening 123 are provided below two openings 121 and two openings 123 arranged in the X direction. When the two openings 121 and the two openings 123 arranged in the X direction are provided in the first row and the one opening 121 and the one opening 123 are provided in the second row, for example, the centers of the opening 121 and the opening 123 in the second row can be positioned between the centers of the opening 121 and the opening 123 on the left side in the first row and the centers of the opening 121 and the opening 123 on the right side in the first row in the X direction.

FIG. 75C is a variation example of the structure illustrated in FIG. 75A, in which two openings 121 and two openings 123 on the lower side are positioned closer to the right side than in FIG. 75A. In the structure illustrated in FIG. 75C, four openings 121 and four openings 123 are arranged in a zigzag manner.

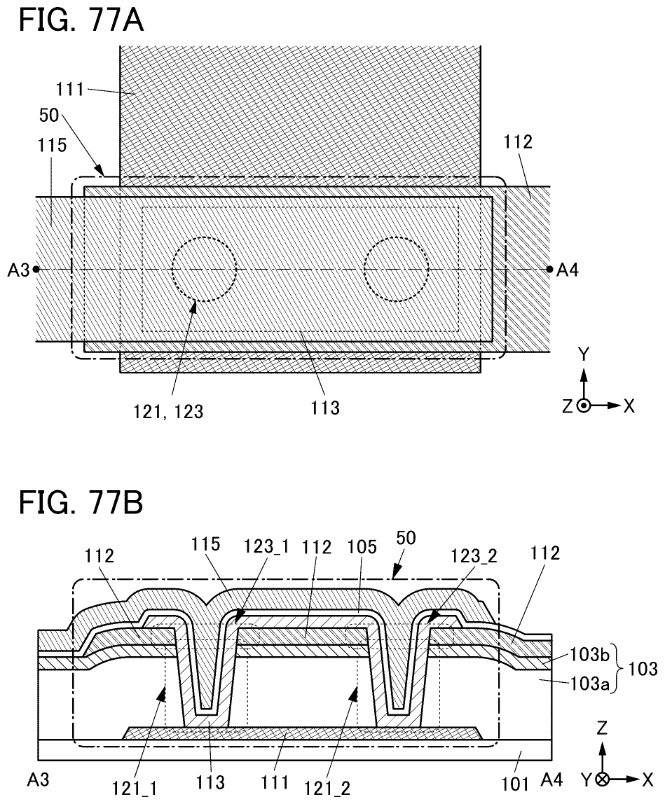

FIG. 76A is a variation example of the structure illustrated in FIG. 65A, in which nine openings 121 and nine openings 123 are arranged in a matrix of three rows and three columns. FIG. 76B is a variation example of the structure illustrated in FIG. 76A, in which the number of each of the openings 121 and the openings 123 provided in the middle row is two. In the example illustrated in FIG. 76B, the openings 121 and the openings 123 in the upper row and the openings 121 and the openings 123 in the middle row are arranged in a zigzag manner. Also in the structure illustrated in FIG. 76B, the openings 121 and the openings 123 in the lower row and the openings 121 and the openings 123 in the middle row are arranged in a zigzag manner.

When the transistor 50 includes a large number of openings 121 and openings 123 as described above, the total length of the periphery of the opening 121 and the periphery of the opening 123 can be long in some cases in the plan view. Since the channel width of the transistor 50 can be equal to the length of the periphery of the opening 123 in the plan view as described above, for example, the channel width of the transistor 50 can be increased in some cases by a plurality of openings 121 and a plurality of openings 123 provided in the transistor 50. Meanwhile, the transistor 50 including a small number of openings 121 and the openings 123 can be manufactured easily and miniaturized in some cases.

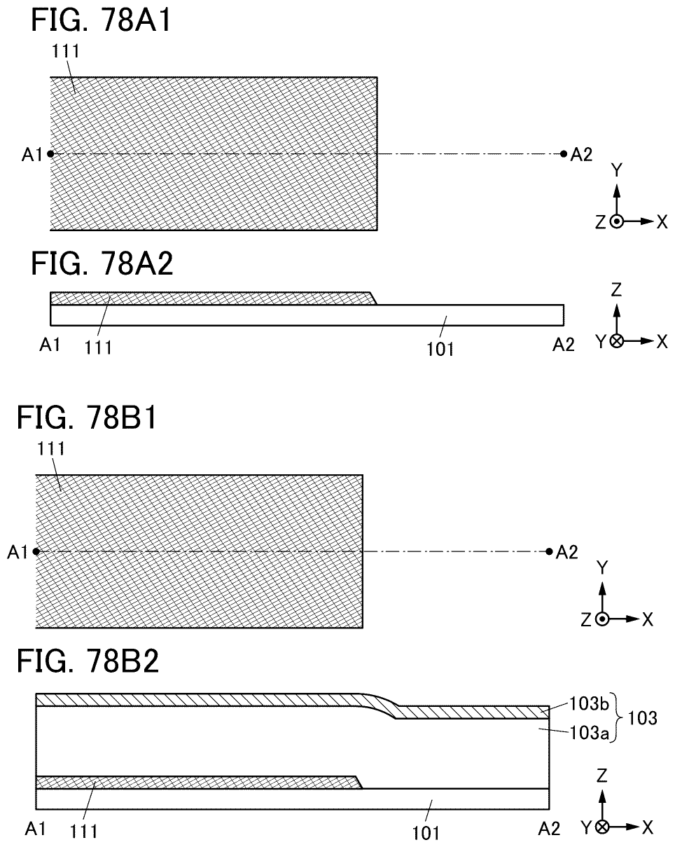

FIG. 77A is a variation example of the structure illustrated in FIG. 73A, in which the semiconductor layer 113 provided in the opening 121_1 and the opening 123_1 is the same as the semiconductor layer 113 provided in the opening 121_2 and the opening 123_2. That is, in the example illustrated in FIG. 77A, the transistor 50 includes two openings 121, two openings 123, and one semiconductor layer 113. FIG. 77B is a cross-sectional view taken along the dashed-dotted line A3-A4 in FIG. 77A.

In the structure illustrated in FIG. 77A and FIG. 77B, for example, when the semiconductor layer 113 is formed by a photolithography method and an etching method, the alignment accuracy of a photomask can be low. Thus, the transistor 50 can be easily manufactured. Meanwhile, in the structure illustrated in FIG. 73A and FIG. 73B, since the surface area of the semiconductor layer 113 can be reduced, entry of impurities into the semiconductor layer 113 can be inhibited in some cases. Note that in the structures illustrated in FIG. 74A to FIG. 76B, the number of semiconductor layers 113 can be one.

### Manufacturing Method Example 1 of Display Apparatus

An example of a method for manufacturing the display apparatus of one embodiment of the present invention will be described below with reference to drawings. Here, a method for manufacturing the display apparatus including the transistor 50 illustrated in FIG. 4A1 and FIG. 4B is described as an example.

Note that thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an ALD method, or the like. A CVD method includes a PECVD method, a thermal CVD method, and the like. An example of a thermal CVD method is a metal organic chemical vapor deposition (MOCVD: Metal Organic CVD) method.

The thin films included in the display apparatus (insulating films, semiconductor films, conductive films, and the like) can be formed by a method such as spin coating, dipping, spray coating, ink-jetting, dispensing, screen printing, offset printing, a doctor knife, a slit coater, a roll coater, a curtain coater, or a knife coater in some cases.

The thin films can be processed by, for example, etching of the thin films in accordance with a pattern of a resist mask that has been formed by a photolithography method. Alternatively, a nanoimprinting method, a sandblasting method, a lift-off method, or the like may be used for the processing of the thin films. Island-shaped thin films may be directly formed by a film formation method using a blocking mask such as a metal mask. A photosensitive thin film can be processed by light exposure and development. That is, the photosensitive thin film can be processed by a photolithography method.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet rays, KrF laser light, ArF laser light, or the like can be used. Light exposure may be performed by liquid immersion light exposure technique. As the light used for light exposure, extreme ultraviolet (EUV) light or X-rays may be used. Instead of the light used for light exposure, an electron beam can be used. It is preferable to use extreme ultraviolet light, X-rays, or an electron beam because extremely minute processing is possible. Note that when light exposure is performed by scanning of a beam such as an electron beam, a photomask is not needed.

For the etching of the thin films, a dry etching method, a wet etching method, or the like can be used.

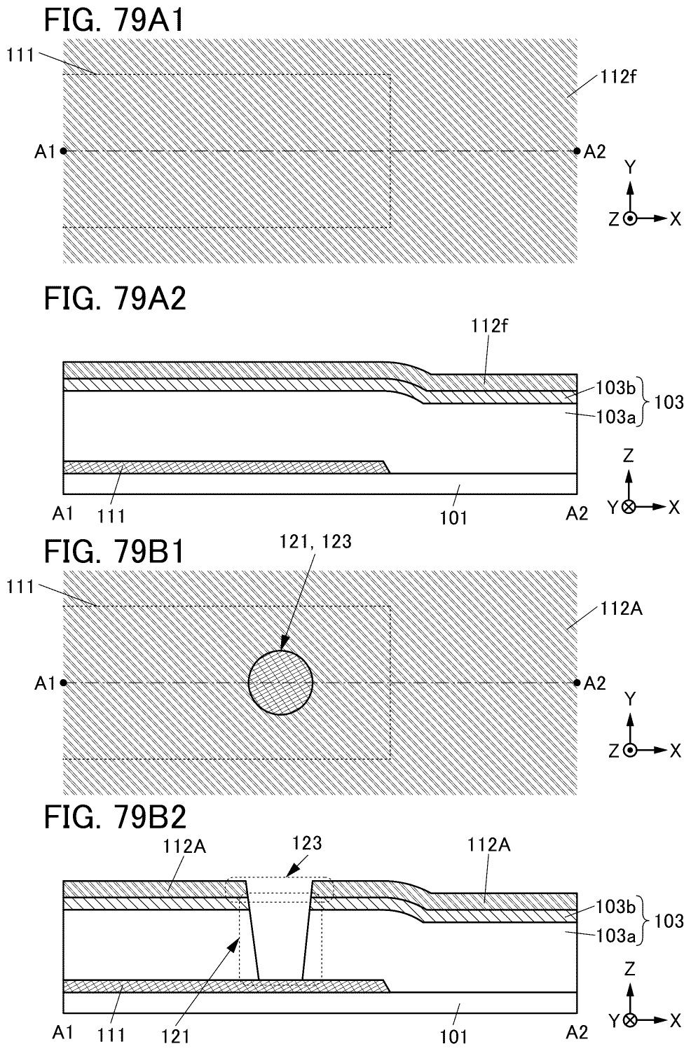

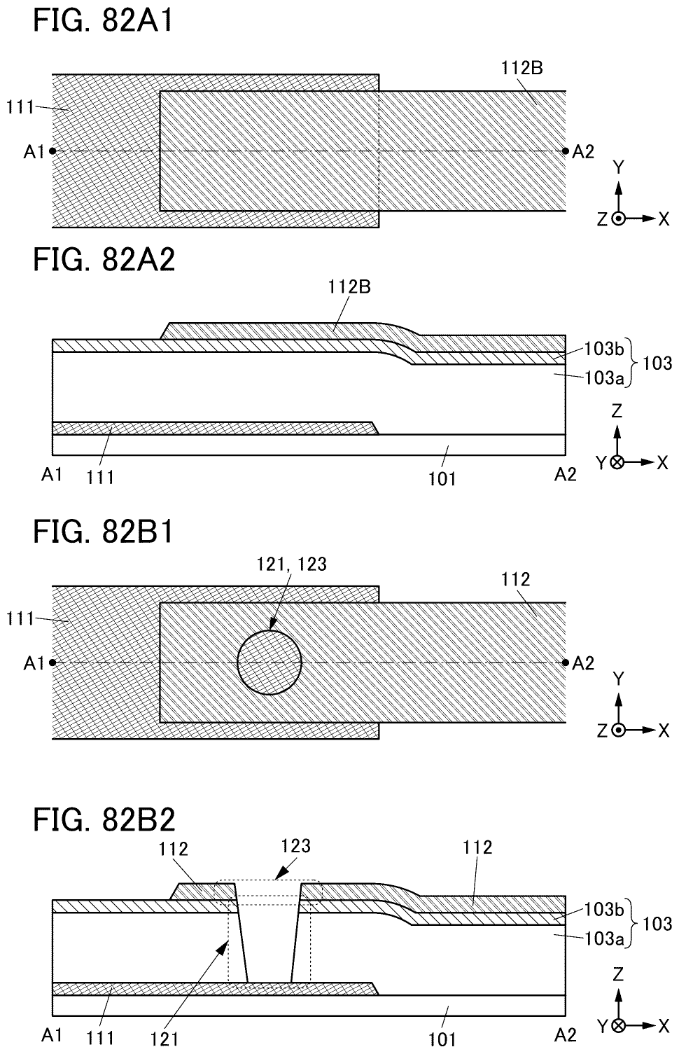

FIG. 78A1 to FIG. 81B2 are diagrams illustrating a method for manufacturing the structure illustrated in FIG. 4A1 and FIG. 4B. In each diagram, A1 and B1 are plan views, and A2 and B2 are cross-sectional views taken along the dashed-dotted line A1-A2 in the plan views.

### [Formation of Conductive Layer 111]

A conductive film to be the conductive layer 111 is formed over the substrate 101. A sputtering method can be suitably used for forming the conductive firm, for example. The conductive film is processed after a resist mask is formed over the conductive film by a photolithography step, whereby the island-shaped conductive layer 111 functioning as one of the source electrode and the drain electrode can be formed (FIG. 78A1 and FIG. 78A2). For the processing of the conductive film, one or both of a wet etching method and a dry etching method are used.

[Formation of Insulating Layer 103a and Insulating Layer 103b]

Next, the insulating layer 103a and the insulating layer 103b are formed over the substrate 101 and the conductive layer 111 (FIG. 78B1 and FIG. 78B2). A PECVD method can be suitably used for forming the insulating layer 103a and the insulating layer 103b, for example. It is preferable that the insulating layer 103b be formed in a vacuum successively after the formation of the insulating layer 103a, without exposure of a surface of the insulating layer 103a to the air. The insulating layer 103a and the insulating layer 103b are successively formed, whereby impurities derived from the air can be inhibited from being attached to the surface of the insulating layer 103a. Examples of the impurities include water and organic substances.

The substrate temperature at the time of forming the insulating layer 103a and the insulating layer 103b is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperature at the time of forming the insulating layer 103a and the insulating layer 103b is in the above range, impurities (e.g., water and hydrogen) released from the insulating layer 103a and the insulating layer 103b can be reduced, which inhibits the diffusion of the impurities into the semiconductor layer 113 formed in a later step. Consequently, the transistor can have favorable electrical characteristics and high reliability.

As described above, the insulating layer 103a and the insulating layer 103b are formed before the semiconductor layer 113 is formed. Hence, there is no need for concern about release of oxygen from the semiconductor layer 113 due to heat applied at the time of forming the insulating layer 103a and the insulating layer 103b.

Heat treatment may be performed after the insulating layer 103a and the insulating layer 103b are formed. By the heat treatment, water and hydrogen can be released from the surface and inside of the insulating layer 103a and the insulating layer 103b.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the amount of hydrogen, water, or the like contained in the atmosphere is preferably as low as possible. As the atmosphere, a high-purity gas with a dew point of −60° C. or lower, preferably −100° C. or lower is preferably used. With the use of an atmosphere where the amount of hydrogen, water, or the like contained is as low as possible, entry of hydrogen, water, and the like into the insulating layer 103a and the insulating layer 103b can be prevented as much as possible. An oven, a rapid thermal annealing (RTA) apparatus, or the like can be used for the heat treatment. With the RTA apparatus, the heat treatment time can be shortened.

[Formation of Conductive Film 112f]

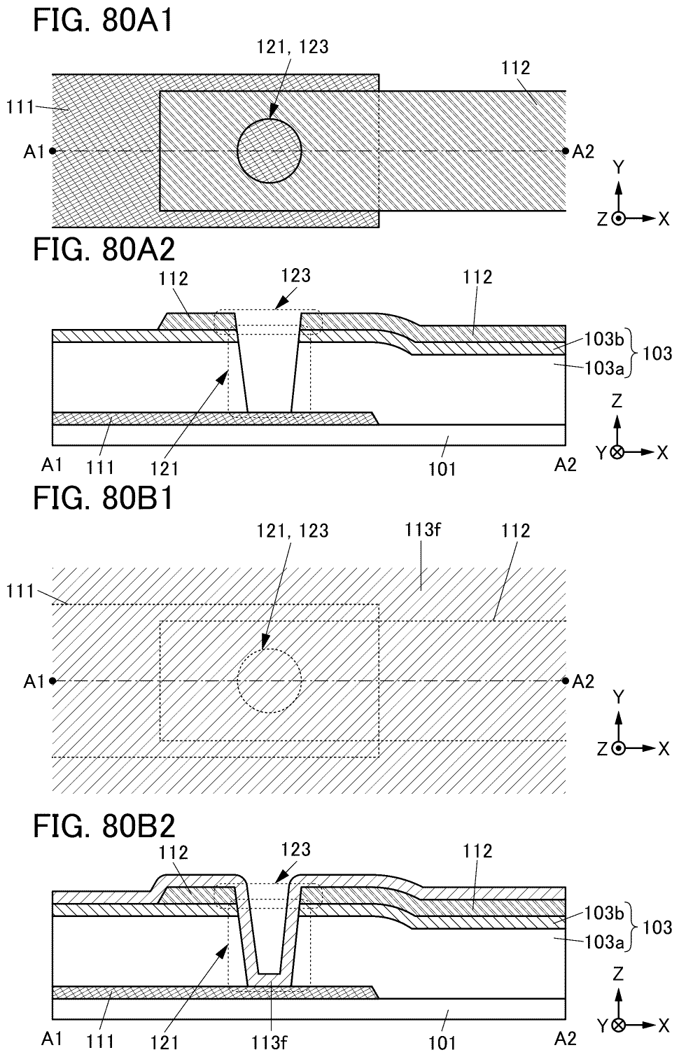

Then, a conductive film 112f to be the conductive layer 112 is formed over the insulating layer 103b (FIG. 79A1 and FIG. 79A2). For the formation of the conductive film 112f, a sputtering method can be suitably used, for example.

### [Formation of Opening 121 and Opening 123]

Next, at least part of a region of the conductive film 112f that overlaps with the conductive layer 111 is removed, so that the conductive layer 112A including the opening 123 is formed (FIG. 79B1 and FIG. 79B2). For the formation of the opening 123, one or both of a wet etching method and a dry etching method can be used, for example, and a wet etching method can be suitably used.

Next, part of a region of the insulating layer 103 (the insulating layer 103a and the insulating layer 103b) that overlaps with the conductive layer 111 is removed. Thus, the opening 121 is formed in the insulating layer 103 (FIG. 79B1 and FIG. 79B2). For the formation of the opening 121, one or both of a wet etching method and a dry etching method can be used, for example, and a dry etching method can be suitably used.

The opening 123 can be formed using a resist mask used for the formation of the opening 121, for example. Specifically, a resist mask is formed over the conductive film 112f, the conductive film 112f is removed with use of the resist mask to form the opening 123, and the insulating layer 103 is removed with use of the resist mask, whereby the opening 121 can be formed. When the width of the opening 123 is made larger than the width of the resist mask by processing, the transistor 50, in which the width of the opening 123 is larger than the width of the opening 121, as illustrated in FIG. 54A, FIG. 54B1, and the like, can be manufactured. Here, in the case where the transistor 50 in which the width of the opening 123 is different from the width of the opening 121 is manufactured, for example, the opening 121 may be formed using a resist mask different from the resist mask used to form the opening 123.

### [Formation of Conductive Layer 112]

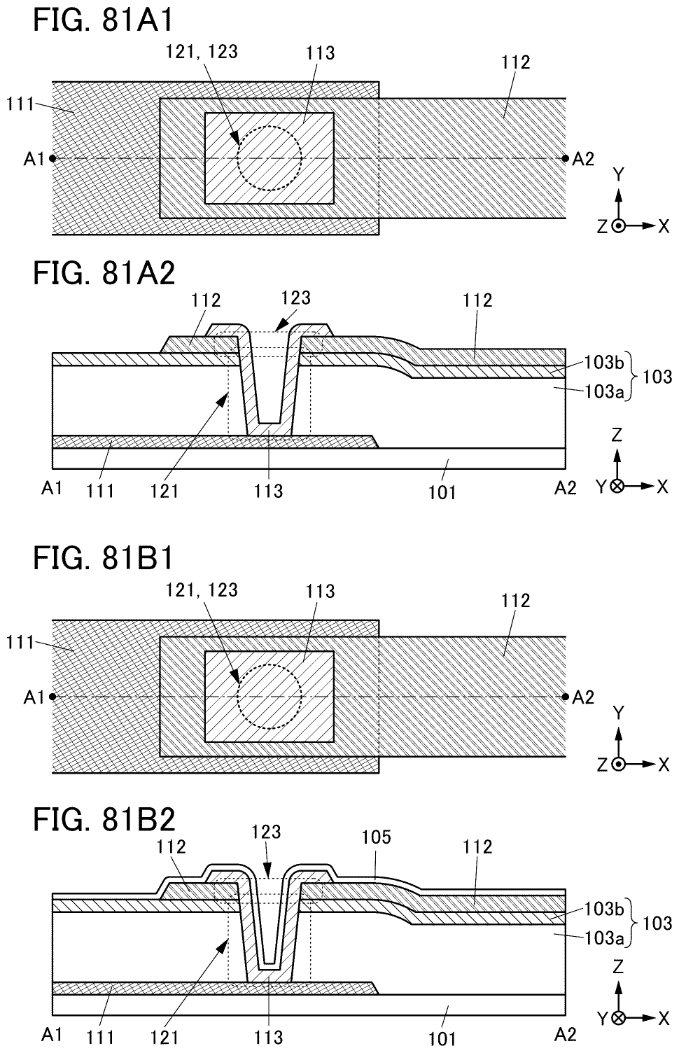

Next, the conductive layer 112A is processed into a desired shape to form the conductive layer 112 (FIG. 80A1 and FIG. 80A2). For the formation of the conductive layer 112, one or both of a wet etching method and a dry etching method can be used, for example, and a wet etching method can be suitably used.

### [Formation of Semiconductor Layer 113]

Subsequently, a semiconductor film 113f to be the semiconductor layer 113 is formed to cover the opening 121 and the opening 123 (FIG. 80B1 and FIG. 80B2). The semiconductor layer film 113f can be provided to include a region in contact with the top surface and the side surface of the conductive layer 112, the top surface and the side surface of the insulating layer 103, and the top surface of the conductive layer 111.

The semiconductor film 113f is preferably formed by a sputtering method using a metal oxide target.

The semiconductor film 113f is preferably a dense film with as few defects as possible. The semiconductor film 113f is preferably a highly purified film in which impurities containing hydrogen elements are reduced as much as possible. It is particularly preferable to use a metal oxide film having crystallinity as the semiconductor film 113f.

In forming the semiconductor film 113f, an oxygen gas is preferably used. In the case of using an oxygen gas at the time of forming the semiconductor film 113f, oxygen can be suitably supplied into the insulating layer 103. For example, in the case where an oxide is used for the insulating layer 103a, oxygen can be suitably supplied to the insulating layer 103a by using an oxygen gas in formation of the semiconductor film 113f.

By the supply of oxygen to the insulating layer 103a, oxygen is supplied to the semiconductor layer 113 in a later step, so that oxygen vacancies (V_{O}) and V_{O}H in the semiconductor layer 113 can be reduced.

When the semiconductor film 113f is deposited, an inert gas (e.g., a helium gas, an argon gas, or a xenon gas) may be mixed in addition to the oxygen gas. Note that when the proportion of an oxygen gas in the whole deposition gas (an oxygen flow rate ratio) at the time of depositing the semiconductor film 113f is higher, the crystallinity of the semiconductor film 113f can be higher and a highly reliable transistor can be provided. By contrast, when the oxygen flow rate ratio is lower, the crystallinity of the semiconductor film 113f is lower and a transistor with a high on-state current can be obtained.

With increasing substrate temperature during the formation of the semiconductor film 113f, the semiconductor film 113f can have higher crystallinity and be denser. By contrast, with decreasing substrate temperature, the semiconductor film 113f can have lower crystallinity and higher electric conductivity.

The substrate temperature at the time of forming the semiconductor film 113f is higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than 140° C., high productivity is achieved, which is preferable. Furthermore, when the semiconductor film 113f is formed with the substrate temperature set at room temperature or without heating the substrate, the crystallinity can be made low.

It is preferable to perform at least one of treatment for desorbing water, hydrogen, an organic substance, and the like adsorbed onto the surface of the insulating layer 103 and treatment for supplying oxygen into the insulating layer 103 before the formation of the semiconductor film 113f. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 103 by plasma treatment in an atmosphere containing an oxidizing gas such as dinitrogen monoxide (N₂O). Performing plasma treatment containing a dinitrogen monoxide gas can supply oxygen while suitably removing an organic substance on the surface of the insulating layer 103. It is preferable that the semiconductor film 113f be formed successively after such treatment, without exposure of the surface of the insulating layer 103 to the air.

Note that in the case where the semiconductor layer 113 has a stacked-layer structure, an upper metal oxide film is preferably formed successively after the formation of a lower metal oxide film without exposure of the surface of the lower metal oxide film to the air.

Next, the semiconductor film 113f is processed into an island shape to form the semiconductor layer 113 (FIG. 81A1 and FIG. 81A2).

For the formation of the semiconductor layer 113, one or both of a wet etching method and a dry etching method can be used, for example, and a wet etching method can be suitably used. At this time, part of the insulating layer 112 in a region not overlapping with the semiconductor layer 113 is etched and thinned in some cases. In a similar manner, part of the insulating layer 103 in a region overlapping with neither the semiconductor layer 113 nor the conductive layer 112 is etched and thinned in some cases. For example, in some cases, the insulating layer 103b of the insulating layer 103 is removed by etching and a surface of the insulating layer 103a is exposed. When a material having high etching selectivity with respect to the semiconductor film 113f is used for the insulating layer 103b, a reduction in the thickness of the insulating layer 103b can be inhibited.

Heat treatment is preferably performed after the semiconductor film 113f is formed or after the semiconductor film 113f is processed into the semiconductor layer 113. By the heat treatment, hydrogen and water that are contained in the semiconductor film 113f or the semiconductor layer 113 or adsorbed onto the surface of the semiconductor film 113f or the semiconductor layer 113 can be removed. Furthermore, the film quality of the semiconductor film 113f or the semiconductor layer 113 is improved by the heat treatment in some cases; for example, defects in the semiconductor film 113f or the semiconductor layer 113 are reduced and the crystallinity of the semiconductor film 113f or the semiconductor layer 113 is improved in some cases.

Furthermore, oxygen can be supplied from the insulating layer 103a to the semiconductor film 113f or the semiconductor layer 113 by heat treatment. In this case, it is further preferable that the heat treatment be performed before the semiconductor film is processed into the semiconductor layer 113. The above description can be referred to for the heat treatment; thus, the detailed description thereof is omitted.

Note that the heat treatment is not necessarily performed. The heat treatment is not necessarily performed in this step, and heat treatment performed in a later step may also serve as the heat treatment in this step. For example, treatment at high temperature in a later step, such as a film formation step, can serve as the heat treatment in some cases.

### [Formation of Insulating Layer 105]

Then, the insulating layer 105 is formed to cover the semiconductor layer 113, the conductive layer 112, and the insulating layer 103 (FIG. 81B1 and FIG. 81B2). For the formation of the insulating layer 105, a PECVD method can be suitably used.

In the case of using a metal oxide for the semiconductor layer 113, the insulating layer 105 preferably functions as a barrier film that inhibits diffusion of oxygen. The insulating layer 105 having a function of inhibiting diffusion of oxygen inhibits diffusion of oxygen into the conductive layer 115 formed in a later step from above the insulating layer 105 and thus can inhibit oxidation of the conductive layer 115. Consequently, the transistor can have favorable electrical characteristics and high reliability.

By increasing the temperature at the time of forming the insulating layer 105 functioning as the gate insulating layer, the insulating layer including a small number of defects can be obtained. However, the high temperature at the time of forming the insulating layer 105 sometimes allows release of oxygen from the semiconductor layer 113, which increases oxygen vacancies (V_{O}) and V_{O}H in the semiconductor layer 113 in some cases. The substrate temperature at the time of forming the insulating layer 105 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 105 is in the above range, release of oxygen from the semiconductor layer 113 can be inhibited while the defects in the insulating layer 105 can be reduced. Consequently, the transistor can have favorable electrical characteristics and high reliability.

It is preferable to perform plasma treatment on the surface of the semiconductor layer 113 before the formation of the insulating layer 105. By the plasma treatment, impurities adsorbed onto the surface of the semiconductor layer 113, such as water, can be reduced. Therefore, impurities at the interface between the semiconductor layer 113 and the insulating layer 105 can be reduced, achieving a highly reliable transistor. The plasma treatment is particularly suitable in the case where the surface of the semiconductor layer 113 is exposed to the air after the formation of the semiconductor layer 113 but before the formation of the insulating layer 105. For example, plasma treatment can be performed in an atmosphere containing oxygen, ozone, nitrogen, dinitrogen monoxide, argon, or the like. The plasma treatment and the formation of the insulating layer 105 are preferably performed successively without exposure to the air.

### [Formation of Conductive Layer 115]

Subsequently, a conductive film to be the conductive layer 115 is formed over the insulating layer 105. A sputtering method can be suitably used for forming the conductive firm, for example. After a resist mask is formed over the conductive film by a photolithography process, the conductive film is processed, so that the island-shaped conductive layer 115 functioning as the gate electrode can be formed.

Through the above-described steps, the transistor 50 illustrated in FIG. 4A1 and FIG. 4B can be manufactured.

### Manufacturing Method Example 2 of Display Apparatus

A manufacturing method of the transistor 50 that is different from the manufacturing method in <Manufacturing method example 1 of display apparatus> described above is described. Note that description of the same portions as the above is omitted and different portions will be described.

FIG. 82A1, FIG. 82A2, FIG. 82B1, and FIG. 82B2 are diagrams illustrating a manufacturing method of the structure illustrated in FIG. 4A1 and FIG. 4B. FIG. 82A1 and FIG. 82B1 are plan views, and FIG. 82A2 and FIG. 82B2 are cross-sectional views taken along the dashed-dotted line A1-A2 in FIG. 82A1 and FIG. 82B1, respectively.

First, as in <Manufacturing method example 1 of display apparatus>, the steps up to the formation of the conductive film 112f are performed. The description of FIG. 78A1 to FIG. 79A2 can be referred to for the steps up to the formation of the conductive film 112f; thus, the detailed description thereof is omitted.

Next, the conductive film 112f is processed to form a conductive layer 112B (FIG. 82A1 and FIG. 82A2). Here, the opening 123 is not necessarily formed in the conductive layer 112B. For the formation of the conductive layer 112B, one or both of a wet etching method and a dry etching method can be used, for example, and a wet etching method can be suitably used.

Next, at least part of a region of the conductive layer 112B that overlaps with the conductive layer 111 is removed, so that the conductive layer 112 including the opening 123 is formed.

Next, part of a region of the insulating layer 103 (the insulating layer 103a and the insulating layer 103b) that overlaps with the conductive layer 111 is removed. Thus, the opening 121 is formed in the insulating layer 103 (FIG. 82B1 and FIG. 82B2).

The description in <Manufacturing method example 1 of display apparatus> can be referred to for the formation of the opening 121 and the opening 123; thus, the detailed description thereof is omitted.

Subsequently, the semiconductor film 113f to be the semiconductor layer 113 is formed to cover the opening 121 and the opening 123 (FIG. 80B1 and FIG. 80B2). The above description in <Manufacturing method example 1 of display apparatus> can be referred to for the steps after the formation of the semiconductor film 113f; thus, the detailed description thereof is omitted.

Through the above-described steps, the transistor 50 illustrated in FIG. 4A1 and FIG. 4B can be manufactured.

The plurality of structure examples described in this embodiment can be combined with each other as appropriate. This embodiment can be combined with the other embodiments as appropriate.

### Embodiment 2

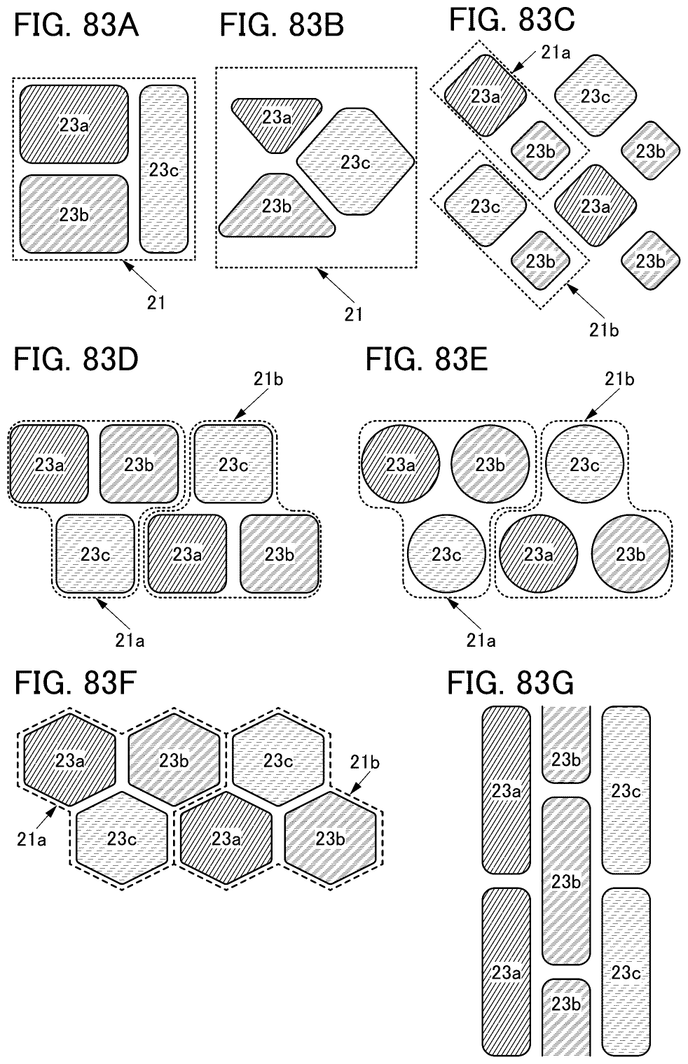

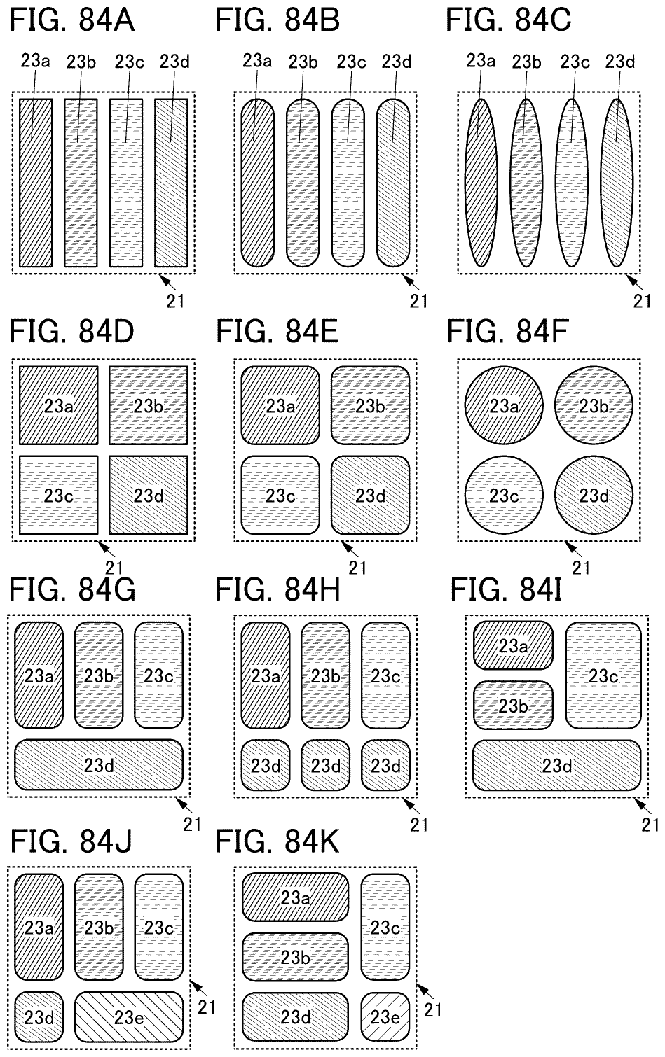

In this embodiment, a display apparatus of one embodiment of the present invention are described with reference to FIG. 83A to FIG. 83G and FIG. 84A to FIG. 84K.

There is no particular limitation on the arrangement of subpixels, and a variety of methods can be employed. Examples of the arrangement of the subpixels include stripe arrangement, S-stripe arrangement, matrix arrangement, delta arrangement, Bayer arrangement, and PenTile arrangement.

The planar shape of a subpixel illustrated in a diagram in this embodiment corresponds to the planar shape of a light-emitting region (or light-receiving region).

Examples of the planar shape of the subpixel include polygons such as a triangle, a tetragon (including a rectangle and a square), and a pentagon; polygons with rounded corners; an ellipse; and a circle.

The circuit layout for forming the subpixel is not limited to being within the range of the subpixel illustrated in a diagram, and may be placed outside the subpixel.

The pixel 21 illustrated in FIG. 83A employs S stripe arrangement. The pixel 21 illustrated in FIG. 83A is composed of three kinds of subpixels: a subpixel 23a, a subpixel 23b, and a subpixel 23c.

The pixel 21 illustrated in FIG. 83B includes the subpixel 23a and the subpixel 23b whose planar shapes are a rough trapezoidal or rough triangle shape with rounded corners and the subpixel 23c whose planar shapes are a rough tetragonal or rough hexagonal shape with rounded corners. The subpixel 23b has a larger light-emitting area than the subpixel 23a. In this manner, the shapes and sizes of the subpixels can be determined independently. For example, the size of a subpixel including a light-emitting element with higher reliability can be smaller.

A pixel 21a and a pixel 21b illustrated in FIG. 83C employ PenTile arrangement. FIG. 83C illustrates an example in which the pixel 21a including the subpixel 23a and the subpixel 23b and the pixel 21b including the subpixel 23b and the subpixel 23c are alternately arranged.

The pixel 21a and the pixel 21b illustrated in FIG. 83D to FIG. 83F employ delta arrangement. The pixel 21a includes two subpixels (the subpixel 23a and the subpixel 23b) in the upper row (first row) and one pixel (the subpixel 23c) in the lower row (second row). The pixel 21b includes one pixel (the subpixel 23c) in the upper row (first row) and two subpixels (the subpixel 23a and the subpixel 23b) in the lower row (second row).

FIG. 83D illustrates an example in which each pixel has a rough tetragonal planar shape with rounded corners, FIG. 83E illustrates an example in which each pixel has a circular planar shape, and FIG. 83F illustrates an example in which each pixel has a rough hexagonal planar shape with rounded corners.

In FIG. 83F, each subpixel is placed inside one of close-packed hexagonal regions. Focusing on one of the subpixels, the subpixel is placed so as to be surrounded by six subpixels. The subpixels are arranged such that subpixels that emit light of the same color are not adjacent to each other. For example, focusing on the subpixel 23a, three subpixels 23b and three subpixels 23c are provided so that these subpixels are alternately arranged to surround the subpixel 23a.

FIG. 83G illustrates an example in which subpixels of different colors are arranged in a zigzag manner. Specifically, the positions of the top sides of two subpixels arranged in the column direction (e.g., the subpixel 23a and the subpixel 23b or the subpixel 23b and the subpixel 23c) are not aligned in the plan view.

For example, in each pixel illustrated in FIG. 83A to FIG. 83G, it is preferable that the subpixel 23a be a subpixel R emitting red light, the subpixel 23b be a subpixel G emitting green light, and the subpixel 23c be a subpixel B emitting blue light. Note that the structure of the subpixels is not limited to this, and the colors and arrangement order of the subpixels can be determined as appropriate. For example, the subpixel 23b may be the subpixel R emitting red light and the subpixel 23a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the planar surface of a subpixel may have a polygonal shape with rounded corners, an elliptical shape, a circular shape, or the like.

To obtain a desired planar shape of the subpixel, a technique of correcting a mask pattern in advance so that a transferred pattern matches with a design pattern (an optical proximity correction (OPC) technique) may be used. Specifically, with the OPC technique, a pattern for correction is added to a corner portion of a figure on a mask pattern, for example.

As shown in FIG. 84A to FIG. 84I, the pixel can include four types of subpixels.

The pixels 21 illustrated in FIG. 84A to FIG. 84C employ stripe arrangement.

FIG. 84A illustrates an example where each subpixel has a rectangular planar shape, FIG. 84B illustrates an example where each subpixel has a planar shape formed by combining two half circles and a rectangle, and FIG. 84C illustrates an example where each subpixel has an elliptical planar shape.

The pixels 21 illustrated in FIG. 84D to FIG. 84F employ matrix arrangement.

FIG. 84D illustrates an example where each subpixel has a square planar shape, FIG. 84E illustrates an example where each subpixel has a substantially square planar shape with rounded corners, and FIG. 84F illustrates an example where each subpixel has a circular planar shape.

FIG. 84G and FIG. 84H each illustrate an example in which one pixel 21 is composed of two rows and three columns.

The pixel 21 illustrated in FIG. 84G includes three subpixels (the subpixel 23a, the subpixel 23b, and the subpixel 23c) in the upper row (first row) and one pixel (a subpixel 23d) in the lower row (second row). In other words, the pixel 21 includes the subpixel 23a in the left column (first column), the subpixel 23b in the center column (second column), the subpixel 23c in the right column (third column), and the subpixel 23d across these three columns.

The pixel 21 illustrated in FIG. 84H includes three subpixels (the subpixel 23a, the subpixel 23b, and the subpixel 23c) in the upper row (first row) and three subpixels 23d in the lower row (second row). In other words, the pixel 21 includes the subpixel 23a and the subpixel 23d in the left column (first column), the subpixel 23b and the subpixel 23d in the center column (second column), and the subpixel 23c and the subpixel 23d in the right column (third column). Matching the positions of the subpixels in the upper row and the lower row as illustrated in FIG. 84H enables efficient removal of dust that would be produced in the manufacturing process, for example. Thus, a display apparatus with high display quality can be provided.

FIG. 84I illustrates an example where one pixel 21 is composed of three rows and two columns.

The pixel 21 illustrated in FIG. 84I includes the subpixel 23a in the upper row (first row), the subpixel 23b in the center row (second row), the subpixel 23c across the first and second rows, and one pixel (the subpixel 23d) in the lower row (third row). In other words, the pixel 21 includes the subpixel 23a and the subpixel 23b in the left column (first column), the subpixel 23c in the right column (second column), and the subpixel 23d across these two columns.

The pixels 21 illustrated in FIG. 84A to FIG. 84I are each composed of four subpixels: the subpixel 23a, the subpixel 23b, the subpixel 23c, and the subpixel 23d.

The subpixel 23a, the subpixel 23b, the subpixel 23c, and the subpixel 23d can include light-emitting elements emitting light of different colors. The subpixel 23a, the subpixel 23b, the subpixel 23c, and the subpixel 23d are subpixels of four colors of R, G, B, and white (W), subpixels of four colors of R, G, B, and Y, or subpixels of R, G, B, and infrared light (IR).

In the pixel 21 illustrated in FIG. 84A to FIG. 84I, it is preferable that the subpixel 23a be the subpixel R emitting red light, the subpixel 23b be the subpixel G emitting green light, the subpixel 23c be the subpixel B emitting blue light, and the subpixel 23d be any of a subpixel W emitting white light, a subpixel Y emitting yellow light, and a subpixel IR emitting near-infrared light, for example. In the case of such a structure, stripe arrangement is employed as the layout of R, G, and B in the pixels 21 illustrated in FIG. 84G and FIG. 84H, leading to higher display quality. In the pixel 21 illustrated in FIG. 84I, what is called S stripe arrangement is employed as the layout of R, G, and B, leading to higher display quality.

The pixel 21 may include a subpixel including a light-receiving element.

In the pixels 21 illustrated in FIG. 84A to FIG. 84I, any one of the subpixel 23a to the subpixel 23d may be a subpixel including a light-receiving element.

In the pixel 21 illustrated in FIG. 84A to FIG. 84I, for example, it is preferable that the subpixel 23a be the subpixel R emitting red light, the subpixel 23b be the subpixel G emitting green light, the subpixel 23c be the subpixel B emitting blue light, and the subpixel 23d be a subpixel S including a light-receiving element. In the case of such a structure, stripe arrangement is employed as the layout of R, G, and B in the pixels 21 illustrated in FIG. 84G and FIG. 84H, leading to higher display quality. In the pixel 21 illustrated in FIG. 84I, what is called S stripe arrangement is employed as the layout of R, G, and B, leading to higher display quality.

There is no particular limitation on the wavelength of light detected by the subpixel S including a light-receiving element. The subpixel S can have a structure where one or both of visible light and infrared light are detected.

As illustrated in FIG. 84J and FIG. 84K, the pixel can include five types of subpixels.

FIG. 84J illustrates an example where one pixel 21 is composed of two rows and three columns.

The pixel 21 illustrated in FIG. 84J includes three subpixels (the subpixel 23a, the subpixel 23b, and the subpixel 23c) in the upper row (first row) and two subpixels (the subpixel 23d and a subpixel 23e) in the lower row (second row). In other words, the pixel 21 includes the subpixel 23a and the subpixel 23d in the left column (first column), the subpixel 23b in the center column (second column), the subpixel 23c in the right column (third column), and the subpixel 23e across the second column and the third column.

FIG. 84K illustrates an example where one pixel 21 is composed of three rows and two columns.

The pixel 21 illustrated in FIG. 84K includes the subpixel 23a in the upper row (first row), the subpixel 23b in the center row (second row), the subpixel 23c across the first row and the second row, and two subpixels (the subpixel 23d and the subpixel 23e) in the lower row (third row). In other words, the pixel 21 includes the subpixel 23a, the subpixel 23b, and the subpixel 23d in the left column (first column), and the subpixel 23c and the subpixel 23e in the right column (second column).

In the pixels 21 illustrated in FIG. 84J and FIG. 84K, it is preferable that the subpixel 23a be the subpixel R emitting red light, the subpixel 23b be the subpixel G emitting green light, and the subpixel 23c be the subpixel B emitting blue light, for example. In the case of such a structure, stripe arrangement is employed as the layout of R, G, and B in the pixel 21 illustrated in FIG. 84J, leading to higher display quality. In addition, what is called S stripe arrangement is employed as the layout of R, G, and B in the pixel 21 illustrated in FIG. 84K, leading to higher display quality.

In the pixel 21 illustrated in FIG. 84J and FIG. 84K, for example, it is preferable to use the subpixel S including a light-receiving element as at least one of the subpixel 23d and the subpixel 23e. In the case where light-receiving elements are used in both the subpixel 23d and the subpixel 23e, the light-receiving elements may have different structures. For example, the wavelength ranges of detected light may be different at least partly. Specifically, one of the subpixel 23d and the subpixel 23e may include a light-receiving element mainly detecting visible light and the other may include a light-receiving element mainly detecting infrared light.

In the pixel 21 illustrated in FIG. 84J and FIG. 84K, for example, it is preferable that the subpixel S including a light-receiving element be used as one of the subpixel 23d and the subpixel 23e and a pixel including a light-emitting element that can be used as a light source be used as the other. For example, it is preferable that one of the subpixel 23d and the subpixel 23e be the subpixel IR emitting infrared light and the other be the subpixel S including a light-receiving element detecting infrared light.

In a pixel including the subpixels R, G, B, IR, and S, while an image is displayed using the subpixels R, G, and B, reflected light of infrared light emitted from the subpixel IR that is used as a light source can be detected by the subpixel S.

As described above, the pixel composed of the subpixels each including the light-emitting element can employ any of a variety of layouts in the display apparatus of one embodiment of the present invention. The display apparatus of one embodiment of the present invention can have a structure where the pixel includes both a light-emitting element and a light-receiving element. Also in this case, any of various layouts can be employed.

The plurality of structure examples described in this embodiment can be combined with each other as appropriate. This embodiment can be combined with the other embodiments as appropriate.

### Embodiment 3

In this embodiment, display apparatuses of one embodiment of the present invention will be described.

The display apparatus of this embodiment can be a high-definition display apparatus. Accordingly, the display apparatus in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

### [Display Apparatus 10A]

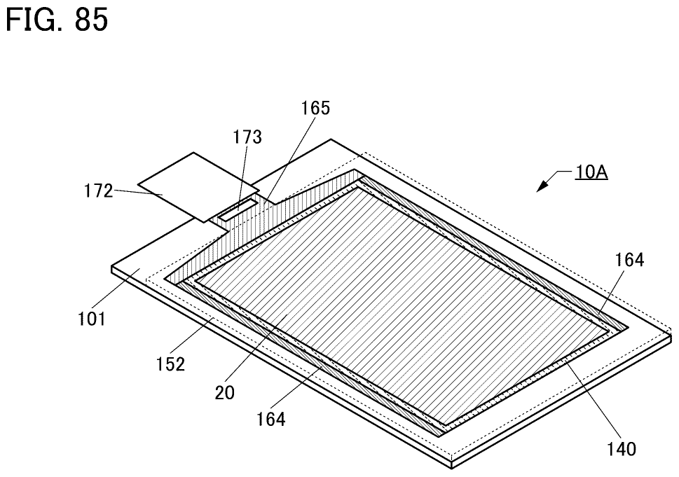

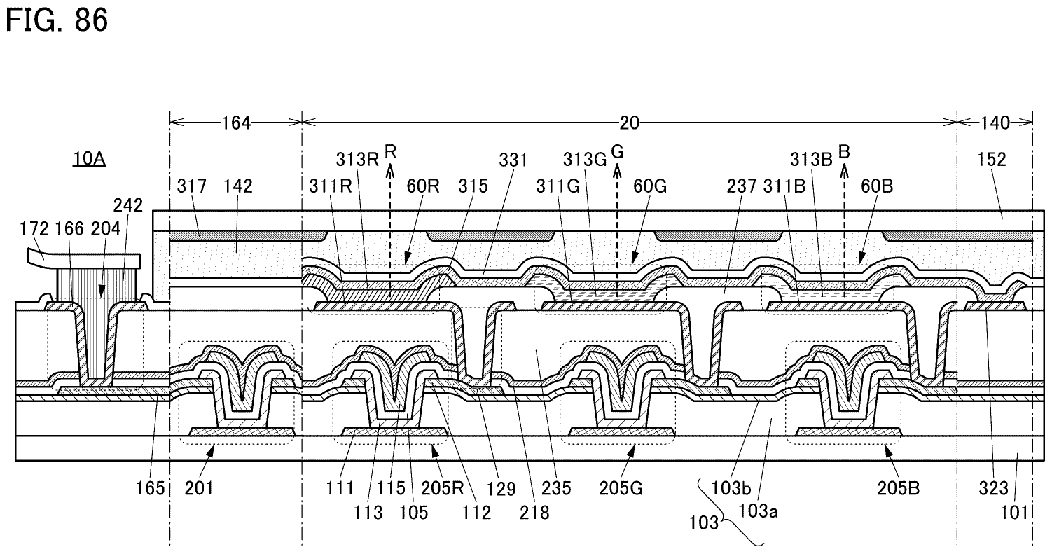

FIG. 85 is a perspective view illustrating a structure example of a display apparatus 10A and FIG. 86 is a cross-sectional view illustrating the structure example of the display apparatus 10A. The structure of the display apparatus 10 described in Embodiment 1 can be applied to the display apparatus 10A.

In the display apparatus 10A, the substrate 152 and the substrate 101 are attached to each other. In FIG. 85, the substrate 152 is denoted by a dashed line.

The display apparatus 10A includes the display portion 20, a connection portion 140, a circuit 164, a wiring 165, and the like. FIG. 85 illustrates an example where an IC 173 and an FPC 172 are mounted on the display apparatus 10A. Thus, the structure illustrated in FIG. 85 can be regarded as a display module including the display apparatus 10A, the IC (integrated circuit), and the FPC.

In this specification and the like a display apparatus in which a substrate is equipped with a connector such as an FPC or mounted with an IC is referred to as a display module.

The connection portion 140 is provided outside the display portion 20. The connection portion 140 can be provided along one or more sides of the display portion 20. The number of connection portions 140 may be one or more. FIG. 85 illustrates an example where the connection portion 140 is provided to surround the four sides of the display portion. A common electrode of a light-emitting element is electrically connected to a conductive layer in the connection portion 140, so that a potential can be supplied to the common electrode through the conductive layer.

The circuit 164 can include at least one of the scan line driver circuit 11, the signal line driver circuit 13, and the power supply circuit 15 illustrated in FIG. 1A and FIG. 2A and the reference potential generation circuit 17 illustrated in FIG. 2A in Embodiment 1.

The wiring 165 has a function of supplying a signal and power to the display portion 20 and the circuit 164. The signal and the power are input to the wiring 165 from the outside through the FPC 172 or input to the wiring 165 from the IC 173.

FIG. 85 illustrates an example where the IC 173 is provided over the substrate 101 by a COG (Chip On Glass) method, a COF (Chip On Film) method, or the like. The IC 173 can include at least one of the scan line driver circuit 11, the signal line driver circuit 13, and the power supply circuit 15 illustrated in FIG. 1A and FIG. 2A and the reference potential generation circuit 17 illustrated in FIG. 2A in Embodiment 1. Note that the display apparatus 10A and the display module are not necessarily provided with an IC. The IC may be mounted on the FPC by a COF method, for example.

FIG. 86 illustrates an example of cross sections of part of a region including the FPC 172, part of the circuit 164, part of the display portion 20, part of the connection portion 140, and part of a region including an end portion of the display apparatus 10A.

The display apparatus 10A illustrated in FIG. 86 includes a transistor 201, a transistor 205R, a transistor 205G, a transistor 205B, a light-emitting element 60R, a light-emitting element 60G, a light-emitting element 60B, and the like between the substrate 101 and the substrate 152. The light-emitting element 60R, the light-emitting element 60G, and the light-emitting element 60B can have a structure similar to that of the light-emitting element 60 illustrated in FIG. 8B in Embodiment 1, for example. Here, the pixel electrode 311 and the layer 313 included in the light-emitting element 60R are referred to as a pixel electrode 311R and a layer 313R, respectively. The pixel electrode 311 and the layer 313 included in the light-emitting element 60G are referred to as a pixel electrode 311G and a layer 313G, respectively. Furthermore, the pixel electrode 311 and the layer 313 included in the light-emitting element 60B are referred to as a pixel electrode 311B and a layer 313B, respectively. The common electrode 315 is provided over the layer 313R, the layer 313G, and the layer 313B. The common electrode 315 is shared by the light-emitting element 60R, the light-emitting element 60G, and the light-emitting element 60B. In the example in FIG. 86, the conductive layer 112 of the transistor 205R is electrically connected to the pixel electrode 311R, the conductive layer 112 of the transistor 205G is electrically connected to the pixel electrode 311G, and the conductive layer 112 of the transistor 205B is electrically connected to the pixel electrode 311B.

The insulating layer 237 is provided to cover the end portion of the top surface of each of the pixel electrode 311R, the pixel electrode 311G, and the pixel electrode 311B. The pixel electrode 311R, the pixel electrode 311G, and the pixel electrode 311B are provided with depressed portions so as to cover the opening 129 provided in the insulating layer 105, the insulating layer 218, and the insulating layer 235. The insulating layer 237 is embedded in the depressed portions.

Although FIG. 86 illustrates a plurality of cross sections of the insulating layer 237, the insulating layer 237 is one continuous layer when the display apparatus 10A is seen from above. In other words, the display apparatus 10A can have a structure including one insulating layer 237. Note that the display apparatus 10A may include a plurality of insulating layers 237 that are separated from each other.

The layer 313R, the layer 313G, and the layer 313B each include at least a light-emitting layer. The layer 313R includes a light-emitting layer emitting red light, the layer 313G includes a light-emitting layer emitting green light, and the layer 313B includes a light-emitting layer emitting blue light. In other words, the layer 313R contains a light-emitting substance emitting red light, the layer 313G contains a light-emitting substance emitting green light, and the layer 313B contains a light-emitting substance emitting blue light. For example, the light-emitting element 60R can emit red light, the light-emitting element 60G can emit green light, and the light-emitting element 60B can emit blue light.

The layer 313R, the layer 313G, and the layer 313B may each include one or more of a hole-injection layer, a hole-transport layer, a hole-blocking layer, a charge-generation layer, an electron-blocking layer, an electron-transport layer, and an electron-injection layer.

For example, the layer 313R, the layer 313G, and the layer 313B may each include a hole-injection layer, a hole-transport layer, a light-emitting layer, an electron-transport layer, and an electron-injection layer in this order. Alternatively, the layer 313R, the layer 313G, and the layer 313B may each include an electron-injection layer, an electron-transport layer, a light-emitting layer, a hole-transport layer, and a hole-injection layer in this order. Furthermore, an electron-blocking layer may be provided between a hole-transport layer and a light-emitting layer, or a hole-blocking layer may be provided between an electron-transport layer and a light-emitting layer.

For each of the light-emitting element 60R, the light-emitting element 60G, and the light-emitting element 60B, a single structure (a structure including only one light-emitting unit) or a tandem structure (a structure including a plurality of light-emitting units) may be employed. The light-emitting unit includes at least one light-emitting layer.

In the case where the light-emitting element 60R, the light-emitting element 60G, and the light-emitting element 60B have a tandem structure, preferably, the layer 313R includes a plurality of light-emitting units that emit red light, the layer 313G includes a plurality of light-emitting units that emit green light, and the layer 313B includes a plurality of light-emitting units that emit blue light. A charge-generation layer is preferably provided between the light-emitting units. In the case where the light-emitting element 60R, the light-emitting element 60G, and the light-emitting element 60B have a tandem structure, the layer 313R, the layer 313G, and the layer 313B can each include a first light-emitting unit, a charge-generation layer over the first light-emitting unit, and a second light-emitting unit over the charge-generation layer, for example.

The layer 313R, the layer 313G, and the layer 313B can each be formed by a vacuum evaporation method using a fine metal mask, for example. In the vacuum evaporation method using a fine metal mask, deposition is performed in an area wider than an opening of the fine metal mask in many cases. Thus, the layer 313R, the layer 313G, and the layer 313B can be formed in the area wider than the opening of the fine metal mask. The end portions of the layer 313R, the layer 313G, and the layer 313B each have a tapered shape. Here, the layer 313R, the layer 313G, and the layer 313B may also be provided not only over the pixel electrode 311 but also over the insulating layer 237. Note that a sputtering method using a fine metal mask or an inkjet method may be used to form the layer 313R, the layer 313G, and the layer 313B.

The protective layer 331 is provided over the light-emitting element 60R, the light-emitting element 60G, and the light-emitting element 60B. The protective layer 331 and the substrate 152 are bonded to each other with the adhesive layer 142. The substrate 152 is provided with the light-blocking layer 317. A solid sealing structure, a hollow sealing structure, or the like can be employed to seal the light-emitting element 60R, the light-emitting element 60G, and the light-emitting element 60B. In FIG. 86, a solid sealing structure is employed in which a space between the substrate 152 and the protective layer 331 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting element 60R, the light-emitting element 60G, and the light-emitting element 60B. Alternatively, the space may be filled with a resin other than the frame-shaped adhesive layer 142.

The protective layer 331 is provided at least in the display portion 20, and preferably provided to cover the entire display portion 20. The protective layer 331 is preferably provided to cover not only the display portion 20 but also the connection portion 140 and the circuit 164. It is also preferable that the protective layer 331 be provided to extend to the end portion of the display apparatus 10A.

A connection portion 204 is provided in a region of the substrate 101 not overlapping with the substrate 152. In the connection portion 204, the wiring 165 is electrically connected to the FPC 172 through a conductive layer 166 and a connection layer 242. The wiring 165 can be provided in the same layer as the conductive layer 112. Thus, the wiring 165 and the conductive layer 112 can be formed using the same material and in the same step. For example, the conductive layer 112 and the wiring 165 can be formed by processing the same conductive film. The conductive layer 166 can be provided in the same layer as the pixel electrode 311R, the pixel electrode 311G, and the pixel electrode 311B. Thus, the conductive layer 166, the pixel electrode 311R, the pixel electrode 311G, and the pixel electrode 311B can be formed using the same material and in the same step. For example, the pixel electrode 311R, the pixel electrode 311G, the pixel electrode 311B, and the conductive layer 166 can be formed by processing the same conductive film. On the top surface of the connection portion 204, the conductive layer 166 is exposed. Thus, the connection portion 204 and the FPC 172 can be electrically connected to each other through the connection layer 242.

The connection portion 204 includes a portion not provided with the protective layer 331 so that the FPC 172 and the conductive layer 166 can be electrically connected to each other. For example, the protective layer 331 is formed over the entire surface of the display apparatus 10A and then a region of the protective layer 331 overlapping with the conductive layer 166 is removed using a mask, so that the conductive layer 166 can be exposed.

A stacked-layer structure of at least one organic layer and a conductive layer may be provided over the conductive layer 166, and the protective layer 331 may be provided over the stacked-layer structure. Then, a separation trigger (a portion that can be a trigger of separation) may be formed in the stacked-layer structure using a laser or a sharp cutter (e.g., a needle or a utility knife) to selectively remove the stacked-layer structure and the protective layer 331 thereover, so that the conductive layer 166 may be exposed. For example, the protective layer 331 can be selectively removed when an adhesive roller is pressed to the substrate 101 and then moved relatively while being rolled. Alternatively, an adhesive tape may be attached to the substrate 101 and then peeled. Since the adhesion between the organic layer and the conductive layer or between the organic layers is low, separation occurs at the interface between the organic layer and the conductive layer or in the organic layer. Thus, a region of the protective layer 331 overlapping with the conductive layer 166 can be selectively removed. For example, when the organic layer remains over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the layer 313R, the layer 313G, or the layer 313B, for example. The organic layer may be formed at the time of forming the layer 313R, the layer 313G, or the layer 313B, or may be provided separately. The conductive layer can be formed using the same step and the same material as the common electrode 315. An ITO film is preferably formed as the common electrode 315 and the conductive layer, for example. Note that in the case where a stacked-layer structure is employed for the common electrode 315, at least one of the layers included in the common electrode 315 is used as the conductive layer.

The top surface of the conductive layer 166 may be covered with a mask so that the protective layer 331 cannot be formed over the conductive layer 166. As the mask, a metal mask (an area metal mask) or a tape or a film having adhesiveness or attachability may be used. The protective layer 331 is formed while the mask is placed and then the mask is removed, whereby the conductive layer 166 can be kept exposed even after the protective layer 331 is formed.

With such a method, a region not provided with the protective layer 331 can be formed in the connection portion 204, and the conductive layer 166 and the FPC 172 can be electrically connected to each other through the connection layer 242 in a region.

A conductive layer 323 is provided over the insulating layer 235 in the connection portion 140. The end portion of the conductive layer 323 is covered with the insulating layer 237. The common electrode 315 is provided over the conductive layer 323; for example, the connection portion 140 includes a region where the conductive layer 323 is in contact with the common electrode 315. The common electrode 315 is electrically connected to the conductive layer 323 provided in the connection portion 140. The conductive layer 323 can be provided in the same layer as the pixel electrode 311R, the pixel electrode 311G, the pixel electrode 311B, and the conductive layer 166. Thus, the conductive layer 323, the pixel electrode 311R, the pixel electrode 311G, the pixel electrode 311B, and the conductive layer 166 can be formed using the same material and in the same step. For example, the pixel electrode 311R, the pixel electrode 311G, the pixel electrode 311B, the conductive layer 166, and the conductive layer 323 can be formed by processing the same conductive film. Note that it is preferable that none of the layer 313R, the layer 313G, and the layer 313B be provided over the conductive layer 323.

The display apparatus 10A has a top-emission structure. Light emitted from the light-emitting element 60R, the light-emitting element 60G, and the light-emitting element 60B are emitted toward the substrate 152 side. Thus, for the substrate 152, a material having a high visible-light-transmitting property is preferably used. In contrast, there is no limitation on the light-transmitting property of a material used for the substrate 101.

For the common electrode 315, a material having a high visible-light-transmitting property is used. A material that reflects visible light is preferably used for each of the pixel electrode 311R, the pixel electrode 311G, and the pixel electrode 311B.

The transistor 201 and the transistor 205 are formed over the substrate 101. These transistors can be manufactured using the same material in the same process. Each of the transistor 201 and the transistor 205 can suitably employ a structure similar to that of the transistor 50 described in Embodiment 1. The transistor 201 provided in the circuit 164 can be the transistor included in the scan line driver circuit 11, the signal line driver circuit 13, or the power supply circuit 15 illustrated in FIG. 1A and FIG. 2A, or the reference potential generation circuit 17 illustrated in FIG. 2A in Embodiment 1.

The transistor included in the circuit 164 and the transistor included in the display portion 20 may have the same structure or different structures. The plurality of transistors included in the circuit 164 may have the same structure or two or more kinds of structures. Similarly, the same structure or two or more kinds of structures may be employed for a plurality of transistors included in the display portion 20.

All of the transistors included in the display portion 20 may be OS transistors or all of the transistors included in the display portion 20 may be Si transistors. Alternatively, some of the transistors included in the display portion 20 may be OS transistors and the others may be Si transistors.

For example, when both an LTPS transistor and an OS transistor are used in the display portion 20, the display apparatus can have low power consumption and high driving capability. A structure in which an LTPS transistor and an OS transistor are used in combination is referred to as LTPO in some cases. In the case where the structure of the display portion 20 is LTPO, an OS transistor can be used as the selection transistor provided in the pixel circuit, and an LTPS transistor can be used as the driving transistor, for example. With the use of the OS transistor as the selection transistor, an image data in the pixel can be retained even when the frame frequency is extremely low (e.g., lower than or equal to 1 fps). Thus, power consumption of the display apparatus can be reduced by stopping the driver circuit in displaying a still image. When an LTPS transistor is used as the driving transistor, the amount of current flowing through the light-emitting element 60 can be increased.

The light-blocking layer 317 is preferably provided on the surface of the substrate 152 on the substrate 101 side. The light-blocking layer 317 can be provided between adjacent light-emitting elements 60, in the connection portion 140, and in the circuit 164, for example. Note that the light-blocking layer 317 may be provided between the protective layer 331 and the adhesive layer 142. A variety of optical members can be provided on the outer surface of the substrate 152.

As the connection layer 242, an anisotropic conductive film (ACF), an anisotropic conductive paste (ACP), or the like can be used.

### [Display Apparatus 10B]

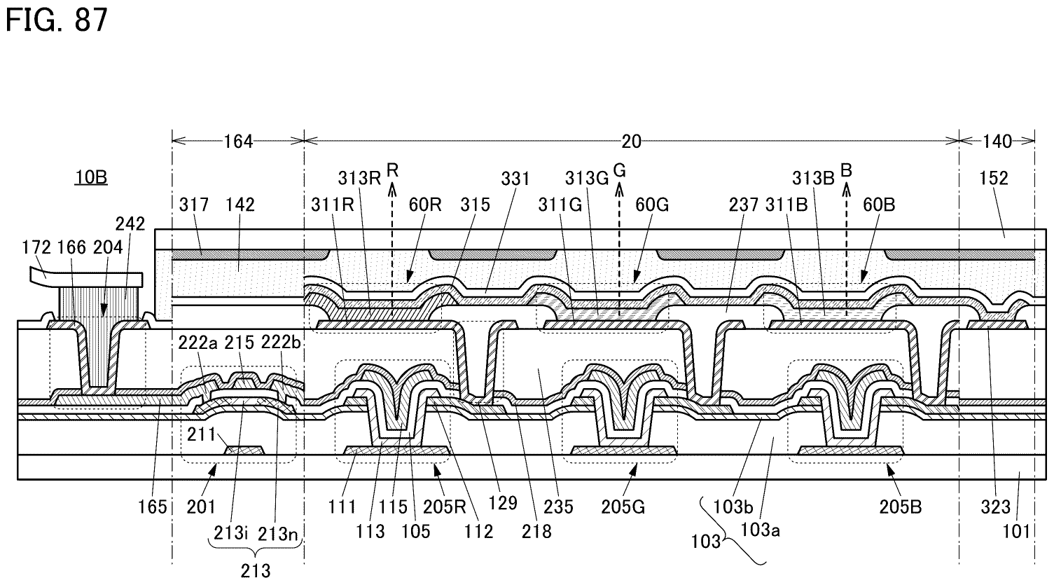

FIG. 87 is a cross-sectional view illustrating the structure example of a display apparatus 10B. The display apparatus 10B is a variation example of the display apparatus 10A and is different from the display apparatus 10A in the structure of the transistor 201, for example.

The transistor 201 included in the display apparatus 10B includes a semiconductor layer 213, the insulating layer 105 functioning as a gate insulating layer, a conductive layer 215 functioning as a gate electrode, a conductive layer 222a functioning as one of a source electrode and a drain electrode, and a conductive layer 222b functioning as the other of the source electrode and the drain electrode. The transistor 201 can include a conductive layer 211. In this case, the conductive layer 215 functions as a first gate electrode, and the conductive layer 211 functions as a second gate electrode. In addition, the insulating layer 105 functions as a first gate insulating layer, and the insulating layer 103 functions as a second gate insulating layer.

The conductive layer 211 is provided over the substrate 101, and the insulating layer 103 is provided over the substrate 101 and the conductive layer 211. The semiconductor layer 213 is provided over the insulating layer 103 to include a region overlapping with the conductive layer 211, and the insulating layer 105 is provided over the insulating layer 103 and the semiconductor layer 213. The conductive layer 215 is provided over the insulating layer 105 to include a region overlapping with the conductive layer 211 and the semiconductor layer 213.

The semiconductor layer 213 includes a channel formation region 213i and a pair of low-resistance regions 213n. Here, a first opening reaching one of the pair of low-resistance regions 213n and a second opening reaching the other of the pair of low-resistance regions 213n are provided in the insulating layer 105. The semiconductor layer 213 and the conductive layer 222a are electrically connected to each other through the first opening, and the semiconductor layer 213 and the conductive layer 222b are electrically connected to each other through the second opening. For example, one of the pair of low-resistance regions 213n is in contact with the conductive layer 222a in the first opening, and the other of the pair of low-resistance regions 213n is in contact with the conductive layer 222b in the second opening.

The conductive layer 211 can be formed in the same layer as the conductive layer 111. Thus, the conductive layer 211 and the conductive layer 111 can be formed using the same material and in the same step. For example, the conductive layer 111 and the conductive layer 211 can be formed by processing the same conductive film. The semiconductor layer 213 can be provided in the same layer as the semiconductor layer 113. Thus, the semiconductor layer 213 and the semiconductor layer 113 can be formed using the same material and in the same step. For example, the semiconductor layer 113 and the semiconductor layer 213 can be formed by processing the same semiconductor film. Furthermore, the conductive layer 215, the conductive layer 222a, and the conductive layer 222b can be provided in the same layer as the conductive layer 115. Thus, the conductive layer 215, the conductive layer 222a, the conductive layer 222b, and the conductive layer 115 can be formed using the same material and in the same step. For example, the conductive layer 115, the conductive layer 215, the conductive layer 222a, and the conductive layer 222b can be formed by processing the same conductive film.

Here, the semiconductor layer 113 and the semiconductor layer 213 may contain different materials. For example, a metal oxide may be used for the semiconductor layer 113, and silicon such as LTPS may be used for the semiconductor layer 213. When a metal oxide is used for the semiconductor layer 113, that is, an OS transistor is used as the transistor 205, it is possible to “inhibit black-level degradation”, “increase the emission luminance”, “increase the number of gray levels”, and “inhibit a variation in the emission luminance among the light-emitting elements 60” as described in Embodiment 1, for example. The transistor 201 can have improved field-effect mobility by using silicon such as LTPS for the semiconductor layer 213. Thus, the circuit 164 can be driven at high speed. When the semiconductor layer 113 and the semiconductor layer 213 are formed in different steps, a material contained in the semiconductor layer 113 and a material contained in the semiconductor layer 213 can be different from each other.

In the case where the transistor 201 includes the conductive layer 211, the channel formation region 213i is positioned between two gate electrodes. In this case, the two gate electrodes may be electrically connected to each other and supplied with the same signal to drive the transistor 201. Alternatively, a potential for controlling the threshold voltage may be supplied to one of the two gate electrodes and a potential for driving may be supplied to the other to control the threshold voltage of the transistor 201.

A transistor having a structure similar to that of the transistor 201 illustrated in FIG. 87 may be provided in the display portion 20. For example, the transistor 51 described in Embodiment 1 can have a structure similar to that of the transistor 201 illustrated in FIG. 87. This might increase the channel length of the transistor 51, in which case the off-state current of the transistor 51 can be reduced in some cases. Accordingly, image data written to the subpixel can be retained for a long time, and the frequency of refresh operation can be reduced in some cases. Thus, when the transistor 51 has a structure similar to that of the transistor 201 illustrated in FIG. 87, the power consumption of the display apparatus of one embodiment of the present invention can be reduced in some cases.

### [Display Apparatus 10C]

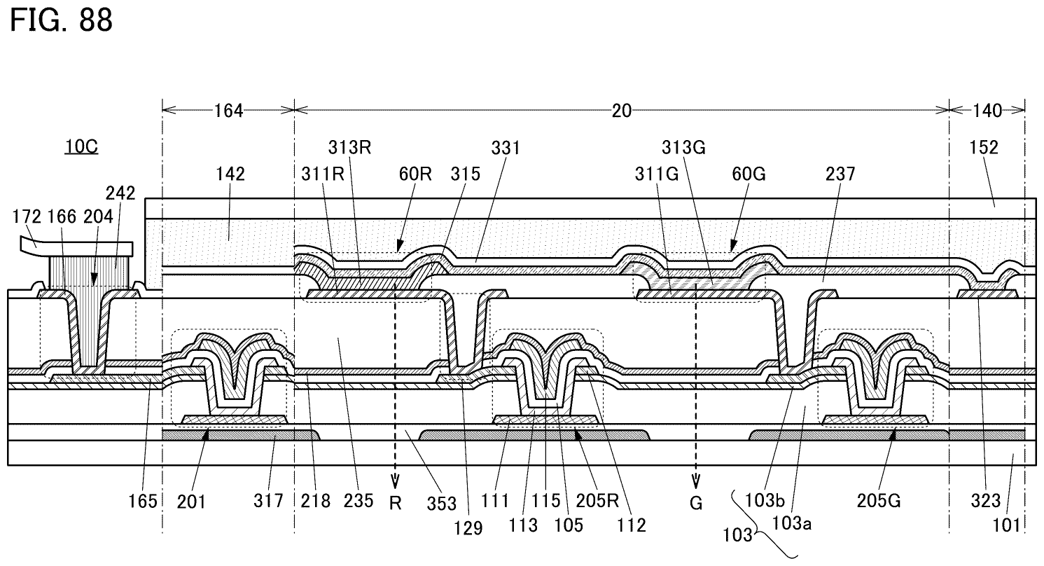

FIG. 88 is a cross-sectional view illustrating the structure example of a display apparatus 10C. The display apparatus 10C is a variation example of the display apparatus 10A and is different from the display apparatus 10A in having a bottom-emission structure, for example.

In the display apparatus 10C, light emitted from the light-emitting element 60 is emitted to the substrate 101 side. For the substrate 101, a material having a high visible-light-transmitting property is preferably used. By contrast, there is no limitation on the light-transmitting property of a material used for the substrate 152.

The light-blocking layer 317 is preferably provided between the substrate 101 and the transistor 201 and between the substrate 101 and the transistor 205. FIG. 88 illustrates an example where the light-blocking layer 317 is provided over the substrate 101, an insulating layer 353 is provided over the light-blocking layer 317 and the substrate 101, and the transistor 201, the transistor 205, and the like are provided over the insulating layer 353.

A material having a high visible-light-transmitting property is used for each of the pixel electrode 311R, the pixel electrode 311G, and the pixel electrode 311B. A material reflecting visible light is preferably used for the common electrode 315.

The structure of the display apparatus 10C can also be applied to the display apparatus 10B. Specifically, the display apparatus 10B can have a bottom-emission structure. When a material having a high visible-light-transmitting property is used for both the pixel electrode 311 and the common electrode 315, the display apparatus 10A, the display apparatus 10B, and the display apparatus 10C can have a dual-emission structure. In the dual-emission display apparatus 10, a material having a high visible-light-transmitting property is preferably used for both the substrate 101 and the substrate 152.

### [Display Apparatus 10D]

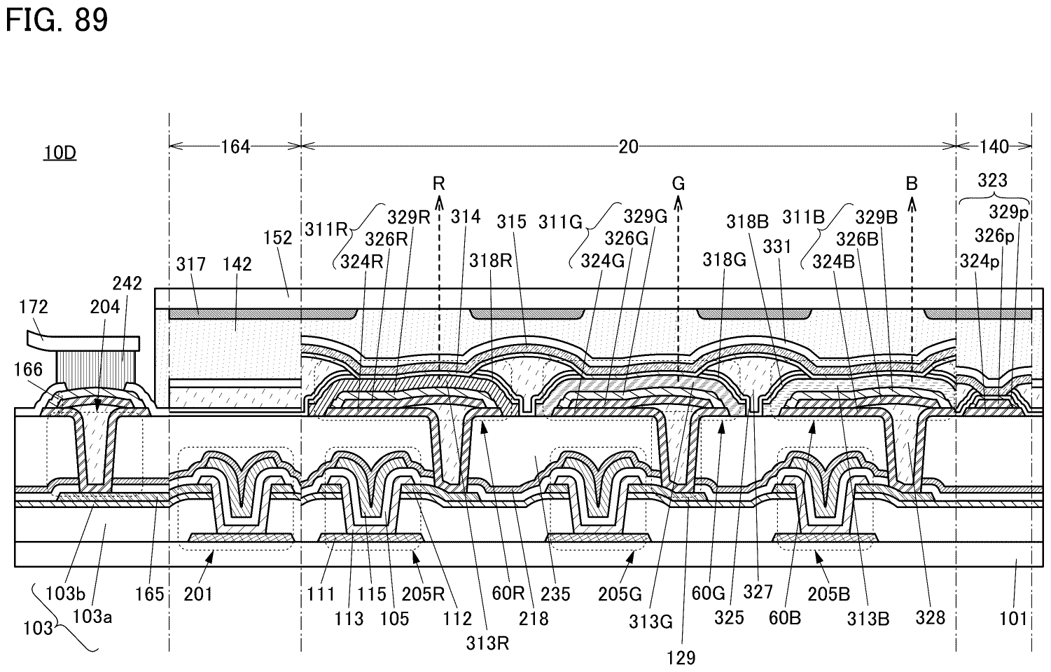

FIG. 89 is a cross-sectional view illustrating the structure example of a display apparatus 10D. The display apparatus 10D is a variation example of the display apparatus 10A and is different from the display apparatus 10A in the structures of the light-emitting element 60R, the light-emitting element 60G, and the light-emitting element 60B, for example. The display apparatus 10D is different from the display apparatus 10A in the structures of the pixel electrode 311R, the pixel electrode 311G, the pixel electrode 311B, the conductive layer 166, and the conductive layer 323. Furthermore, the display apparatus 10D is different from the display apparatus 10A in that the insulating layer 237 is not provided, the layer 313 covers the top surface and the side surface of the pixel electrode 311, and a layer 328, an insulating layer 325, an insulating layer 327, and a common layer 314 are provided.

As illustrated in FIG. 89, the pixel electrode 311 included in the light-emitting element 60 has a stacked-layer structure including a conductive layer 324, a conductive layer 326 over the conductive layer 324, and a conductive layer 329 over the conductive layer 326. Here, the conductive layer 324, the conductive layer 326, and the conductive layer 329 included in the pixel electrode 311R are referred to as a conductive layer 324R, a conductive layer 326R, and a conductive layer 329R, respectively. The conductive layer 324, the conductive layer 326, and the conductive layer 329 included in the pixel electrode 311G are referred to as a conductive layer 324G, a conductive layer 326G, and a conductive layer 329G, respectively. The conductive layer 324, the conductive layer 326, and the conductive layer 329 included in the pixel electrode 311B are referred to as a conductive layer 324B, a conductive layer 326B, and a conductive layer 329B, respectively.

The conductive layer 324 is electrically connected to the conductive layer 112 included in the transistor 205 through the opening 129 provided in the insulating layer 105, the insulating layer 218, and the insulating layer 235.

The end portion of the conductive layer 326 is positioned inward from the end portion of the conductive layer 324 and the end portion of the conductive layer 329. In other words, the end portion of the conductive layer 326 is positioned over the conductive layer 324, and the top surface and the side surface of the conductive layer 326 are covered with the conductive layer 329.

For the conductive layer 324, no particular limitations are imposed on the properties of transmitting and reflecting visible light. As the conductive layer 324, a conductive layer having a visible-light-transmitting property or a conductive layer having a visible-light-reflecting property can be used. As the conductive layer having a visible-light-transmitting property, an oxide conductive layer can be used, for example. Specifically, In—Si—Sn oxide (ITSO) can be suitably used for the conductive layer 324. Examples of the conductive layer having a visible-light-reflecting property include metal such as aluminum, magnesium, titanium, chromium, nickel, copper, yttrium, zirconium, silver, tin, zinc, silver, platinum, gold, molybdenum, tantalum, and tungsten, and an alloy containing the metal as its main component. As the alloy that can be used for the conductive layer 324, an alloy containing aluminum such as an alloy of aluminum, nickel, and lanthanum (Al—Ni—La), and an alloy containing silver such as an alloy of silver and magnesium and an alloy of silver, palladium, and copper (APC: Ag—Pd—Cu). The conductive layer 324 may have a stacked-layer structure of a conductive layer having a visible-light-transmitting property and a conductive layer having visible-light-reflecting property over the conductive layer. For the conductive layer 324, a material with high adhesion to the formation surface of the conductive layer 324 (here, the insulating layer 235) is preferably used. Accordingly, film separation of the conductive layer 324 can be inhibited.

As the conductive layer 326, a conductive layer having a visible-light-reflecting property can be used. The conductive layer 326 may have a stacked-layer structure of a conductive layer having a visible-light-transmitting property and a conductive layer having a visible-light-reflecting property over the conductive layer. For the conductive layer 326, a material that can be used for the conductive layer 324 can be used. Specifically, a stacked-layer structure of In—Si—Sn oxide (ITSO) and an alloy of silver, palladium, and copper (APC) over the In—Si—Sn oxide (ITSO) can be suitably used for the conductive layer 326.

For the conductive layer 329, a material that can be used for the conductive layer 324 can be used. As the conductive layer 329, a conductive layer having a visible-light-transmitting property can be used. Specifically, In—Si—Sn oxide (ITSO) can be used for the conductive layer 329.

In the case where a material that is easily oxidized is used for the conductive layer 326, a material that is not easily oxidized is used for the conductive layer 329 and the conductive layer 326 is covered with the conductive layer 329, whereby oxidation of the conductive layer 326 can be inhibited. In addition, precipitation of a metal component included in the conductive layer 326 can be inhibited. For example, in the case where a material containing silver is used for the conductive layer 326, In—Si—Sn oxide (ITSO) can be suitably used for the conductive layer 329. Thus, oxidation of the conductive layer 326 can be inhibited, and precipitation of silver can be inhibited.

For example, the conductive layer 323 can have a stacked-layer structure of a conductive layer 324p, a conductive layer 326p over the conductive layer 324p, and a conductive layer 329p over the conductive layer 326p. The conductive layer 324p can be provided in the same layer as the conductive layer 324R, the conductive layer 324G, and the conductive layer 324B. Thus, the conductive layer 324p, the conductive layer 324R, the conductive layer 324G, and the conductive layer 324B can be formed using the same material and in the same step. For example, the conductive layer 324R, the conductive layer 324G, the conductive layer 324B, and the conductive layer 324p can be formed by processing the same conductive film. The conductive layer 326p, the conductive layer 326R, the conductive layer 326G, and the conductive layer 326B can be formed using the same material and in the same step. For example, the conductive layer 326R, the conductive layer 326G, the conductive layer 326B, and the conductive layer 326p can be formed by processing the same conductive film. Furthermore, the conductive layer 329p, the conductive layer 329R, the conductive layer 329G, and the conductive layer 329B can be formed using the same material and in the same step. For example, the conductive layer 329R, the conductive layer 329G, the conductive layer 329B, and the conductive layer 329p can be formed by processing the same conductive film.

FIG. 89 illustrates an example where the thickness of the conductive layer 329p is different from the thicknesses of the conductive layer 329R, the conductive layer 329G, and the conductive layer 329B. The thicknesses of the conductive layer 329p, the conductive layer 329R, the conductive layer 329G, and the conductive layer 329B may be different depending on the resistivities of materials used for these layers. In the case of making the thicknesses different, the conductive layer 329p may be formed in a step different from a step of forming the conductive layer 329R, the conductive layer 329G, and the conductive layer 329B. Alternatively, some formation steps may be common between the conductive layer 329p and the conductive layer 329R, the conductive layer 329G, and the conductive layer 329B.

Depressed portions are formed in the conductive layer 324R, the conductive layer 324G, and the conductive layer 324B so as to cover the opening 129. The layer 328 is embedded in each of the depressed portions.

The layer 328 has a planarization function for the depressed portions of the conductive layer 324R, the conductive layer 324G, and the conductive layer 324B. The conductive layer 326R electrically connected to the conductive layer 324R is provided over the conductive layer 324R and the layer 328. The conductive layer 326G electrically connected to the conductive layer 324G is provided over the conductive layer 324G and the layer 328. The conductive layer 326B electrically connected to the conductive layer 324B is provided over the conductive layer 324B and the layer 328. Through the above steps, regions overlapping with the depressed portions of the conductive layer 324R, the conductive layer 324G, and the conductive layer 324B can function as the light-emitting regions, increasing the aperture ratio of the pixels.

The layer 328 may be an insulating layer or a conductive layer. Any of a variety of inorganic insulating materials, organic insulating materials, or conductive materials can be used for the layer 328 as appropriate. Specifically, the layer 328 is preferably formed using an insulating material and is particularly preferably formed using an organic insulating material.

In the case where the layer 328 is a conductive layer, the layer 328 can function as part of a pixel electrode.

The layer 328 included in the display apparatus 10D can also be used for the display apparatus 10A, the display apparatus 10B, and the display apparatus 10C. For example, instead of the insulating layer 237, the layer 328 can be embedded in at least part of the depressed portions in the pixel electrode 311R, the pixel electrode 311G, and the pixel electrode 311B.

FIG. 89 illustrates an example where the end portion of the layer 313 is positioned outward from the end portion of the pixel electrode 311. The layer 313 is formed to cover the end portion of the pixel electrode 311. Such a structure enables the entire top surface of the pixel electrode 311 to be a light-emitting region, and the aperture ratio can be increased as compared with the structure where the end portion of the island-shaped layer 313 is positioned inward from the end portion of the pixel electrode 311. Covering the side surface of the pixel electrode 311 with the layer 313 can inhibit contact between the pixel electrode 311 and the common electrode 315, thereby inhibiting a short circuit of the light-emitting element 60.

The insulating layer 237 is not provided between the pixel electrode 311 and the layer 313. Thus, the distance between adjacent light-emitting elements 60 can be shortened. Accordingly, the display apparatus 10D can have high definition or high resolution. In addition, a mask for forming the insulating layer is not needed, which leads to a reduction in manufacturing cost of the display apparatus.

The layer 313 can be formed by a photolithography method and an etching method, for example. Specifically, a film to be the layer 313 is formed across a plurality of pixel electrodes 311 that have been formed for respective subpixels. Next, a mask layer is formed over the film to be the layer 313, and a resist mask is formed over the mask layer by a photolithography method. After that, the mask layer and the film to be the layer 313 are processed by an etching method, for example, and the resist mask is removed. A mask layer having a two-layer structure of a first mask layer and a second mask layer over the first mask layer is used, for example. In this case, a resist mask is formed over the second mask layer and the second mask layer is processed. Then, the resist mask is removed. After that, the first mask layer and the film to be the layer 313 are processed using the second mask layer as a hard mask, for example. In this manner, one island-shaped layer 313 is formed for every pixel electrode 311. Thus, the layer 313 can be divided into island-shaped layers 313 for respective subpixels. By performing a series of steps from the formation of the film to be the layer 313 to the processing of the film three times, for example, the layer 313R, the layer 313G, and the layer 313B can be separately formed.

In this specification and the like, a mask layer (also referred to as a sacrificial layer) refers to a layer that is positioned above at least a light-emitting layer (specifically, a layer processed into an island shape among layers included in an EL layer) and has a function of protecting the light-emitting layer in the manufacturing process.

When the island-shaped layer 313 is formed without using a fine metal mask, the formed layer 313 can have a minute size. Providing the island-shaped layer 313 for each light-emitting element 60 can inhibit a leakage current between the adjacent light-emitting elements 60. This can inhibit crosstalk due to unintended light emission, so that a display apparatus with extremely high contrast can be obtained. Specifically, a display apparatus having high current efficiency at low luminance can be obtained.

In this specification and the like, a device manufactured using a metal mask or a fine metal mask (FMM) is sometimes referred to as a device having an MM (metal mask) structure. In this specification and the like, a device manufactured without using a metal mask or an FMM is sometimes referred to as a device having an MML (metal maskless) structure.

In the case where the island-shaped layer 313 is formed without using a fine metal mask, a surface of the layer 313 is exposed in the manufacturing process of the display apparatus. The layer 313R, the layer 313G, and the layer 313B each preferably include a carrier-transport layer over a light-emitting layer. Alternatively, the layer 313R, the layer 313G, and the layer 313B each preferably include a carrier-blocking layer over the light-emitting layer. Alternatively, the layer 313R, the layer 313G, and the layer 313B each preferably include a carrier-blocking layer over the light-emitting layer, and a carrier-transport layer over the carrier-blocking layer. Accordingly, the light-emitting layer can be inhibited from being exposed on the outermost surface, thereby reducing damage to the light-emitting layer. Thus, the reliability of the light-emitting element 60 can be increased.

In the case where the light-emitting element 60 has a tandem structure in which, for example, the layer 313 includes a first light-emitting unit, a charge-generation layer over the first light-emitting unit, and a second light-emitting unit over the charge-generation layer, a surface of the second light-emitting unit is exposed in the manufacturing process of the display apparatus. Thus, the second light-emitting unit preferably includes a carrier-transport layer over a light-emitting layer. Alternatively, the second light-emitting unit preferably includes a carrier-blocking layer over the light-emitting layer. Alternatively, the second light-emitting unit preferably includes a carrier-blocking layer over the light-emitting layer, and a carrier-transport layer over the carrier-blocking layer. Accordingly, the light-emitting layer can be inhibited from being exposed on the outermost surface, thereby reducing damage to the light-emitting layer. Thus, the reliability of the light-emitting element 60 can be increased. Note that in the case where three or more light-emitting units are provided, the uppermost light-emitting unit preferably includes one or both of a carrier-transport layer and a carrier-blocking layer over the light-emitting layer.

The upper temperature limits of the compounds contained in the layer 313R, the layer 313G, and the layer 313B are each preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition points (Tg) of these compounds are each preferably higher than or equal to 100° C. and lower than or equal to 180° C., further preferably higher than or equal to 120° C. and lower than or equal to 180° C., still further preferably higher than or equal to 140° C. and lower than or equal to 180° C. This inhibits a reduction in light emission efficiency and a decrease in lifetime which are due to damage to the layer 313R, the layer 313G, and the layer 313B by heat applied in a process.

In a region between adjacent light-emitting elements 60, the insulating layer 325 and the insulating layer 327 over the insulating layer 325 are provided. Although FIG. 89 illustrates a plurality of cross sections of the insulating layer 325 and the insulating layer 327, the insulating layer 325 and the insulating layer 327 are each one continuous layer when the display apparatus 10D is seen from above. In other words, the display apparatus 10D can have a structure including one insulating layer 325 and one insulating layer 327, for example. Note that the display apparatus 10D may include a plurality of insulating layers 325 that are separated from each other, and may include a plurality of insulating layers 327 that are separated from each other.

The insulating layer 325 preferably includes regions in contact with the side surfaces of the layer 313R, the layer 313G, and the layer 313B. The insulating layer 325 includes regions in contact with the layer 313R, the layer 313G, and the layer 313B, whereby film separation of the layer 313R, the layer 313G, and the layer 313B can be inhibited. When the insulating layer 325 is closely attached to the layer 313R, the layer 313G, or the layer 313B, the effect of fixing or bonding the adjacent layers 313 by the insulating layer 325 is obtained. Thus, the reliability of the light-emitting element 60 can be increased. In addition, the yield of the light-emitting element 60 can be increased.

For the insulating layer 325, a material that can be used for the protective layer 331 can be used, and an inorganic material can be used, for example. It is particularly preferable to use aluminum oxide for the protective layer 331 because the etching selectivity of the insulating layer 325 and the layer 313 can be increased to protect the layer 313.

The insulating layer 325 preferably has a function of a barrier insulating layer against at least one of water and oxygen. Alternatively, the insulating layer 325 preferably has a function of inhibiting diffusion of at least one of water and oxygen. Alternatively, the insulating layer 325 preferably has a function of capturing or fixing (also referred to as gettering) at least one of water and oxygen. Note that in this specification and the like, a barrier insulating layer refers to an insulating layer having a barrier property. A barrier property in this specification and the like refers to a function of inhibiting diffusion of a particular substance (also referred to as low permeability).

When the insulating layer 325 has a function of a barrier insulating layer or a gettering function, entry of impurities (typically, at least one of water and oxygen) that might diffuse into the light-emitting element from the outside can be inhibited. With this structure, a highly reliable light-emitting element and a highly reliable display apparatus can be provided.

The insulating layer 327 is provided over the insulating layer 325 to fill a depressed portion formed on the insulating layer 325. The insulating layer 327 can be configured to overlap with the side surface and part of the top surface of each of the layer 313R, the layer 313G, and the layer 313B with the insulating layer 325 therebetween. The insulating layer 327 preferably covers at least part of the side surface of the insulating layer 325. The insulating layer 325 and the insulating layer 327 can fill a gap between the adjacent island-shaped layers, whereby unevenness of the formation surface of the layers, e.g., the common electrode 315, to be provided over the island-shaped layers can be reduced and the coverage with the layers can be improved. This can inhibit a connection defect due to the step disconnection. In addition, an increase in electric resistance, which is caused by local thinning of the common electrode 315 due to the step, can be inhibited. The top surface of the insulating layer 327 preferably has a shape with higher flatness; however, it may have a projecting portion, a convex surface, a concave surface, or a depressed portion.

An insulating layer containing an organic material can be suitably used for the insulating layer 327. As the organic material, a photosensitive organic resin is preferably used, and for example, a photosensitive resin composition including an acrylic resin is preferably used. Note that in this specification and the like, an acrylic resin refers to not only a polymethacrylic acid ester or a methacrylic resin, but also all the acrylic polymer in a broad sense in some cases. Note that the materials that can be used for the insulating layer 327 can also be used for the layer 328.

A mask layer 318R is positioned over the layer 313R included in the light-emitting element 60R, a mask layer 318G is positioned over the layer 313G included in the light-emitting element 60G, and a mask layer 318B is positioned over the layer 313B included in the light-emitting element 60B. The mask layer 318 is provided to surround the light-emitting region. In other words, the mask layer 318 has an opening in a portion overlapping with the light-emitting region. The mask layer 318R is a remaining part of a mask layer provided over the layer 313R at the time of forming the layer 313R. In a similar manner, the mask layer 318G is a remaining part of the mask layer provided at the time of forming the layer 313G, and the mask layer 318B is a remaining part of the mask layer provided at the time of forming the layer 313B. Thus, the mask layer used to protect the layer 313 in manufacture of the display apparatus may partly remain in the display apparatus of one embodiment of the present invention.

Although the mask layer 318 has a single-layer structure in FIG. 89, the mask layer 318 may have a stacked-layer structure. For example, the mask layer 318 may have a two-layer structure or a stacked-layer structure of three or more layers. After the formation of the film to be the layer 313, a first mask layer and a second mask layer over the first mask layer are formed as mask layers in some cases. After that, the layer 313R, the layer 313G, and the layer 313B are formed using the mask layers, the second mask layer is removed, and then an opening reaching the layer 313 is formed in the first mask layer in some cases. In that case, the mask layer 318 remaining in the display apparatus 10D has a single-layer structure. In other words, the mask layer 318 may include a smaller number of layers than the mask layer formed in the manufacturing process of the display apparatus 10D.

In the display apparatus 10D, the common layer 314 is provided over the layer 313R, the layer 313G, the layer 313B, and the insulating layer 327 and the common electrode 315 is provided over the common layer 314. Like the common electrode 315, the common layer 314 is shared by the light-emitting element 60R, the light-emitting element 60G, and the light-emitting element 60B. In the case where the light-emitting element 60 includes the common layer 314, the layer 313 and the common layer 314 can be collectively referred to as an EL layer. Note that the common layer 314 is not necessarily included in the EL layer.

The common layer 314 includes an electron-injection layer or a hole-injection layer, for example. Alternatively, the common layer 314 may include a stack of an electron-transport layer and an electron-injection layer, or may include a stack of a hole-transport layer and a hole-injection layer. Here, a structure can be employed where the layer included in the common layer 314 is not included in the layer 313. For example, when the common layer 314 includes an electron-injection layer, the layer 313 does not necessarily include an electron-injection layer. When the common layer 314 includes a hole-injection layer, the layer 313 does not necessarily include a hole-injection layer.

In the case where the common layer 314 is provided in the display apparatus, the common electrode 315 can be formed successively after the formation of the common layer 314, without interposing a step of etching or the like. For example, after the common layer 314 is formed in a vacuum, the common electrode 315 can be formed in a vacuum without exposing the substrate 101 to the air. In other words, the common layer 314 and the common electrode 315 can be successively formed in a vacuum. Accordingly, the lower surface of the common electrode 315 can be a clean surface, as compared with the case where the common layer 314 is not provided in the display apparatus. Thus, in the case where the surface of the layer 313 is exposed to the air after the formation of the layer 313, the common layer 314 is preferably provided in the display apparatus.

In the example in FIG. 89, the common layer 314 is not provided in the connection portion 140. For example, by using a mask for specifying a formation area (also referred to as an area mask or a rough metal mask to distinguish from a fine metal mask), the common layer 314 and the common electrode 315 can be formed in different regions.

Here, in the case where the electric resistance of the common layer 314 in the thickness direction is low enough to be negligible, electrical continuity between the conductive layer 323 and the common electrode 315 can be maintained even when the common layer 314 is provided between the conductive layer 323 and the common electrode 315. When the common layer 314 is provided not only in the display portion 20 but also in the connection portion 140, the common layer 314 can be formed, for example, without using a metal mask such as an area mask. Thus, the manufacturing process of the display apparatus 10D can be simplified.

Although the display apparatus 10D in FIG. 89 has a top-emission structure, the display apparatus 10D may have a bottom-emission structure or a dual-emission structure.

The structure of the display apparatus 10D is also applicable to the display apparatus 10A, the display apparatus 10B, and the display apparatus 10C. Specifically, at least one of the structure of the light-emitting element 60, the point where the insulating layer 237 is not included, the point where the insulating layer 325 is included, and the point where the insulating layer 327 is included can be used for the display apparatus 10A, the display apparatus 10B, and the display apparatus 10C.

### [Display Apparatus 10E]

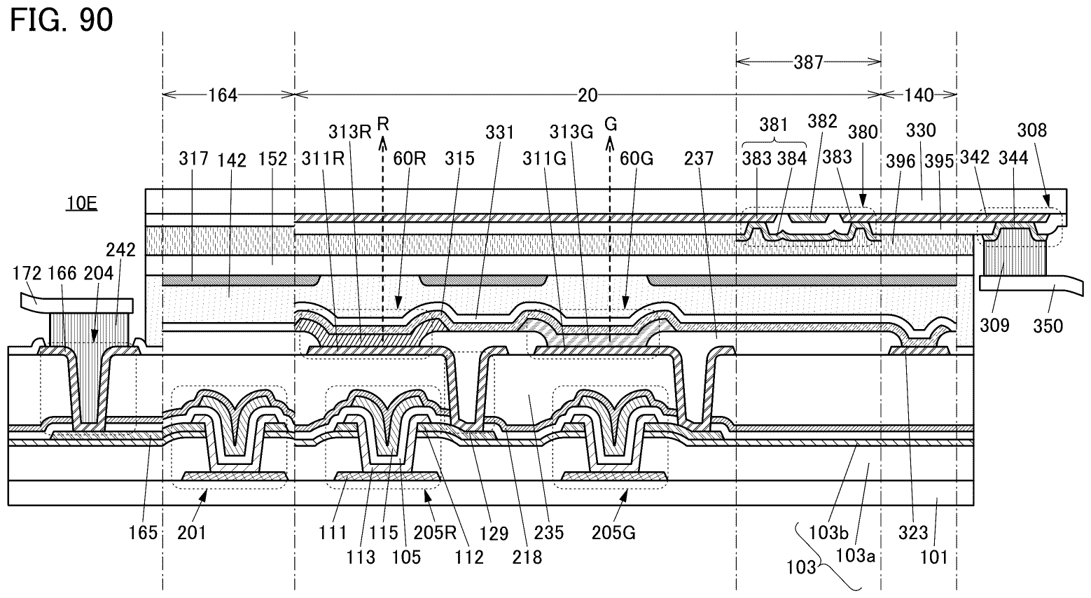

FIG. 90 is a cross-sectional view illustrating the structure example of a display apparatus 10E. A display apparatus 10F is a variation example of the display apparatus 10A and is different from the display apparatus 10A in that a touch sensor is included. FIG. 90 illustrates a structure example of a sensing portion 387 provided with a touch sensor.

In this specification and the like, a display apparatus including a touch sensor is referred to as a touch panel.

In the display apparatus 10E, an adhesive layer 396 is provided over the substrate 152, and an insulating layer 395 is provided over the adhesive layer 396. Thus, the substrate 152 and the insulating layer 395 are attached to each other with the adhesive layer 396. A substrate 330 is provided over the insulating layer 395.

The sensing portion 387 is included in the display portion 20. In the sensing portion 387, a sensor element 380 (also referred to as a sensing device, a sensor element, or a sensor device) is provided as a touch sensor on a surface of the substrate 330 on the substrate 152 side. The sensor element 380 can sense the approach or contact of a sensing target such as a finger or a stylus to the display apparatus 10E.

The sensor element 380 includes an electrode 381 and an electrode 382. FIG. 90 illustrates an example where the electrode 381 includes an electrode 383 and an electrode 384.

The electrode 382 and the electrode 383 can be provided in the same layer. Thus, the electrode 382 and the electrode 383 can be formed using the same material and in the same step. For example, the electrode 382 and the electrode 383 can be formed by processing the same conductive film.

In the sensing portion 387, the insulating layer 395 is provided to cover at least part of the electrode 382 and the electrode 383. The electrode 384 is electrically connected to two electrodes 383, between which the electrode 382 is provided, through openings formed in the insulating layer 395. Thus, the electrode 384 includes a region overlapping with the electrode 382.

A wiring 342, a conductive layer 344, a connection layer 309, and an FPC 350 are provided in a region of the substrate 330 that does not overlap with the substrate 152. The wiring 342 and the FPC 350 are electrically connected to each other through the conductive layer 344 and the connection layer 309 in a connection portion 308. The wiring 342 can be provided in the same layer as the electrode 382 and the electrode 383. Thus, the wiring 342, the electrode 382, and the electrode 383 can be formed using the same material and in the same step. For example, the wiring 342, the electrode 382, and the electrode 383 can be formed by processing the same conductive film. The conductive layer 344 can be provided in the same layer as the electrode 384. Thus, the conductive layer 344 and the electrode 384 can be formed using the same material and in the same step. For example, the conductive layer 344 and the electrode 384 can be formed by processing the same conductive film.

In order to electrically connect the FPC 350 and the conductive layer 344, a portion where the insulating layer 395 is not provided is generated in the connection portion 308. For example, after the insulating layer 395 is formed over the entire substrate 330, an opening reaching the wiring 342 is formed in the insulating layer 395, whereby the wiring 342 can be exposed. After that, the conductive layer 344 is formed, and the connection layer 309 and the FPC 350 are provided to be electrically connected to the conductive layer 344. In the above manner, the wiring 342 and the FPC 350 can be electrically connected to each other through the conductive layer 344 and the connection layer 309.

Like the connection layer 242, the connection layer 309 can be formed using an ACF, an ACP, or the like.

Note that the sensor element 380 may be provided in the display apparatus 10B, the display apparatus 10C, and the display apparatus 10D. Thus, the display apparatus 10B, the display apparatus 10C, and the display apparatus 10D can each have a function of a touch panel.

The sensor element 380 included in FIG. 90 is a capacitive sensor element. Examples of the capacitive type include a surface capacitive type and a projected capacitive type. Examples of the projected capacitive type include a self-capacitive type and a mutual capacitive type. With the use of a mutual capacitive type, simultaneous sensing of multiple points can be achieved. Note that the sensor element included in the display apparatus of one embodiment of the present invention is not limited to a capacitive type, and any of a variety of types such as a resistive type, a surface acoustic wave type, an infrared type, an optical type, and a pressure-sensitive type can be used.

The display apparatus 10E illustrated in FIG. 90 has a structure in which the sensor element 380 is formed on the substrate 330 and the substrate 152 is attached thereto; however, one embodiment of the present invention is not limited thereto. For example, the sensor element 380 may be formed between the substrate 101 and the substrate 152.

### [Display Apparatus 10F]

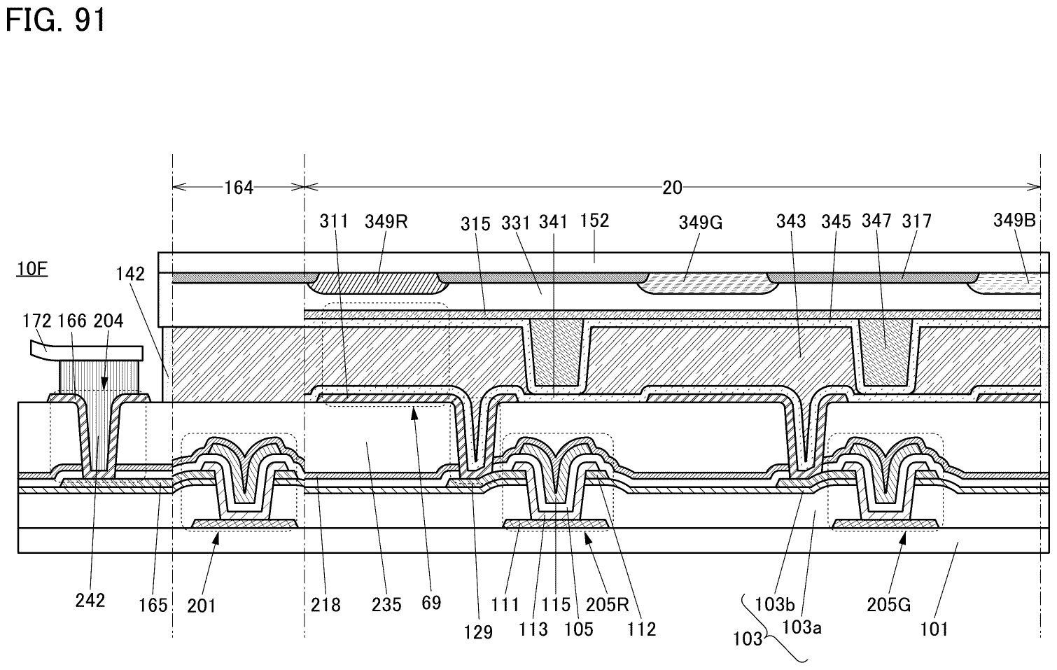

FIG. 91 is a cross-sectional view illustrating a structure example of the display apparatus 10F. The display apparatus 10F is a variation example of the display apparatus 10C and is different from the display apparatus 10F in that the liquid crystal element 69 is included as a display element.

The liquid crystal element 69 includes the pixel electrode 311 and the common electrode 315, and a liquid crystal layer 343 is provided between the pixel electrode 311 and the common electrode 315. An insulating layer 341 is provided between the pixel electrode 311 and the liquid crystal layer 343, and an insulating layer 345 is provided between the liquid crystal layer 343 and the common electrode 315. The insulating layer 341 and the insulating layer 345 each have a function of an alignment film.

A spacer 347 is provided between the liquid crystal elements 69. The spacer 347 is a columnar spacer obtained by selectively etching an insulating layer and is provided to control the distance (cell gap) between the pixel electrode 311 and the common electrode 315. Note that the spacer 347 may be a spherical spacer.

On the surface of the substrate 152 on the substrate 101 side, the light-blocking layer 317, a coloring layer 349R, a coloring layer 349G, a coloring layer 349B, the protective layer 331, the common electrode 315, the spacer 347, and the insulating layer 345 are provided in this order. The coloring layer 349R, the coloring layer 349G, and the coloring layer 349B are provided in regions of the display portion 20 where the light-blocking layers 317 are not provided. Note that the protective layer 331 can function as a planarization layer. An end portion of the coloring layer 349R, an end portion of the coloring layer 349G, and an end portion of the coloring layer 349B each overlap with an end portion of the light-blocking layer 317. The insulating layer 235 and the protective layer 331 are bonded to each other with the adhesive layer 142.

A backlight is provided in the display apparatus 10F. The backlight can be provided on the substrate 101 side, specifically, on the outer side (the side opposite to the formation surfaces of the transistor 201 and the transistor 205) of the substrate 101. Note that in the case where the display apparatus 10F is a reflective liquid crystal display apparatus, the display apparatus 10F is not necessarily provided with a backlight.

The coloring layer 349R includes a region overlapping with the liquid crystal element 69, and has a transmittance of red light higher than that of light of other colors, for example. Thus, light emitted from the liquid crystal element 69 including a region overlapping with the coloring layer 349R is extracted as red light to the outside of the display apparatus 10F. The coloring layer 349G includes a region overlapping with the liquid crystal element 69, and has a transmittance of green light higher than that of light of other colors, for example. Thus, light emitted from the liquid crystal element 69 including a region overlapping with the coloring layer 349G is extracted as green light to the outside of the display apparatus 10F. Furthermore, the coloring layer 349B includes a region overlapping with the liquid crystal element 69, and has a transmittance of blue light higher than that of light of other colors, for example. Thus, light emitted from the liquid crystal element 69 including a region overlapping with the coloring layer 349B is extracted as blue light to the outside of the display apparatus 10F. In this manner, the display apparatus 10F can perform full-color display.

Examples of a material that can be used for the coloring layer 349 include a metal material, a resin material, and a resin material containing a pigment or dye. The coloring layer 349 can be formed by an inkjet method, for example.

Although FIG. 91 illustrates an example of a display apparatus including a liquid crystal element with a vertical electric field mode, one embodiment of the present invention is not limited thereto and may be a display apparatus including a liquid crystal element with a horizontal electric field mode, for example. In the case of employing a horizontal electric field mode, a liquid crystal exhibiting a blue phase for which an alignment film is not used may be used. The blue phase is one of liquid crystal phases, which is generated just before a cholesteric phase changes into an isotropic phase while the temperature of a cholesteric liquid crystal is increased. Since the blue phase appears only in a narrow temperature range, a liquid crystal composition in which a chiral material is mixed at 5 weight % or more is used for the liquid crystal layer 343 in order to improve the temperature range. The liquid crystal composition that contains the liquid crystal exhibiting a blue phase and the chiral material has a short response time and exhibits optical isotropy. In addition, the liquid crystal composition that contains the liquid crystal exhibiting a blue phase and the chiral material does not need alignment treatment and has small viewing angle dependence. Since an alignment film is not necessarily provided, rubbing treatment is unnecessary. Accordingly, electrostatic breakdown caused by the rubbing treatment can be inhibited, and defects or damage of the display apparatus in the manufacturing process can be reduced.

The structure of the transistor 201 included in the display apparatus 10F is not limited to the structure illustrated in FIG. 91, and the structure illustrated in FIG. 87 may be employed, for example. The display apparatus 10F may have a function of a touch panel by providing the sensor element 380 illustrated in FIG. 90, for example.

The coloring layer 349R, the coloring layer 349G, and the coloring layer 349B included in the display apparatus 10F may be provided in a display apparatus including the light-emitting element 60, specifically, the display apparatus 10A to the display apparatus 10D, and the like. For example, the coloring layer 349R can be provided to include a region overlapping with the light-emitting element 60R, the coloring layer 349G can be provided to include a region overlapping with the light-emitting element 60G, and the coloring layer 349B can be provided to include a region overlapping with the light-emitting element 60B. For example, in a top-emission display apparatus such as the display apparatus 10A, the display apparatus 10B, and the display apparatus 10D, the coloring layer 349 can be provided between the light-emitting element 60 and the substrate 152, specifically, the coloring layer 349 can be provided between the protective layer 331 and the substrate 152. For example, the coloring layer 349 can be provided over the protective layer 331; specifically, the coloring layer 349 can be provided to include a region in contact with the protective layer 331. In that case, the protective layer 331 is preferably planarized. Here, when the adjacent coloring layers 349 include a region where they overlap with each other, a structure in which the light-blocking layer 317 is not provided can be employed. In addition, the coloring layer 349 may be provided on the substrate 152. In this case, for example, part of the coloring layer 349 can be in contact with the light-blocking layer 317, in which case an end portion of the coloring layer 349 can overlap with the light-blocking layer 317.

In a bottom-emission display apparatus such as the display apparatus 10C, the coloring layer 349 can be provided between the light-emitting element 60 and the substrate 101. For example, the coloring layer 349 can be provided over the insulating layer 218.

Provision of the coloring layer 349R, the coloring layer 349G, and the coloring layer 349B in the display apparatus including the light-emitting element 60 enables display of a full-color image on the display portion 20 even when the light-emitting element 60R, the light-emitting element 60G, and the light-emitting element 60B are light-emitting elements that emit light of the same color, e.g., light-emitting elements that emit white light. When the light-emitting element 60R, the light-emitting element 60G, and the light-emitting element 60B are light-emitting elements that emit light of the same color, the layer 313R, the layer 313G, and the layer 313B can be formed in the same step. This allows simplification of the manufacturing process of the display apparatus and an increase in the yield of the display apparatus. Thus, an inexpensive display apparatus can be achieved. Meanwhile, the structure without the coloring layer 349 can increase the light extraction efficiency of the display apparatus as compared with the case where the coloring layer 349 is provided. Accordingly, a bright image can be displayed on the display portion 20. In the case where images displayed on the display portion 20 have the same luminance, the structure without the coloring layer 349 can have lower emission luminance of the light-emitting element 60 than the structure with the coloring layer 349, and the power consumption of the display apparatus can be reduced accordingly.

Note that even in the case where the coloring layer 349R, the coloring layer 349G, and the coloring layer 349B are provided in the display apparatus including the light-emitting element 60, the light-emitting element 60R, the light-emitting element 60G, and the light-emitting element 60B may emit different light. For example, in the case where the red light transmittance of the coloring layer 349R is higher than the transmittance of light of other colors, the green light transmittance of the coloring layer 349G is higher than the transmittance of light of other colors, and the blue light transmittance of the coloring layer 349B is higher than the transmittance of light of other colors, the light-emitting element 60R may emit red light, the light-emitting element 60G may emit green light, and the light-emitting element 60B may emit blue light. In that case, providing the coloring layer 349 can improve the color purity of light emitted from the light-emitting element 60. Consequently, the display apparatus can achieve high display quality. Meanwhile, as described above, the structure without the coloring layer 349 can have higher light extraction efficiency of the display apparatus as compared with the case where the coloring layer 349 is provided.

The plurality of structure examples described in this embodiment can be combined with each other as appropriate. This embodiment can be combined with the other embodiments as appropriate.

### Embodiment 4

In this embodiment, electronic devices of one embodiment of the present invention will be described.

Electronic devices in this embodiment are each provided with the display apparatus of one embodiment of the present invention in a display portion. Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have a high definition, and thus can be suitably used for an electronic device having a relatively small display portion. Examples of such an electronic device include watch-type and bracelet-type information terminals (wearable devices) and wearable devices that can be worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (definition) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of such a display apparatus having one or both of high resolution and high definition can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with, for example, a camera and have a function of capturing a still image or a moving image, a function of storing the captured image in a storage medium (an external storage medium or a storage medium incorporated in the camera), a function of displaying the captured image on the display portion, and the like.

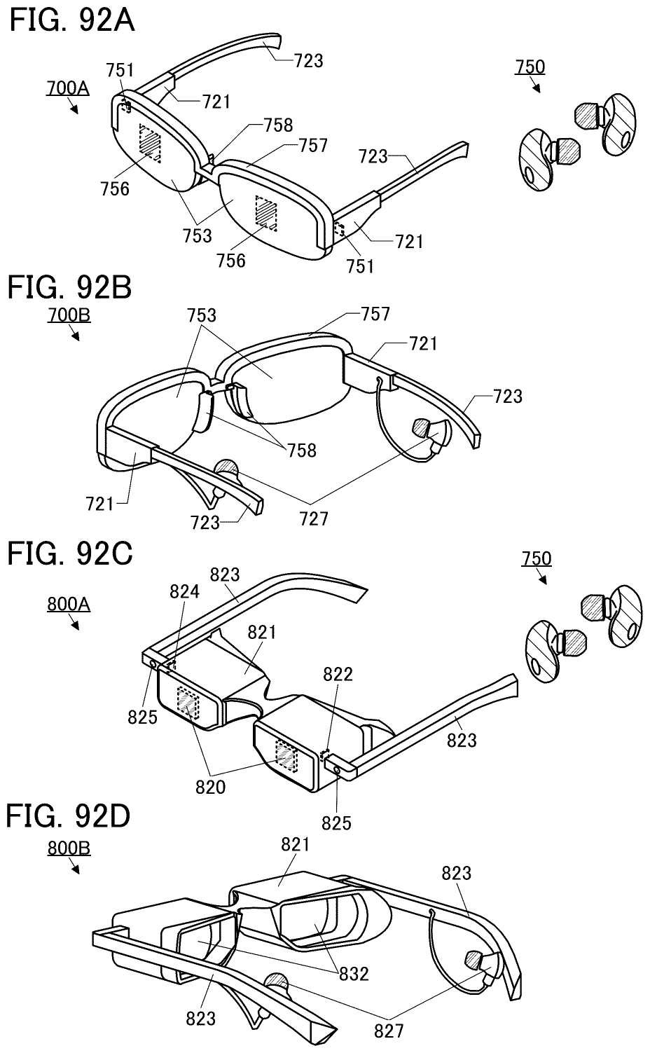

Examples of head-mounted wearable devices will be described with reference to FIG. 92A to FIG. 92D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 92A and an electronic device 700B illustrated in FIG. 92B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panel 751. Thus, the electronic devices are capable of performing ultrahigh-definition display.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic device 700A and the electronic device 700B are each provided with a battery so that they can be charged wirelessly and/or by wire.

A touch sensor module may be provided in the housing 721. The touch sensor module has a function of detecting a touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

Any of various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 800A illustrated in FIG. 92C and an electronic device 800B illustrated in FIG. 92D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic devices are capable of performing ultrahigh-definition display. This enables a user to feel a high sense of immersion.

The display portions 820 are positioned inside the housing 821 so as to be seen through the lenses 832. When the pair of the display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be worn on the user's head with the wearing portions 823. FIG. 92C illustrate an example where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. In other words, the image capturing portion 825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as a bone-conduction earphone. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, for example, a cable supplying a video signal from a video output device, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 92A has a function of transmitting information to the earphones 750 with the wireless communication function. As another example, the electronic device 800A in FIG. 92C has a function of transmitting information to the earphones 750 with the wireless communication function.

The electronic device may include an earphone portion. The electronic device 700B in FIG. 92B includes earphone portions 727. For example, a structure in which the earphone portions 727 and the control portion are connected to each other by wire may be employed. Part of a wiring that connects the earphone portion 727 and the control portion may be positioned inside the housing 721 or the wearing portion 723.

Similarly, the electronic device 800B illustrated in FIG. 92D includes earphone portions 827. For example, a structure in which the earphone portions 827 and the control portion 824 are connected to each other by wire may be employed. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

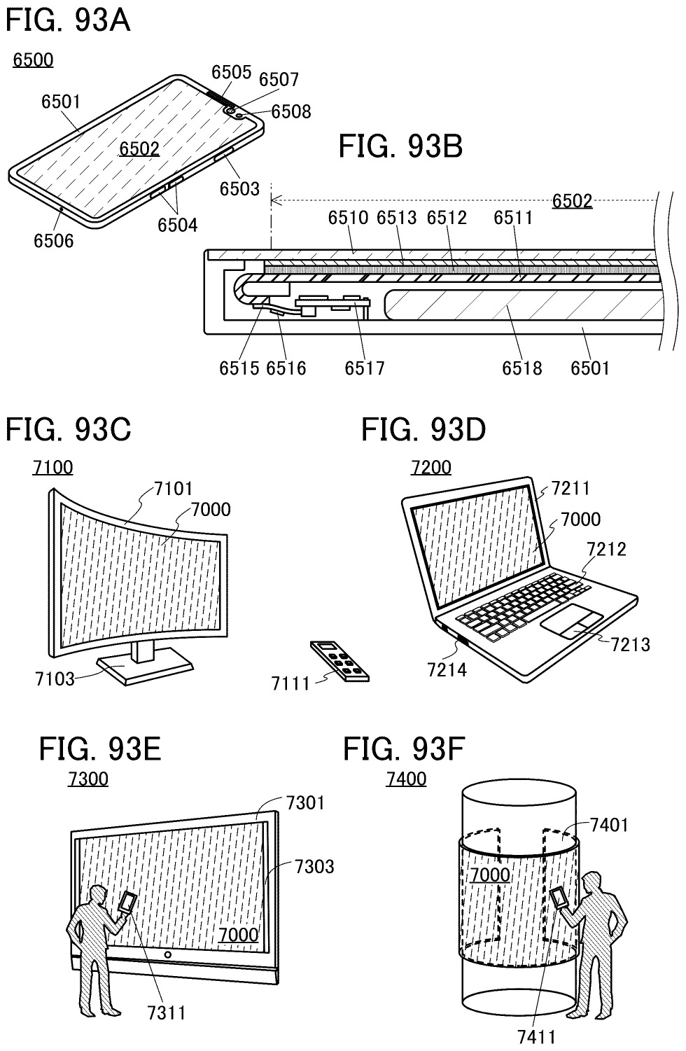

An electronic device 6500 illustrated in FIG. 93A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 93B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 93C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000.

Operation of the television device 7100 illustrated in FIG. 93C can be performed with an operation switch provided in the housing 7101 and a separate remote controller 7111. Alternatively, the display portion 7000 may include a touch sensor, and the television device 7100 may be operated by a touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 93D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000.

FIG. 93E and FIG. 93F illustrate examples of digital signage.

Digital signage 7300 illustrated in FIG. 93E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 93F illustrates digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in each of FIG. 93E and FIG. 93F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, in the case of an application for providing information such as route information or traffic information, usability can be enhanced by intuitive operation.

As illustrated in FIG. 93E and FIG. 93F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

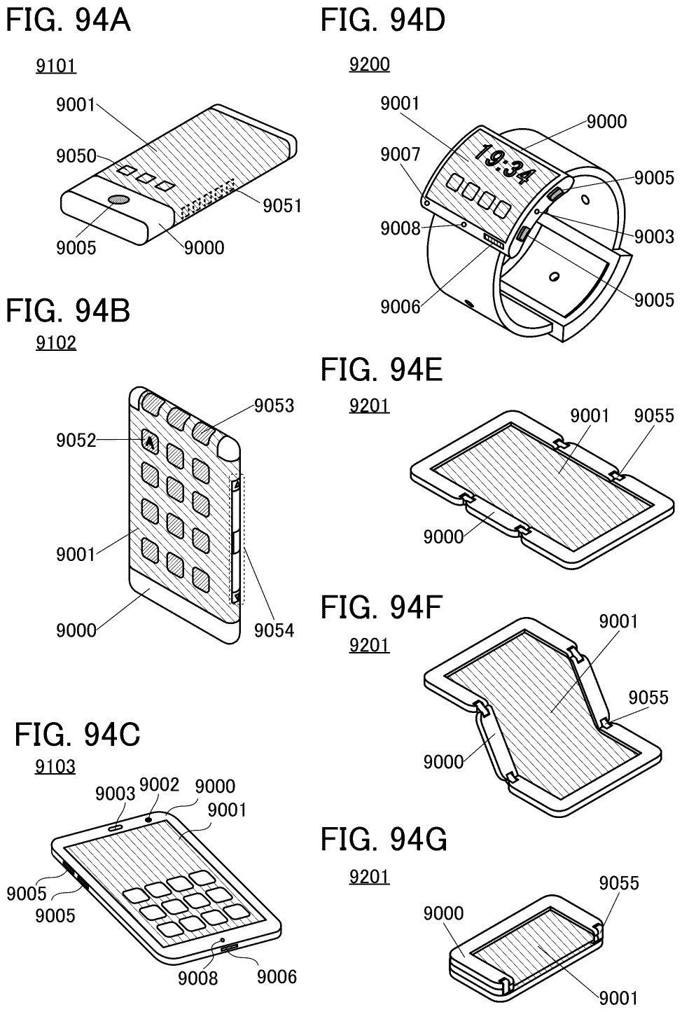

Electronic devices illustrated in FIG. 94A to FIG. 94G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like. The display apparatus of one embodiment of the present invention can be used in the display portions 9001.

The electronic devices illustrated in FIG. 94A to FIG. 94G will be described in detail below.

FIG. 94A is a perspective view of a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display characters and image information on its plurality of surfaces. FIG. 94A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 94B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 94C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 94D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 94E to FIG. 94G are perspective views of a foldable portable information terminal 9201. FIG. 94E is a perspective view illustrating the portable information terminal 9201 that is opened. FIG. 94G is a perspective view illustrating the portable information terminal 9201 that is folded. FIG. 94F is a perspective view illustrating the portable information terminal 9201 that is shifted from one of the states in FIG. 94E and FIG. 94G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

The plurality of structure examples described in this embodiment can be combined with each other as appropriate. This embodiment can be combined with the other embodiments as appropriate.

### REFERENCE NUMERALS

10A: display apparatus, 10B: display apparatus, 10C: display apparatus, 10D: display apparatus, 10E: display apparatus, 10F: display apparatus, 10: display apparatus, 11: scan line driver circuit, 13: signal line driver circuit, 15: power supply circuit, 17: reference potential generation circuit, 20: display portion, 21a: pixel, 21b: pixel, 21: pixel, 23a: subpixel, 23B: subpixel, 23b: subpixel, 23c: subpixel, 23d: subpixel, 23e: subpixel, 23G: subpixel, 23R: subpixel, 23: subpixel, 40A: pixel circuit, 40B: pixel circuit, 40C: pixel circuit, 40D: pixel circuit, 40E: pixel circuit, 40F: pixel circuit, 41a: wiring, 41b: wiring, 41c: wiring, 41d: wiring, 41e: wiring, 41f: wiring, 41g: wiring, 41: wiring, 43a: wiring, 43b: wiring, 43: wiring, 45: wiring, 47: wiring, 48: wiring, 49: wiring, 50: transistor, 51: transistor, 52: transistor, 53: transistor, 54: transistor, 57: capacitor, 58: capacitor, 60B: light-emitting element, 60G: light-emitting element, 60R: light-emitting element, 60: light-emitting element, 61: transistor, 62: transistor, 63: transistor, 64: transistor, 65: transistor, 66: transistor, 67: capacitor, 68: capacitor, 69: liquid crystal element, 101: substrate, 103a: insulating layer, 103b: insulating layer, 103: insulating layer, 105: insulating layer, 111a: conductive layer, 111b: conductive layer, 111c: conductive layer, 111: conductive layer, 112A: conductive layer, 112a: conductive layer, 112B: conductive layer, 112b: conductive layer, 112c: conductive layer, 112f: conductive film, 112: conductive layer, 113_1: semiconductor layer, 113_2: semiconductor layer, 113a: semiconductor layer, 113b: semiconductor layer, 113c: semiconductor layer, 113f:

semiconductor film, 113: semiconductor layer, 115a: conductive layer, 115b: conductive layer, 115c: conductive layer, 115: conductive layer, 119: conductive layer, 121_1: opening, 121_2: opening, 121a: opening, 121b: opening, 121c: opening, 121: opening, 123_1: opening, 123_2: opening, 123a: opening, 123b: opening, 123c: opening, 123: opening, 125a: opening, 125b: opening, 125c: opening, 125d: opening, 125: opening, 127a: opening, 127b: opening, 127: opening, 129: opening, 131: conductive layer, 135: conductive layer, 137: conductive layer, 140: connection portion, 142: adhesive layer, 152: substrate, 161a: tapered portion, 161b: tapered portion, 164: circuit, 165: wiring, 166: conductive layer, 172: FPC, 173: IC, 201: transistor, 204: connection portion, 205B: transistor, 205G: transistor, 205R: transistor, 205: transistor, 211: conductive layer, 213i: channel formation region, 213n: low-resistance region, 213: semiconductor layer, 215: conductive layer, 218: insulating layer, 222a: conductive layer, 222b: conductive layer, 235: insulating layer, 237: insulating layer, 242: connection layer, 308: connection portion, 309: connection layer, 311B: pixel electrode, 311G: pixel electrode, 311R: pixel electrode, 311: pixel electrode, 313B: layer, 313G: layer, 313R: layer, 313: layer, 314: common layer, 315: common electrode, 317: light-blocking layer, 318B: mask layer, 318G: mask layer, 318R: mask layer, 318: mask layer, 323: conductive layer, 324B: conductive layer, 324G: conductive layer, 324p: conductive layer, 324R: conductive layer, 324: conductive layer, 325: insulating layer, 326B: conductive layer, 326G: conductive layer, 326p: conductive layer, 326R: conductive layer, 326: conductive layer, 327: insulating layer, 328: layer, 329B: conductive layer, 329G: conductive layer, 329p: conductive layer, 329R: conductive layer, 329: conductive layer, 330: substrate, 331: protective layer, 341: insulating layer, 342: wiring, 343: liquid crystal layer, 344: conductive layer, 345: insulating layer, 347: spacer, 349B: coloring layer, 349G: coloring layer, 349R: coloring layer, 349: coloring layer, 350: FPC, 353: insulating layer, 380: sensor element, 381: electrode, 382: electrode, 383: electrode, 384: electrode, 387: sensing portion, 395: insulating layer, 396: adhesive layer, 400: memory device, 410: memory portion, 411: word line driver circuit, 413: bit line driver circuit, 415: power supply circuit, 420A: memory cell, 420B: memory cell, 420C: memory cell, 420D: memory cell, 420E: memory cell, 420: memory cell, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a pixel, a power supply circuit, and a scan line driver circuit,
wherein the pixel comprises a first transistor, a second transistor, and a first insulating layer,
wherein the first transistor comprises a first conductive layer, a second conductive layer, a third conductive layer, a first semiconductor layer, and a second insulating layer,
wherein the first insulating layer is provided over the first conductive layer,
wherein the first insulating layer comprises a first opening reaching the first conductive layer,
wherein the first conductive layer is electrically connected to the power supply circuit,
wherein the second conductive layer is provided over the first insulating layer,
wherein the second conductive layer comprises a second opening comprising a region overlapping with the first opening,
wherein the first semiconductor layer is provided to comprise a region in contact with the first conductive layer and a region in contact with the second conductive layer and comprise a region positioned in the first opening and a region positioned in the second opening,
wherein the second insulating layer is provided over the first semiconductor layer to comprise a region positioned in the first opening and a region positioned in the second opening,
wherein the third conductive layer is provided to comprise a region positioned in the first opening and a region positioned in the second opening and comprise a region facing the first semiconductor layer with the second insulating layer therebetween,
wherein the second transistor comprises the second insulating layer, a second semiconductor layer below the second insulating layer, and a fourth conductive layer over the second insulating layer,
wherein the fourth conductive layer comprises a region overlapping with the second semiconductor layer,
wherein the fourth conductive layer is electrically connected to the scan line driver circuit, and
wherein the fourth conductive layer comprises a region overlapping with the first conductive layer with the first insulating layer and the second insulating layer therebetween.

2. The display apparatus according to claim 1,
wherein the second transistor comprises a fifth conductive layer in contact with the second semiconductor layer, and
wherein the fifth conductive layer is electrically connected to the third conductive layer.

3. The display apparatus according to claim 2,
wherein the display apparatus comprises a signal line driver circuit,
wherein the second transistor comprises a sixth conductive layer in contact with the second semiconductor layer, and
wherein the sixth conductive layer is electrically connected to the signal line driver circuit.

4. The display apparatus according to claim 1,
wherein the first semiconductor layer and the second semiconductor layer each comprise a metal oxide.

5. The display apparatus according to claim 4,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.

6. The display apparatus according to claim 1,
wherein the pixel comprises a display element, and
wherein a pixel electrode of the display element is electrically connected to the second conductive layer.

7. The display apparatus according to claim 6,
wherein the display apparatus comprises a reference potential generation circuit,
wherein the pixel comprises a third transistor,
wherein the third transistor comprises a seventh conductive layer, an eighth conductive layer, a ninth conductive layer, a third semiconductor layer, and the second insulating layer,
wherein the first insulating layer is provided over the seventh conductive layer,
wherein the first insulating layer comprises a third opening reaching the seventh conductive layer,
wherein the seventh conductive layer is electrically connected to the pixel electrode,
wherein the eighth conductive layer is provided over the first insulating layer,
wherein the eighth conductive layer comprises a fourth opening comprising a region overlapping with the third opening,
wherein the eighth conductive layer is electrically connected to the reference potential generation circuit,
wherein the third semiconductor layer is provided to comprise a region in contact with the seventh conductive layer and a region in contact with the eighth conductive layer and comprise a region positioned in the third opening and a region positioned in the fourth opening,
wherein the second insulating layer is provided over the third semiconductor layer to comprise a region positioned in the third opening and a region positioned in the fourth opening,
wherein the ninth conductive layer is provided to comprise a region positioned in the third opening and a region positioned in the fourth opening and comprises a region facing the third semiconductor layer with the second insulating layer therebetween,
wherein the ninth conductive layer is electrically connected to the scan line driver circuit, and
wherein the eighth conductive layer comprises a region overlapping with the fourth conductive layer and a region overlapping with the ninth conductive layer.

8. The display apparatus according to claim 7,
wherein the third semiconductor layer comprises a metal oxide.

9. The display apparatus according to claim 8,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.

10. A display apparatus comprising:
a pixel, a scan line driver circuit, and a power supply circuit,
wherein the pixel comprises a first transistor, a second transistor, and a first insulating layer,
wherein the first transistor comprises a first conductive layer, a second conductive layer, a third conductive layer, a first semiconductor layer, and a second insulating layer,
wherein the first insulating layer is provided over the first conductive layer,
wherein the first insulating layer comprises a first opening reaching the first conductive layer,
wherein the second conductive layer is provided over the first insulating layer,
wherein the second conductive layer comprises a second opening comprising a region overlapping with the first opening,
wherein the first semiconductor layer is provided to comprise a region in contact with the first conductive layer and a region in contact with the second conductive layer and comprise a region positioned in the first opening and a region positioned in the second opening,
wherein the second insulating layer is provided over the first semiconductor layer to comprise a region positioned in the first opening and a region positioned in the second opening,
wherein the third conductive layer is provided to comprise a region positioned in the first opening and a region positioned in the second opening and comprise a region facing the first semiconductor layer with the second insulating layer therebetween,
wherein the third conductive layer is electrically connected to the scan line driver circuit,
wherein the second transistor comprises a fourth conductive layer, a fifth conductive layer, a sixth conductive layer, a second semiconductor layer, and the second insulating layer,
wherein the first insulating layer is provided over the fourth conductive layer,
wherein the first insulating layer comprises a third opening reaching the fourth conductive layer,
wherein the fourth conductive layer is electrically connected to the power supply circuit,
wherein the fifth conductive layer is provided over the first insulating layer,
wherein the fifth conductive layer comprises a fourth opening comprising a region overlapping with the third opening,
wherein the second semiconductor layer is provided to comprise a region in contact with the fourth conductive layer and a region in contact with the fifth conductive layer and comprise a region positioned in the third opening and a region positioned in the fourth opening,
wherein the second insulating layer is provided over the second semiconductor layer to comprise a region positioned in the third opening and a region positioned in the fourth opening,
wherein the sixth conductive layer is provided to comprise a region positioned in the third opening and a region positioned in the fourth opening and comprise a region facing the second semiconductor layer with the second insulating layer therebetween, and
wherein the third conductive layer comprises a region overlapping with the fourth conductive layer with the first insulating layer and the second insulating layer therebetween.

11. The display apparatus according to claim 10,
wherein the display apparatus comprises a signal line driver circuit,
wherein the first conductive layer is electrically connected to the signal line driver circuit, and
wherein the first conductive layer comprises a region overlapping with the third conductive layer.

12. The display apparatus according to claim 10,
wherein the second conductive layer is electrically connected to the sixth conductive layer.

13. The display apparatus according to claim 10,
wherein the first semiconductor layer and the second semiconductor layer each comprise a metal oxide.

14. The display apparatus according to claim 13,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.

15. The display apparatus according to, claim 10,
wherein the pixel comprises a display element, and
wherein a pixel electrode of the display element is electrically connected to the fifth conductive layer.

16. The display apparatus according to claim 15,
wherein the display apparatus comprises a reference potential generation circuit,
wherein the pixel comprises a third transistor,
wherein the third transistor comprises a seventh conductive layer, an eighth conductive layer, a ninth conductive layer, a third semiconductor layer, and the second insulating layer,
wherein the first insulating layer is provided over the seventh conductive layer,
wherein the first insulating layer comprises a fifth opening reaching the seventh conductive layer,
wherein the seventh conductive layer is electrically connected to the pixel electrode,
wherein the eighth conductive layer is provided over the first insulating layer,
wherein the eighth conductive layer comprises a sixth opening comprising a region overlapping with the fifth opening,
wherein the eighth conductive layer is electrically connected to the reference potential generation circuit,
wherein the third semiconductor layer is provided to comprise a region in contact with the seventh conductive layer and a region in contact with the eighth conductive layer and comprise a region positioned in the fifth opening and a region positioned in the sixth opening,
wherein the second insulating layer is provided over the third semiconductor layer to comprise a region positioned in the fifth opening and a region positioned in the sixth opening,
wherein the ninth conductive layer is provided to comprise a region positioned in the fifth opening and a region positioned in the sixth opening and comprise a region facing the third semiconductor layer with the second insulating layer therebetween,
wherein the ninth conductive layer is electrically connected to the scan line driver circuit, and
wherein the eighth conductive layer comprises a region overlapping with the third conductive layer and a region overlapping with the ninth conductive layer.

17. The display apparatus according to claim 16,
wherein the third semiconductor layer comprises a metal oxide.

18. The display apparatus according to claim 17,
wherein the metal oxide comprises indium, zinc, and M, and
wherein M is one or more kinds selected from aluminum, titanium, gallium, germanium, tin, yttrium, zirconium, lanthanum, cerium, neodymium, and hafnium.
